(19) United States
(12) Patent Application Publication
(10) Pub. No.: US 2026/0334078 A1
(43) Pub. Date: Oct. 22, 2026

(54) LIGHT EMITTING ELEMENT, FUSED POLYCYCLIC COMPOUND FOR THE SAME, AND ELECTRONIC APPARATUS INCLUDING THE SAME

(71) Applicant: Samsung Display Co., Ltd., Yongin-si (KR)

(72) Inventors: Yasuhiko ASHIKARI, Yokohama-shi (JP); Keigo HOSHI, Yokohama-shi (JP); Nobutaka AKASHI, Yokohama-shi (JP); JEONGEUN KIM, Yongin-si (KR)

(21) Appl. No.: 19/441,762

(22) Filed: Jan. 6, 2026

(30) Foreign Application Priority Data
Apr. 4, 2025 (JP) 2025-062272

(51) Int. Cl. H10K 85/60; C07F 5/02; C09K 11/02; C09K 11/06; H10K 50/12; H10K 85/30

(52) U.S. Cl. CPC H10K 85/658; C07F 5/027; C09K 11/02; C09K 11/06; H10K 85/346; H10K 85/6572; C09K 2211/1007; C09K 2211/1018; H10K 50/12

(57) ABSTRACT

A light emitting element includes a first electrode, a second electrode on the first electrode, and an emission layer between the first electrode and the second electrode. The emission layer includes a first compound represented by Formula 1.

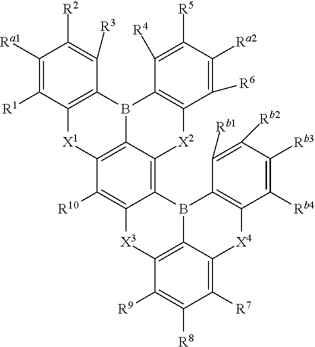

### CROSS-REFERENCE TO RELATED APPLICATION

The present application claims priority to and the benefit of Japanese Patent Application No. 2025-062272, filed on Apr. 4, 2025, in the Japan Patent Office, the entire disclosure of which is incorporated herein by reference.

### BACKGROUND

### 1. Field

One or more embodiments of the present disclosure herein relate to a light emitting element, a fused polycyclic compound used therein, and an electronic apparatus including the light emitting element.

### 2. Description of the Related Art

An organic electroluminescent display device, which include organic electroluminescent elements, has been used as a display device in electronic apparatuses. The organic electroluminescent display device is a display device including self-luminescent light emitting elements in which holes and electrons are respectively injected from a first electrode and a second electrode into an emission layer under a driving voltage and light emits through a light emitting material of the emission layer.

When applying light emitting elements to display devices, improvements in light efficiency and operational lifespan are desired or required, and thus there is continued demand for the development of materials for light emitting elements that may stably achieve such improvements.

### SUMMARY

One or more embodiments of the present disclosure are directed toward a light emitting element having improved light emitting efficiency and lifespan.

One or more embodiments of the present disclosure are directed toward a fused polycyclic compound that has improved quantum efficiency and material stability.

One or more embodiments of the present disclosure are directed toward an electronic apparatus having excellent or suitable display quality by including a light emitting element with improved light emitting efficiency and lifespan.

Additional aspects will be set forth in part in the description which follows and, in part, will be apparent from the description, or may be learned by practice of the presented embodiments.

One or more embodiments of the present disclosure provides a fused polycyclic compound represented by Formula 1.

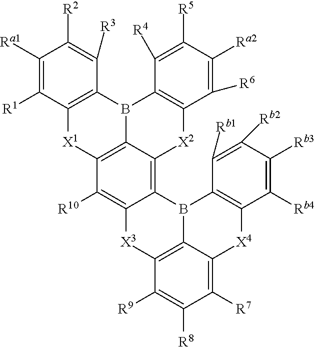

In Formula 1, X^{a} to X^{d} may each independently be O, S, or NR^{X}, R^{X} is a hydrogen atom, a deuterium atom, a halogen atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 30 ring-forming carbon atoms, or be represented by Formula x, R^{a1} and R^{a2} may each independently be a substituted or unsubstituted alkyl group of 1 to 20 carbon atoms, or a substituted or unsubstituted cycloalkyl group of 3 to 30 ring-forming carbon atoms, R¹ to R¹⁰ and R^{b1} to R^{b4} may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and at least one selected from among R^{b1} to R^{b4} is a substituted or unsubstituted aryl group of 6 to 30 ring-forming carbon atoms.

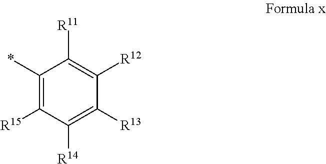

In Formula x, R¹¹ to R¹⁵ may each independently be a hydrogen atom, a deuterium atom, a halogen atom, a substituted or unsubstituted alkyl group of 1 to 20 carbon atoms, a substituted or unsubstituted cycloalkyl group of 3 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring.

Formula 1 above may be represented by one selected from among Formula 1-1 to Formula 1-5.

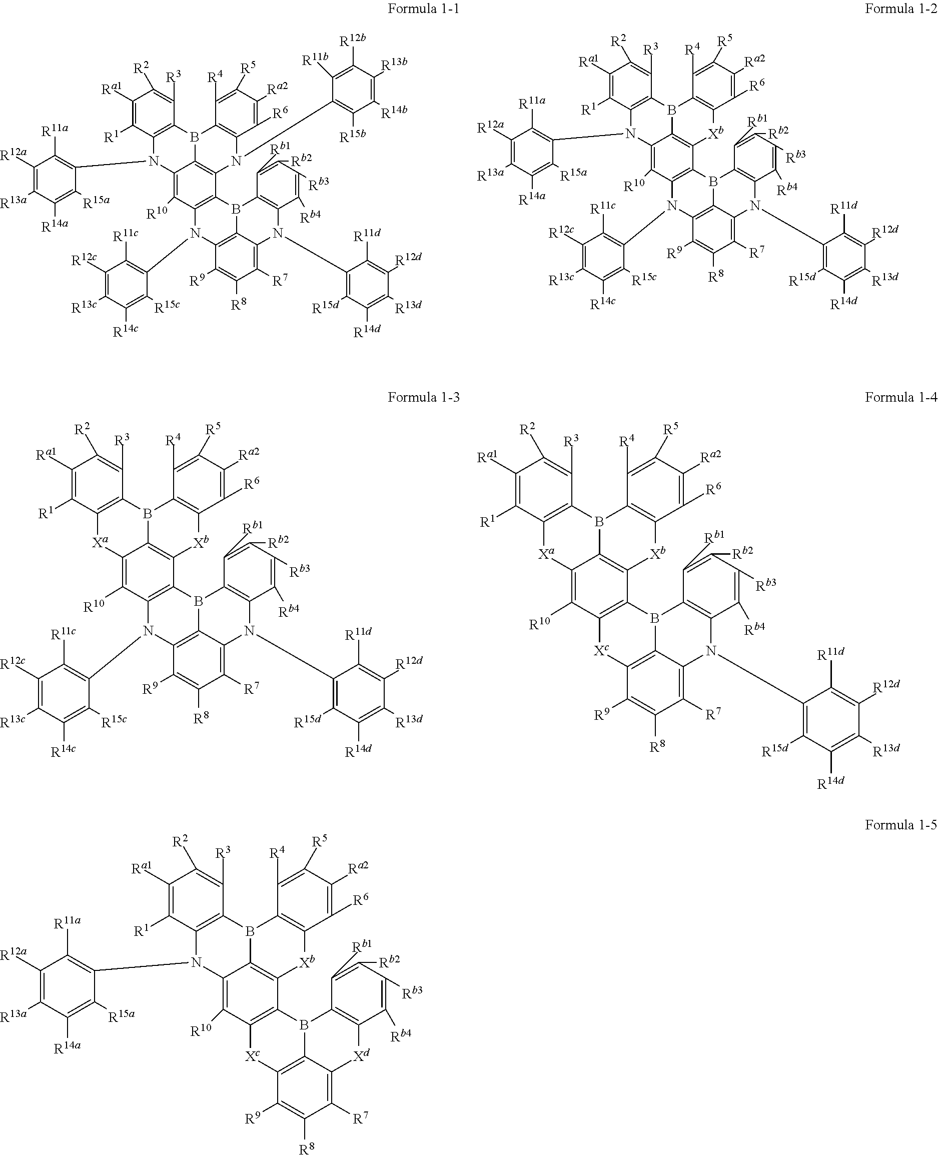

In Formula 1-1 to Formula 1-5, R^{11a} to R^{15a}, R^{11b} to R^{15b}, R^{11c} to R^{15c}, and R^{11d} to R^{15d} may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring, and X^{a} to X^{d} and R¹ to R¹⁰ may each independently be the same as defined in Formula 1.

In Formula 1, at least one selected from among R^{b1} to R^{b4} may be represented by Formula b.

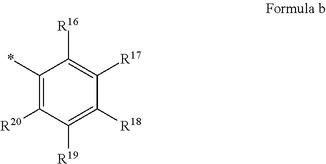

In Formula b, R¹⁶ to R²⁰ may each independently be a hydrogen atom, a deuterium atom, a halogen atom, a cyano group, a substituted or unsubstituted thio group, a substituted or unsubstituted oxy group of 1 to 20 carbon atoms, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring.

In Formula 1, R^{a1} and R^{a2} may each independently be a substituted or unsubstituted methyl group, a substituted or unsubstituted ethyl group, a substituted or unsubstituted propyl group, a substituted or unsubstituted isopropyl group, a substituted or unsubstituted isobutyl group, a substituted or unsubstituted t-butyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted cycloheptyl group, a substituted or unsubstituted bicyclopentyl group, a substituted or unsubstituted norbornyl group, or a substituted or unsubstituted adamantyl group.

In Formula 1, R⁸ may be a substituted or unsubstituted alkyl group of 1 to 20 carbon atoms, or a substituted or unsubstituted aryl group of 6 to 30 ring-forming carbon atoms.

In one or more embodiments, at least one of hydrogen atoms of the compound represented by Formula 1 may be substituted with a deuterium atom.

In one or more embodiments, the fused polycyclic compound represented by Formula 1 may be any one selected from among the compounds in Compound Group 1.

According to one or more embodiments of the present disclosure, a light emitting element includes: a first electrode; a second electrode on (e.g., arranged on) the first electrode; and an emission layer between (e.g., arranged between) the first electrode and the second electrode and including a fused polycyclic compound represented by Formula 1.

The emission layer may further include at least one selected from among a second compound represented by Formula HT-1 and a third compound represented by Formula ET-1.

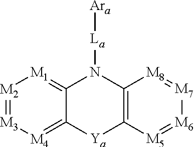

In Formula HT-1 above, M₁ to Mₐ may each independently be N or CRₐ₁₁, L_{q1} is a direct linkage, a substituted or unsubstituted arylene group of 6 to 30 ring-forming carbon atoms, or a substituted or unsubstituted heteroarylene group of 2 to 30 ring-forming carbon atoms, Yₐ is a direct linkage, CRₐ₁₂Rₐ₁₃, or SiRₐ₁₄Rₐ₁₅, Arₐ is a substituted or unsubstituted aryl group of 6 to 30 ring-forming carbon atoms, or a substituted or unsubstituted heteroaryl group of 2 to 30 ring-forming carbon atoms, and Rₐ₁₁ to Rₐ₁₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and/or be combined with an adjacent group to form a ring.

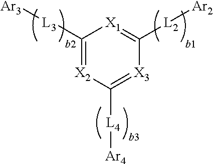

In Formula ET-1, at least one selected from among Zₐ to Z_{c} is N, and the remainder are CRₐ₁₆, Rₐ₁₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms, b11 to b13 may each independently be an integer of 0 to 10, Ar_{b} to Arₐ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and L_{q2} to L_{q4} may each independently be a direct linkage, a substituted or unsubstituted arylene group of 6 to 30 ring-forming carbon atoms, or a substituted or unsubstituted heteroarylene group or 2 to 30 ring-forming carbon atoms.

The emission layer may further include a fourth compound represented by Formula D-1.

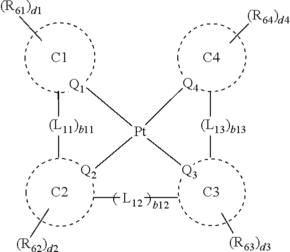

In Formula D-1, Q to 04 may each independently be C or N, C1 to C4 may each independently be a substituted or unsubstituted hydrocarbon ring of 5 to 30 ring-forming carbon atoms, or a substituted or unsubstituted heterocycle of 2 to 30 ring-forming carbon atoms, L₁₁ to L₁₃ may each independently be a direct linkage,

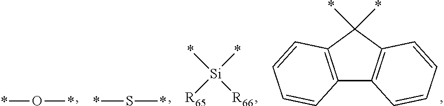

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b21 to b23 may each independently be 0 or 1, and R₆₁ to R₆₄, R_{b5}, and R_{b6} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and d1 to d4 may each independently be an integer of 0 to 4.

In one or more embodiments, the emission layer may be to emit delayed fluorescence.

In one or more embodiments, the emission layer may be to emit blue light.

In one or more embodiments, at least one hydrogen atom of the first compound represented by Formula 1 may be substituted with a deuterium atom.

In one or more embodiments, the first compound may include at least one selected from among the compounds in Compound Group 1.

In one or more embodiments, the first compound serves as a dopant in an emission layer that includes one or more host materials and optionally a sensitizer.

According one or more embodiments of the present disclosure, an electronic apparatus includes a display module containing a plurality of light emitting elements, and at least one of the plurality of light emitting elements includes a first electrode, a second electrode on (e.g., arranged on) the first electrode, and an emission layer between (e.g., arranged between) the first electrode and the second electrode and containing the fused polycyclic compound according to one or more embodiments of the present disclosure.

In one or more embodiments, the electronic apparatus may include a plurality of display devices that are independently controlled or selected and display images, and at least one selected from among the plurality of display devices may include the display module.

In one or more embodiments, the electronic apparatus may further include at least one among a processor, a memory, or a power module.

In one or more embodiments, the electronic apparatus may be at least a television, a monitor, an outdoor billboard, a personal computer, a laptop computer, a personal digital assistant, a vehicle device, a game console, a smartphone, a tablet computer, a smartwatch, a head-mounted display, or a camera.

For example, in one or more embodiments, the organic light-emitting element includes an emission layer including a fused polycyclic compound represented by Formula 1, which functions as a dopant and is configured to emit delayed fluorescence, such as blue light. The emission layer may further include one or more host compounds, such as a hole-transporting host and/or an electron-transporting host, and optionally a sensitizer compound to enhance energy transfer and emission efficiency. The compound of Formula 1 may be deuterated to improve stability and device lifetime. The disclosed compounds and device structures are suitable for integration into electronic apparatuses, display modules of televisions, monitors, smartphones, and/or other image display devices. The embodiments provide improved light emission efficiency, color purity, and operational lifespan, addressing longstanding challenges in organic electroluminescent display technologies.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a block diagram of an electronic apparatus according to one or more embodiments of the present disclosure;

FIG. 2 illustrates schematic diagrams of electronic apparatus according to one or more embodiments of the present disclosure;

FIG. 3 is a plan view showing a display module according to one or more embodiments of the present disclosure;

FIG. 4 is a cross-sectional view showing a portion corresponding to the line I-I′ in FIG. 3 one or more embodiments of the present disclosure;

FIG. 5 is a cross-sectional view schematically showing a light emitting element according to one or more embodiments of the present disclosure;

FIG. 6 is a cross-sectional view schematically showing a light emitting element according to one or more embodiments of the present disclosure;

FIG. 7 is a cross-sectional view schematically showing a light emitting element according to one or more embodiments of the present disclosure;

FIG. 8 is a cross-sectional view schematically showing a light emitting element according to one or more embodiments of the present disclosure;

FIG. 9 is a cross-sectional view schematically showing a light emitting element according to one or more embodiments of the present disclosure;

FIG. 10 shows the absorption spectra of Compound X-10 and Compound X-10′;

FIG. 11A is an image showing the highest occupied molecular orbital (HOMO) orbital distribution of Compound X-9;

FIG. 11B is an image showing the lowest unoccupied molecular orbital (LUMO) orbital distribution of Compound X-9;

FIG. 12A is an image showing the HOMO orbital distribution of Compound C-16;

FIG. 12B is an image showing the LUMO orbital distribution of Compound C-16;

FIG. 13 is a cross-sectional view showing a display module according to one or more embodiments of the present disclosure;

FIG. 14 is a cross-sectional view showing a display module according to one or more embodiments of the present disclosure;

FIG. 15 is a cross-sectional view showing a display module according to one or more embodiments of the present disclosure;

FIG. 16 is a cross-sectional view showing a display module according to one or more embodiments of the present disclosure;

FIG. 17 is a perspective view of an electronic apparatus according to one or more embodiments of the present disclosure;

FIG. 18 is a perspective view of an electronic apparatus according to one or more embodiments of the present disclosure; and

FIG. 19 is a diagram showing the interior of a vehicle in which an electronic apparatus according to one or more embodiments of the present disclosure is arranged.

### DETAILED DESCRIPTION

The present disclosure may be modified in one or more suitable ways and may take one or more suitable forms, and specific/example embodiments are illustrated in the drawings and will be described in more detail in the text. However, this is not intended to limit the present disclosure to a specific disclosure form, but should be understood to include all modifications, equivalents, or substitutes included in the teachings and technical scope of the disclosure.

In this disclosure, it will be understood that if (e.g., when) an element (or a region, a layer, a portion, and/or the like) is referred to as being “on”, “connected to” or “coupled to” another element, it may be directly arranged on, connected to, or coupled to the other element, or other elements may be arranged therebetween. In contrast, “directly on” may refer to that there are no additional layers, films, regions, plates, and/or the like, between the element and the other element. For example, “directly on” or “directly under” may refer to two layers or two members are arranged without utilizing an additional member such as an adhesive member therebetween.

In the present disclosure, like reference numerals or symbols refer to like elements throughout, and duplicative descriptions thereof may not be provided for conciseness. In the drawings, the thickness, ratio, and/or size of an element may be exaggerated or reduced for effectively describing the technical contents. As used herein, the term “and/or” or “or” include any and all combinations of one or more of the associated listed elements.

It will be understood that, although the terms “first”, “second”, and/or the like may be used herein to describe one or more suitable elements, the elements are not to be limited by these terms. These terms are only used to distinguish one element, component, region, layer, or section from another element, component, region, layer or section. For instance, a first element, component, region, layer or section discussed herein could be termed a second element, component, region, layer or section without departing from the scope and teaching of the disclosure. Similarly, a second element, component, region, layer, or section could be termed a first element, component, region, layer, or section. In this specification, the singular expressions “a”, “an” and “the” are intended to include the plural forms as well, unless the context clearly indicates otherwise. Further, the utilization of “may” when describing embodiments of the present disclosure refers to “one or more embodiments of the present disclosure”.

In addition, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

It will be further understood that the terms “comprise(s)/comprising”, “include(s)/including”, and/or “has(have)/having”, if (e.g., when) used in this disclosure, specify the presence of stated features, numbers, steps, operations, elements, components or combinations thereof, but do not preclude the possibility of the presence or addition of one or more other features, numbers, steps, operations, elements, components, and/or combinations thereof. Additionally, the terms “comprise(s)/comprising,” “include(s)/including,” “has(have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this disclosure, the term “substituted or unsubstituted” corresponds to substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the illustrated substituents may be substituted or unsubstituted. For example, a biphenyl group may be interpreted as an aryl group or a phenyl group substituted with a phenyl group.

In this disclosure, the term “forming a ring via the combination with an adjacent group” may refer to forming a substituted or unsubstituted hydrocarbon ring, or a substituted or unsubstituted heterocycle via the combination with an adjacent group. The hydrocarbon ring may include an aliphatic hydrocarbon ring and/or an aromatic hydrocarbon ring. The heterocycle includes an aliphatic heterocycle and/or an aromatic heterocycle. The hydrocarbon ring and the heterocycle may each be a monocyclic ring or polycyclic ring. In one or more embodiments, the ring formed by adjacent groups being bonded to each other may be combined with another ring to form a spiro structure.

In this disclosure, the term “adjacent group” may refer to a substituent substituted for an atom which is directly combined with an atom substituted with the corresponding substituent, another substituent substituted for an atom which is substituted with the corresponding substituent, or a substituent sterically positioned at the nearest position to the corresponding substituent. For example, in 1,2-dimethylbenzene, two methyl groups may be interpreted as “adjacent groups” to each other, and in 1,1-diethylcyclopentene, two ethyl groups may be interpreted as “adjacent groups” to each other. In addition, in 4,5-dimethylphenanthrene, two methyl groups may be interpreted as “adjacent groups” to each other.

In this disclosure, examples of a halogen atom may include fluorine, chlorine, bromine, or iodine.

In this disclosure, an alkyl group may be a linear or branched type (kind). The carbon number of the alkyl group may be 1 to 60, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, and/or the like, but the embodiments of the present disclosure are not limited thereto.

In this disclosure, a cycloalkyl group may refer to a ring-type (kind) alkyl group. The carbon number of the cycloalkyl group may be 3 to 60, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicyclopentyl group, a bicycloheptyl group, and/or the like, but the embodiments of the present disclosure are not limited thereto.

In this disclosure, an alkenyl group refers to a hydrocarbon group including one or more carbon-carbon double bonds in the middle or at the terminal of an alkyl group having a carbon number of 2 or more. The alkenyl group may be a linear chain or a branched chain. The carbon number in the alkenyl group is not specifically limited, but may be 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, and/or the like, but the embodiments of the present disclosure are not limited thereto.

In this disclosure, an alkynyl group refers to a hydrocarbon group including one or more carbon-carbon triple bonds in the middle or at the terminal end of an alkyl group having a carbon number of 2 or more. The alkynyl group may be a linear chain or a branched chain. The carbon number in the alkynyl group is not specifically limited, but may be 2 to 30, 2 to 20, or 2 to 10. Examples of the alkynyl group include an ethynyl group, a propynyl group, and/or the like, but the embodiments of the present disclosure are not limited thereto.

In this disclosure, a hydrocarbon ring group refers to an optional functional group or substituent derived from an aliphatic hydrocarbon ring. The hydrocarbon ring group may be a saturated hydrocarbon ring group of 5 to 20 ring-forming carbon atoms.

In this disclosure, an aryl group refers to an optional functional group or substituent derived from an aromatic hydrocarbon ring. The aryl group may be a monocyclic aryl group or a polycyclic aryl group. The carbon number for forming rings in the aryl group may be 6 to 60, 6 to 30, 6 to 20, or 6 to 15. Examples of the aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl, and/or the like, but the embodiments of the present disclosure are not limited thereto.

In this disclosure, a fluorenyl group may be substituted, and two substituents may be combined with each other to form a spiro structure. Examples of a substituted fluorenyl group are as follows, but embodiments of the disclosure are not limited thereto.

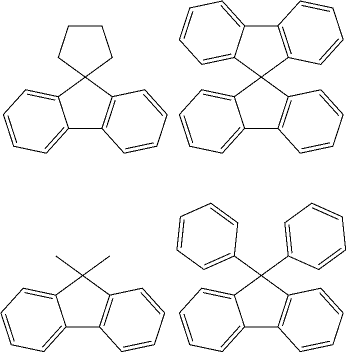

In this disclosure, a heterocyclic group refers to an optional functional group or substituent derived from a ring including one or more selected from among B, O, N, P, S, Si, and Se as heteroatoms. The heterocyclic group may include an aliphatic heterocyclic group and/or an aromatic heterocyclic group. The aromatic heterocyclic group may be a heteroaryl group. The aliphatic heterocyclic group and the aromatic heterocyclic group may each be a monocyclic ring or a polycyclic ring.

In this disclosure, a heterocyclic group may include one or more selected from among B, O, N, P, S, Si, and Se as heteroatoms. If (e.g., when) the heterocyclic group includes two or more heteroatoms, two or more heteroatoms may be the same as or different from each other. The heterocyclic group may be a monocyclic heterocyclic group or a polycyclic heterocyclic group and has the concept including a heteroaryl group. The carbon number for forming rings of the heterocyclic group may be 2 to 60, 2 to 30, 2 to 20, and 2 to 10.

In this disclosure, an aliphatic heterocyclic group may include one or more selected from among B, O, N, P, S, Si, and Se as heteroatoms. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiments of the present disclosure are not limited thereto.

In this disclosure, a heteroaryl group may include one or more selected from among B, O, N, P, S, Si, and Se as heteroatoms. If (e.g., when) the heteroaryl group includes two or more heteroatoms, two or more heteroatoms may be the same as or different from each other. The heteroaryl group may be a monocyclic heterocyclic group or polycyclic heterocyclic group. The carbon number for forming rings of the heteroaryl group may be 2 to 60, 2 to 30, 2 to 20, or 2 to 10. Examples of the heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyridine, pyrido pyrazine, pyrazino pyrazine, isoquinoline, indole, carbazole, N-arylcarbazole, N-heteroarylcarbazole, N-alkylcarbazole, benzoxazole, benzimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, and/or the like, but the embodiments of the present disclosure are not limited thereto.

In this disclosure, the same explanation on the aryl group described above may be applied to an arylene group, except that the arylene group is a divalent group. The same explanation on the heteroaryl group described above may be applied to a heteroarylene group except that the heteroarylene group is a divalent group.

In this disclosure, a silyl group includes an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiments of the present disclosure are not limited thereto.

In this disclosure, the carbon number of a carbonyl group is not specifically limited, but the carbon number may be 1 to 40, 1 to 30, or 1 to 20. For example, the carbonyl group may have the structures, but the embodiments of the present disclosure are not limited thereto.

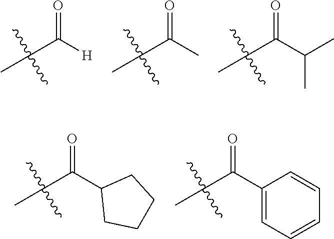

In this disclosure, the carbon number of a sulfinyl group and sulfonyl group is not specifically limited but may be 1 to 30. The sulfinyl group may include an alkyl sulfinyl group and/or an aryl sulfinyl group. The sulfonyl group may include an alkyl sulfonyl group and/or an aryl sulfonyl group.

In this disclosure, a thio group may include an alkyl thio group and/or an aryl thio group. The thio group may refer to the alkyl group or aryl group described above combined with a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but the embodiments of the present disclosure are not limited thereto.

In this disclosure, an oxy group may refer to the alkyl group or aryl group described above which is combined with an oxygen atom. The oxy group may include an alkoxy group and/or an aryl oxy group. The alkoxy group may be a linear, branched or cyclic chain. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like. However, embodiments of the disclosure are not limited thereto.

In this disclosure, a boron group may refer to the alkyl group or aryl group described above combined with a boron atom. The boron group includes an alkyl boron group and/or an aryl boron group. Examples of the boron group include a dimethyl boron group, a diethyl boron group, a t-butyl methyl boron group, a diphenyl boron group, a phenyl boron group, and/or the like, but the embodiments of the present disclosure are not limited thereto.

In this disclosure, the carbon number of an amine group is not specifically limited but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, and/or the like, but the embodiments of the present disclosure are not limited thereto.

In this disclosure, alkyl groups in an alkylthiol group, alkylsulfoxy group, alkylaryl group, alkylamino group, alkyl boron group, alkyl silyl group, and alkyl amine group may be the same as the illustrations of the alkyl group described above.

In this disclosure, aryl groups in an aryloxy group, arylthio group, arylsulfoxy group, arylamino group, aryl boron group, aryl silyl group, and aryl amine group may be the same as the illustrations of the aryl group described above.

In this disclosure, a direct linkage may refer to a single bond.

In this disclosure,

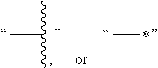

each refer to a position to be connected.

Hereinafter, embodiments of the disclosure will be explained referring to the accompanying drawings.

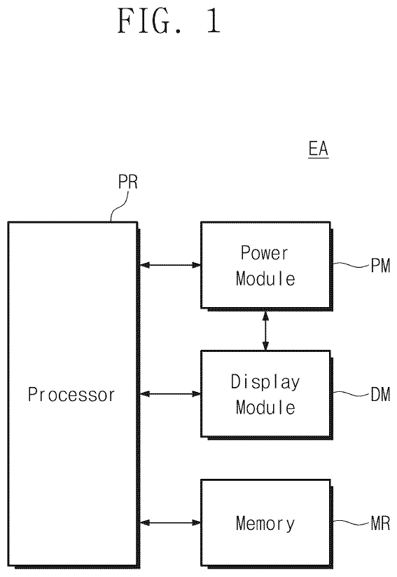

FIG. 1 is a block diagram of an electronic apparatus according one or more embodiments of the present disclosure. Referring to FIG. 1, an electronic apparatus EA according to one or more embodiments may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information necessary for the operation of the processor PR and/or the display module DM. When the processor PR executes an application stored in the memory MR, an image data signal and/or an input control signal is transmitted to the display module DM, and the display module DM may process the received signal and output image information through a display screen. The display module DM may include a display panel that displays an image.

The power module PM may include a power supply module, such as a power adapter or a battery device, and a power conversion module that converts power supplied by the power supply module to generate power desired or required for the operation of the electronic apparatus EA.

At least one of the components of the electronic apparatus EA described herein may be included in the display module according to one or more embodiments, which will be described in more detail later, or in the display device of one or more embodiments including the display module. In one or more embodiments, some of individual modules functionally included in one module may be included in a display device and other may be provided separately from the display device. For example, a display device may include a display module DM, and a processor PR, a memory MR, and a power module PM may be provided in the form of other devices within the electronic apparatus EA other than the display device.

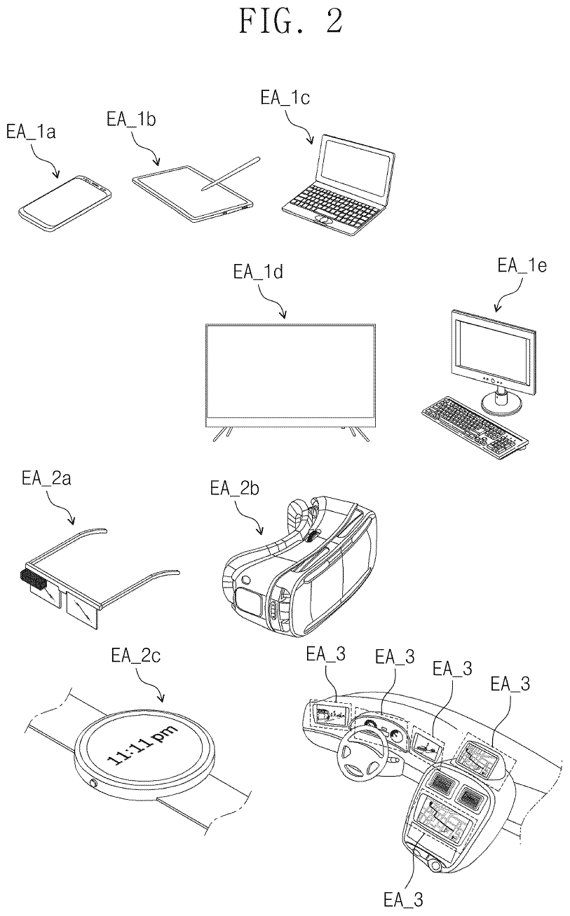

FIG. 2 illustrates schematic diagrams of embodiments of one or more suitable embodiments of the electronic apparatus.

Referring to FIG. 2, one or more suitable electronic apparatuses including a display module according to one or more embodiments may include not only electronic apparatuses for displaying images, such as a smart phone EA_1a, a tablet PC EA_1b, a laptop EA_1c, a TV EA_1d, and a desk monitor EA_1e, but also wearable electronic apparatuses, such as smart glasses EA_2a, a head-mounted display EA_2b, and a smart watch EA_2c, and vehicle electronic apparatuses EA_3, such as a dashboard of a car, center fascia, a Center Information Display (CID) arranged on a dashboard, and a room mirror display, and/or the like, of a vehicle.

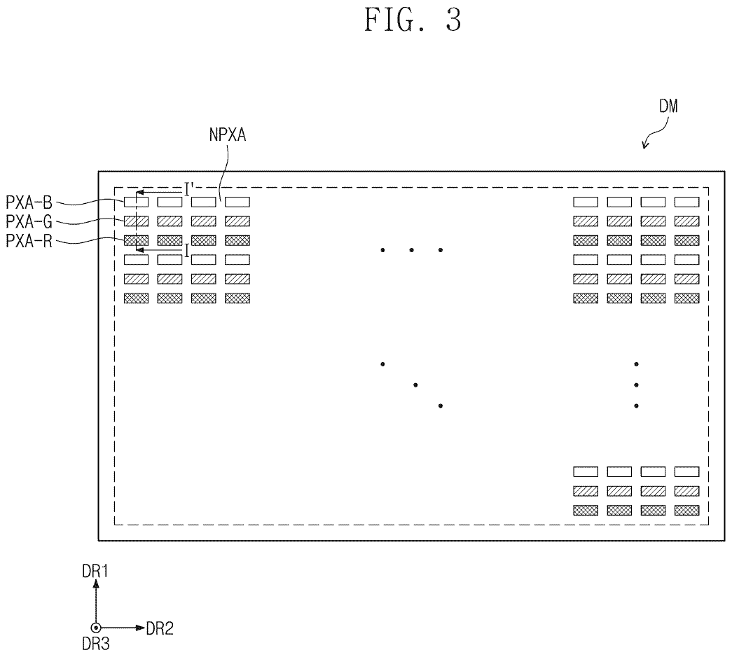

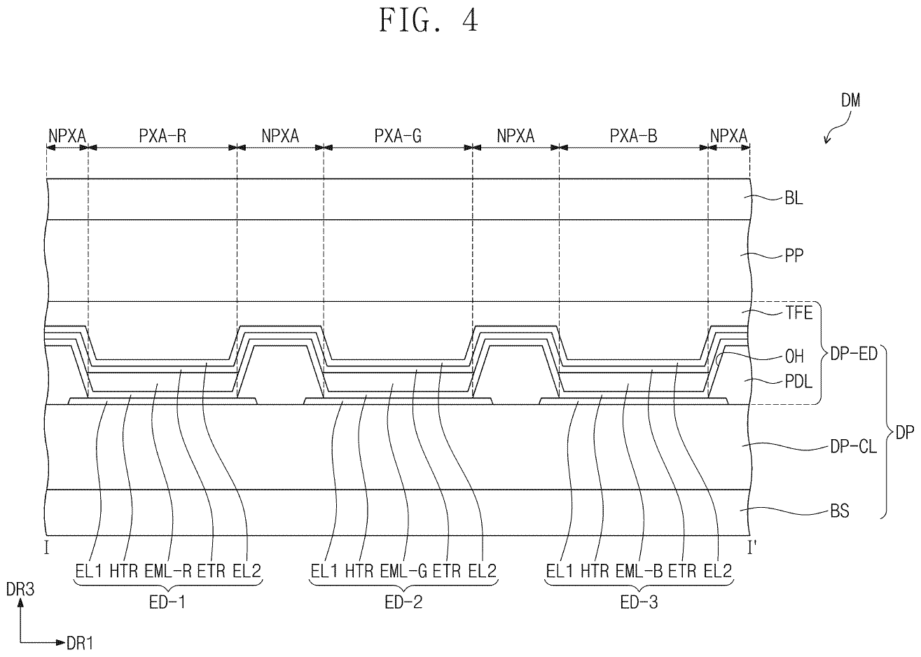

FIG. 3 is a plan view showing a display module DM according to one or more embodiments. FIG. 4 is a cross-sectional view of a display module DM according to one or more embodiments of the present disclosure. FIG. 4 is a cross-sectional view showing a portion corresponding to the line I-I′ in FIG. 3.

The display module DM may include a plurality of light emitting elements ED-1, ED-2 and ED-3. In one or more embodiments, the display module DM may further include a display panel DP including a plurality of light emitting elements ED-1, ED-2, and ED-3 and an optical layer PP arranged on the display panel DP.

The display panel DP may include a base layer BS, a circuit layer DP-CL provided on the base layer BS and a display element layer DP-ED. The display element layer DP-ED may include a pixel definition layer PDL, light emitting elements ED-1, ED-2, and ED-3 arranged in the pixel definition layer PDL, and an encapsulation layer TFE arranged on the light emitting elements ED-1, ED-2 and ED-3.

The base layer BS may be a member providing a base surface on which the display element layer DP-ED is arranged. The base layer BS may be a glass substrate, a metal substrate, a plastic substrate, and/or the like. However, one or more embodiments of the disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include multiple transistors. Each of the transistors may include a control electrode, an input electrode, and an output electrode. For example, in one or more embodiments, the circuit layer DP-CL may include switching transistors and driving transistors for driving the light emitting elements ED-1, ED-2, and ED-3 of the display element layer DP-ED.

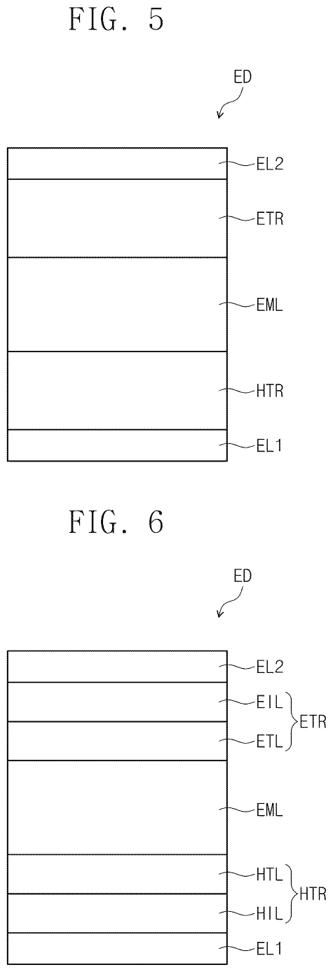

Each of the light emitting elements ED-1, ED-2, and ED-3 may independently have the structures of light emitting elements ED of according to one or more embodiments shown in FIGS. 5-9. Each of the light emitting elements ED-1, ED-2, and ED-3 may include a first electrode EL1, a hole transport region HTR, a respective emission layer EML-R, EML-G, or EML-B, an electron transport region ETR, and a second electrode EL2.

An optical layer PP is arranged on the display panel DP to control the light reflected from the display panel DP due to external light. The optical layer PP may include, for example, a polarizing layer or a color filter layer. In one or more embodiments, the optical layer PP may not be provided in the display module DM.

A base substrate BL may be arranged on the optical layer PP. The base substrate BL may be a member providing a base surface where the optical layer PP is arranged. The base substrate BL may be a glass substrate, a metal substrate, a plastic substrate, and/or the like. However, embodiments of the present disclosure are not limited thereto, and the base substrate BL may be an inorganic layer, an organic layer or a composite material layer. In one or more embodiments, the base substrate BL may not be provided.

The display module DM according to one or more embodiments may further include a filling layer. The filling layer may be arranged between a display element layer DP-ED and a base substrate BL. The filling layer may be an organic layer. The filling layer may include at least one among an acrylic resin, a silicon-based resin, or an epoxy-based resin.

FIG. 4 shows an embodiment where the emission layers EML-R, EML-G, and EML-B of light emitting elements ED-1, ED-2, and ED-3 are each in the opening parts OH defined in a pixel definition layer PDL and a hole transport region HTR, an electron transport region ETR, and a second electrode EL2 are each provided as a common layer in all light emitting elements ED-1, ED-2, and ED-3. However, embodiments of the present disclosure are not limited thereto, for example, in one or more embodiments the hole transport region HTR and the electron transport region ETR may be patterned and provided in the opening parts OH defined in the pixel definition layer PDL. For example, in one or more embodiments, the hole transport region HTR, the emission layers EML-R, EML-G, and EML-B, and the electron transport region ETR of the light emitting elements ED-1, ED-2, and ED-3 may be patterned by an ink jet printing method and/or the like.

An encapsulation layer TFE may cover the light emitting elements ED-1, ED-2, and ED-3. The encapsulation layer TFE may encapsulate a display element layer DP-ED. The encapsulation layer TFE may be a thin film encapsulation layer. The encapsulation layer TFE may be one layer or a stacked layer of multiple layers. The encapsulation layer TFE may include at least one insulating layer. The encapsulation layer TFE according to one or more embodiments may include at least one inorganic layer (hereinafter, encapsulating inorganic layer). In addition, the encapsulation layer TFE according to one or more embodiments may include at least one organic layer (hereinafter, encapsulating organic layer) and at least one encapsulating inorganic layer.

The encapsulating inorganic layer protects the display element layer DP-ED from moisture and/or oxygen, and the encapsulating organic layer protects the display element layer DP-ED from foreign materials, such as dust particles and/or the like. The encapsulating inorganic layer may include silicon nitride, silicon oxy nitride, silicon oxide, titanium oxide, aluminum oxide, and/or the like, but embodiments of the present disclosure are not limited particularly thereto. The encapsulating organic layer may include an acrylic compound, an epoxy-based compound, and/or the like. The encapsulating organic layer may include a photopolymerizable organic material, but embodiments of the present disclosure are not limited particularly thereto. The encapsulation layer TFE may be arranged on the second electrode EL2 and may be arranged while filling the opening parts OH.

Referring to FIG. 3 and FIG. 4, the display module DM may include a non-light emitting area NPXA and light emitting areas PXA-R, PXA-G, and PXA-B. The light emitting areas PXA-R, PXA-G, and PXA-B may be areas emitting light produced from the respective light emitting elements ED-1, ED-2, and ED-3. The display module DM may include a first light emitting area PXA-R, a second light emitting area PXA-G, and a third light emitting area PXA-B spaced and/or apart (e.g., spaced apart or separated) from one another on a plane.

The first to third light emitting areas PXA-R, PXA-G, and PXA-B may be areas separated by the pixel definition layer PDL. The non-light emitting areas NPXA may be areas between neighboring light emitting areas PXA-R, PXA-G, and PXA-B and may be areas corresponding to the pixel definition layer PDL. In this disclosure, each of the light emitting areas PXA-R, PXA-G and PXA-B may correspond to each pixel. The pixel definition layer PDL may divide the light emitting elements ED-1, ED-2 and ED-3. The respective emission layers EML-R, EML-G, and EML-B of the light emitting elements ED-1, ED-2 and ED-3 may be arranged and divided in the opening parts OH defined in the pixel definition layer PDL.

The light emitting areas PXA-R, PXA-G, and PXA-B may be divided into multiple groups according to the color of light produced from the light emitting elements ED-1, ED-2, and ED-3. FIG. 3 and FIG. 4 illustrate three light emitting areas PXA-R, PXA-G, and PXA-B emitting red color light, green color light, and blue color light. For example, the first light emitting area PXA-R may be referred to as a red light emitting area, the second light emitting area may be PXA-G referred to as a green light emitting area, and the third light emitting area PXA-B may be referred to as a blue light emitting area.

In the display module DM according to one or more embodiments, a plurality of light emitting elements ED-1, ED-2, and ED-3 may be to emit light having different wavelength ranges. For example, the display module DM in one or more embodiments may include a first light emitting element ED-1 emitting red light, a second light emitting element ED-2 emitting green light, and a third light emitting element ED-3 emitting blue light. For example, in one or more embodiments, each of the red light emitting area PXA-R, the green light emitting area PXA-G, and the blue light emitting area PXA-B of the display module DM may correspond to the first light emitting element ED-1, the second light emitting element ED-2, and the third light emitting element ED-3.

However, one or more embodiments of the present disclosure are not limited thereto, and the first to third light emitting elements ED-1, ED-2, and ED-3 may be to emit light in substantially the same wavelength range, or at least one thereof may be to emit light in a different wavelength range. For example, in one or more embodiments, all of the first to third light emitting elements ED-1, ED-2, and ED-3 may be to emit blue light.

The light emitting areas PXA-R, PXA-G, and PXA-B in the display module DM according to one or more embodiments may be arranged in a stripe shape. Referring to FIG. 3, a plurality of first light emitting areas PXA-R may be aligned along a second direction axis DR2, a plurality of second light emitting areas PXA-G may be aligned along a second direction axis DR2, and a plurality of third light emitting areas PXA-B may be arranged along a second direction axis DR2. In addition, the first light emitting areas PXA-R, the second light emitting areas PXA-G, and the third light emitting areas PXA-B may be alternately arranged along a first direction axis DR1.

FIG. 3 and FIG. 4 show that the areas of the light emitting areas PXA-R, PXA-G, and PXA-B are similar, but embodiments of the present disclosure are not limited thereto. The areas of the light emitting areas PXA-R, PXA-G, and PXA-B may be different from each other according to the wavelength range of light emitted. The areas of the light emitting areas PXA-R, PXA-G, and PXA-B may refer to areas on a plane defined by the first direction axis DR1 and the second direction axis DR2.

The arrangement type (kind) of the light emitting areas PXA-R, PXA-G, and PXA-B is not limited to the configuration shown in FIG. 3, and the arrangement order of the first light emitting areas PXA-R, the second light emitting areas PXA-G and the third light emitting areas PXA-B may be provided in one or more suitable combinations according to the properties of display quality desired or required for the display module DM and a display device including the same. For example, the arrangement type (kind) of the light emitting areas PXA-R, PXA-G, and PXA-B may be a pentile (PENTILE®) arrangement type (kind) (for example, an RGBG matrix, an RGBG structure, or an RGBG matrix structure), or a diamond (Diamond Pixel™) arrangement type (kind) (e.g., a display (e.g., an OLED display) containing red, blue, and green (RGB) emission regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting areas PXA-R, PXA-G and PXA-B may be different from one another. For example, in one or more embodiments, the area of the second light emitting area PXA-G, which is a green light emitting area, may be smaller than the area of the third light emitting area PXA-B, which is a blue light emitting area, but embodiments of the disclosure are not limited thereto.

Hereinafter, FIGS. 5-9 are each cross-sectional views schematically showing light emitting elements according to one or more embodiments. Referring to FIG. 5, a light emitting element ED according to one or more embodiments may include a first electrode EL1, a hole transport region HTR, an emission layer EML, an electron transport region ETR, and a second electrode EL2, sequentially stacked.

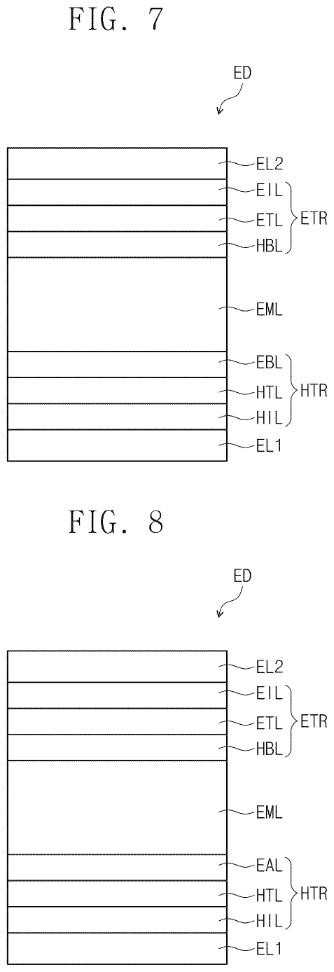

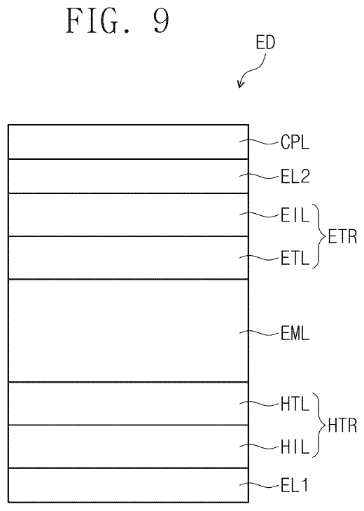

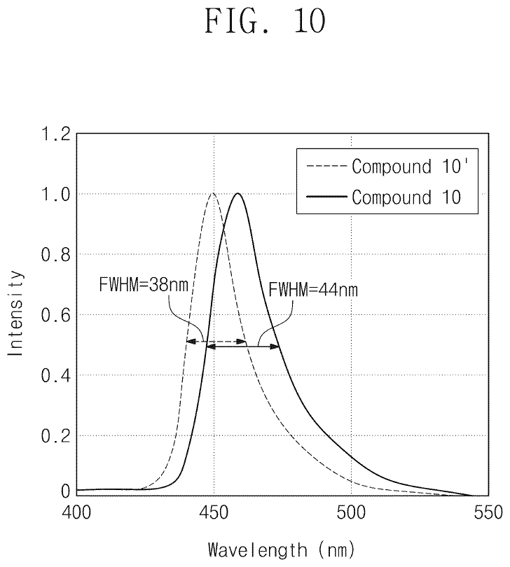

Compared to FIG. 5, FIG. 6 shows the cross-sectional view of a light emitting element ED of one or more embodiments, wherein a hole transport region HTR includes a hole injection layer HIL and a hole transport layer HTL, and an electron transport region ETR includes an electron injection layer EIL and an electron transport layer ETL. In addition, compared to FIG. 5, FIG. 7 shows the cross-sectional view of a light emitting element ED of one or more embodiments, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared to FIG. 5, FIG. 8 shows the cross-sectional view of a light emitting element ED of one or more embodiments, wherein a hole transport region HTR includes a hole injection layer HIL, a hole transport layer HTL, and a light emitting auxiliary layer EAL, and an electron transport region ETR includes an electron injection layer EIL, an electron transport layer ETL, and a hole blocking layer HBL. Compared to FIG. 6, FIG. 9 shows the cross-sectional view of a light emitting element ED of one or more embodiments, including a capping layer CPL arranged on the second electrode EL2.

The first electrode EL1 has conductivity (e.g., is a conductor). The first electrode EL1 may be formed using a metal material, a metal alloy or a conductive compound. The first electrode EL1 may be an anode or a cathode. However, embodiments of the disclosure are not limited thereto. In one or embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), compounds of two or more selected therefrom, mixtures of two or more selected therefrom, or one or more oxides thereof.

In embodiments where the first electrode EL1 is the transmissive electrode, the first electrode EL1 may include a transparent metal oxide, such as indium tin oxide (ITO), indium zinc oxide (IZO), zinc oxide (ZnO), and indium tin zinc oxide (ITZO), and/or the like. In embodiments where the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, W, compounds thereof, or mixtures thereof (for example, a mixture of Ag and Mg). In one or more embodiments, the first electrode EL1 may have a structure including multiple layers including a reflective layer or a transflective layer formed using the materials described above, and a transmissive conductive layer formed using ITO, IZO, ZnO, or ITZO. For example, in one or more embodiments, the first electrode EL1 may include a three-layer structure of ITO/Ag/ITO. However, embodiments of the present disclosure are not limited thereto. The first electrode EL1 may include one of the metal materials described above, combinations of two or more metal materials selected from among the metal materials described above, or oxides of the metal materials described above. The thickness of the first electrode EL1 may be from about 700 ångströms (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one among a hole injection layer HIL, a hole transport layer HTL, a light emitting auxiliary layer EAL, and an electron blocking layer EBL. The thickness of the hole transport region HTR may be, for example, from about 50 Å to about 15,000 Å. The light emitting auxiliary layer EAL may be referred to as a buffer layer.

The hole transport region HTR may have a single layer formed using a single material, a single layer formed using multiple different materials, or a multilayer structure including multiple layers formed using multiple different materials.

For example, in one or more embodiments, the hole transport region HTR may have the structure of a single layer of a hole injection layer HIL or a hole transport layer HTL and may have a structure of a single layer formed using a hole injection material and a hole transport material. In one or more embodiments, the hole transport region HTR may have a structure of a single layer formed using multiple different materials, or a structure stacked from the first electrode EL1 of hole injection layer HIL/hole transport layer HTL, hole injection layer HIL/hole transport layer HTL/light emitting auxiliary layer EAL, hole injection layer HIL/light emitting auxiliary layer EAL, hole transport layer HTL/light emitting auxiliary layer EAL, hole injection layer HIL/hole transport layer HTL/light emitting auxiliary layer EAL, or hole injection layer HIL/hole transport layer HTL/electron blocking layer EBL, but embodiments of the present disclosure are not limited thereto.

The hole transport region HTR may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

In one or more embodiments, the hole transport region HTR may include a compound represented by Formula H-1.

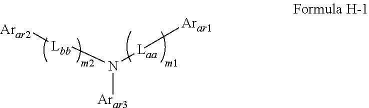

In Formula H-1, Lₐₐ and L_{bb} may each independently be a direct linkage, a substituted or unsubstituted arylene group of 6 to 30 ring-forming carbon atoms, or a substituted or unsubstituted heteroarylene group of 2 to 30 ring-forming carbon atoms. m1 and m2 may each independently be an integer of 0 to 10. If (e.g., when) m1 or m2 is an integer of 2 or more, Lₐₐ in plurality and/or L_{bb} may each independently be a substituted or unsubstituted arylene group of 6 to 30 ring-forming carbon atoms or a substituted or unsubstituted heteroarylene group of 2 to 30 ring-forming carbon atoms.

In Formula H-1, Arₐᵣ₁ and Arₐᵣ₂ may each independently be a substituted or unsubstituted aryl group of 6 to 30 ring-forming carbon atoms or a substituted or unsubstituted heteroaryl group of 2 to 30 ring-forming carbon atoms. In addition, in Formula H-1, Arₐᵣ₃ may be a substituted or unsubstituted aryl group of 6 to 30 ring-forming carbon atoms.

In one or more embodiments, the compound represented by Formula H-1 may be a monoamine compound. In one or more embodiments, the compound represented by Formula H-1 may be a diamine compound in which at least one among Arₐᵣ₁ to Arₐᵣ₃ includes an amine group as a substituent. In one or more embodiments, the compound represented by Formula H-1 may be a carbazole-based compound in which at least one among Arₐᵣ₁ and Arₐᵣ₂ includes a substituted or unsubstituted carbazole group, or a fluorene-based compound in which at least one among Arₐᵣ₁ and Arₐᵣ₂ includes a substituted or unsubstituted fluorene group.

The compound represented by Formula H-1 may be any one selected from among the compounds in Compound Group H. However, the compounds shown in Compound Group H are only examples, and the compound represented by Formula H-1 is not limited to the compounds represented in Compound Group H.

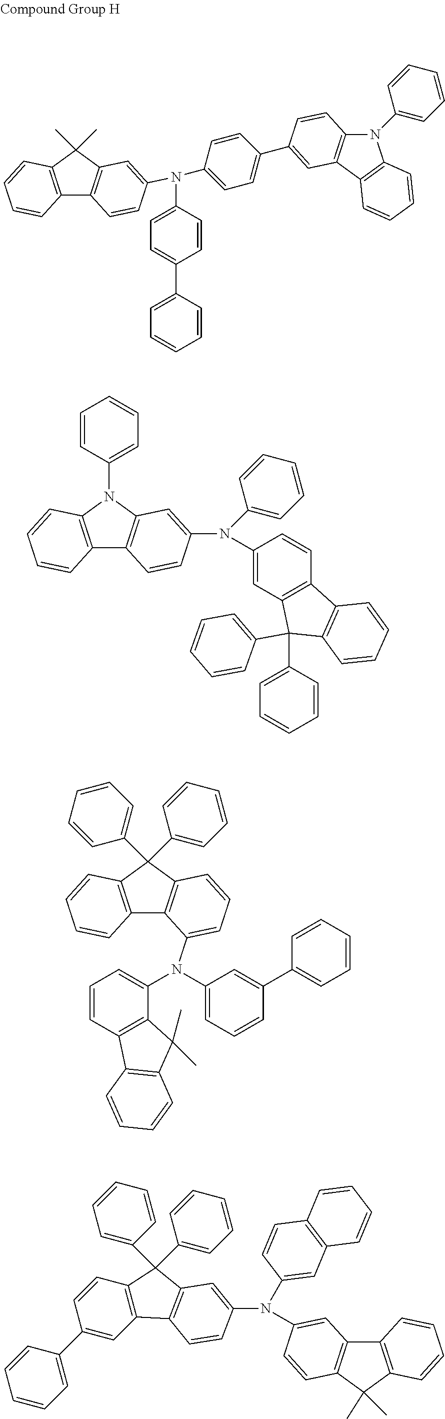 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

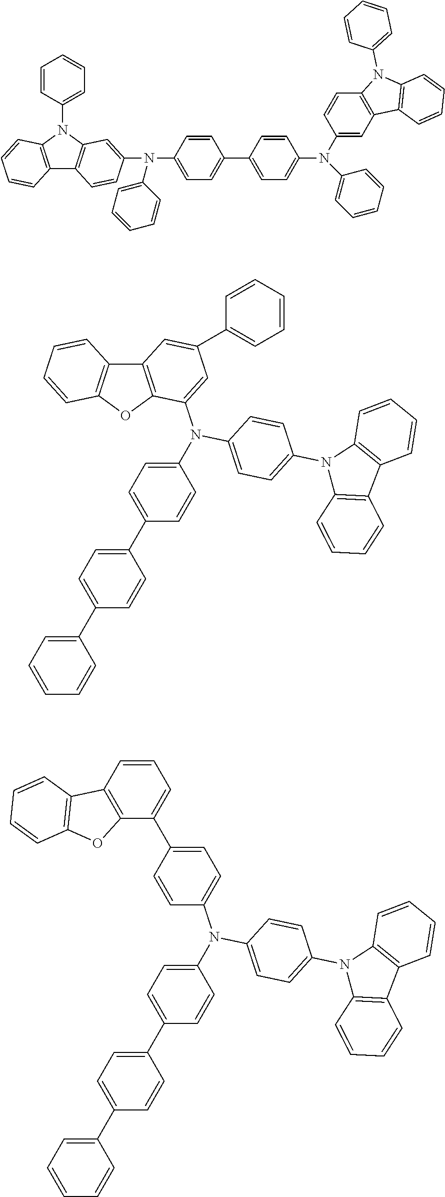 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

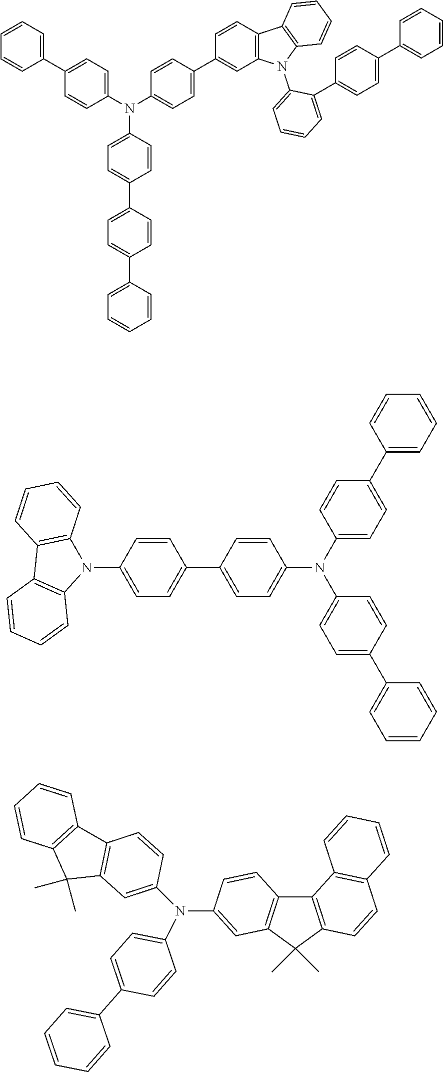 [SMILES: c1ccc(-c2ccc(-c3ccc(N(c4ccc(-c5ccccc5)cc4)c4ccc(-c5ccc6c7ccccc7n(-c7ccccc7-c7ccc(-c8ccccc8)cc7)c6c5)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

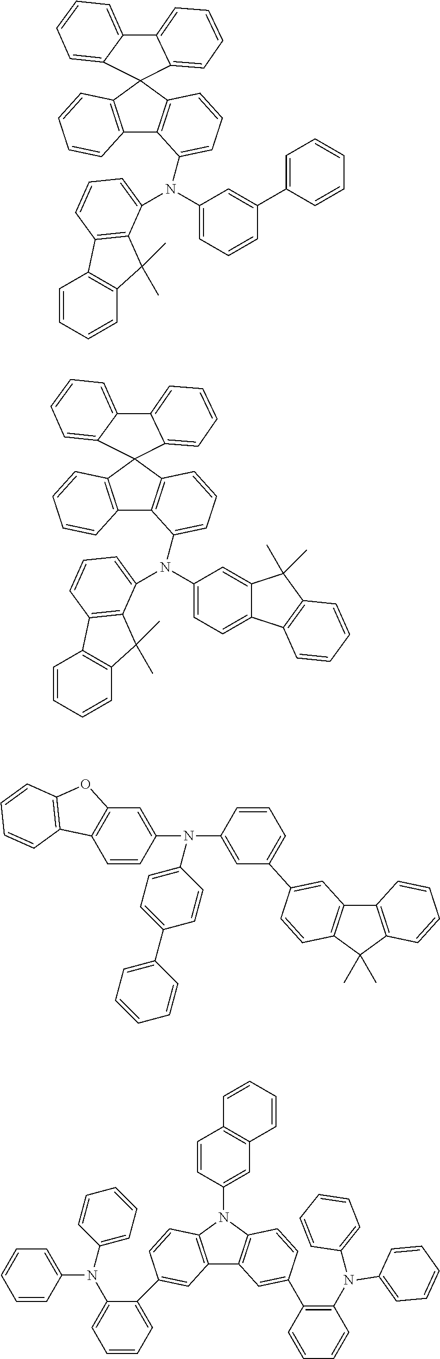

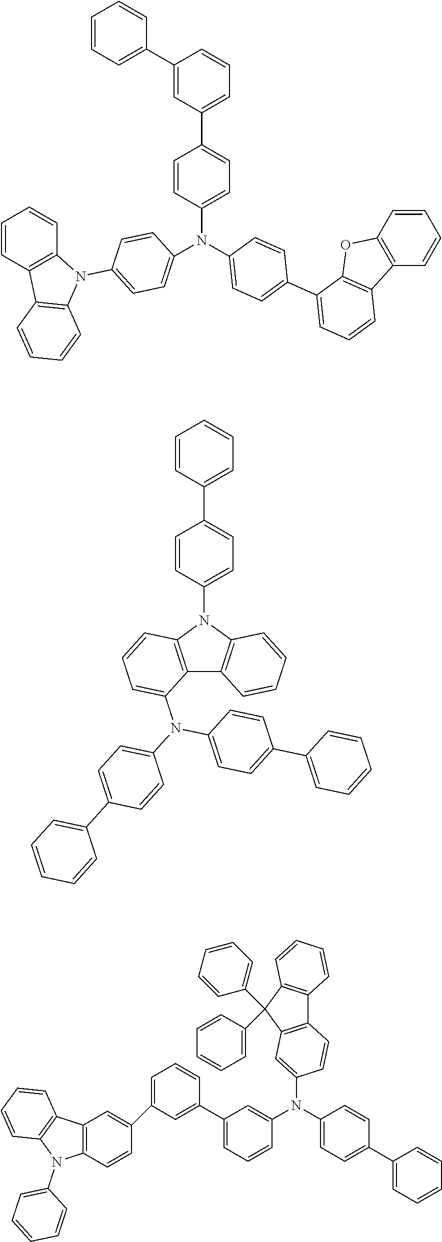 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

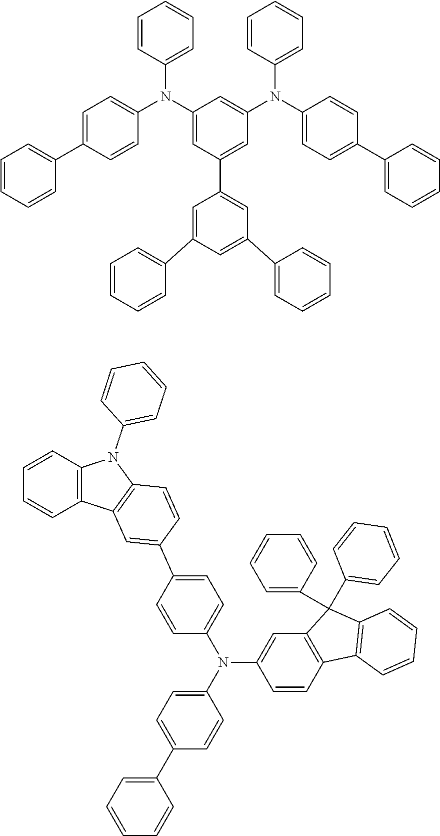 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport region HTR may include one or more selected from among a phthalocyanine compound, such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HAT-CN), and/or the like.

In or more embodiments, the hole transport region HTR may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalen-1-yl)-N,N′-diphenyl-benzidine (NPB), 4,4′-cyclohexylidiene bis[N,N-bis(4-methylphenyl)benzenamine](TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

In or more embodiments, the hole transport region HTR may include the compounds of the hole transport region in at least one among the hole injection layer HIL, hole transport layer HTL, light emitting auxiliary layer EAL, and electron blocking layer EBL.

In or more embodiments, the thickness of the hole transport region HTR may be from about 100 Å to about 10,000 Å, for example, from about 100 Å to about 5,000 Å. If (e.g., when) the hole transport region HTR includes a hole injection layer HIL, the thickness of the hole injection region HIL may be, for example, from about 30 Å to about 1,000 Å. If (e.g., when) the hole transport region HTR includes a hole transport layer HTL, the thickness of the hole transport layer HTL may be from about 30 Å to about 1,000 Å. For example, if (e.g., when) the hole transport region HTR includes an electron blocking layer, the thickness of the electron blocking layer EBL may be from about 10 Å to about 1,000 Å. If (e.g., when) the thicknesses of the hole transport region HTR, the hole injection layer HIL, the hole transport layer HTL and the electron blocking layer EBL satisfy the ranges described above, satisfactory hole transport properties may be achieved without substantial increase in driving voltage.

In one or more embodiments, the hole transport region HTR may further include a charge generating material to increase conductivity (e.g., electric conductivity) in addition to the materials described above. The charge generating material may be dispersed uniformly (e.g., substantially uniformly) or non-uniformly (e.g., substantially uniformly) in the hole transport region HTR. The charge-generating material may be, for example, a p-dopant. The p-dopant may include at least one among metal halide compounds, quinone derivatives, metal oxides, and cyano group-containing compounds, but embodiments of the present disclosure are not limited thereto. For example, in one or more embodiments, the p-dopant may include metal halide compounds such as CuI and RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxide and/or molybdenum oxide, and/or cyano group-containing compounds such as dipyrazino[2,3-f: 2′,3′-h]quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one selected from among a light emitting auxiliary layer EAL and an electron blocking layer EBL in addition to the hole injection layer HIL and the hole transport layer HTL. The light emitting auxiliary layer EAL may compensate for a resonance distance according to the wavelength of light emitted from an emission layer EML and may increase light emitting efficiency by controlling hole charge balance. In addition, light emitting auxiliary layer EAL may play the role of preventing or reducing electron injection into the hole transport region HTR. As materials included in the light emitting auxiliary layer EAL, materials which may be included in the hole transport region HTR may be used. The electron blocking layer EBL is a layer playing the role of blocking the injection of electrons from the electron transport region ETR into the hole transport region HTR.

In the light emitting element ED of one or more embodiments, the emission layer EML may include the fused polycyclic compound according to one or more embodiments of the present disclosure. In the light emitting element ED of an embodiment, the emission layer EML may include a first compound, which is the fused polycyclic compound of an embodiment, and at least one compound among a second compound and a third compound. In addition, in the light emitting element ED of an embodiment, the emission layer EML may further include a fourth compound. The second compound may include a fused ring of three rings including a nitrogen atom as a ring-forming atom. The third compound may include a hexagonal ring group including at least one nitrogen atom as a ring-forming atom. The fourth compound may include an organometallic complex. The second to fourth compounds will be described in more detail.

In the light emitting element ED of one or more embodiments, the emission layer EML may include the fused polycyclic compound of one or more embodiments as a dopant. The fused polycyclic compound of one or more embodiments may be a dopant material of the emission layer EML.

In this disclosure, the fused polycyclic compound according to one or more embodiments may also be referred to as a first compound. The fused polycyclic compound according to one or more embodiments includes a boron-containing fused ring as a core structure. The fused polycyclic compound according to one or more embodiments, which is the first compound, may include a core structure including two boron atoms as ring-forming atoms and including a heteroatom as a ring-forming atom in addition to the boron atoms. The core structure of the fused polycyclic compound according to one or more embodiments may include a boron-containing hetero fused ring structure in the form of fused nine rings. The core structure of the fused polycyclic compound according to one or more embodiments may be represented as including a heteroborine skeleton including two boron atoms as ring-forming atoms.

The fused polycyclic compound according to one or more embodiments may exhibit thermally activated delayed fluorescence (TADF) light emitting characteristics by reverse intersystem crossing.

In addition, the fused polycyclic compound according to one or more embodiments may include a fused ring structure of nine rings, containing four heteroatoms and two boron atoms as ring-forming atoms, as a central structure. Each of the four heteroatoms may each independently be N, O, or S. The fused polycyclic compound according to one or more embodiments may include first substituents (R^{a1} and R^{a2} in Formula 1), respectively bonded to both para positions with respect to a boron atom, and second substituents (R^{b1} to R^{b4} in Formula 1) bonded to an adjacent ring to another boron atom.

The fused polycyclic compound according to one or more embodiments may include an alkyl group or a cycloalkyl group as the first substituent and an aryl group as the second substituent, thereby exhibiting narrow full width at half maximum (FWHM) and narrow stokes shift characteristics and resulting in high efficiency and excellent or suitable material stability by suppressing or reducing the broadening of the LUMO orbital. Accordingly, a light emitting element of one or more embodiments, including the fused polycyclic compound of one or more embodiments may exhibit high light emitting efficiency and long-life characteristics.

The fused polycyclic compound according to one or more embodiments may be represented by Formula 1.

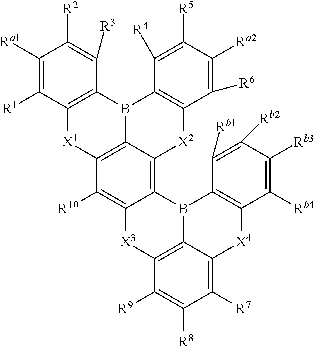

In Formula 1, X^{a} to X^{d} may each independently be O, S, or NR^{X}, and R^{X} may be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or represented by Formula x.

In Formula 1, at least one among X^{a} to X^{d} may be NR^{X}. For example, at least one among X^{a} to X^{d} may be NR^{X}, and the remainder other than NR^{X} among X^{a} to X^{d} may each independently be O or S. For example, X^{a} to X^{d} may all be NR^{X}.

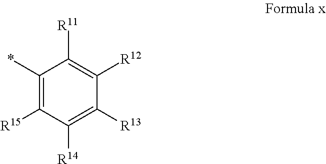

In Formula x, R¹¹ to R¹⁵ may each independently be a hydrogen atom, a deuterium atom, a halogen atom, a cyano group, a substituted or unsubstituted alkyl group of 1 to 20 carbon atoms, a substituted or unsubstituted cycloalkyl group of 3 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring.

For example, R¹¹ to R¹⁵ may each independently be a hydrogen atom, a cyano group, a substituted or unsubstituted methyl group, a substituted or unsubstituted isopropyl group, a substituted or unsubstituted t-butyl group, a substituted or unsubstituted cyclohexyl group, an alkyl-substituted or unsubstituted phenyl group, or a substituted or unsubstituted biphenyl group.

In one or more embodiments, R^{X} may be represented by one among (e.g., selected from among) x-101 to x-125. For example, Formula x may be represented by one among x-101 to x-125.

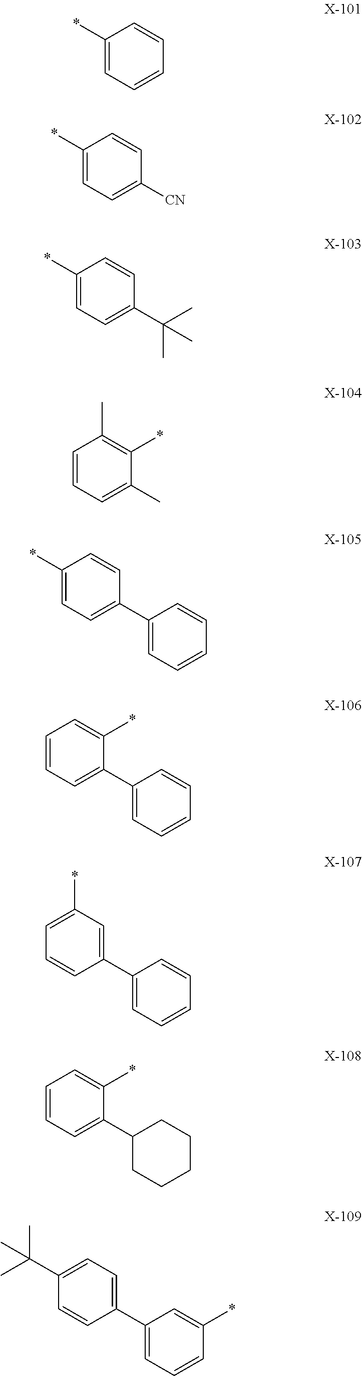

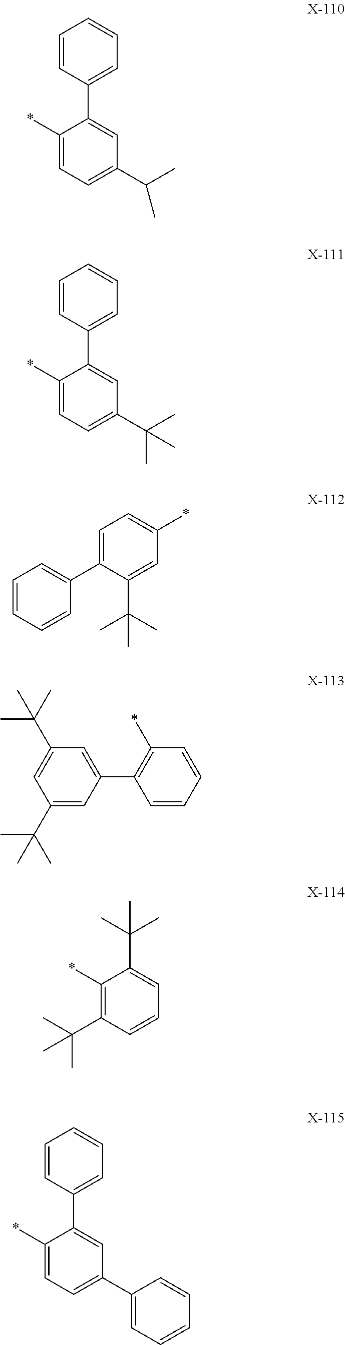

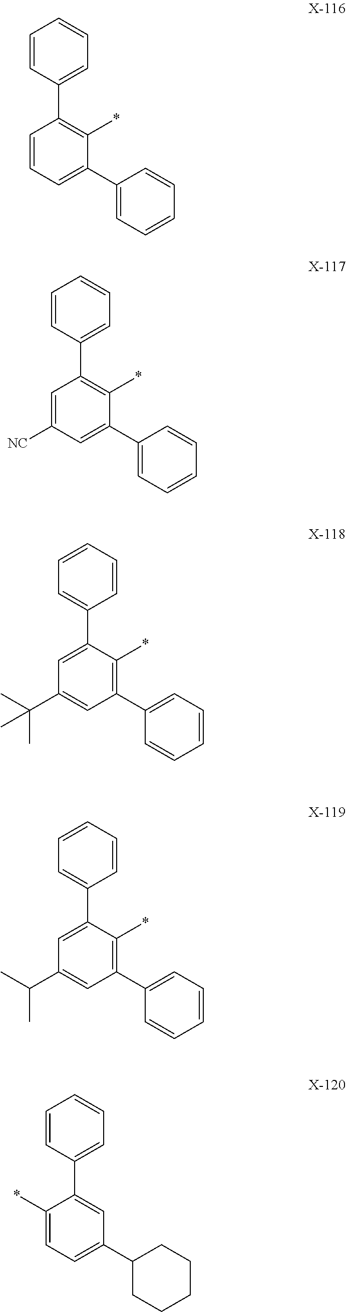 [SMILES: *c1c(-c2ccccc2)cccc1-c1ccccc1 ; *c1c(-c2ccccc2)cc(C#N)cc1-c1ccccc1 ; *c1c(-c2ccccc2)cc(C(C)(C)C)cc1-c1ccccc1 ; *c1c(-c2ccccc2)cc(C(C)C)cc1-c1ccccc1 ; *c1ccc(C2CCCCC2)cc1-c1ccccc1]

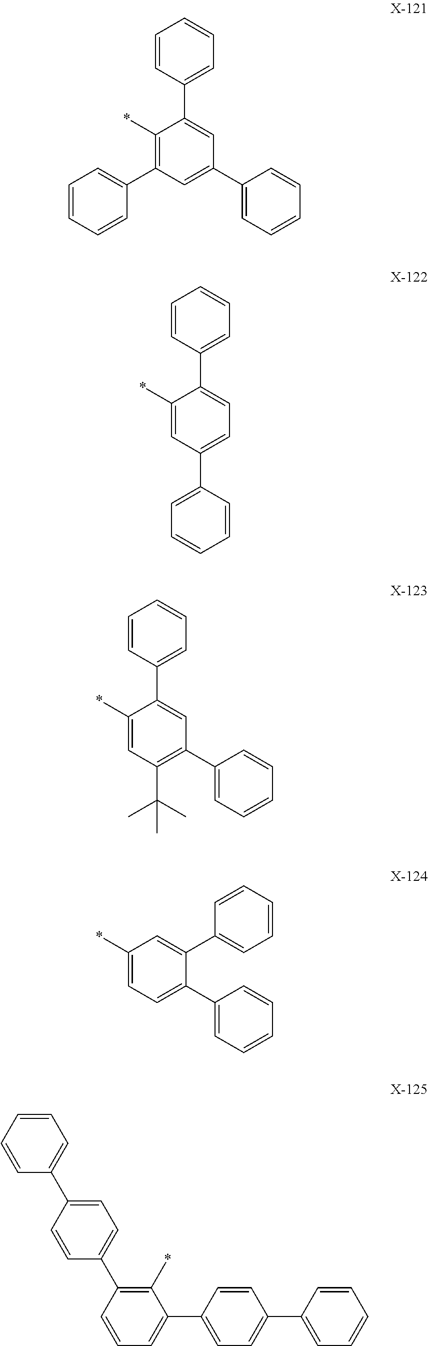 [SMILES: *c1c(-c2ccccc2)cc(-c2ccccc2)cc1-c1ccccc1 ; *c1cc(-c2ccccc2)ccc1-c1ccccc1 ; *c1cc(C(C)(C)C)c(-c2ccccc2)cc1-c1ccccc1 ; *c1ccc(-c2ccccc2)c(-c2ccccc2)c1 ; *c1c(-c2ccc(-c3ccccc3)cc2)cccc1-c1ccc(-c2ccccc2)cc1]

In Formula 1, R^{a1} and R^{a2} may each independently be a substituted or unsubstituted alkyl group of 1 to 20 carbon atoms, or a substituted or unsubstituted cycloalkyl group of 3 to 30 ring-forming carbon atoms.

For example, in one or more embodiments, R^{a1} and R^{a2} may each independently be a substituted or unsubstituted methyl group, a substituted or unsubstituted ethyl group, a substituted or unsubstituted propyl group, a substituted or unsubstituted isopropyl group, a substituted or unsubstituted isobutyl group, a substituted or unsubstituted t-butyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted cycloheptyl group, a substituted or unsubstituted bicyclopentyl group, a substituted or unsubstituted norbornyl group, or a substituted or unsubstituted adamantyl group.

In Formula 1, R¹ to R¹⁰ and R^{b1} to R^{b4} may each independently be a hydrogen atom, a deuterium atom, a halogen atom, a substituted or unsubstituted oxy group of 1 to 20 carbon atoms, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

For example, in one or more embodiments, R¹ to R¹⁰ and R^{b1} to R^{b4} may each independently be a hydrogen atom, a deuterium atom, a substituted or unsubstituted methoxy group, a substituted or unsubstituted methylthio group, a substituted or unsubstituted t-butyl group, a substituted or unsubstituted phenyl group, a substituted or unsubstituted biphenyl group, a substituted or unsubstituted naphthyl group, or a substituted or unsubstituted terphenyl group.

In one or more embodiments, R⁸ may be a substituted or unsubstituted t-butyl group, or a substituted or unsubstituted terphenyl group. For example, each of R¹ to R⁷, R⁹, and R¹⁰ may be a hydrogen atom.

In Formula 1, at least one among R^{b1} to R^{b4} may be a substituted or unsubstituted aryl group of 6 to 30 ring-forming carbon atoms.

In Formula 1, at least one among R^{b1} to R^{b4} may be represented by Formula b.

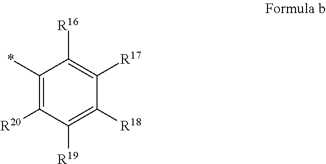

In Formula b, R¹⁶ to R²⁰ may independently be a hydrogen atom, a deuterium atom, a halogen atom, a cyano group, a substituted or unsubstituted thio group, a substituted or unsubstituted oxy group of 1 to 20 carbon atoms, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring.

For example, R¹⁶ to R²⁰ may independently be a hydrogen atom, a deuterium atom, a cyano group, a substituted or unsubstituted methoxy group, a substituted or unsubstituted dialkylamine group, a substituted or unsubstituted isopropyloxy group, a substituted or unsubstituted methylthio group, a substituted or unsubstituted t-butyl group, a substituted or unsubstituted phenyl group, a substituted or unsubstituted phenylthiol group, or a substituted or unsubstituted carbazole group, and/or be combined with an adjacent group from each other to form an aliphatic hydrocarbon ring, an aromatic hydrocarbon ring, or a heterocycle.

In one or more embodiments, R^{b1} to R^{b4} may be represented by one among b-101 to b-119. For example, at least one among R^{b1} to R^{b4} may be represented by one among b-102 to b-119.

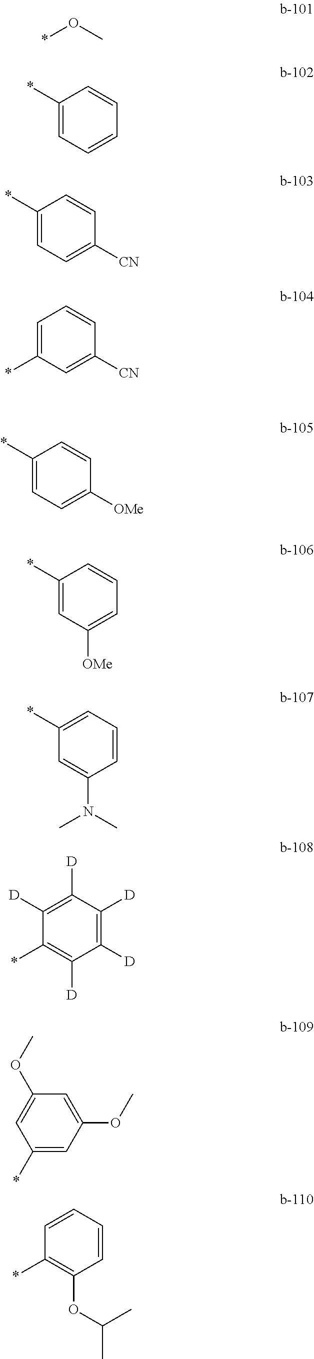

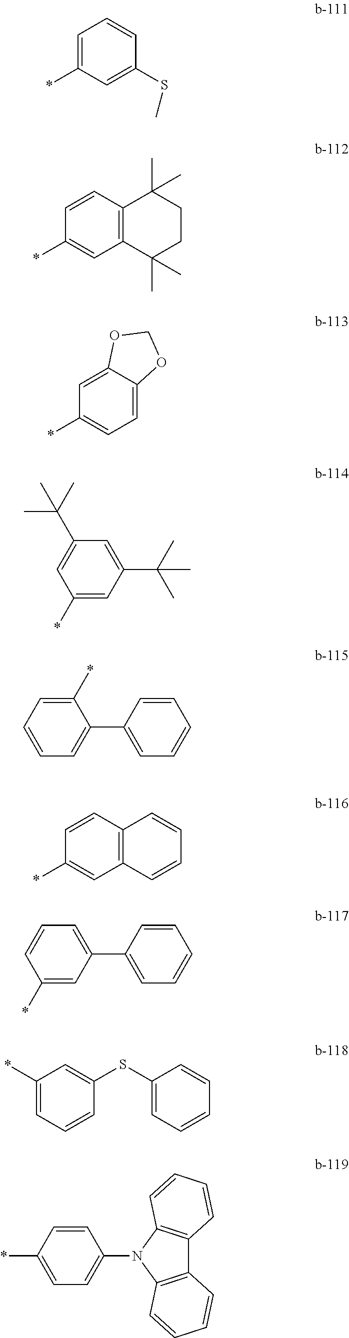

The fused polycyclic compound according to one or more embodiments may be represented by one among Formula 1-1 to Formula 1-5.

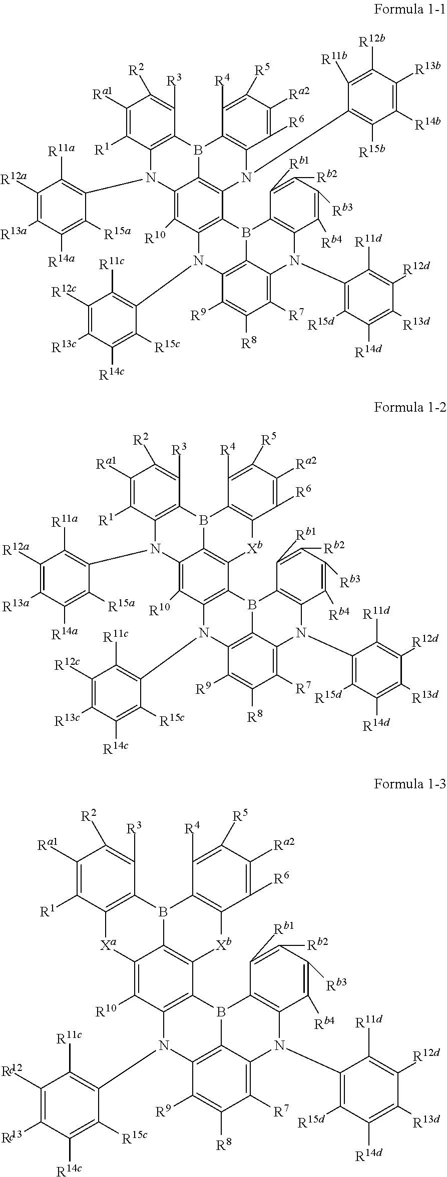

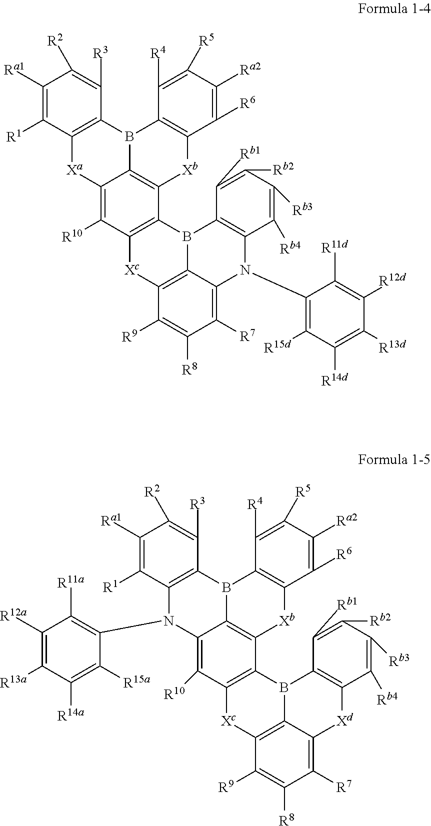

In Formula 1-1 to Formula 1-5, R^{11a} to R^{15a}, R^{11b} to R^{15b}, R^{11c} to R^{15c}, and R^{11d} to R^{15d} may each independently be a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring, and X^{a} to X^{d} and R¹ to R¹⁰ may each independently be the same as defined in Formula 1.

For example, R^{11a} to R^{15a}, R^{11b} to R^{15b}, R^{11c} to R^{15c}, and R^{11d} to R^{15d} may each independently be a hydrogen atom, a cyano group, a substituted or unsubstituted methyl group, a substituted or unsubstituted isopropyl group, a substituted or unsubstituted t-butyl group, a substituted or unsubstituted cyclohexyl group, an alkyl-substituted or unsubstituted phenyl group, or a substituted or unsubstituted biphenyl group.

The fused polycyclic compound according to one or more embodiments may be represented by any one selected from among the compounds in Compound Group 1. A light emitting element ED according to one or more embodiments may include at least one selected from among the compounds in Compound Group 1.

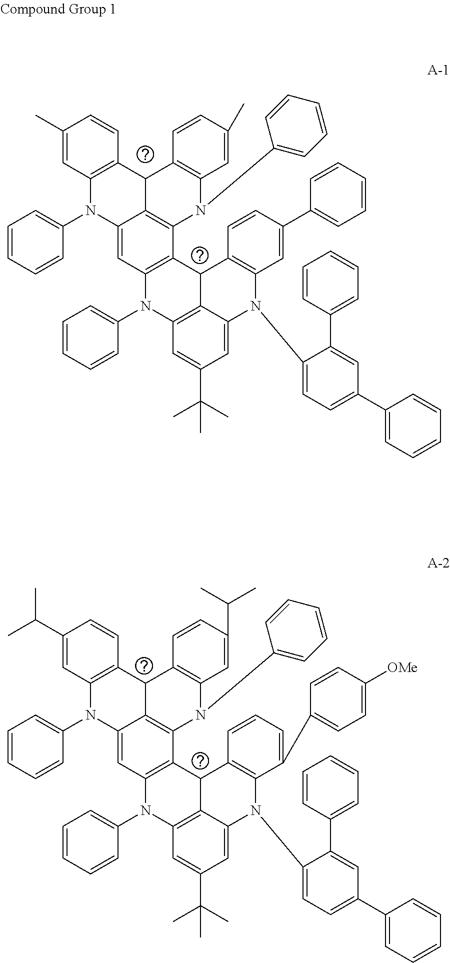 [SMILES: Cc1ccc2c(c1)N(c1ccccc1)c1cc3c(c4c1C2c1ccc(C)cc1N4c1ccccc1)C1c2ccc(-c4ccccc4)cc2N(c2ccc(-c4ccccc4)cc2-c2ccccc2)c2cc(C(C)(C)C)cc(c21)N3c1ccccc1 ; COc1ccc(-c2cccc3c2N(c2ccc(-c4ccccc4)cc2-c2ccccc2)c2cc(C(C)(C)C)cc4c2C3c2c(cc3c5c2N(c2ccccc2)c2cc(C(C)C)ccc2C5c2ccc(C(C)C)cc2N3c2ccccc2)N4c2ccccc2)cc1]

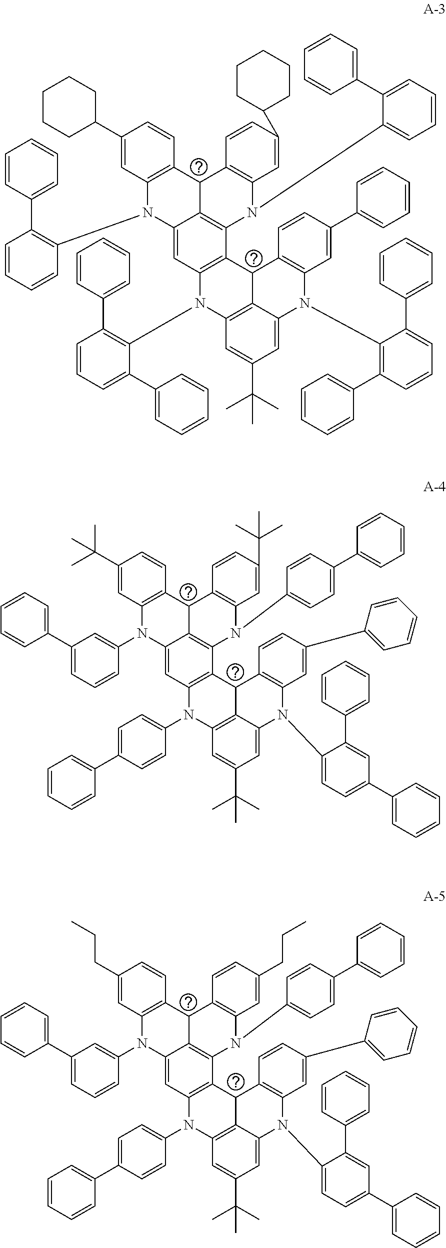

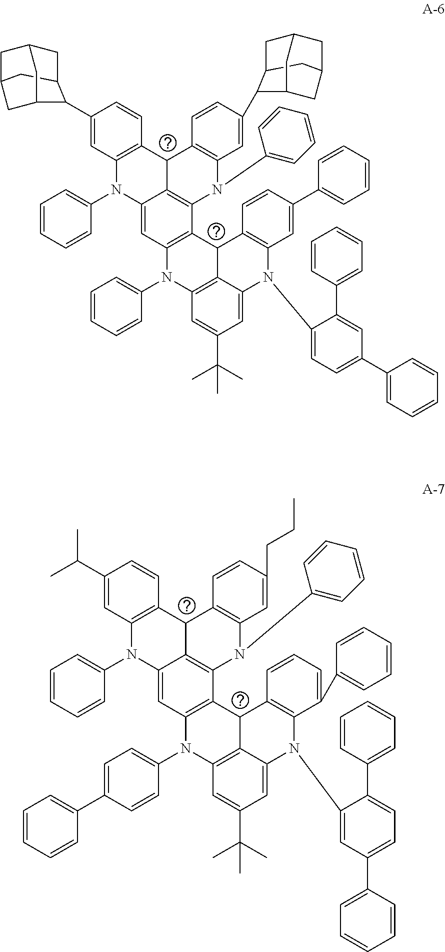 [SMILES: CC(C)(C)c1cc2c3c(c1)N(c1ccc(-c4ccccc4)cc1-c1ccccc1)c1cc(-c4ccccc4)ccc1C3c1c(cc3c4c1N(c1ccccc1)c1cc(C5C6CC7CC(C6)CC5C7)ccc1C4c1ccc(C4C5CC6CC(C5)CC4C6)cc1N3c1ccccc1)N2c1ccccc1 ; CCCc1ccc2c(c1)N(c1ccccc1)c1c3c(cc4c1C1c5cccc(-c6ccccc6)c5N(c5cc(-c6ccccc6)ccc5-c5ccccc5)c5cc(C(C)(C)C)cc(c51)N4c1ccc(-c4ccccc4)cc1)N(c1ccccc1)c1cc(C(C)C)ccc1C23]

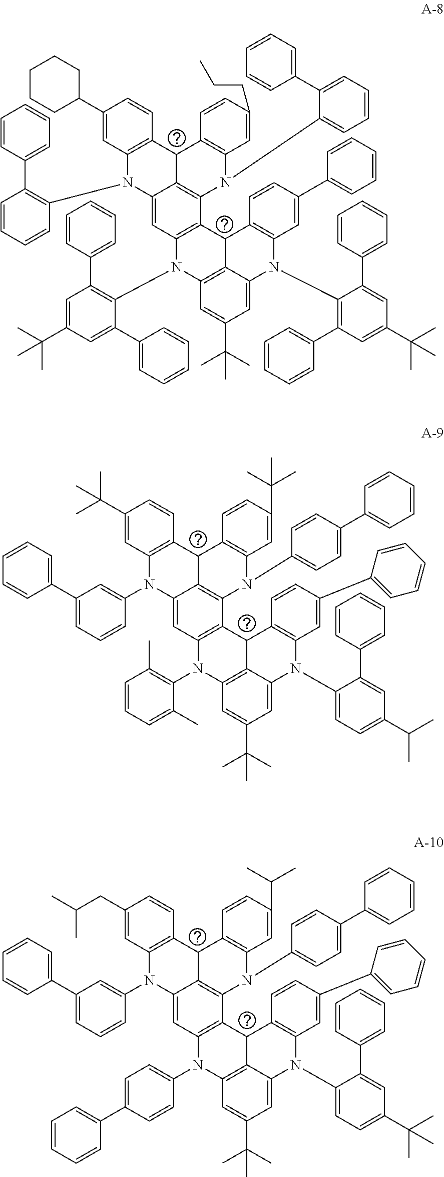

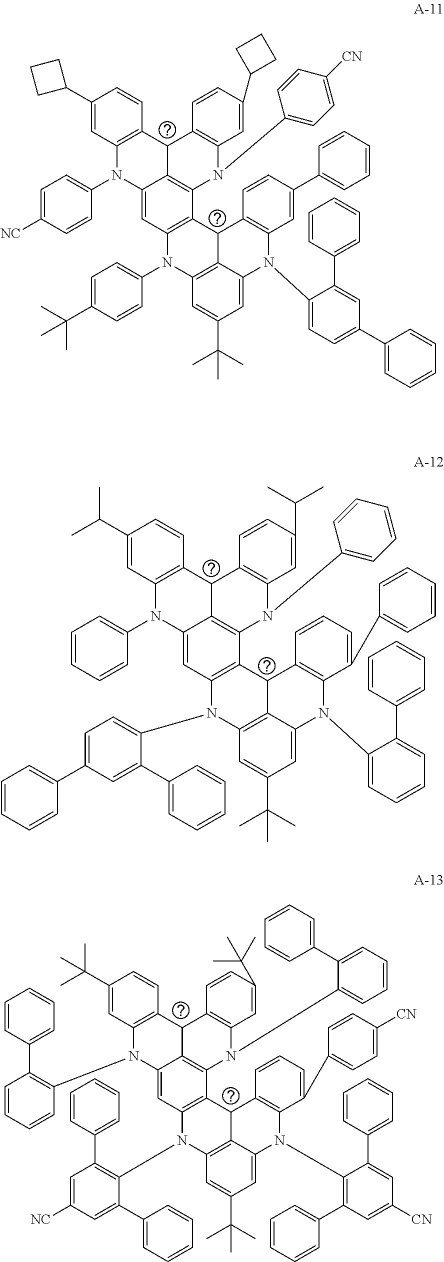

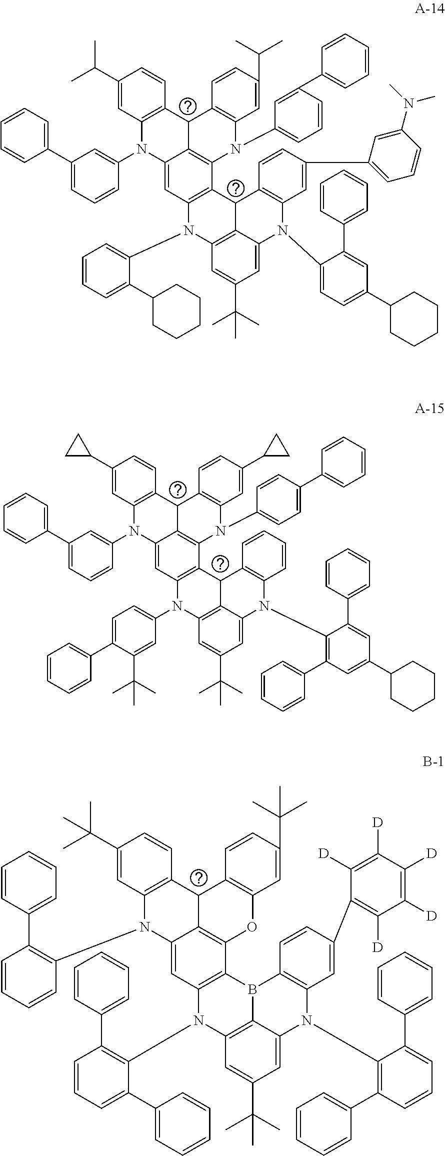

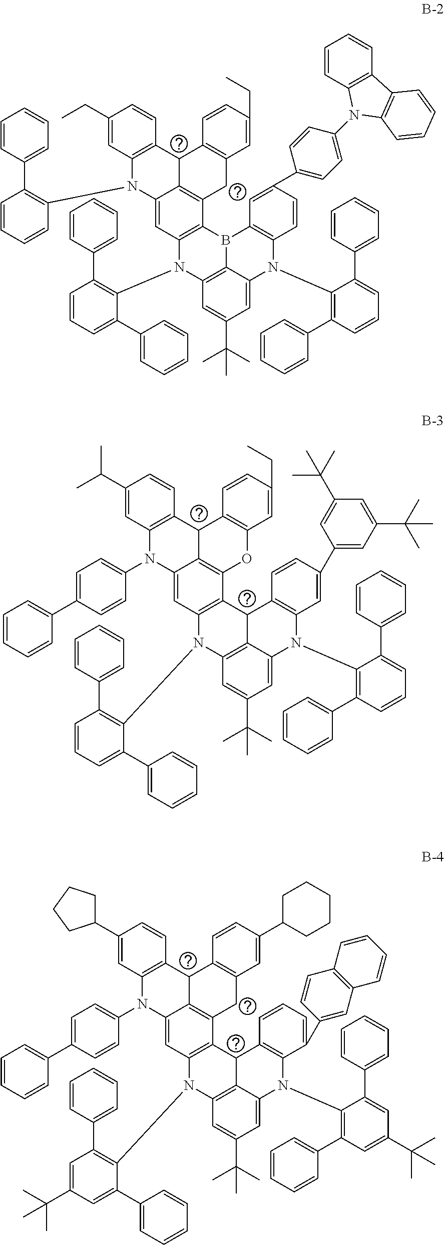

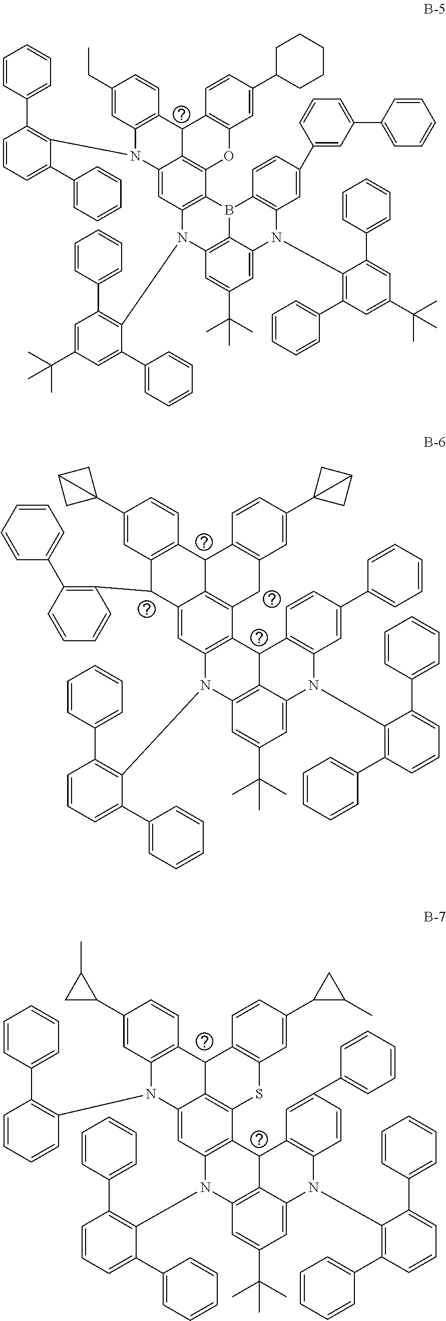

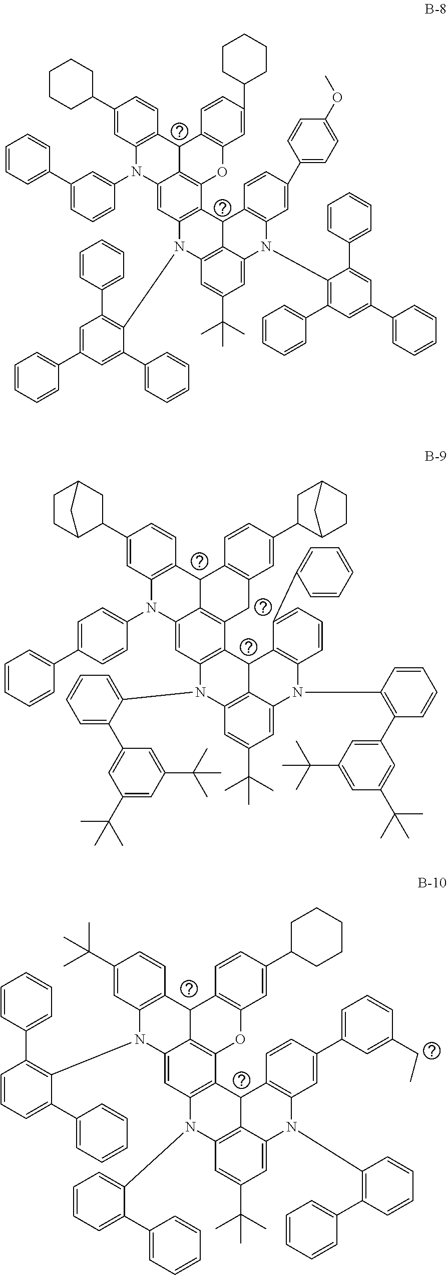

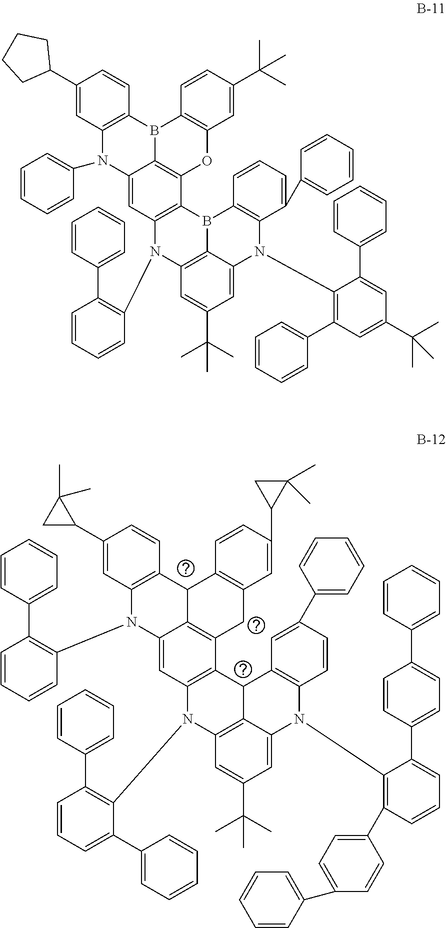 [SMILES: CC(C)(C)c1ccc2c(c1)Oc1c3c(cc4c1B1c5cccc(-c6ccccc6)c5N(c5c(-c6ccccc6)cc(C(C)(C)C)cc5-c5ccccc5)c5cc(C(C)(C)C)cc(c51)N4c1ccccc1-c1ccccc1)N(c1ccccc1)c1cc(C4CCCC4)ccc1B23 ; CC(C)(C)c1cc2c3c(c1)N(c1c(-c4ccccc4)cccc1-c1ccccc1)c1cc4c5c(c1C3c1cc(-c3ccccc3)ccc1N2c1c(-c2ccc(-c3ccccc3)cc2)cccc1-c1ccc(-c2ccccc2)cc1)Cc1cc(C2CC2(C)C)ccc1C5c1ccc(C2CC2(C)C)cc1N4c1ccccc1-c1ccccc1]

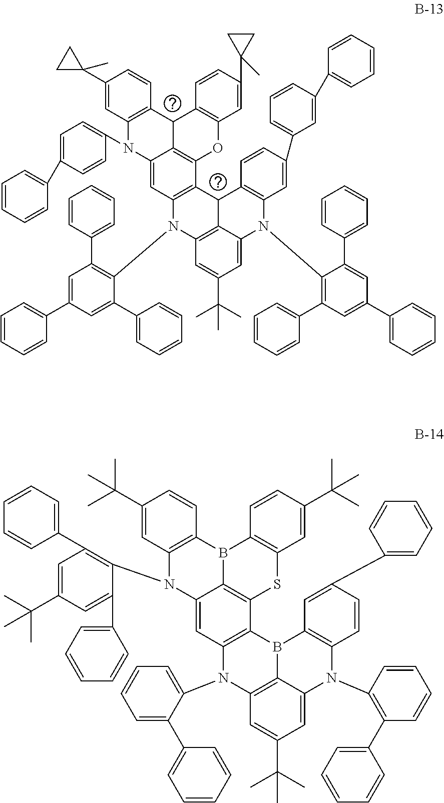 [SMILES: CC(C)(C)c1cc2c3c(c1)N(c1c(-c4ccccc4)cc(-c4ccccc4)cc1-c1ccccc1)c1cc4c5c(c1C3c1ccc(-c3cccc(-c6ccccc6)c3)cc1N2c1c(-c2ccccc2)cc(-c2ccccc2)cc1-c1ccccc1)Oc1cc(C2(C)CC2)ccc1C5c1ccc(C2(C)CC2)cc1N4c1ccc(-c2ccccc2)cc1 ; CC(C)(C)c1ccc2c(c1)Sc1c3c(cc4c1B2c1ccc(C(C)(C)C)cc1N4c1c(-c2ccccc2)cc(C(C)(C)C)cc1-c1ccccc1)N(c1ccccc1-c1ccccc1)c1cc(C(C)(C)C)cc2c1B3c1cc(-c3ccccc3)ccc1N2c1ccccc1-c1ccccc1]

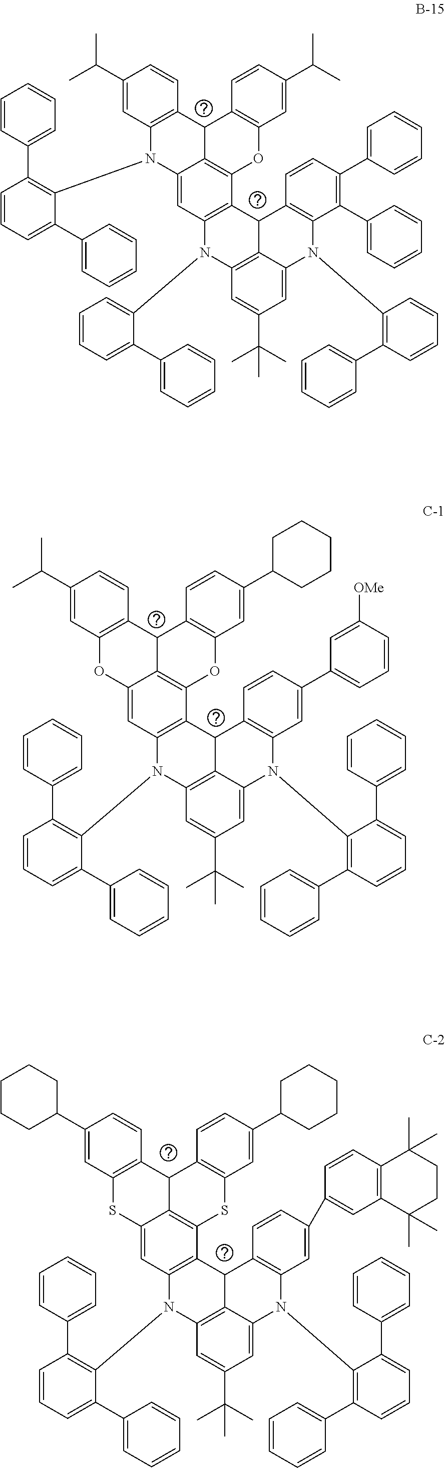

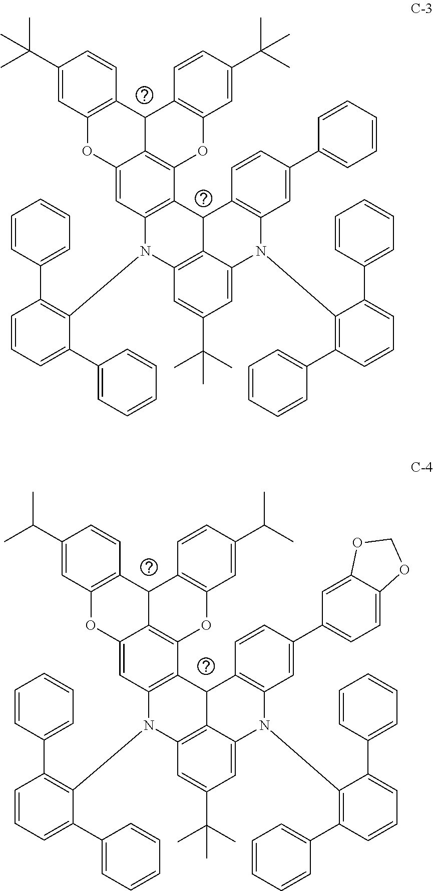 [SMILES: CC(C)(C)c1ccc2c(c1)Oc1cc3c(c4c1C2c1ccc(C(C)(C)C)cc1O4)C1c2ccc(-c4ccccc4)cc2N(c2c(-c4ccccc4)cccc2-c2ccccc2)c2cc(C(C)(C)C)cc(c21)N3c1c(-c2ccccc2)cccc1-c1ccccc1 ; CC(C)c1ccc2c(c1)Oc1cc3c(c4c1C2c1ccc(C(C)C)cc1O4)C1c2ccc(-c4ccc5c(c4)OCO5)cc2N(c2c(-c4ccccc4)cccc2-c2ccccc2)c2cc(C(C)(C)C)cc(c21)N3c1c(-c2ccccc2)cccc1-c1ccccc1]

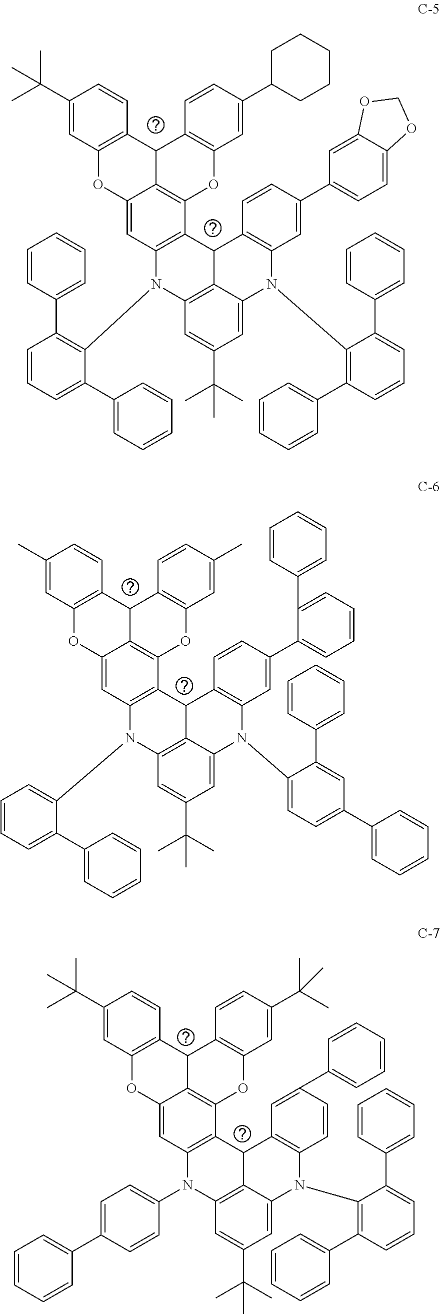 [SMILES: CC(C)(C)c1ccc2c(c1)Oc1cc3c(c4c1C2c1ccc(C2CCCCC2)cc1O4)C1c2ccc(-c4ccc5c(c4)OCO5)cc2N(c2c(-c4ccccc4)cccc2-c2ccccc2)c2cc(C(C)(C)C)cc(c21)N3c1c(-c2ccccc2)cccc1-c1ccccc1 ; Cc1ccc2c(c1)Oc1cc3c(c4c1C2c1ccc(C)cc1O4)C1c2ccc(-c4ccccc4-c4ccccc4)cc2N(c2ccc(-c4ccccc4)cc2-c2ccccc2)c2cc(C(C)(C)C)cc(c21)N3c1ccccc1-c1ccccc1 ; CC(C)(C)c1ccc2c(c1)Oc1cc3c(c4c1C2c1ccc(C(C)(C)C)cc1O4)C1c2cc(-c4ccccc4)ccc2N(c2c(-c4ccccc4)cccc2-c2ccccc2)c2cc(C(C)(C)C)cc(c21)N3c1ccc(-c2ccccc2)cc1]

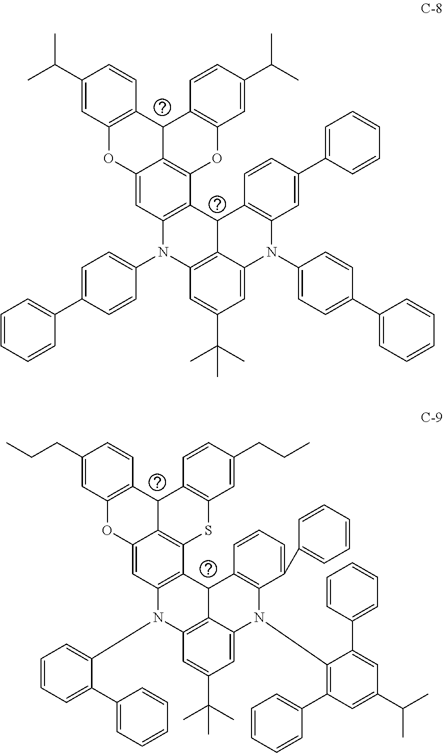 [SMILES: CC(C)c1ccc2c(c1)Oc1cc3c(c4c1C2c1ccc(C(C)C)cc1O4)C1c2ccc(-c4ccccc4)cc2N(c2ccc(-c4ccccc4)cc2)c2cc(C(C)(C)C)cc(c21)N3c1ccc(-c2ccccc2)cc1 ; CCCc1ccc2c(c1)Oc1cc3c(c4c1C2c1ccc(CCC)cc1S4)C1c2cccc(-c4ccccc4)c2N(c2c(-c4ccccc4)cc(C(C)C)cc2-c2ccccc2)c2cc(C(C)(C)C)cc(c21)N3c1ccccc1-c1ccccc1]

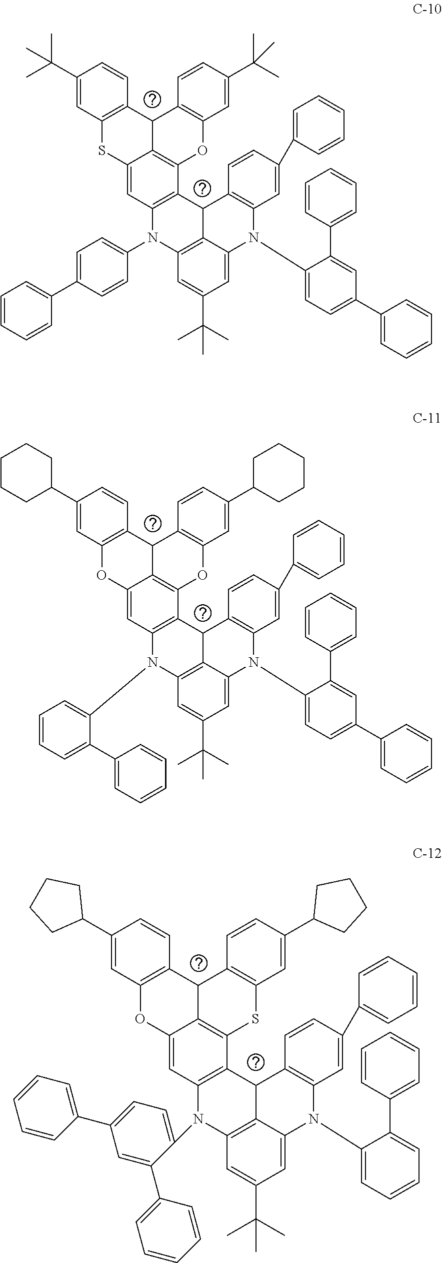 [SMILES: CC(C)(C)c1ccc2c(c1)Oc1c3c(cc4c1C1c5ccc(-c6ccccc6)cc5N(c5ccc(-c6ccccc6)cc5-c5ccccc5)c5cc(C(C)(C)C)cc(c51)N4c1ccc(-c4ccccc4)cc1)Sc1cc(C(C)(C)C)ccc1C23 ; CC(C)(C)c1cc2c3c(c1)N(c1ccccc1-c1ccccc1)c1cc4c5c(c1C3c1ccc(-c3ccccc3)cc1N2c1ccc(-c2ccccc2)cc1-c1ccccc1)Oc1cc(C2CCCCC2)ccc1C5c1ccc(C2CCCCC2)cc1O4 ; CC(C)(C)c1cc2c3c(c1)N(c1ccc(-c4ccccc4)cc1-c1ccccc1)c1cc4c5c(c1C3c1ccc(-c3ccccc3)cc1N2c1ccccc1-c1ccccc1)Sc1cc(C2CCCC2)ccc1C5c1ccc(C2CCCC2)cc1O4]

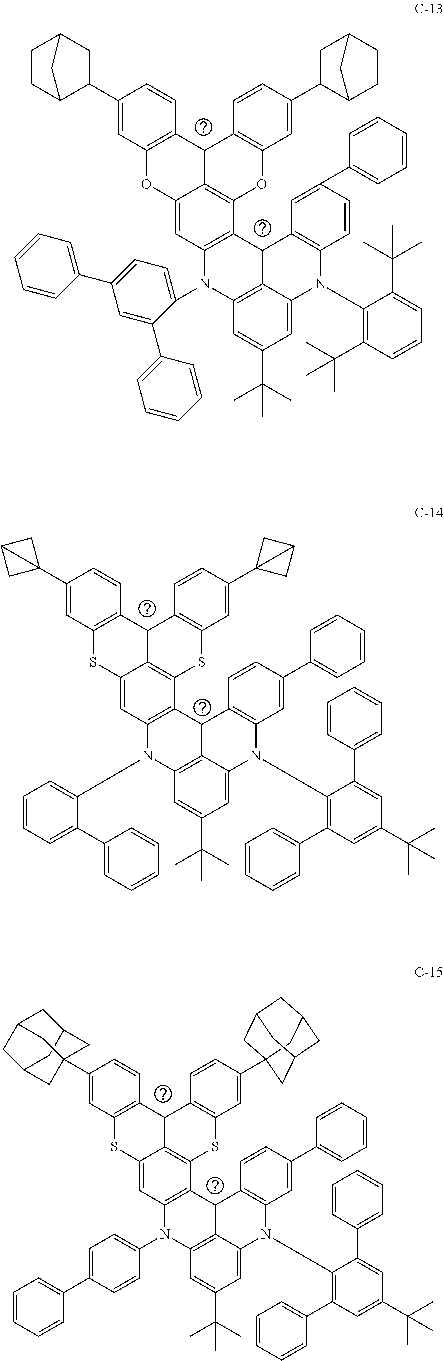

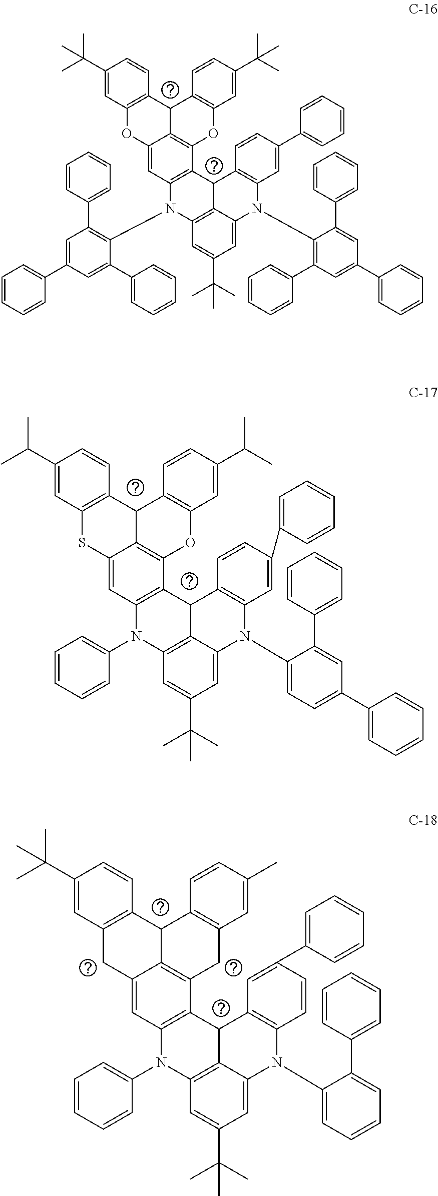

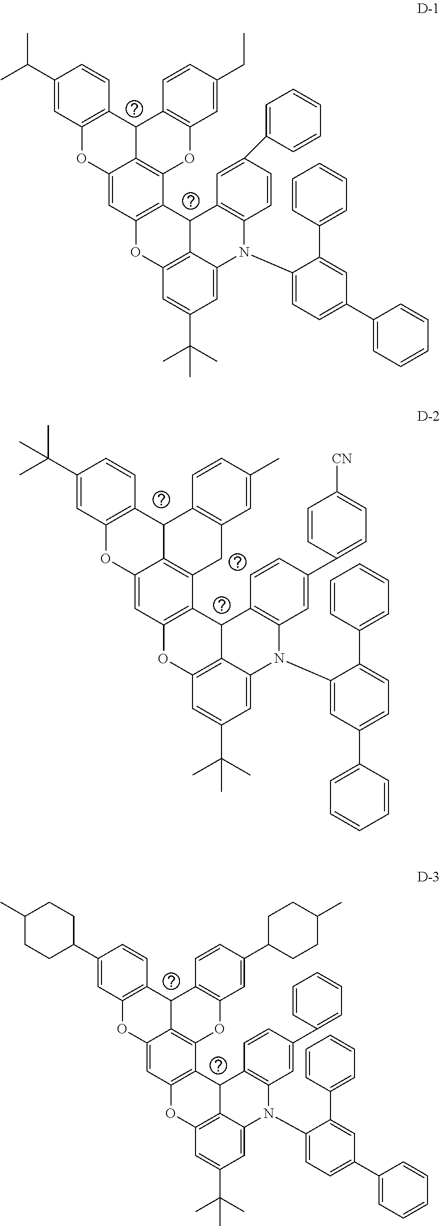 [SMILES: CCc1ccc2c(c1)Oc1c3c(cc4c1C1c5cc(-c6ccccc6)ccc5N(c5ccc(-c6ccccc6)cc5-c5ccccc5)c5cc(C(C)(C)C)cc(c51)O4)Oc1cc(C(C)C)ccc1C23 ; Cc1ccc2c(c1)Cc1c3c(cc4c1C1c5ccc(-c6ccc(C#N)cc6)cc5N(c5cc(-c6ccccc6)ccc5-c5ccccc5)c5cc(C(C)(C)C)cc(c51)O4)Oc1cc(C(C)(C)C)ccc1C23 ; CC1CCC(c2ccc3c(c2)Oc2cc4c(c5c2C3c2ccc(C3CCC(C)CC3)cc2O5)C2c3ccc(-c5ccccc5)cc3N(c3ccc(-c5ccccc5)cc3-c3ccccc3)c3cc(C(C)(C)C)cc(c32)O4)CC1]

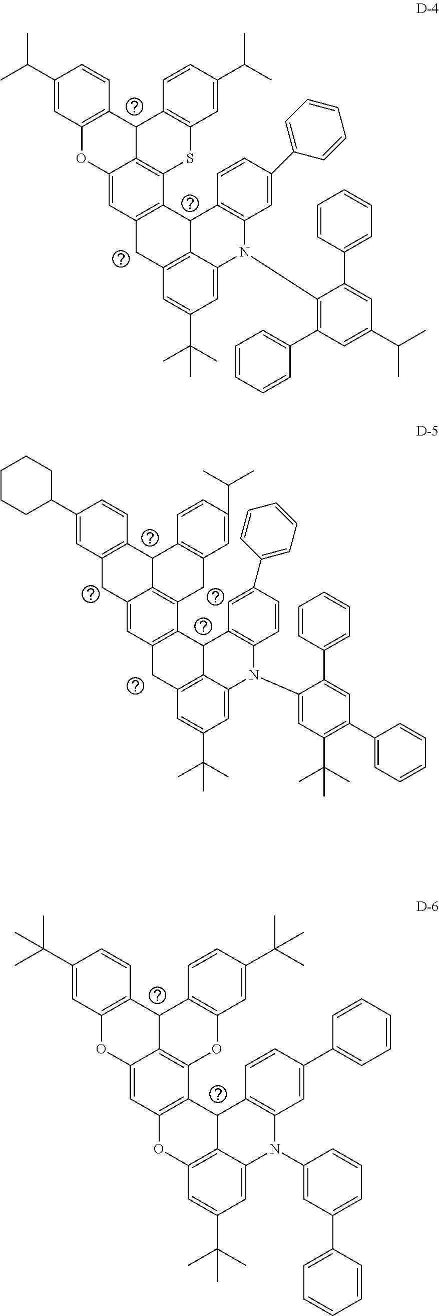

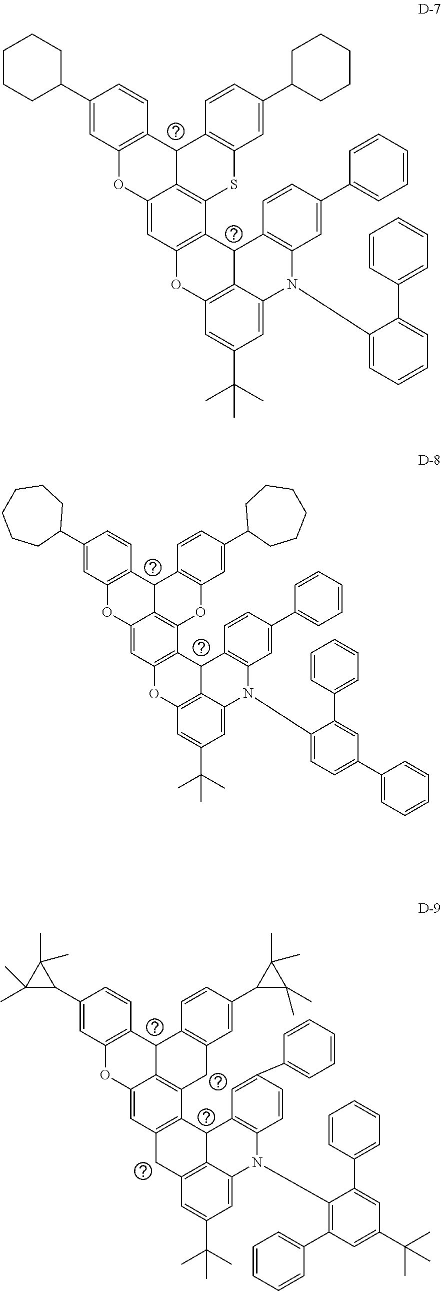 [SMILES: CC(C)(C)c1cc2c3c(c1)N(c1ccccc1-c1ccccc1)c1cc(-c4ccccc4)ccc1C3c1c(cc3c4c1Sc1cc(C5CCCCC5)ccc1C4c1ccc(C4CCCCC4)cc1O3)O2 ; CC(C)(C)c1cc2c3c(c1)N(c1ccc(-c4ccccc4)cc1-c1ccccc1)c1cc(-c4ccccc4)ccc1C3c1c(cc3c4c1Oc1cc(C5CCCCCC5)ccc1C4c1ccc(C4CCCCCC4)cc1O3)O2 ; CC(C)(C)c1cc(-c2ccccc2)c(N2c3ccc(-c4ccccc4)cc3C3c4c(cc(C(C)(C)C)cc42)Cc2cc4c5c(c23)Cc2cc(C3C(C)(C)C3(C)C)ccc2C5c2ccc(C3C(C)(C)C3(C)C)cc2O4)c(-c2ccccc2)c1]

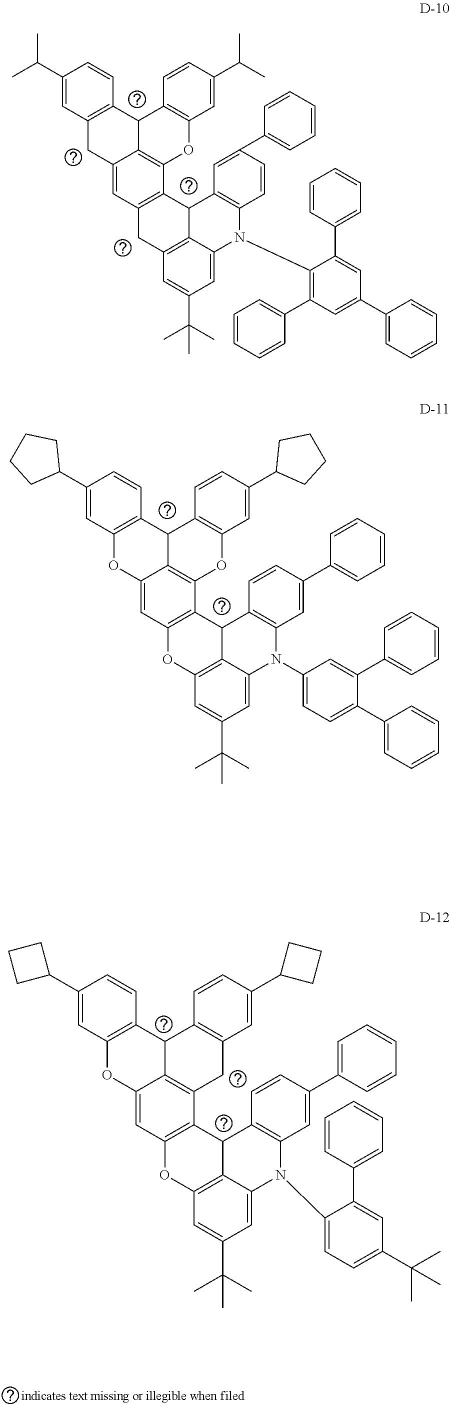 [SMILES: CC(C)c1ccc2c(c1)Cc1cc3c(c4c1C2c1ccc(C(C)C)cc1O4)C1c2cc(-c4ccccc4)ccc2N(c2c(-c4ccccc4)cc(-c4ccccc4)cc2-c2ccccc2)c2cc(C(C)(C)C)cc(c21)C3 ; CC(C)(C)c1cc2c3c(c1)N(c1ccc(-c4ccccc4)c(-c4ccccc4)c1)c1cc(-c4ccccc4)ccc1C3c1c(cc3c4c1Oc1cc(C5CCCC5)ccc1C4c1ccc(C4CCCC4)cc1O3)O2 ; CC(C)(C)c1ccc(N2c3cc(-c4ccccc4)ccc3C3c4c(cc(C(C)(C)C)cc42)Oc2cc4c5c(c23)Cc2cc(C3CCC3)ccc2C5c2ccc(C3CCC3)cc2O4)c(-c2ccccc2)c1]

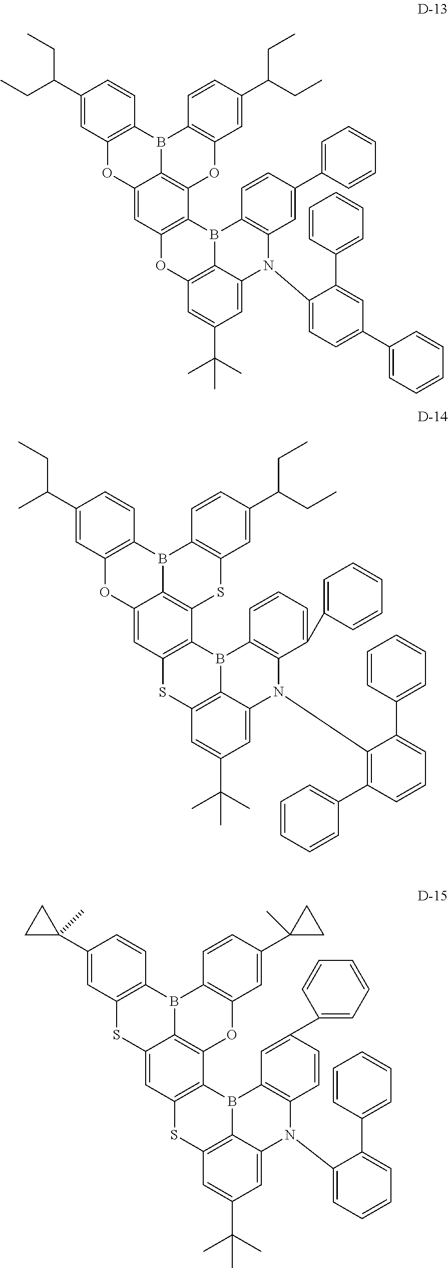

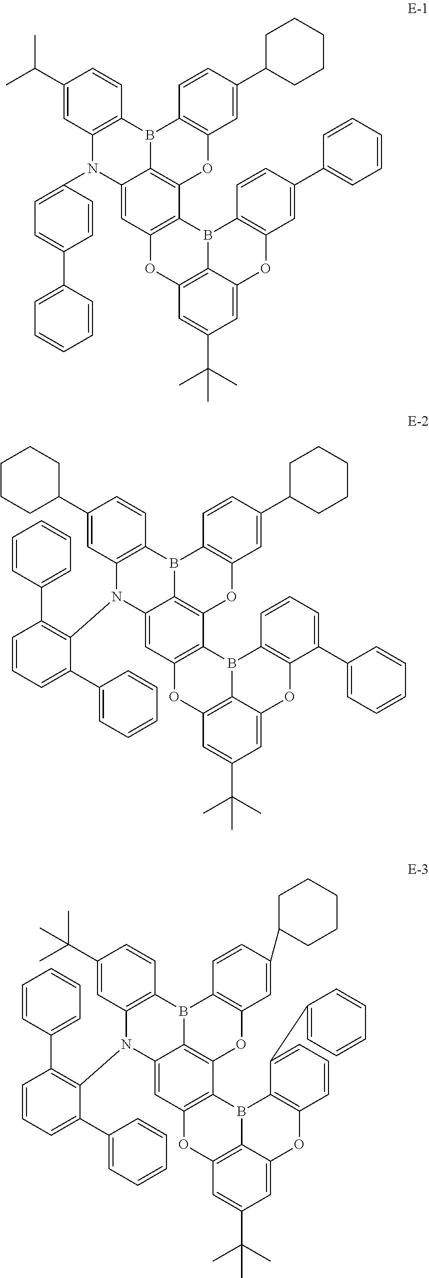 [SMILES: CC(C)c1ccc2c(c1)N(c1ccc(-c3ccccc3)cc1)c1cc3c(c4c1B2c1ccc(C2CCCCC2)cc1O4)B1c2ccc(-c4ccccc4)cc2Oc2cc(C(C)(C)C)cc(c21)O3 ; CC(C)(C)c1cc2c3c(c1)Oc1c(cccc1-c1ccccc1)B3c1c(cc3c4c1Oc1cc(C5CCCCC5)ccc1B4c1ccc(C4CCCCC4)cc1N3c1c(-c3ccccc3)cccc1-c1ccccc1)O2 ; CC(C)(C)c1cc2c3c(c1)Oc1cc4c5c(c1B3c1c(cccc1-c1ccccc1)O2)Oc1cc(C2CCCCC2)ccc1B5c1ccc(C(C)(C)C)cc1N4c1c(-c2ccccc2)cccc1-c1ccccc1]

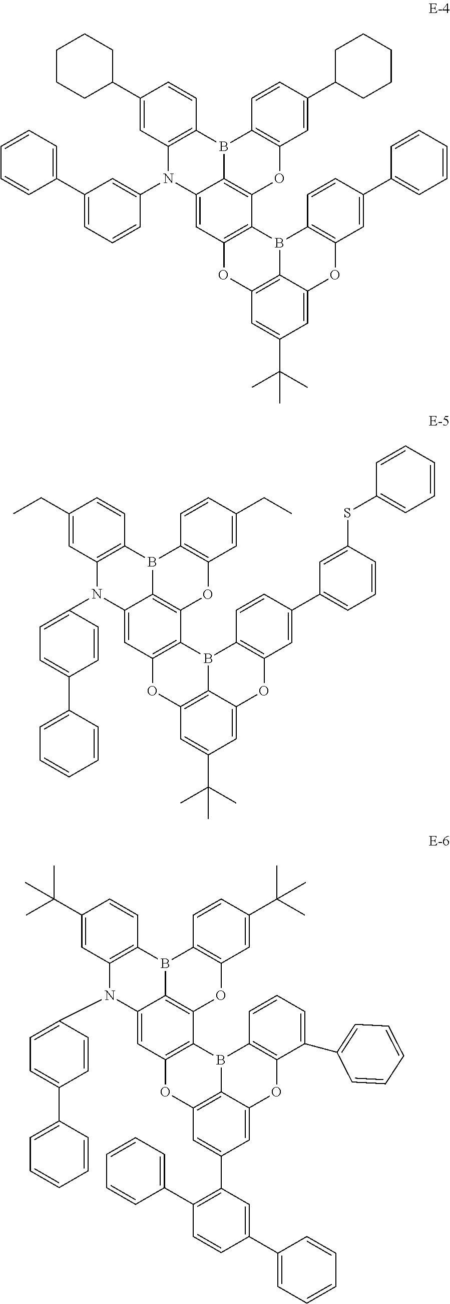 [SMILES: CC(C)(C)c1cc2c3c(c1)Oc1cc4c5c(c1B3c1ccc(-c3ccccc3)cc1O2)Oc1cc(C2CCCCC2)ccc1B5c1ccc(C2CCCCC2)cc1N4c1cccc(-c2ccccc2)c1 ; CCc1ccc2c(c1)Oc1c3c(cc4c1B2c1ccc(CC)cc1N4c1ccc(-c2ccccc2)cc1)Oc1cc(C(C)(C)C)cc2c1B3c1ccc(-c3cccc(Sc4ccccc4)c3)cc1O2 ; CC(C)(C)c1ccc2c(c1)Oc1c3c(cc4c1B2c1ccc(C(C)(C)C)cc1N4c1ccc(-c2ccccc2)cc1)Oc1cc(-c2cc(-c4ccccc4)ccc2-c2ccccc2)cc2c1B3c1cccc(-c3ccccc3)c1O2]

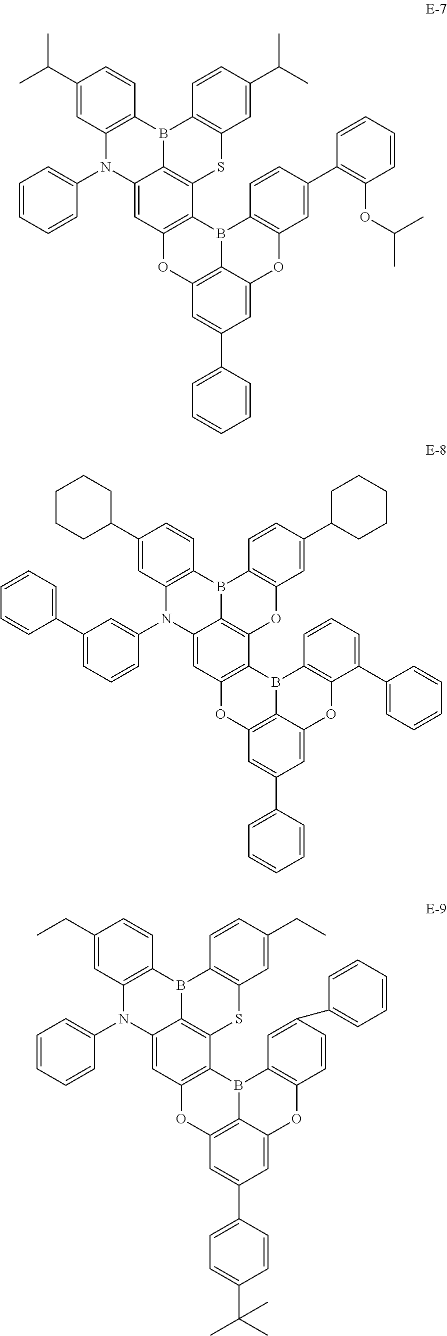 [SMILES: CC(C)Oc1ccccc1-c1ccc2c(c1)Oc1cc(-c3ccccc3)cc3c1B2c1c(cc2c4c1Sc1cc(C(C)C)ccc1B4c1ccc(C(C)C)cc1N2c1ccccc1)O3 ; c1ccc(-c2cccc(N3c4cc(C5CCCCC5)ccc4B4c5ccc(C6CCCCC6)cc5Oc5c6c(cc3c54)Oc3cc(-c4ccccc4)cc4c3B6c3cccc(-c5ccccc5)c3O4)c2)cc1 ; CCc1ccc2c(c1)Sc1c3c(cc4c1B2c1ccc(CC)cc1N4c1ccccc1)Oc1cc(-c2ccc(C(C)(C)C)cc2)cc2c1B3c1cc(-c3ccccc3)ccc1O2]

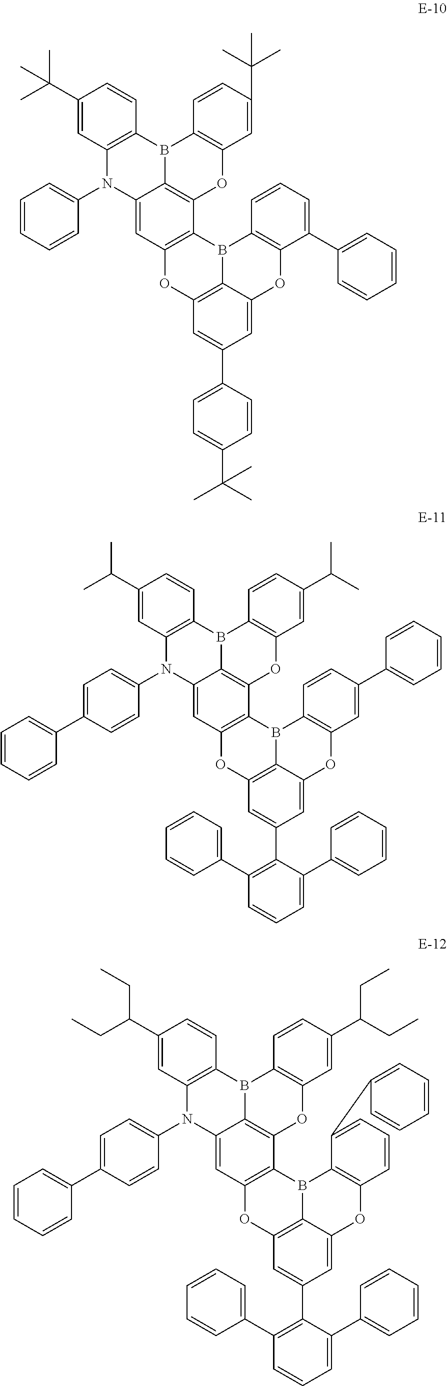 [SMILES: CC(C)(C)c1ccc(-c2cc3c4c(c2)Oc2c(cccc2-c2ccccc2)B4c2c(cc4c5c2Oc2cc(C(C)(C)C)ccc2B5c2ccc(C(C)(C)C)cc2N4c2ccccc2)O3)cc1 ; CC(C)c1ccc2c(c1)Oc1c3c(cc4c1B2c1ccc(C(C)C)cc1N4c1ccc(-c2ccccc2)cc1)Oc1cc(-c2c(-c4ccccc4)cccc2-c2ccccc2)cc2c1B3c1ccc(-c3ccccc3)cc1O2 ; CCC(CC)c1ccc2c(c1)Oc1c3c(cc4c1B2c1ccc(C(CC)CC)cc1N4c1ccc(-c2ccccc2)cc1)Oc1cc(-c2c(-c4ccccc4)cccc2-c2ccccc2)cc2c1B3c1c(cccc1-c1ccccc1)O2]

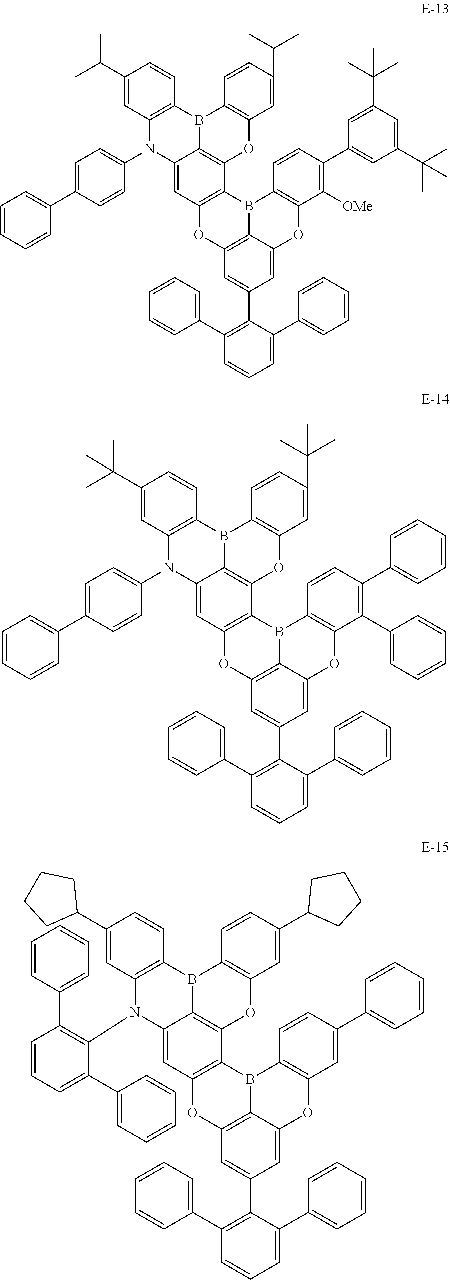 [SMILES: COc1c(-c2cc(C(C)(C)C)cc(C(C)(C)C)c2)ccc2c1Oc1cc(-c3c(-c4ccccc4)cccc3-c3ccccc3)cc3c1B2c1c(cc2c4c1Oc1cc(C(C)C)ccc1B4c1ccc(C(C)C)cc1N2c1ccc(-c2ccccc2)cc1)O3 ; CC(C)(C)c1ccc2c(c1)Oc1c3c(cc4c1B2c1ccc(C(C)(C)C)cc1N4c1ccc(-c2ccccc2)cc1)Oc1cc(-c2c(-c4ccccc4)cccc2-c2ccccc2)cc2c1B3c1ccc(-c3ccccc3)c(-c3ccccc3)c1O2 ; c1ccc(-c2ccc3c(c2)Oc2cc(-c4c(-c5ccccc5)cccc4-c4ccccc4)cc4c2B3c2c(cc3c5c2Oc2cc(C6CCCC6)ccc2B5c2ccc(C5CCCC5)cc2N3c2c(-c3ccccc3)cccc2-c2ccccc2)O4)cc1]

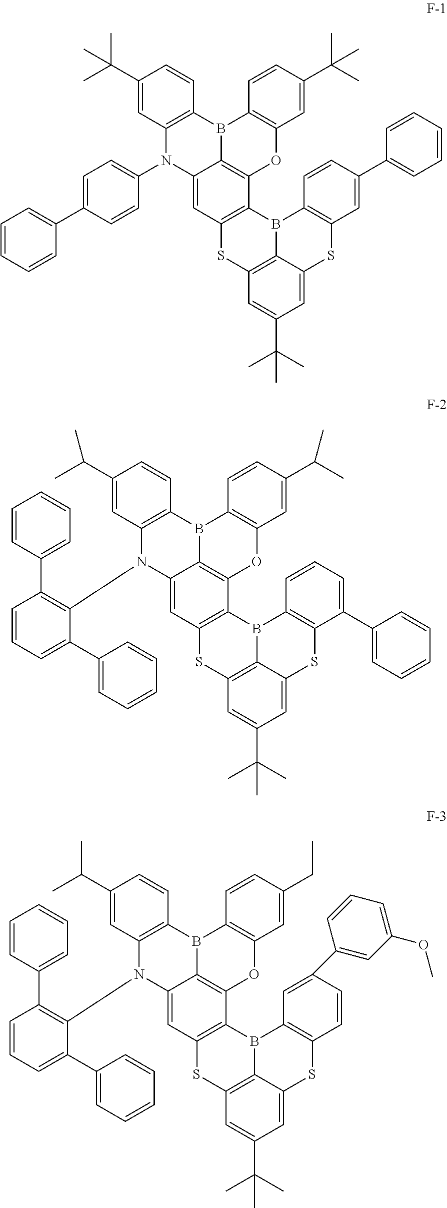 [SMILES: CC(C)(C)c1ccc2c(c1)Oc1c3c(cc4c1B2c1ccc(C(C)(C)C)cc1N4c1ccc(-c2ccccc2)cc1)Sc1cc(C(C)(C)C)cc2c1B3c1ccc(-c3ccccc3)cc1S2 ; CC(C)c1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cccc(-c3ccccc3)c1S2 ; CCc1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cc(-c3cccc(OC)c3)ccc1S2]

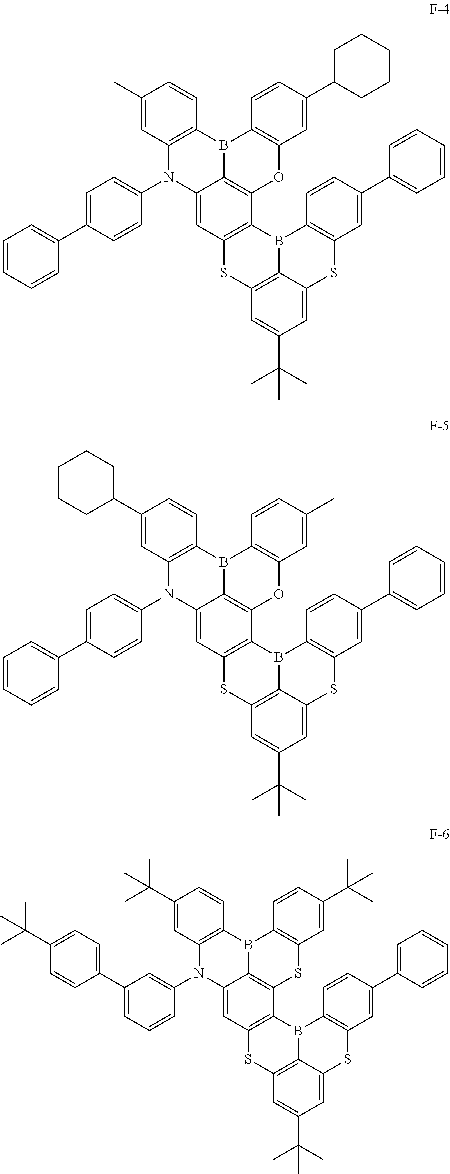 [SMILES: Cc1ccc2c(c1)N(c1ccc(-c3ccccc3)cc1)c1cc3c(c4c1B2c1ccc(C2CCCCC2)cc1O4)B1c2ccc(-c4ccccc4)cc2Sc2cc(C(C)(C)C)cc(c21)S3 ; Cc1ccc2c(c1)Oc1c3c(cc4c1B2c1ccc(C2CCCCC2)cc1N4c1ccc(-c2ccccc2)cc1)Sc1cc(C(C)(C)C)cc2c1B3c1ccc(-c3ccccc3)cc1S2 ; CC(C)(C)c1ccc(-c2cccc(N3c4cc(C(C)(C)C)ccc4B4c5ccc(C(C)(C)C)cc5Sc5c6c(cc3c54)Sc3cc(C(C)(C)C)cc4c3B6c3ccc(-c5ccccc5)cc3S4)c2)cc1]

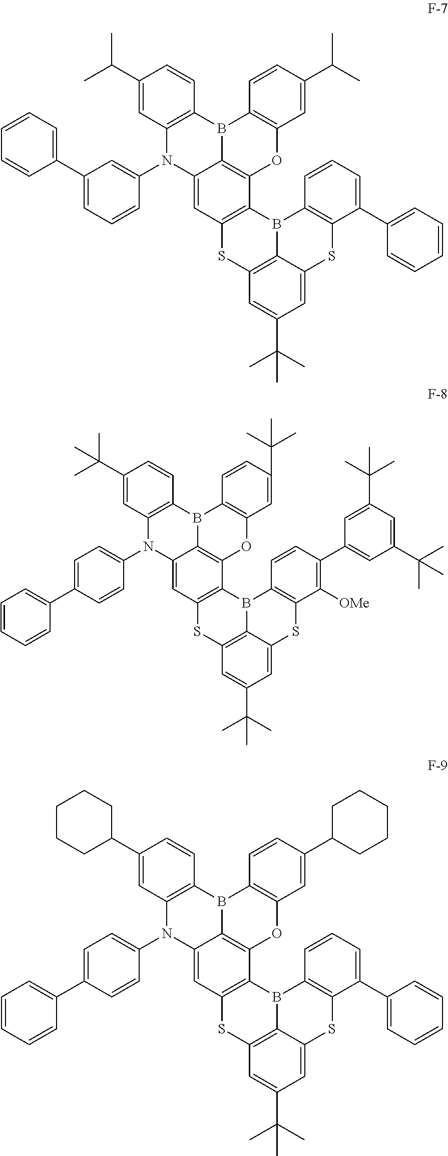

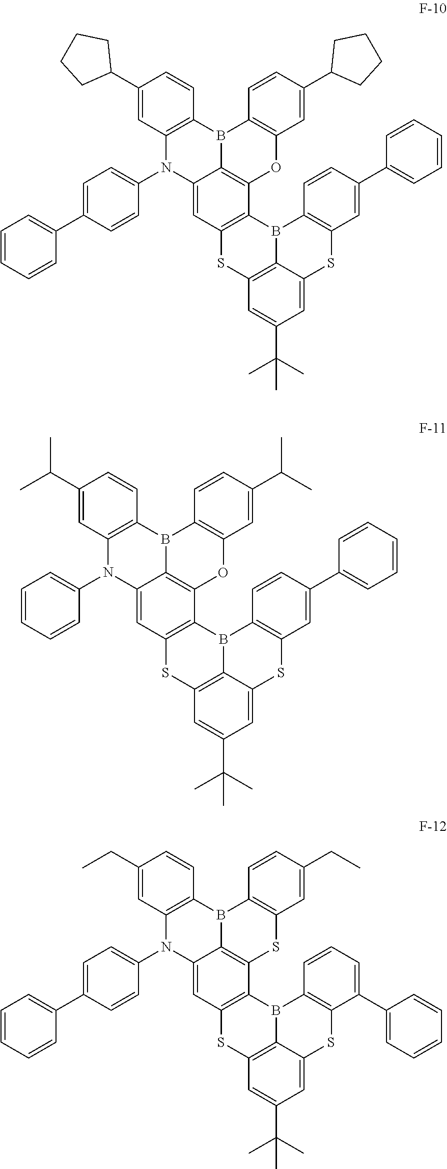 [SMILES: CC(C)(C)c1cc2c3c(c1)Sc1cc4c5c(c1B3c1ccc(-c3ccccc3)cc1S2)Oc1cc(C2CCCC2)ccc1B5c1ccc(C2CCCC2)cc1N4c1ccc(-c2ccccc2)cc1 ; CC(C)c1ccc2c(c1)Oc1c3c(cc4c1B2c1ccc(C(C)C)cc1N4c1ccccc1)Sc1cc(C(C)(C)C)cc2c1B3c1ccc(-c3ccccc3)cc1S2 ; CCc1ccc2c(c1)Sc1c3c(cc4c1B2c1ccc(CC)cc1N4c1ccc(-c2ccccc2)cc1)Sc1cc(C(C)(C)C)cc2c1B3c1cccc(-c3ccccc3)c1S2]

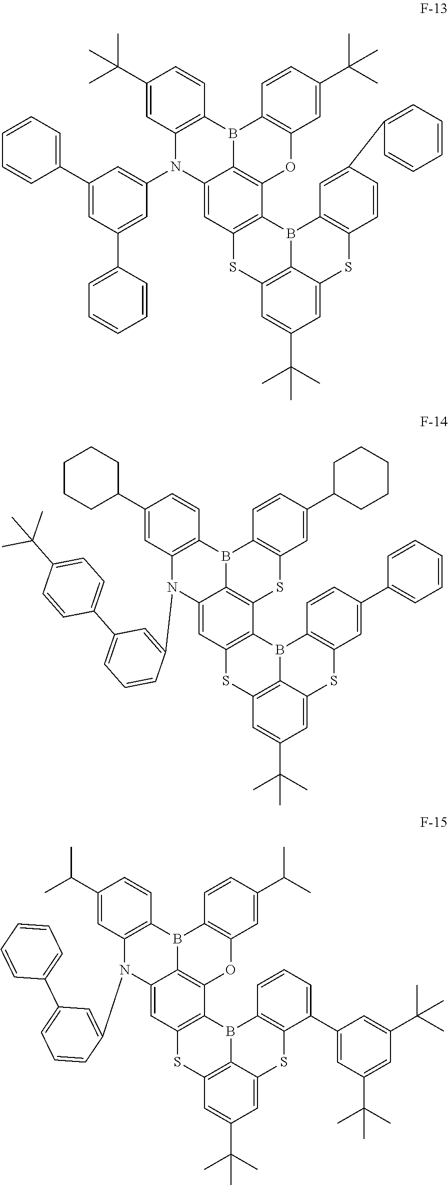

In Compound Group 1, D is a deuterium atom.

The fused polycyclic compound according to one or more embodiments may be used as a delayed fluorescence material. For example, the fused polycyclic compound according to one or more embodiments may be used as a thermally activated delayed fluorescence (TADF) material. The fused polycyclic compound according to one or more embodiments may exhibit a high fluorescence quantum yield. For example, the fused polycyclic compound according to one or more embodiments may exhibit a high fluorescence quantum yield in a blue wavelength range having a maximum central wavelength (e.g., peak emission wavelength) of about 470 nm or less.

The fused polycyclic compound according to one or more embodiments may include a boron-containing fused ring containing two boron atoms as ring-forming atoms, as a central structure. The fused polycyclic compound according to one or more embodiments may include a fused heterocycle of nine six-membered rings, as a central structure and may include a fused ring of nine rings containing four heteroatoms and two boron atoms as ring-forming atoms, as a central structure.

The fused polycyclic compound according to one or more embodiments may include first substituents (R^{a1} and R^{a2} in Formula 1) bonded to both para positions to one of the two boron atoms, and second substituents (R^{b1} to R^{b4} in Formula 1) bonded to an adjacent ring to another boron atom.

The compounds including a fused ring of nine rings may not protect the redox-active sites and have defects of degraded material stability and reduced element lifespan. In addition, as the multiple resonance (MR) characteristic decreases and the charge transfer (CT) characteristic increases, the full width at half maximum (FWHM) and stokes shift values increase, which may arise a defect of deteriorating light emitting efficiency.

FIG. 10 shows the absorption spectra of Compound X-10 and Compound X-10′. Referring to FIG. 10, Compound X-10, in which the first substituent is a phenyl group, and Compound X-10′, in which the first substituent is a hydrogen atom, emit light at a wavelength of about 450 nm to about 470 nm. Compound X-10, in which the first substituent is a phenyl group, has a full width at half maximum (FWHM) of about 44 nm, whereas Compound X-10′, in which the first substituent, the phenyl group, is removed from Compound X-10, has a full width at half maximum (FWHM) that is reduced to about 38 nm.

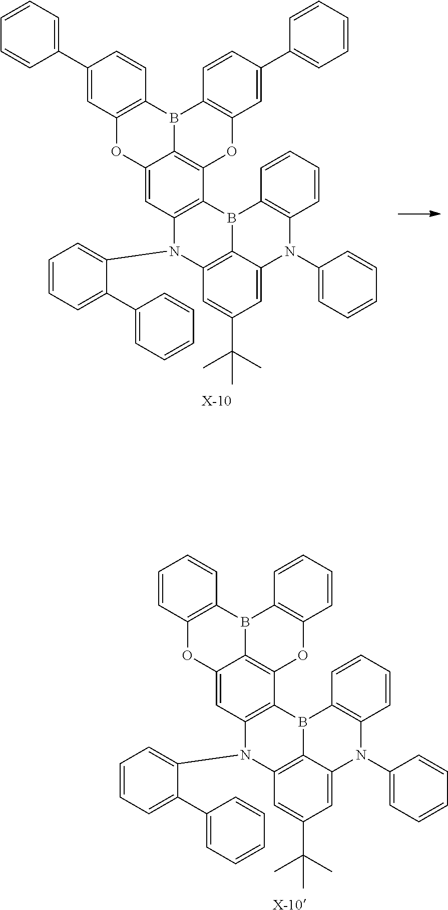

The fused polycyclic compound according to one or more embodiments includes a fused ring of nine rings, containing four heteroatoms and two boron atoms as ring-forming atoms, as a central structure. The fused polycyclic compound of an embodiment includes an alkyl group or a cycloalkyl group as the first substituent, and an aryl group as the second substituent, thereby exhibiting narrow full width at half maximum and narrow stokes shift characteristics, ensuring high efficiency and suppressing or reducing expansion of the LUMO orbital. In addition, because appropriate or suitable steric protection of the redox-active site is possible, material stability and lifespan characteristics may be improved. Accordingly, a light emitting element of one or more embodiments including the fused polycyclic compound of an embodiment may exhibit high light emitting efficiency and long-life characteristics.

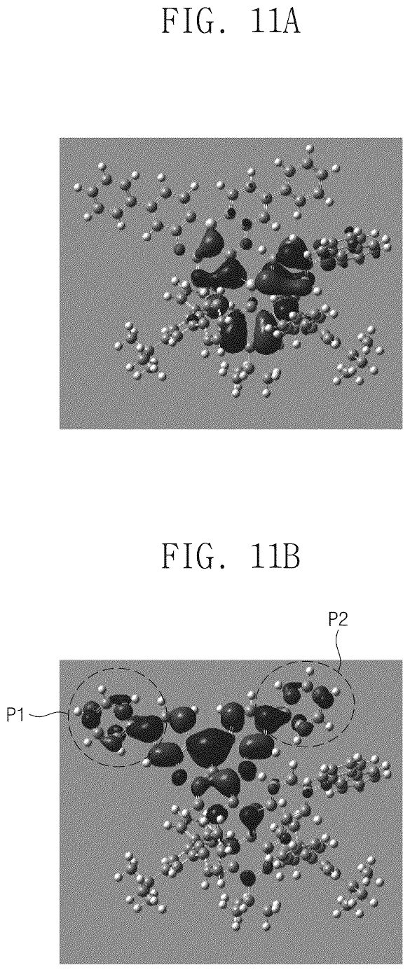

FIG. 11A is an image showing the highest occupied molecular orbital (HOMO) orbital distribution of Compound X-9, and FIG. 11B is an image showing the lowest unoccupied molecular orbital (LUMO) orbital distribution of Compound X-9.

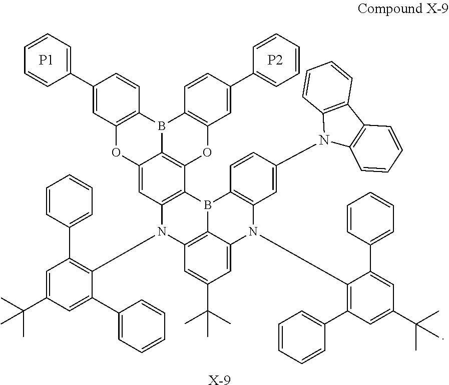

Compound X-9, unlike the fused polycyclic compound according to other embodiments, is a compound in which the first substituents (R^{a1} and R^{a2} in Formula 1) are unsubstituted phenyl groups and the second substituent (R^{b3} in Formula 1) is an unsubstituted carbazole group. In Compound X-9, “P1” and “P2” are indicated for convenience of explanation, and P1 and P2 in Compound X-9 correspond to P1 and P2 in FIG. 11B.

Referring to FIGS. 11A and 11B, the LUMO orbital of Compound X-9 is extended to the cyclic groups indicated by P1 and P2 by the first substituent, which is an aryl group. Accordingly, the redox-active site of a molecule protrudes outward, and the stability of the molecule may be reduced.

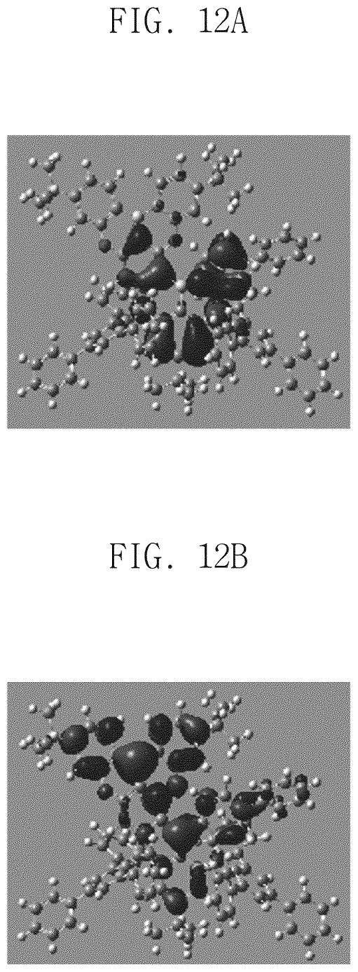

FIG. 12A is an image showing the HOMO orbital distribution of Compound C-16, and FIG. 12B is an image showing the LUMO orbital distribution of Compound C-16.

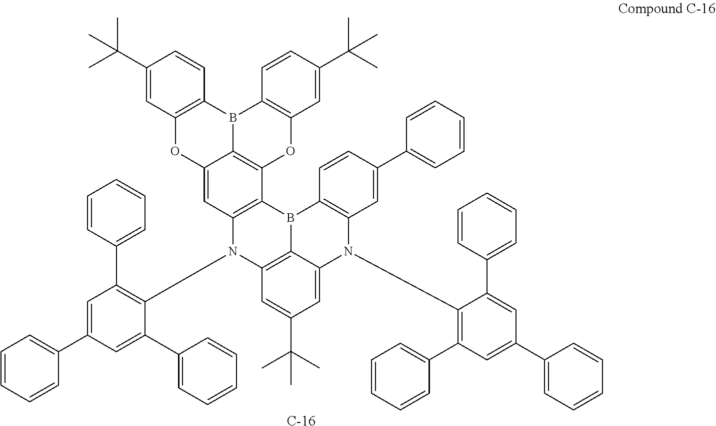

Compound C-16, which is the fused polycyclic compound according to one or more embodiments, is a compound in which the first substituents (R^{a1} and R^{a2} in Formula 1) are unsubstituted terphenyl groups and the second substituent (R^{b3} in Formula 1) is an unsubstituted phenyl group.

Referring to FIGS. 12A and 12B, Compound C-16 introduces a terphenyl group, which is an alkyl group, as the first substituent, and the redox-active site of the molecule may be protected and LUMO orbital may be prevented or reduced from diffusing, thereby exhibiting excellent or suitable molecular stability. In addition, by introducing a phenyl group, which is an aryl group, as the second substituent along with the first substituents, narrow full width at half maximum and narrow stokes shift characteristics may be achieved, and high light emitting efficiency and long lifespan may be secured.

In a light emitting element according to one or more embodiments, the emission layer EML may be a delayed fluorescence emitting layer including a host and a dopant. More specifically, the emission layer EML may be to emit thermally activated delayed fluorescence (TADF). In one or more embodiments, the fused polycyclic compound may be a thermally activated delayed fluorescence (TADF) dopant.

The emission layer EML may include the fused polycyclic compound according to one or more embodiments as a dopant. The fused polycyclic compound one or more embodiments may be to emit blue light. For example, the fused polycyclic compound according to one or more embodiments may be a light emitting material having a maximum light emitting wavelength in a wavelength range of about 430 nm to about 490 nm. For example, the fused polycyclic compound according to one or more embodiments may be a light emitting material having a maximum light emitting wavelength in a wavelength range of about 440 nm to about 470 nm.

In one or more embodiments, the emission layer EML includes the fused polycyclic compound of an embodiment and may include at least one of the second to fourth compounds. In one or more embodiments, the emission layer EML may include a second compound represented by Formula HT-1. For example, the second compound may be used as a hole transporting host material of the emission layer EML.

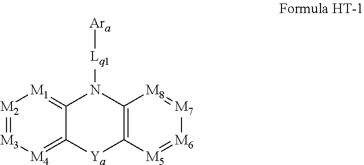

In Formula HT-1, M₁ to M₈ may each independently be N or CRₐ₁₁. For example, M₁ to M₈ all may be CRₐ₁₁. In one or more embodiments, any one among M₁ to M₈ may be N, and the remainder may be CRₐ₁₁.

In Formula HT-1, L_{q1} may be a direct linkage, a substituted or unsubstituted arylene group of 6 to 30 ring-forming carbon atoms, or a substituted or unsubstituted heteroarylene group of 2 to 30 ring-forming carbon atoms. For example, in one or more embodiments, L_{q1} may be a direct linkage, a substituted or unsubstituted phenylene group, a substituted or unsubstituted divalent biphenyl group, or a substituted or unsubstituted divalent carbazole group, but an embodiment of the disclosure is not limited thereto.

In Formula HT-1, Yₐ may be a direct linkage, CRₐ₁₂Rₐ₁₃, or SiRₐ₁₄Rₐ₁₅. For example, two six-membered rings (e.g., two benzene rings) connected to the nitrogen atom of Formula HT-1 may be connected via a direct linkage,

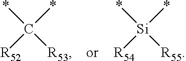

In Formula HT-1, if (e.g., when) Yₐ is a direct linkage, the second compound represented by Formula HT-1 may include a carbazole moiety.

In Formula HT-1, Arₐ may be a substituted or unsubstituted aryl group of 6 to 30 ring-forming carbon atoms, or a substituted or unsubstituted heteroaryl group of 2 to 30 ring-forming carbon atoms. For example, in one or more embodiments, Arₐ may be a substituted or unsubstituted carbazole group, a substituted or unsubstituted dibenzofuran group, a substituted or unsubstituted dibenzothiophene group, or a substituted or unsubstituted biphenyl group, and/or the like, but embodiments of the present disclosure are not limited thereto.

In Formula HT-1, Rₐ₁₁ to Rₐ₁₅ and R₅₂ to R₅₄ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms. In one or more embodiments, one or more selected from among Rₐ₁₁ to Rₐ₁₅ may be combined with an adjacent group to form a ring. For example, in one or more embodiments, Rₐ₁₁ to Rₐ₁₅ may each independently be a hydrogen atom or a deuterium atom. Rₐ₁₁ to Rₐ₁₅ may each independently be an unsubstituted methyl group or an unsubstituted phenyl group.

In one or more embodiments, the second compound represented by Formula HT-1 may be any one selected from among compounds represented in Compound Group 2. The emission layer EML may include at least one selected from among the compounds represented in Compound Group 2 as a hole transporting host material.

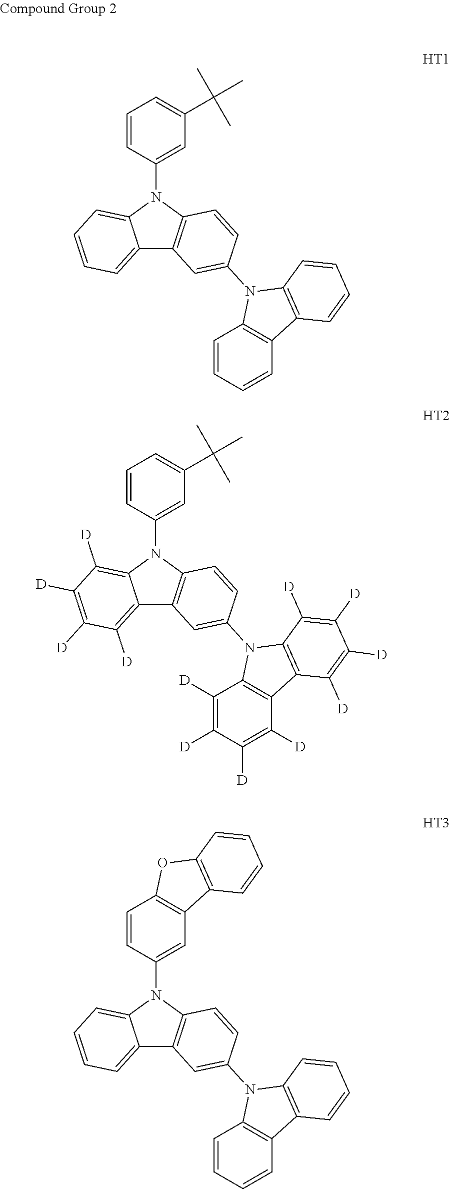

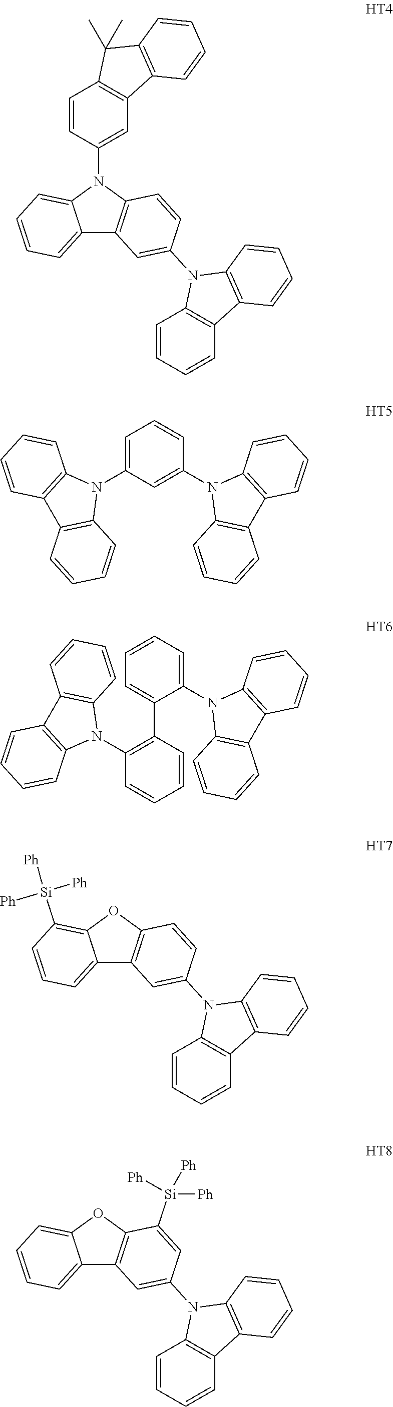 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

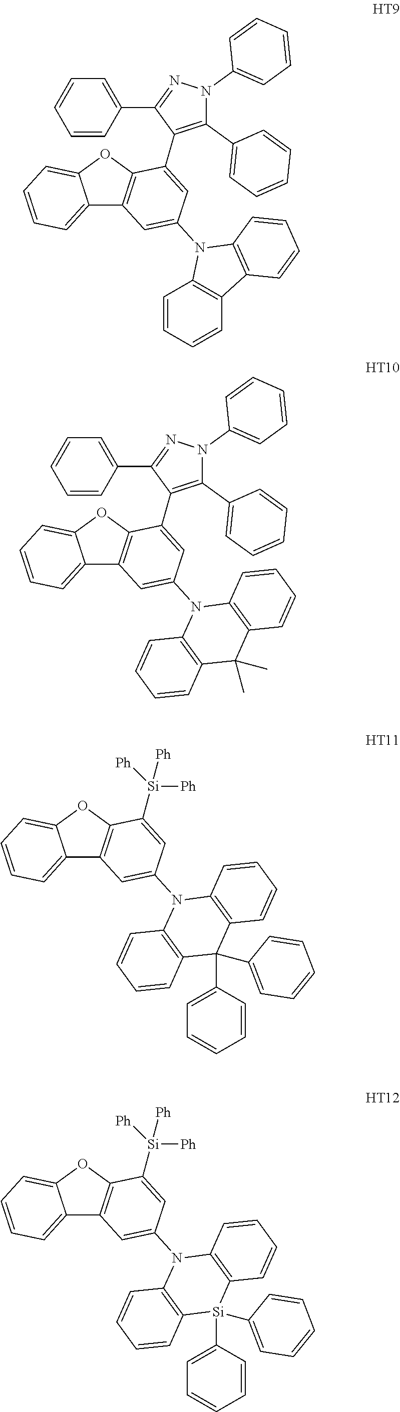 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

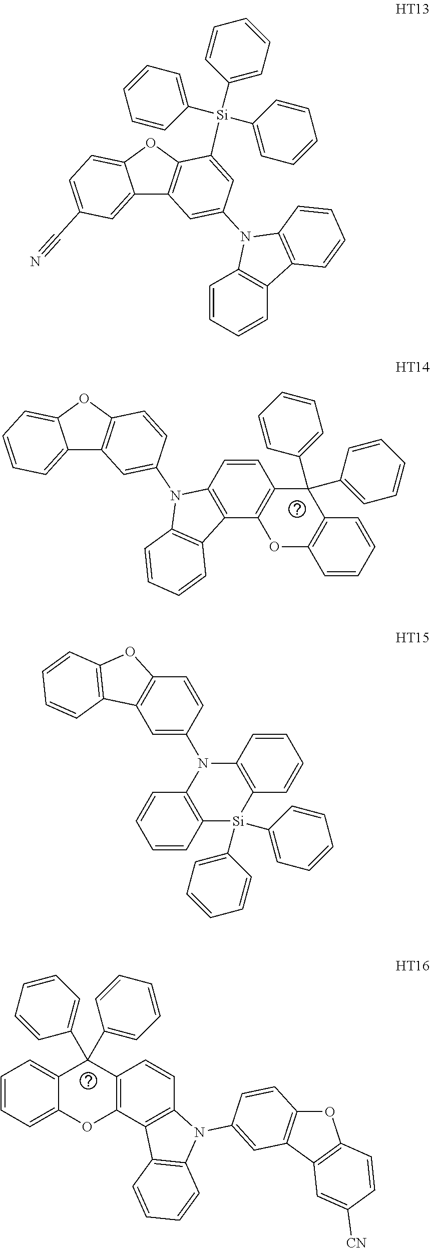 [SMILES: N#Cc1ccc2oc3c([Si](c4ccccc4)(c4ccccc4)c4ccccc4)cc(-n4c5ccccc5c5ccccc54)cc3c2c1 ; c1ccc(C2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)C(c4ccccc4)(c4ccccc4)c4ccccc4O6)cc3c2c1]

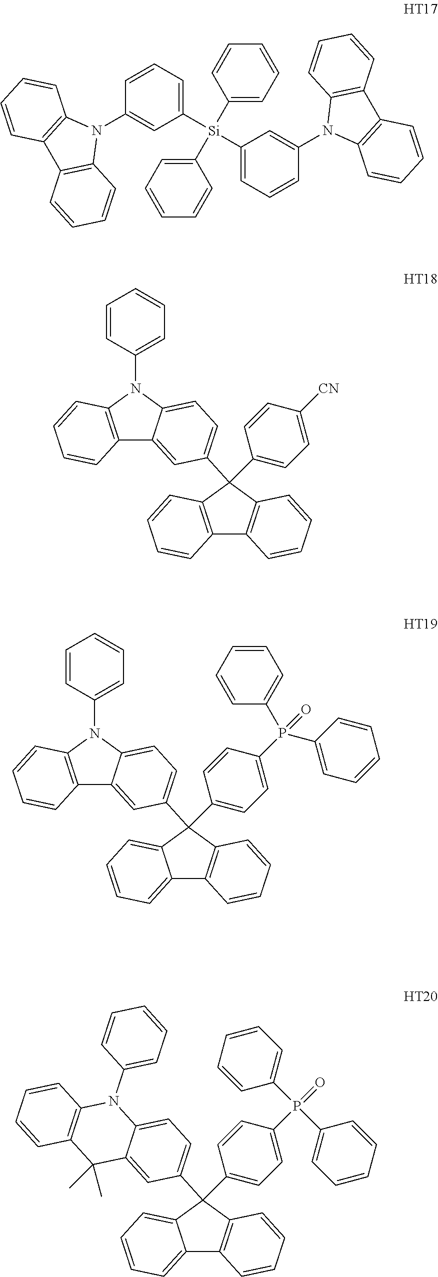 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

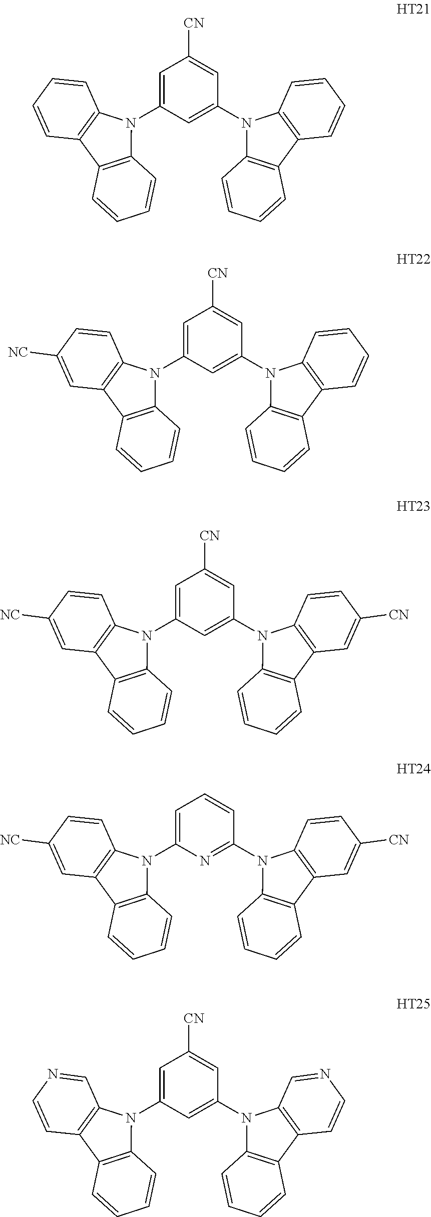 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

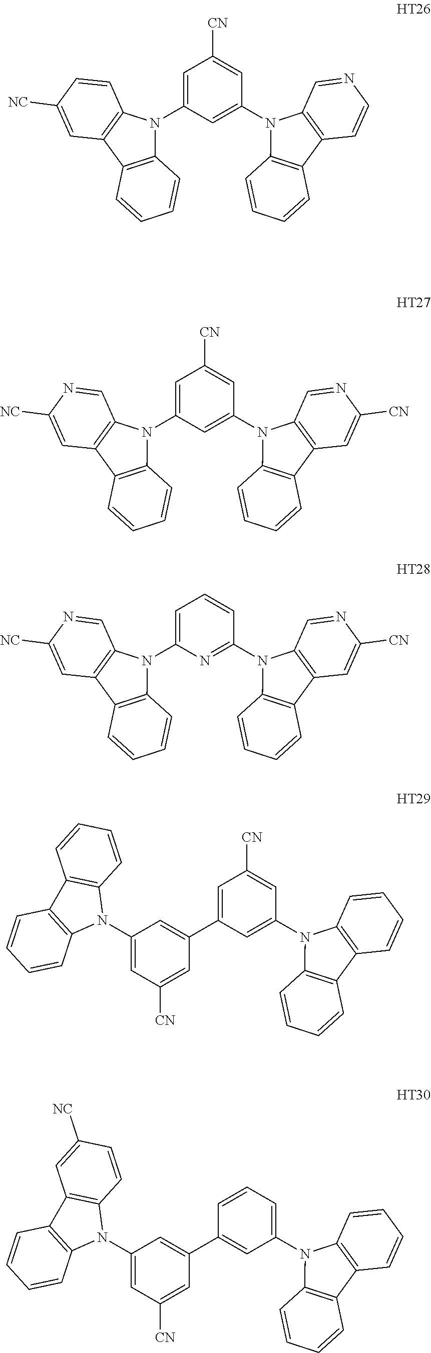 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

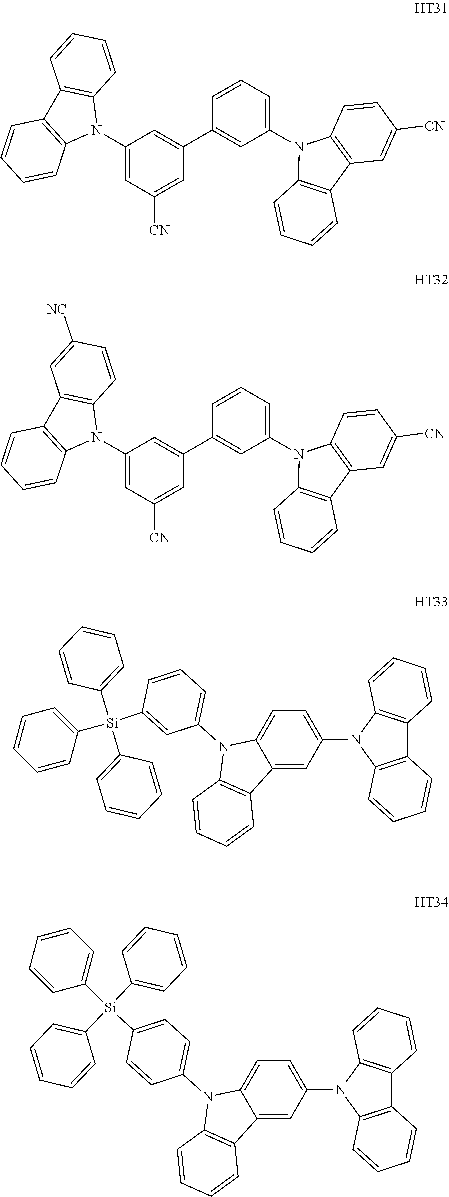 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

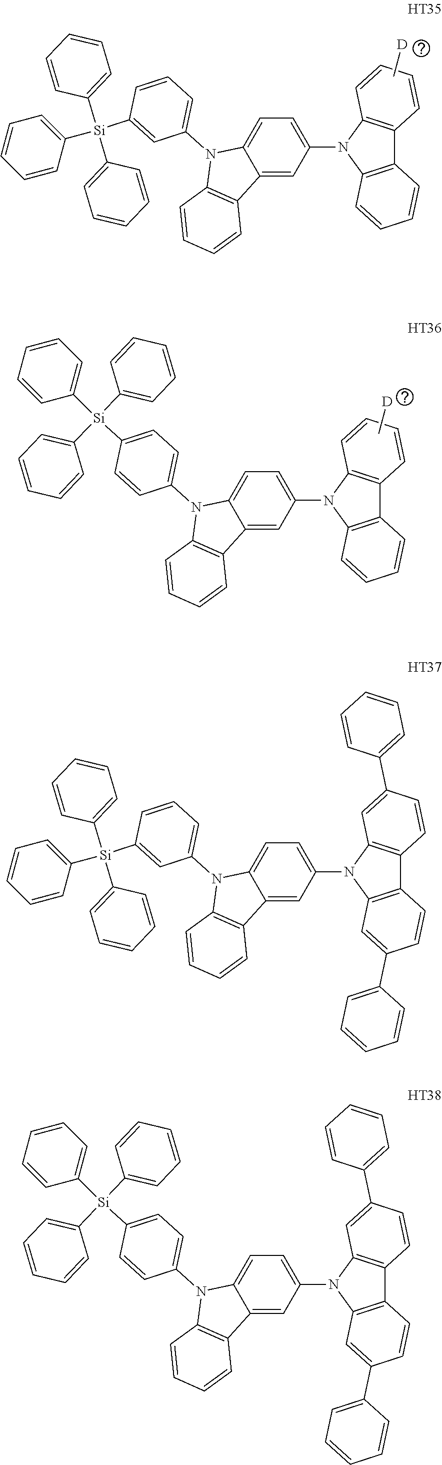

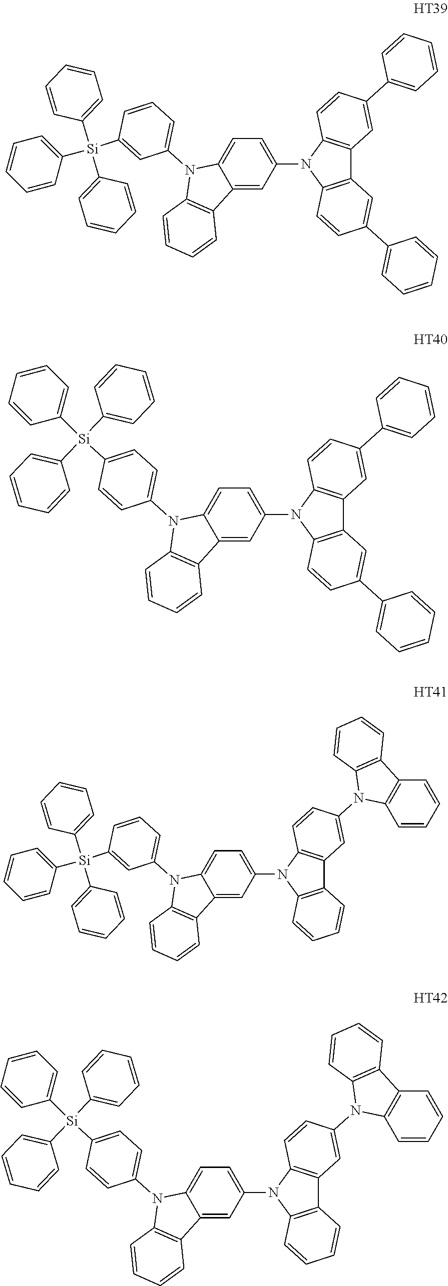 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

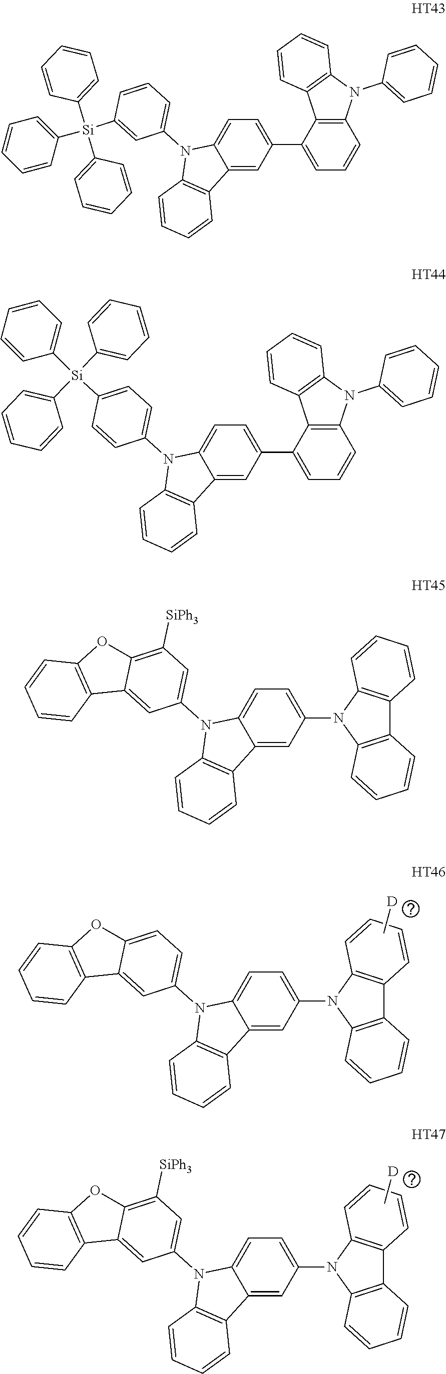

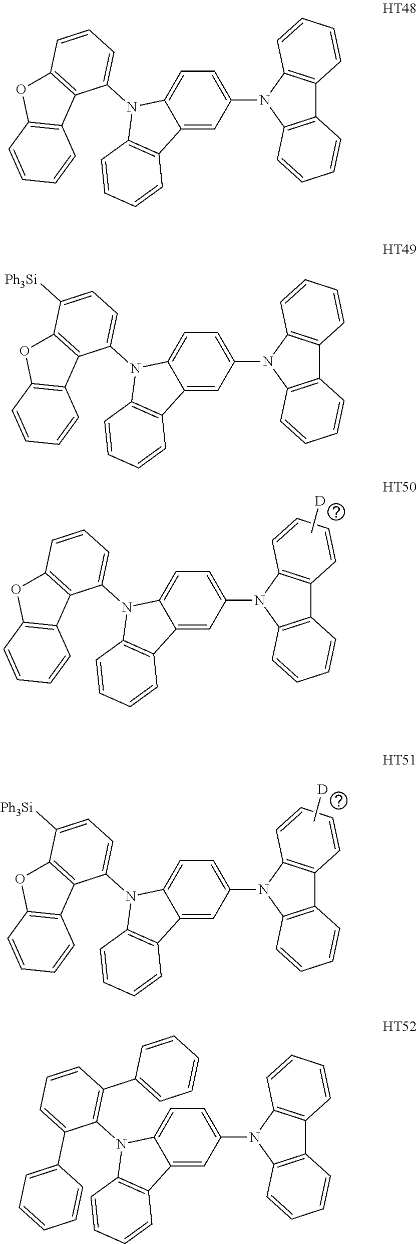

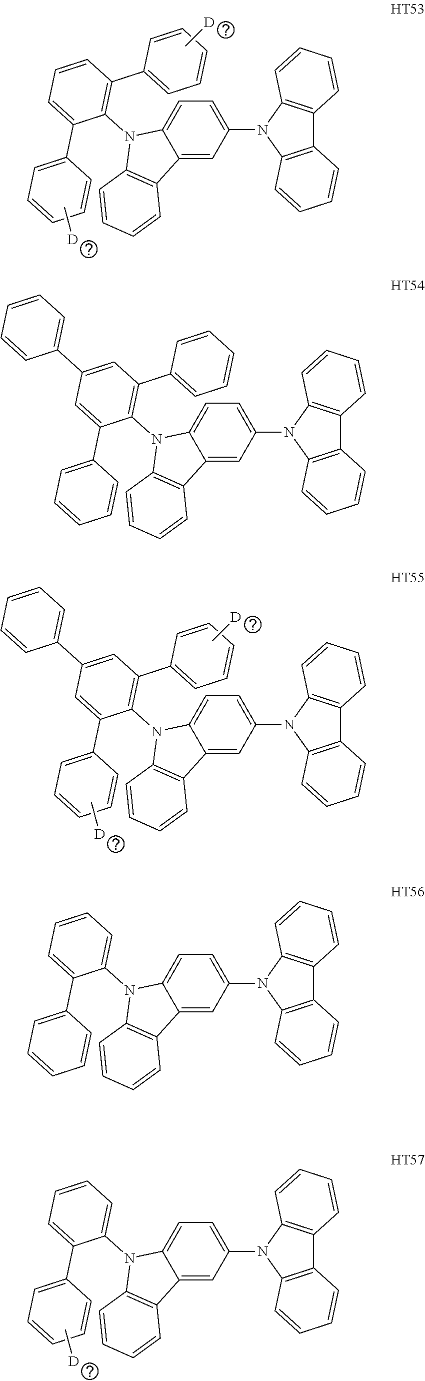

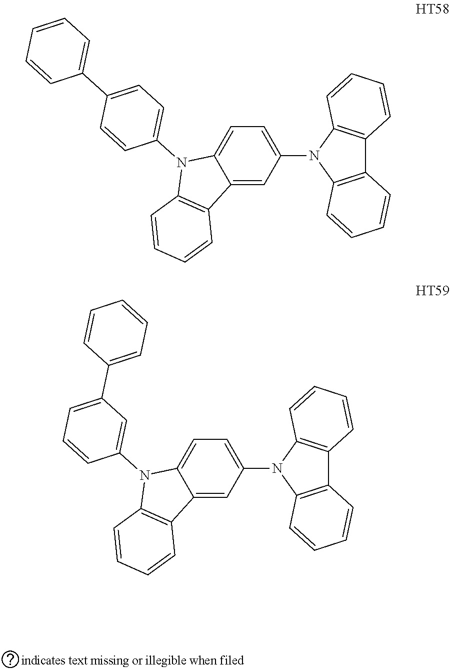 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In the specific compounds represented in Compound Group 2, “D” refers to a deuterium atom, and “Ph” may refer to a substituted or unsubstituted phenyl group. For example, in the specific compounds represented in Compound Group 2, “Ph” may be an unsubstituted phenyl group.

In one or more embodiments, the emission layer EML may include a third compound represented by Formula ET-1. For example, the third compound may be used as an electron transporting host material of the emission layer EML.

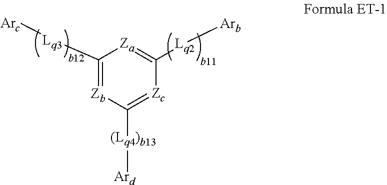

In Formula ET-1, at least one selected from among Zₐ to Z_{c} may be N, and the remainder may be CRₐ₁₆. For example, in one or more embodiments, any one selected from among Zₐ to Z_{c} may be N, and the remainder two may each independently be CRₐ₁₆. In these embodiments, the third compound represented by Formula ET-1 may include a pyridine moiety. In one or more embodiments, two among Zₐ to Z_{c} may be N, and the remainder one may be CRₐ₁₆. In these embodiments, the third compound represented by Formula ET-1 may include a pyrimidine moiety. In one or more embodiments, all Zₐ to Z_{c} may be N. In the embodiments, the third compound represented by Formula ET-1 may include a triazine moiety.

In Formula ET-1, Rₐ₁₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms.

In Formula ET-1, b11 to b13 may each independently be an integer of 0 to 10.

In Formula ET-1, Ar_{b} to Ar_{d} may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms. For example, in one or more embodiments, Ar_{b} to Ar_{d} may each independently be substituted or unsubstituted phenyl groups or substituted or unsubstituted carbazole groups.

In Formula ET-1, L_{q2} to L_{q4} may each independently be a direct linkage, a substituted or unsubstituted arylene group of 6 to 30 ring-forming carbon atoms, or a substituted or unsubstituted heteroarylene group or 2 to 30 ring-forming carbon atoms. If (e.g., when) b11 to b13 are integers of 2 or more, L_{q2} to L_{q4} may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the third compound may be any one selected from among the compounds in Compound Group 3. The light emitting element ED according to one or more embodiments may include at least one of the compounds in Compound Group 3.

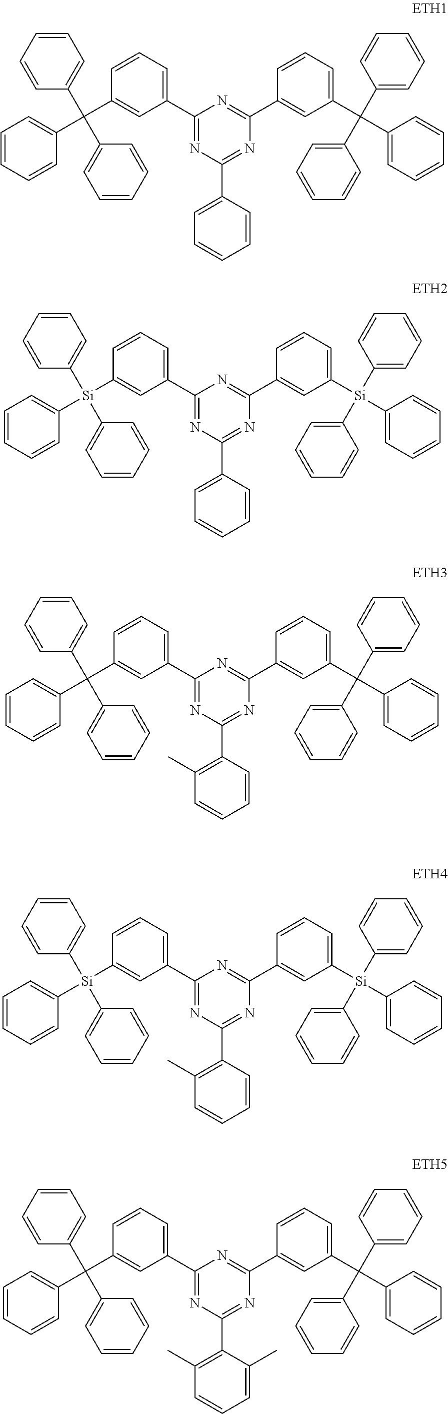

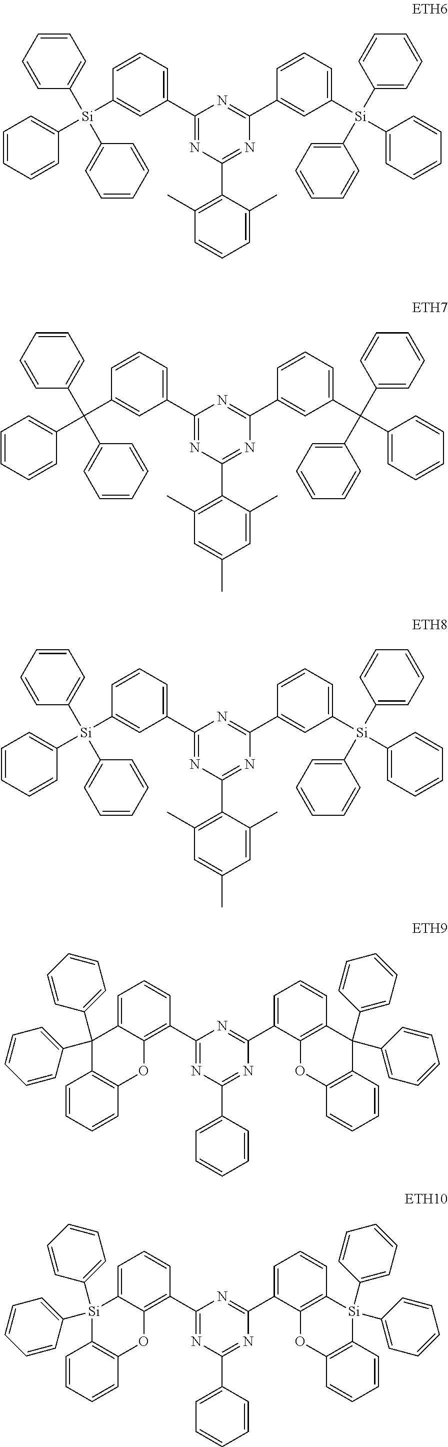

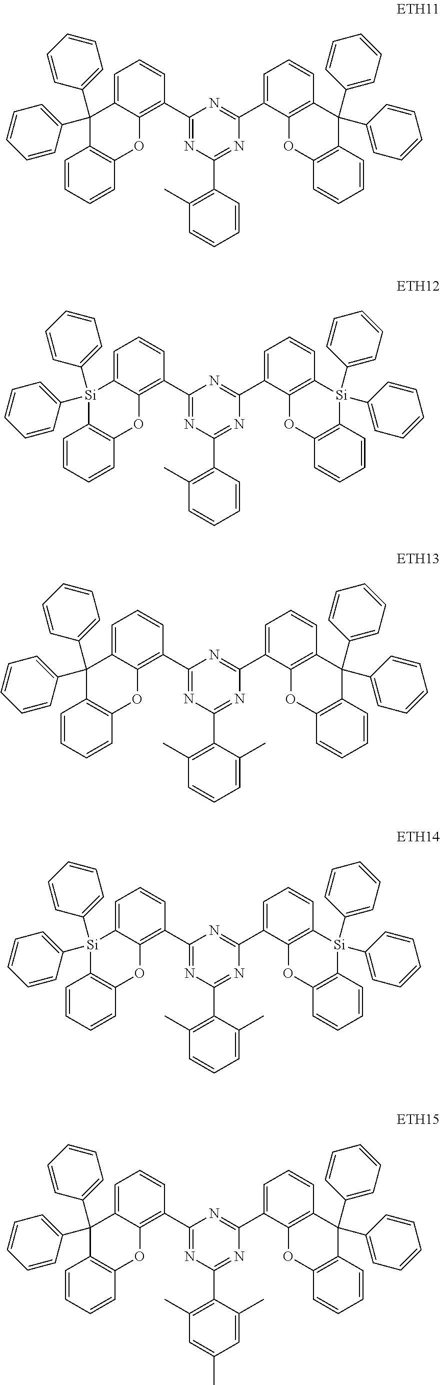

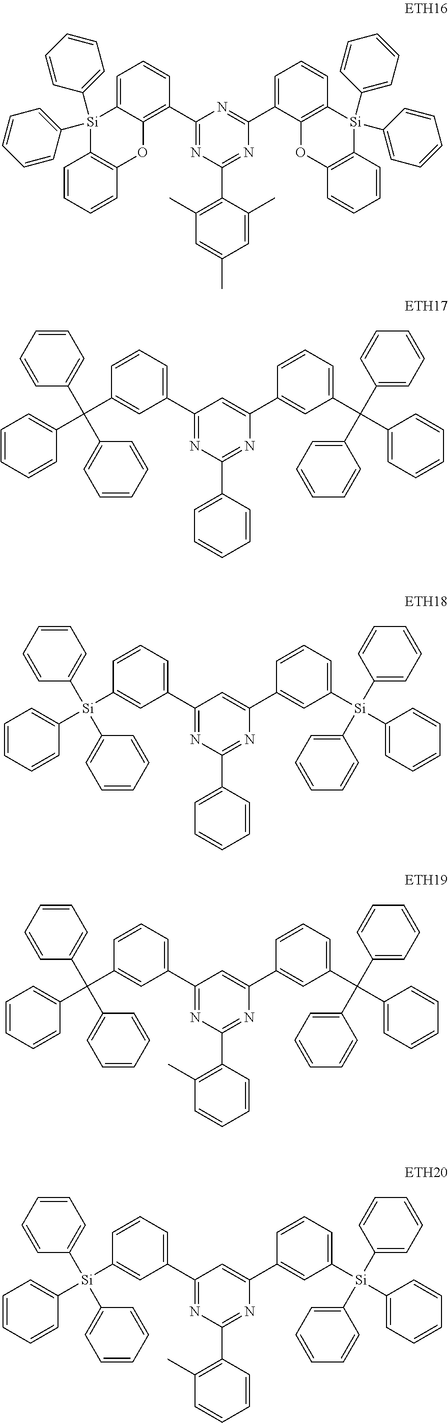

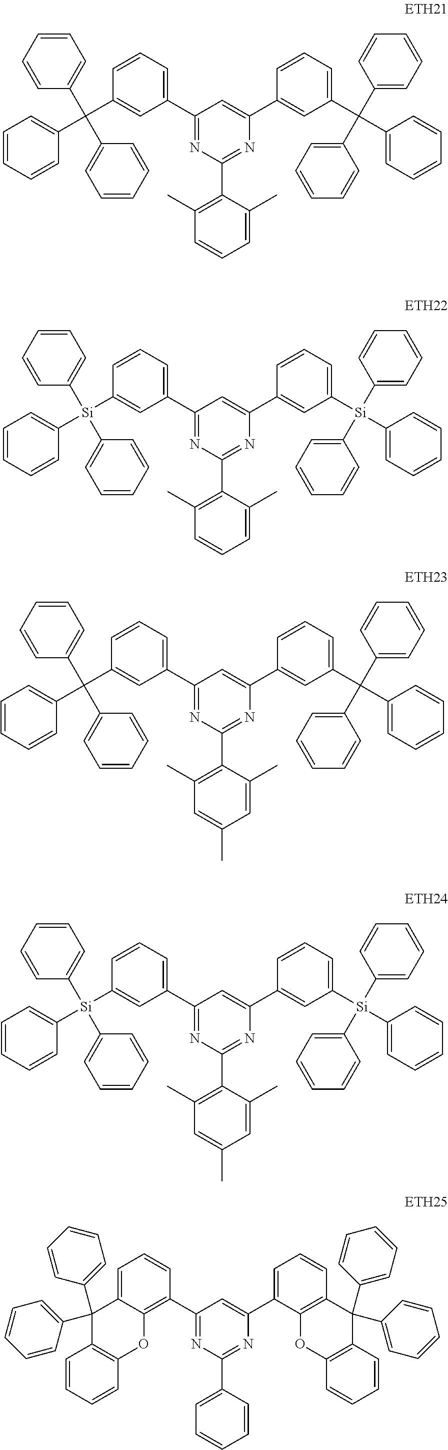

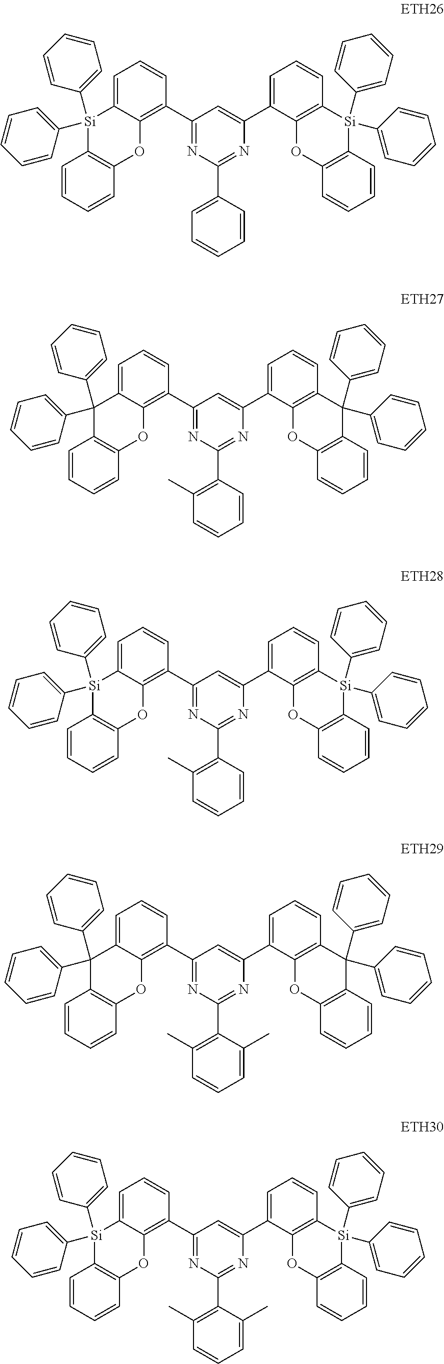

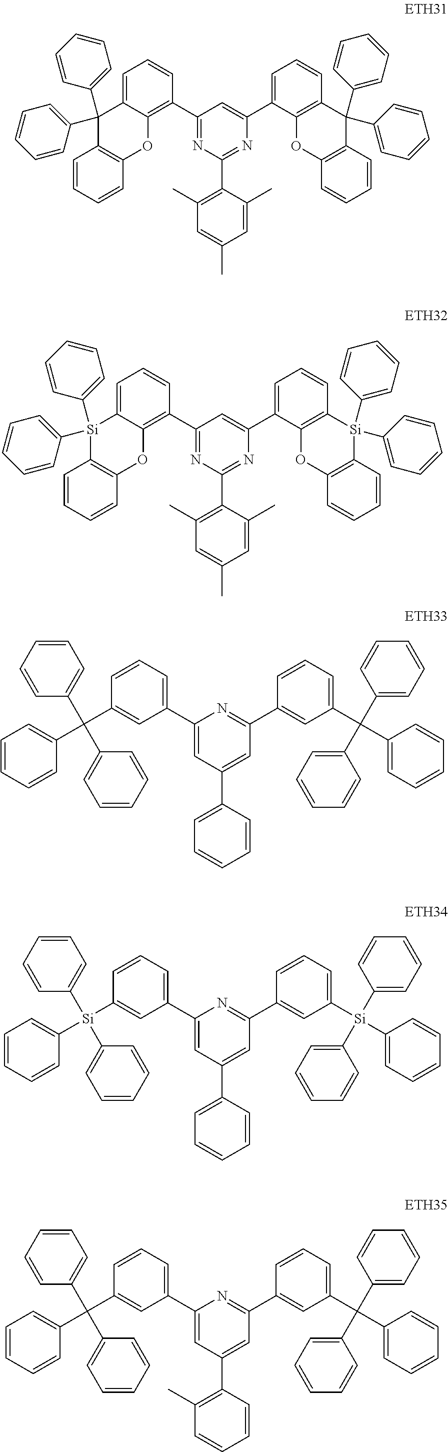

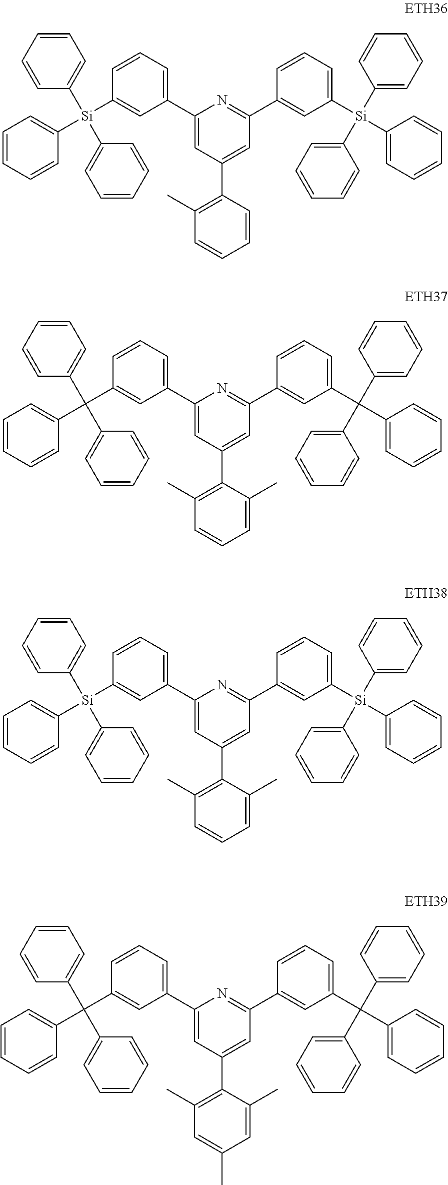 [SMILES: Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1]

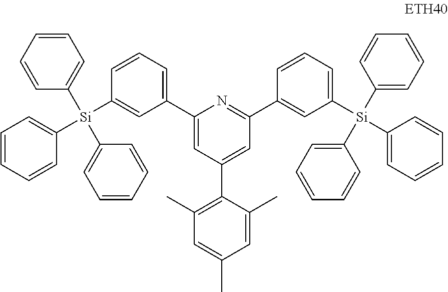 [SMILES: Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

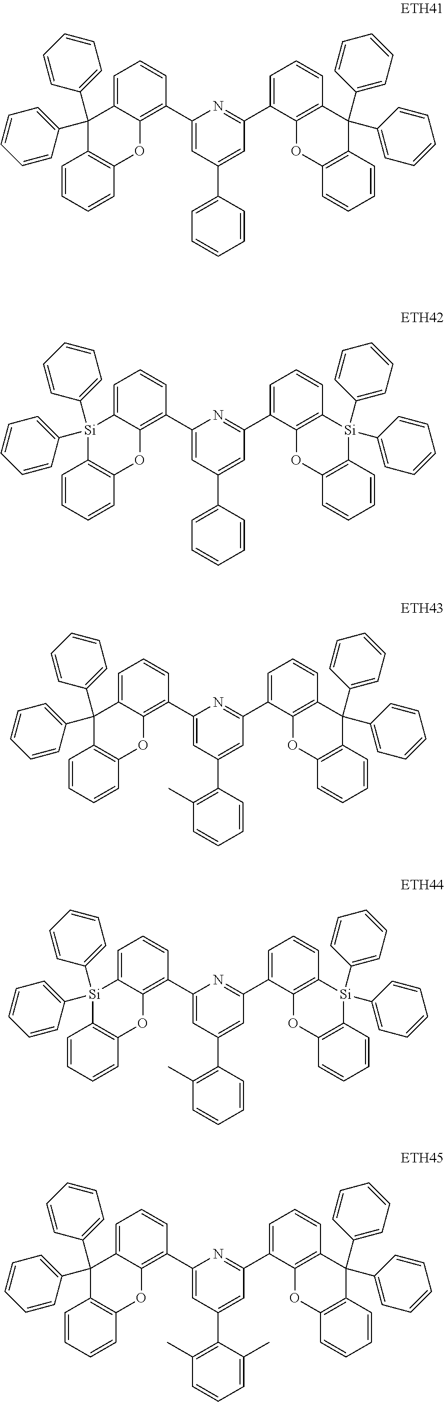

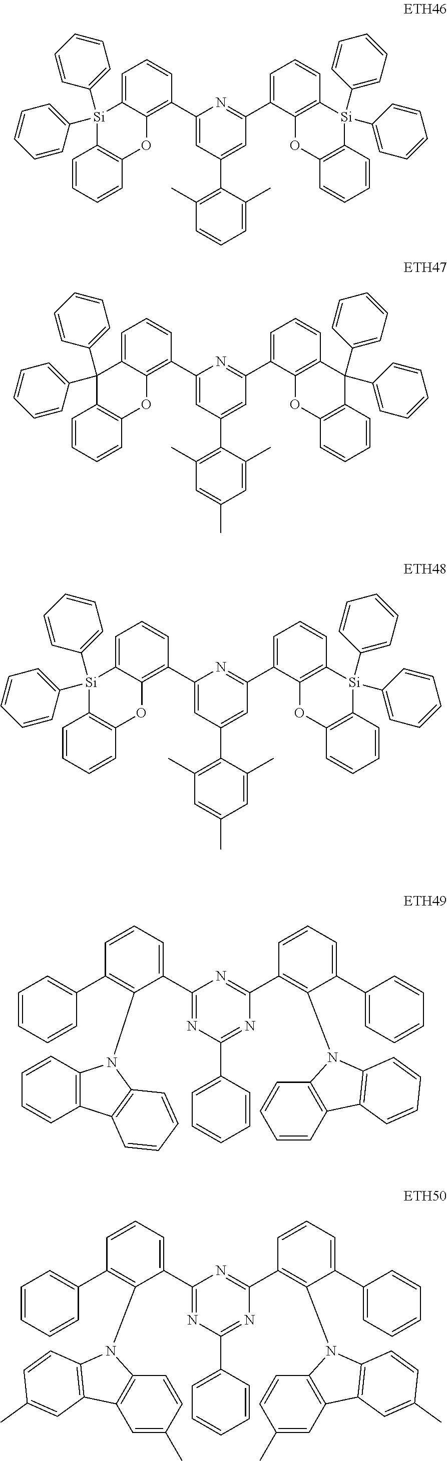

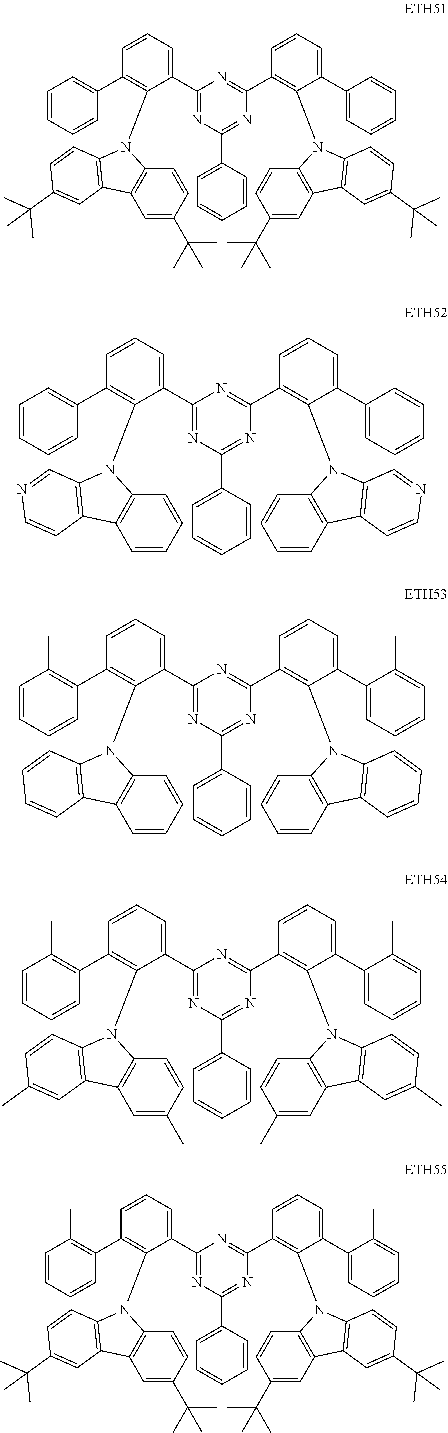

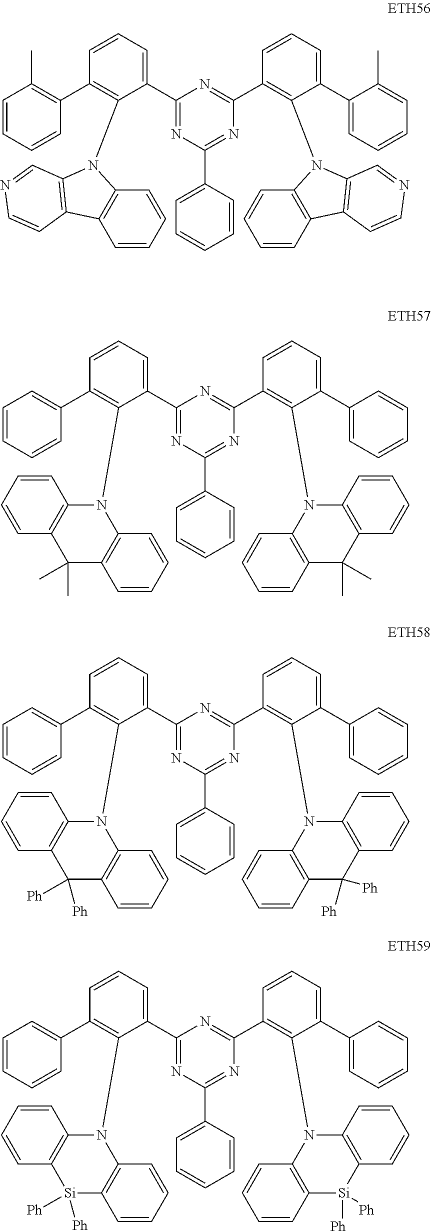

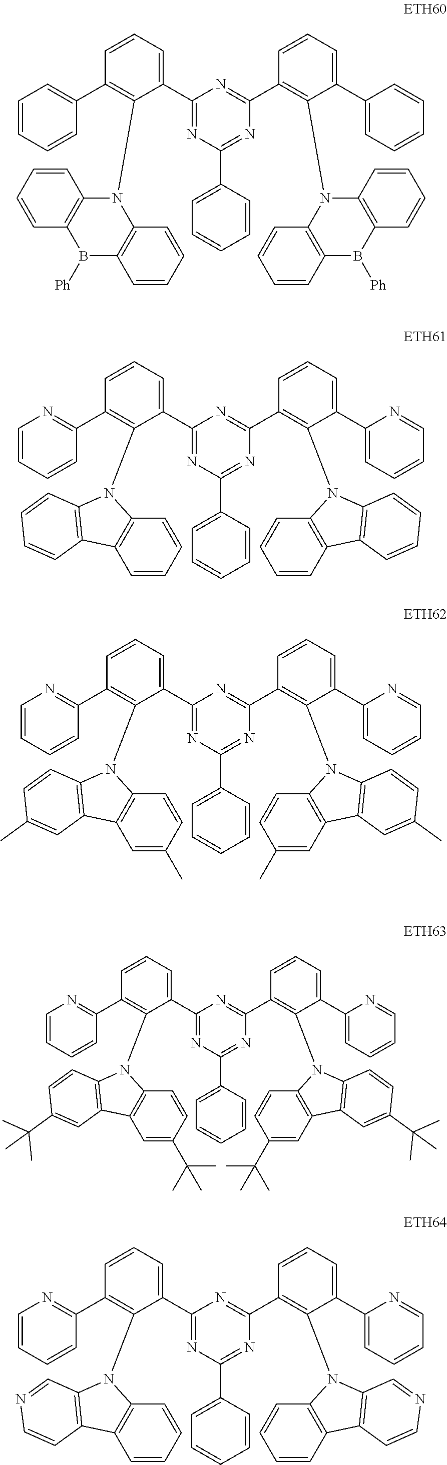

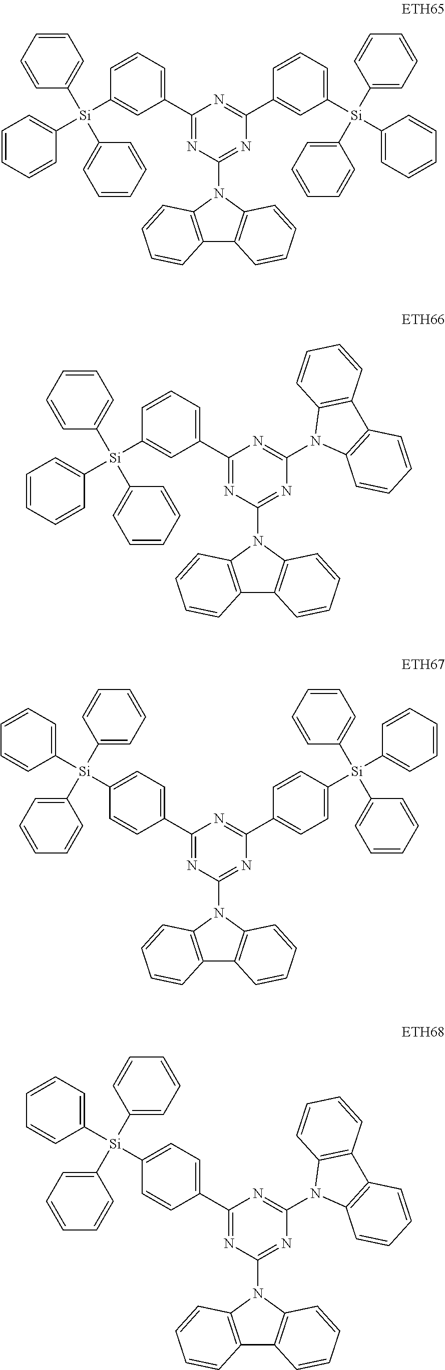 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

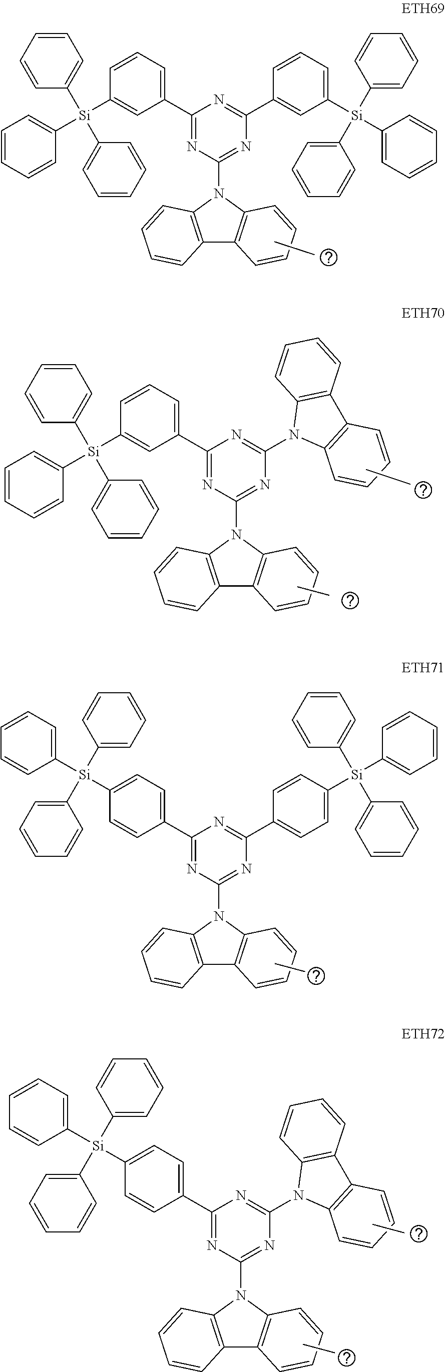

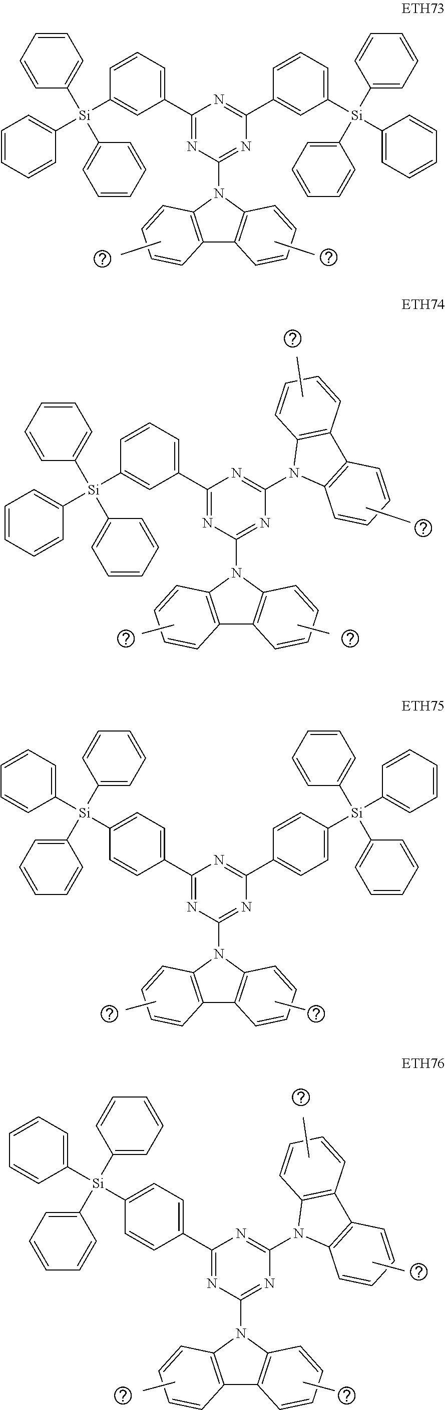

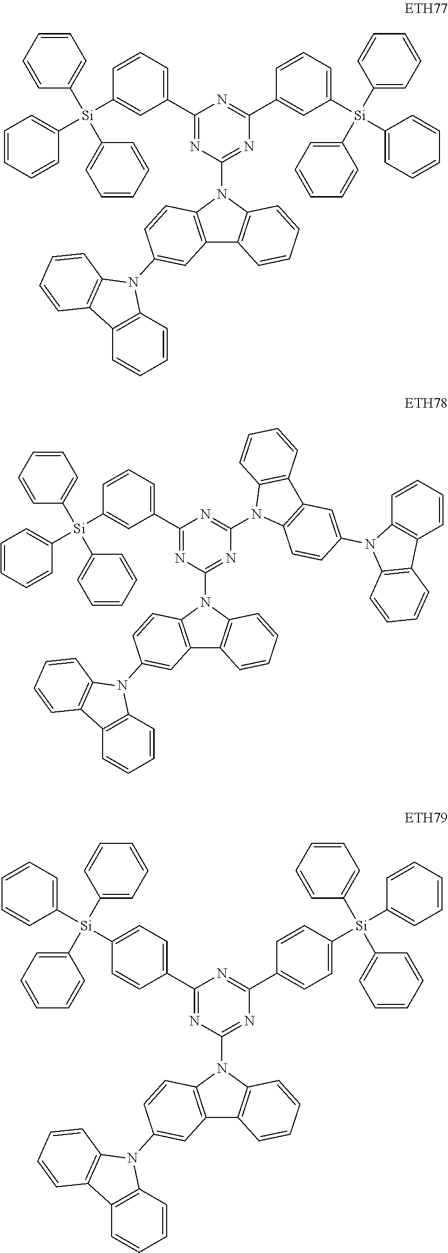 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

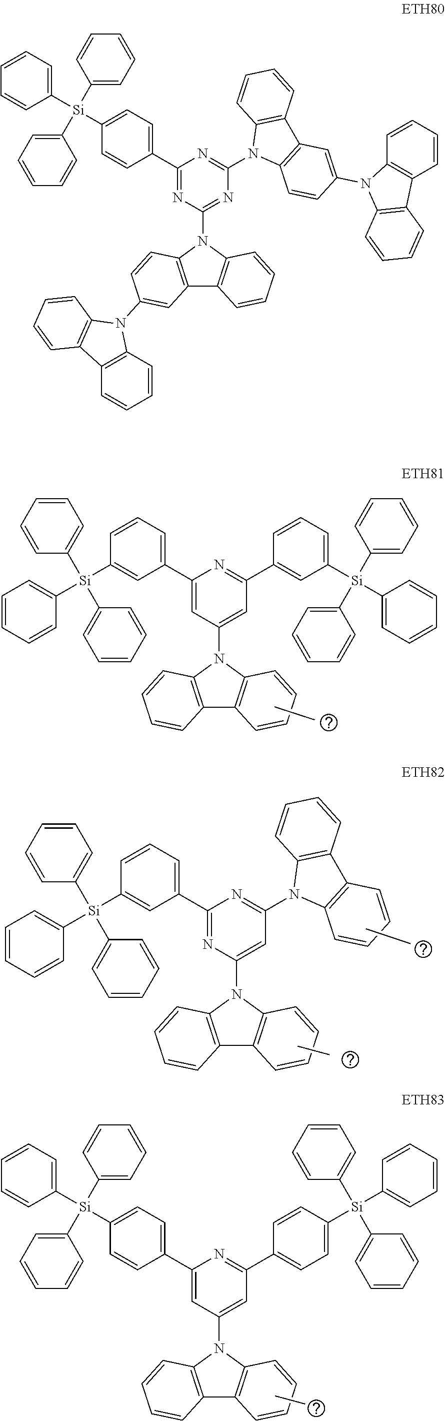

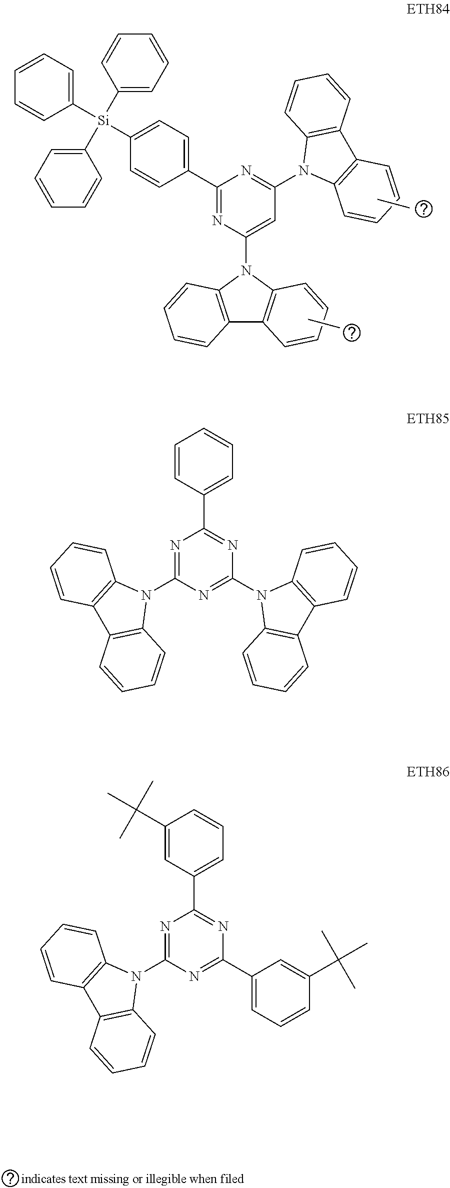

In the specific compounds represented in Compound Group 3, “D” refers to a deuterium atom, and “Ph” refers to an unsubstituted phenyl group.

In one or more embodiments, the emission layer EML includes the second compound and the third compound, and the second compound and the third compound may form an exciplex. In the emission layer EML, an exciplex may be formed by a hole transporting host and an electron transporting host. In this regard, the triplet energy of the exciplex formed by the hole transporting host and the electron transporting host may correspond to a difference between the lowest unoccupied molecular orbital (LUMO) energy level of the electron transporting host and the highest occupied molecular orbital (HOMO) energy level of the hole transporting host.

For example, in one or more embodiments, the absolute value of the triplet (T1) energy level of the exciplex formed by the hole transporting host and the electron transporting host may be from about 2.4 eV to about 3.0 eV. In addition, the triplet energy of the exciplex may be a value smaller than the energy gap of each host material. The exciplex may have a triplet energy of about 3.0 eV or less, which is an energy gap of the hole transporting host and the electron transporting host.

In one or more embodiments, the emission layer EML may further include a fourth compound in addition to the first to third compounds described above. The fourth compound may be used as a phosphorescence sensitizer of the emission layer EML. Energy may be transferred from the fourth compound to the first compound, thereby arising light emission.

For example, in one or more embodiments, the light layer EML may include an organometallic complex including Pt (platinum) as a central metal atom and ligands bonded to the central metal atom, as the fourth compound. In one or more embodiments of the light emitting element ED, the emission layer EML may include a compound represented by Formula D-1 as the fourth compound.

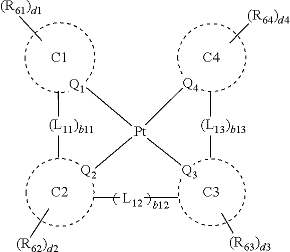

In Formula D-1, Q₁ to Q₄ may each independently be C or N. C1 to C4 may each independently be a substituted or unsubstituted hydrocarbon ring of 5 to 30 ring-forming carbon atoms, or a substituted or unsubstituted heterocycle of 2 to 30 ring-forming carbon atoms.

In Formula D-1, L₁₁ to L₁₃ may each independently be a direct linkage,

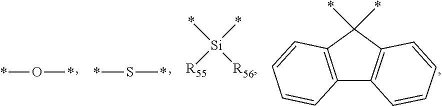

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms. In L₁₁ to L₁₃, “-*” refers to a connecting portion to C1 to C4.

In Formula D-1, b21 to b23 may each independently be 0 or 1. If (e.g., when) b21 is 0, C1 and C2 may not be connected to each other. If (e.g., when) b22 is 0, C2 and C3 may not be connected to each other. If (e.g., when) b23 is 0, C3 and C4 may not be connected to each other.

In Formula D-1, R₆₁ to R₆₄, R_{b5}, and R_{b6} may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms. In one or more embodiments, one or more selected from among R⁶¹ to R⁶⁴, R_{b5}, and R_{b6} may be connected with an adjacent group to form a ring. R⁶¹ to R⁶⁴, R_{b5}, and R_{b6} may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may be unsubstituted by R₆₁ to R₆₄, respectively. A case where each of d1 to d4 is 4, and each of R₆₁ to R₆₄ is a hydrogen atom, may be the same as a case where each of d1 to d4 is 0. If (e.g., when) each of d1 to d4 is an integer of 2 or more, each of R₆₁ to R₆₄ provided in plurality may be all the same, or at least one selected from the plurality of R₆₁ to R₆₄ may be different.

In Formula D-1, C1 to C4 may each independently be a substituted or unsubstituted hydrocarbon ring or a substituted or unsubstituted heterocycle, represented by any one selected from among C-1 to C-5.

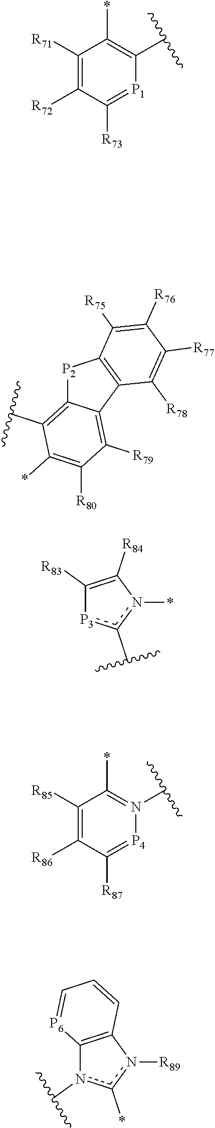

In C-1 to C-5, P1 may be C—* or CR_{c4}, P₂ may be N—* or NR_{c11}, P₃ may be N—* or NR_{c12}, P₄ may be C—* or CR_{c18}, P₆ may be C—* or CR_{c20}. R_{c1} to R_{c20} may each independently be a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or may be bonded to an adjacent group to form a ring.

In addition, in C-1 to C-5,

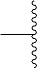

is a portion connected to the central metal atom Pt, and “-*” corresponds to a portion connected to a neighboring ring group (C1 to C5) or an adjacent linker (L₁₁ to L₁₃).

The emission layer EML according to one or more embodiments may include the first compound, which is the fused polycyclic compound, and at least one selected from among the second to fourth compounds. For example, in one or more embodiments, the emission layer EML may include the first compound, the second compound, and the third compound. In the emission layer EML, the second compound and the third compound may form an exciplex, and energy may be transferred from the exciplex to the first compound to arise light emission.

In addition, the emission layer EML may include the first compound, the second compound, the third compound, and the fourth compound. In the emission layer EML, the second compound and the third compound may form an exciplex, and energy may be transferred from the exciplex to the fourth compound and the first compound to arise light emission. In one or more embodiments, the fourth compound may be a sensitizer. In the light emitting element ED of one or more embodiments, the fourth compound included in the emission layer EML may function as a sensitizer to transfer energy from the host to the first compound, which is a light emitting dopant. For example, the fourth compound acting as an auxiliary dopant may accelerate the energy transfer to the first compound, which is a light emitting dopant, thereby increasing the light emission ratio of the first compound. Therefore, the emission layer EML of one or more embodiments may have improved emission efficiency. In addition, if (e.g., when) the energy transfer to the first compound is increased, the excitons formed in the emission layer EML may not accumulate inside the emission layer EML and quickly emit light, so that the deterioration of the light emitting element may be reduced. Therefore, the lifespan of the light emitting element ED according to one or more embodiments may be improved.

The light emitting element ED according to one or more embodiments may include all of the first compound, the second compound, the third compound, and the fourth compound, so that the emission layer EML includes a combination of two host materials and two dopant materials. In the light emitting element ED according to one or more embodiments, the emission layer EML may exhibit excellent or suitable emission efficiency characteristics by concurrently (e.g., simultaneously) including two different hosts, which are the second compound and the third compound, the first compound emitting delayed fluorescence, and the fourth compound including an organometallic complex.

In one or more embodiments, the fourth compound represented by Formula D-1 may be represented by at least any one selected from among the compounds represented in Compound Group 4. The emission layer EML may include at least one of the compounds represented in Compound Group 4 as a sensitizer material.

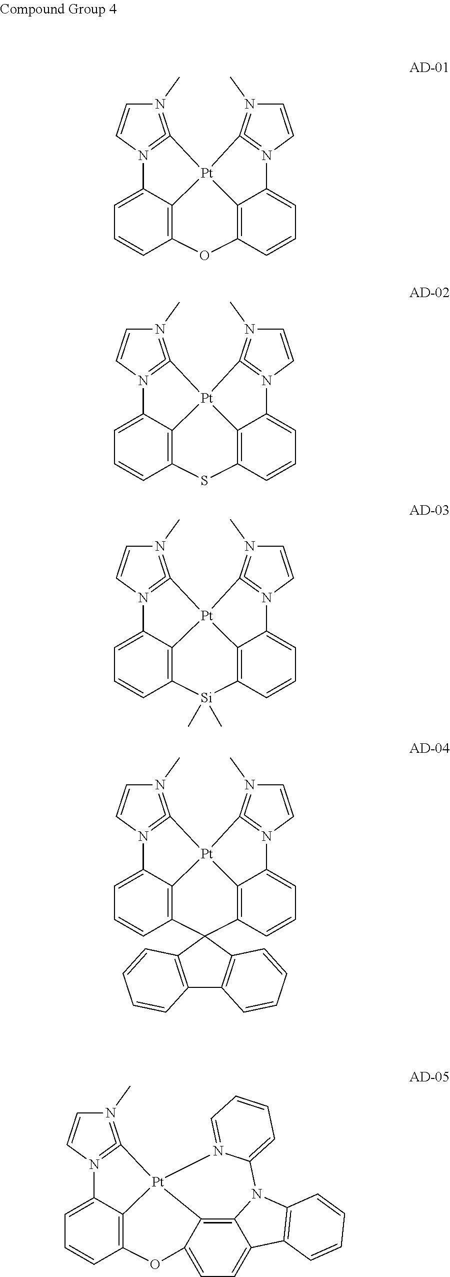

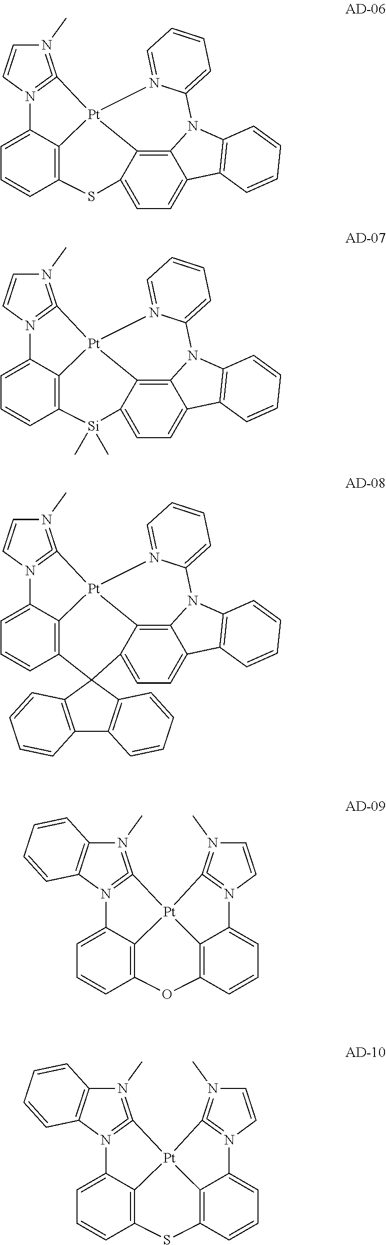

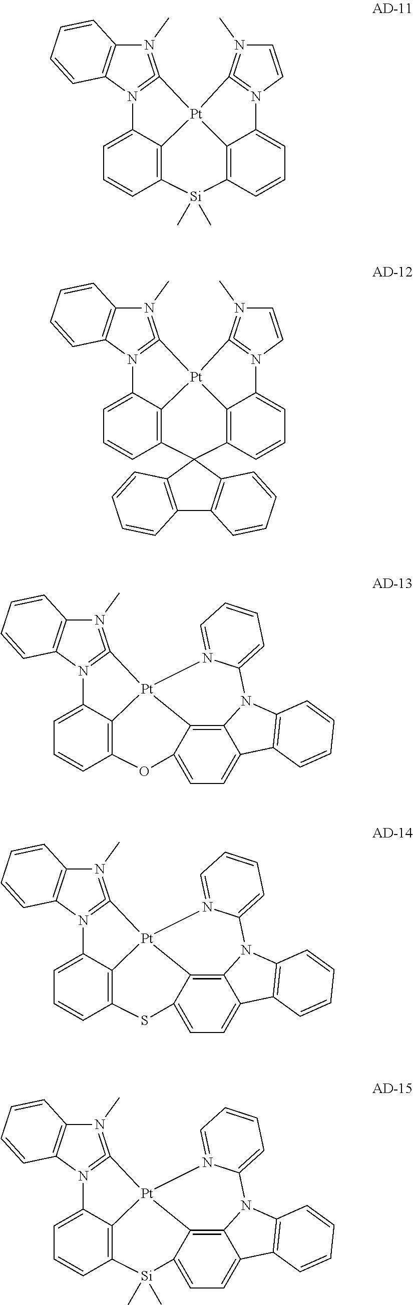

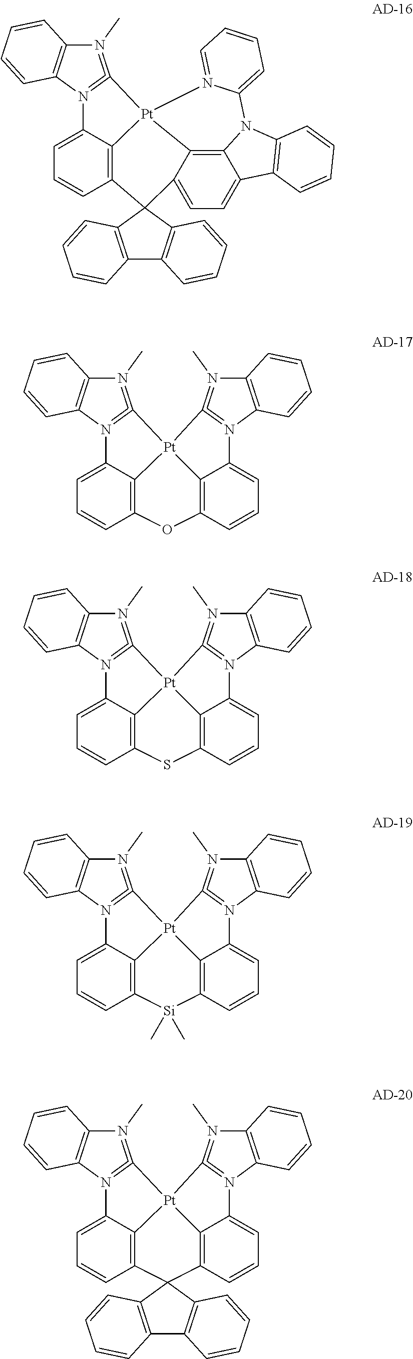

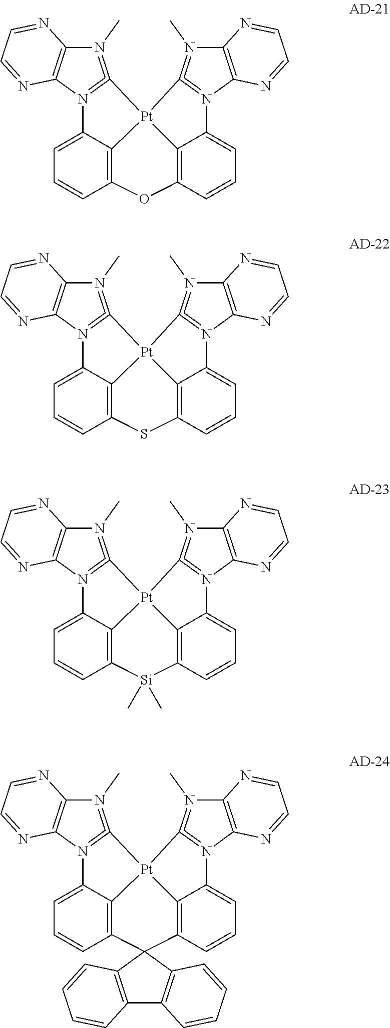

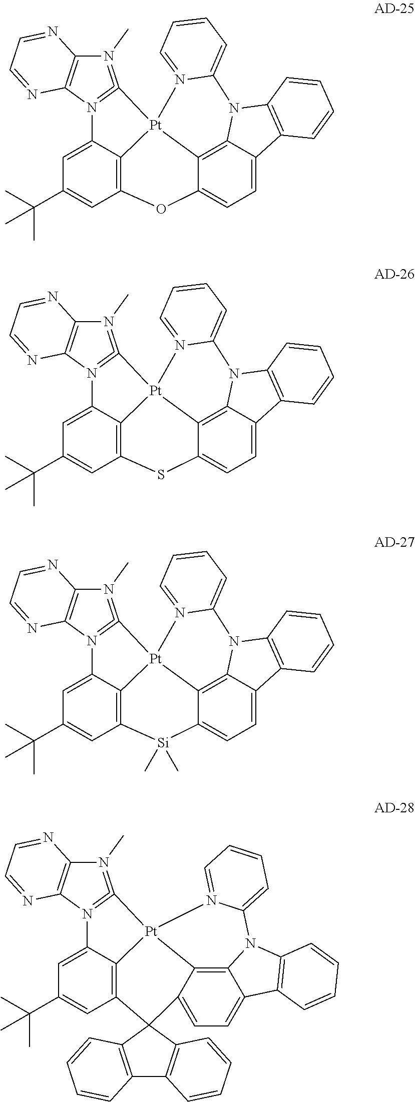

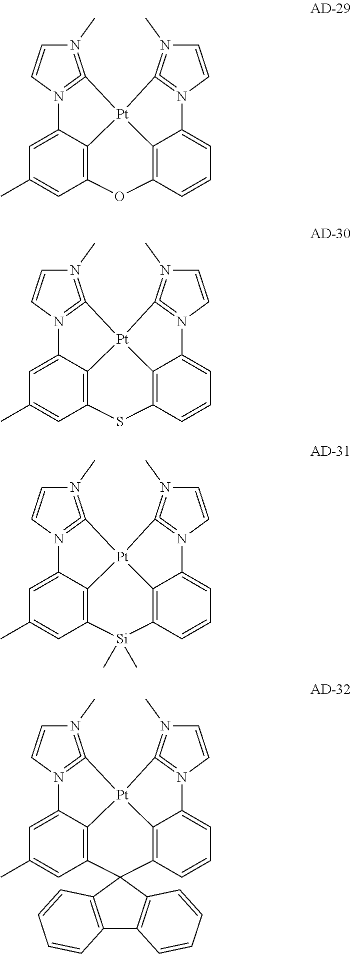

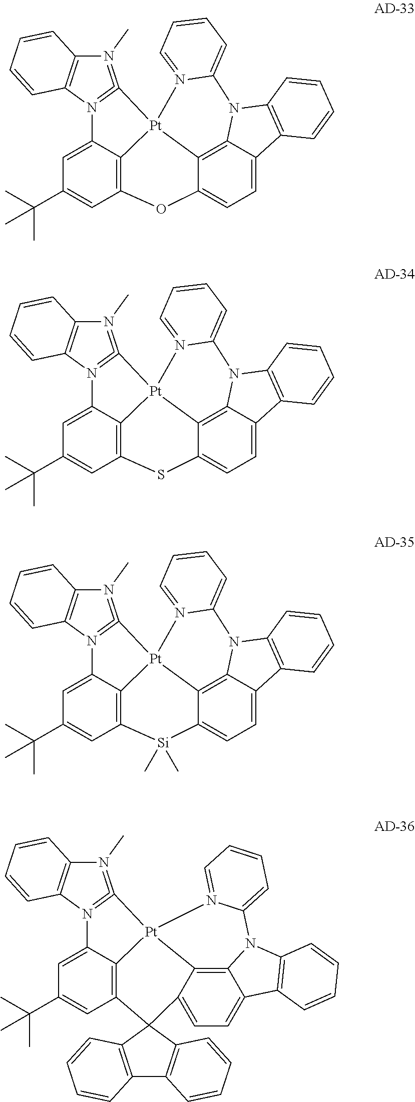

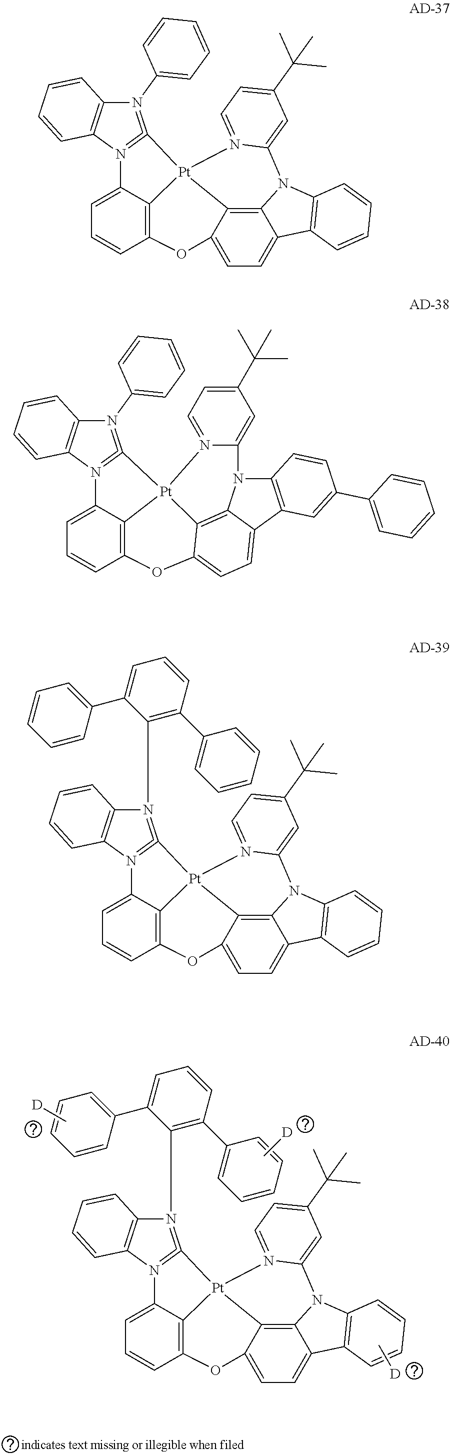

In the specific compounds represented in Compound Group 4, “D” refers to a deuterium atom.

In the light emitting element ED according to one or more embodiments, if (e.g., when) the emission layer EML includes all of the first compound, the second compound, and the third compound described above, the content (e.g., amount) of the first compound may be about 0.1 wt % to about 5 wt % based on the total weight of the first compound, the second compound, and the third compound. However, embodiments of the disclosure are not limited thereto. When the content (e.g., amount) of the first compound satisfies the ratio described above, energy transfer from the second compound and the third compound to the first compound may be increased, and thus, the emission efficiency and the element lifespan may be increased.

The content (e.g., amount) of the second compound and the third compound in the emission layer EML may be the remainder excluding the weight of the first compound described above. For example, in one or more embodiments, the sum of the content (e.g., amount) of the second compound and the content (e.g., amount) of the third compound in the emission layer EML may be about 65 wt % to about 95 wt % based on the total weight of the first compound, the second compound, and the third compound.

The weight ratio of the second compound and the third compound in the total weight of the second compound and the third compound may be about 3:7 to 7:3.

When the content (e.g., amount) of the second compound and the content (e.g., amount) of the third compound satisfies the above-described ratio, charge balance characteristic within the emission layer EML may be improved, so that the emission efficiency and the element lifespan may increase. When the content (e.g., amount) of the second compound and the content (e.g., amount) of the third compound deviates from the above-described ratio range, the charge balance within the emission layer EML may be broken, so that the emission efficiency may be reduced, and the element may easily deteriorate.

In one or more embodiments, when the emission layer EML includes the fourth compound, the content (e.g., amount) of the fourth compound may be about 10 wt % to about 30 wt % based on the total weight of the first compound, the second compound, the third compound, and the fourth compound in the emission layer EML. However, embodiments of the present disclosure are not limited thereto. When the content (e.g., amount) of the fourth compound satisfies the content (e.g., amount) described above, energy transfer from the host to the first compound, which is a light emitting dopant, may be increased, thereby improving the light emitting ratio, and thus the emission efficiency of the emission layer EML may be improved. When the first compound, the second compound, the third compound, and the fourth compound included in the emission layer EML satisfy the content (e.g., amount) ratio ranges described above, excellent or suitable emission efficiency and long lifespan may be achieved.

The emission layer EML may have a thickness of, for example, about 100 Å to about 1,000 Å or about 100 Å to about 300 Å. The emission layer EML may have a single layer formed using a single material, a single layer formed using multiple different materials, or a multilayer structure having multiple layers formed using multiple different materials.

In the light emitting elements ED according to one or more embodiments illustrated in FIGS. 5-9, the emission layer EML may include the fused polycyclic compound according to one or more embodiments described above as a dopant. In addition, in the light emitting elements ED according to one or more embodiments illustrated in FIGS. 5-9, the emission layer EML may include at least one of the first compound, which is the fused polycyclic compound according to one or more embodiments, the second compound represented by Formula HT-1, and the third compound represented by Formula ET-1. In addition, in the light emitting elements ED of embodiments illustrated in FIGS. 5-9, the emission layer EML may include the first compound, which is the fused polycyclic compound according to one or more embodiments, the second compound represented by Formula HT-1, the third compound represented by Formula ET-1, and the fourth compound represented by Formula D-1.

In the light emitting element ED according to one or more embodiments, the emission layer EML may further include anthracene derivatives, pyrene derivatives, fluoranthene derivatives, chrysene derivatives, dihydrobenzanthracene derivatives, or triphenylene derivatives. For example, in one or more embodiments, the emission layer EML may further include anthracene derivatives and/or pyrene derivatives.

In the light emitting elements ED according to one or more embodiments, shown in FIGS. 5-9, the emission layer EML may include a host and a dopant, and the emission layer EML may further include a compound represented by Formula E-1. The compound represented by Formula E-1 may be used as a fluorescence host material.

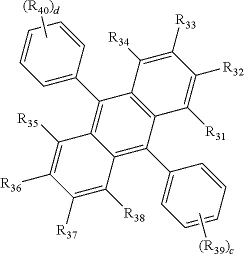

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, and/or optionally combined with an adjacent group to form a ring. In one or more embodiments, one or more selected from among R₃₁ to R₄₀ may each independently be combined with an adjacent group to form a saturated hydrocarbon ring, an unsaturated hydrocarbon ring, a saturated heterocycle or an unsaturated heterocycle.

In Formula E-1, “c” and “d” may each independently be an integer of 0 to 5.

The compound represented by Formula E-1 may be any one selected from among Compound E1 to Compound E19.

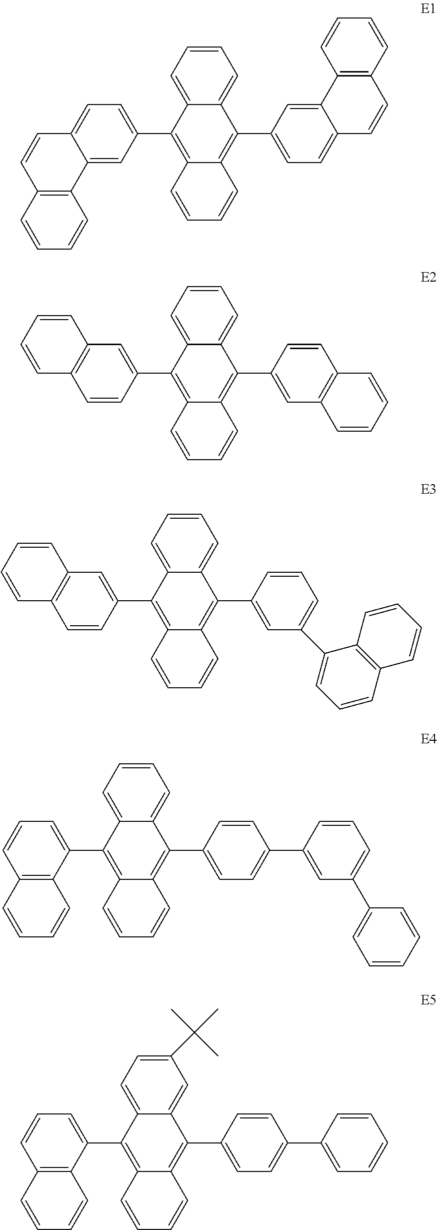

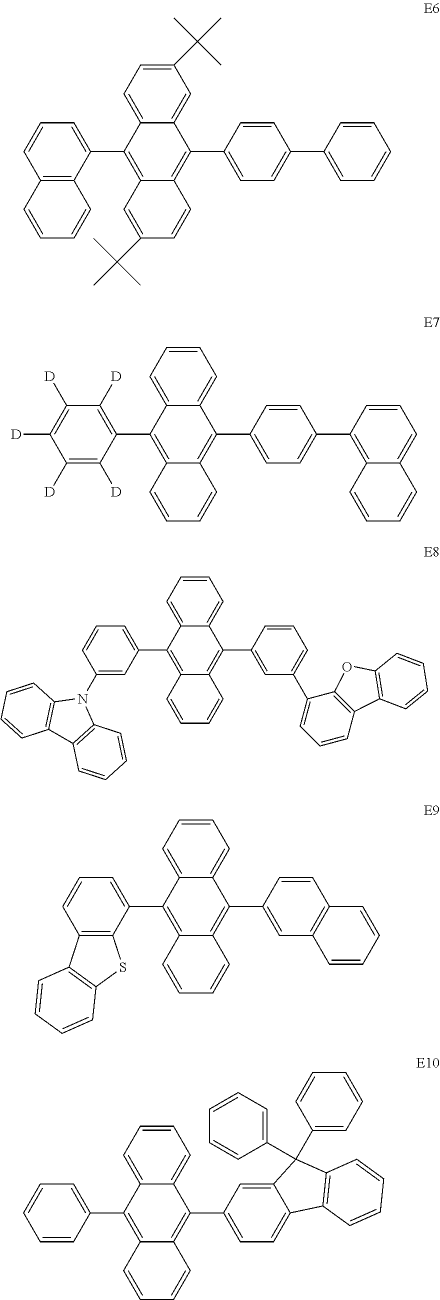

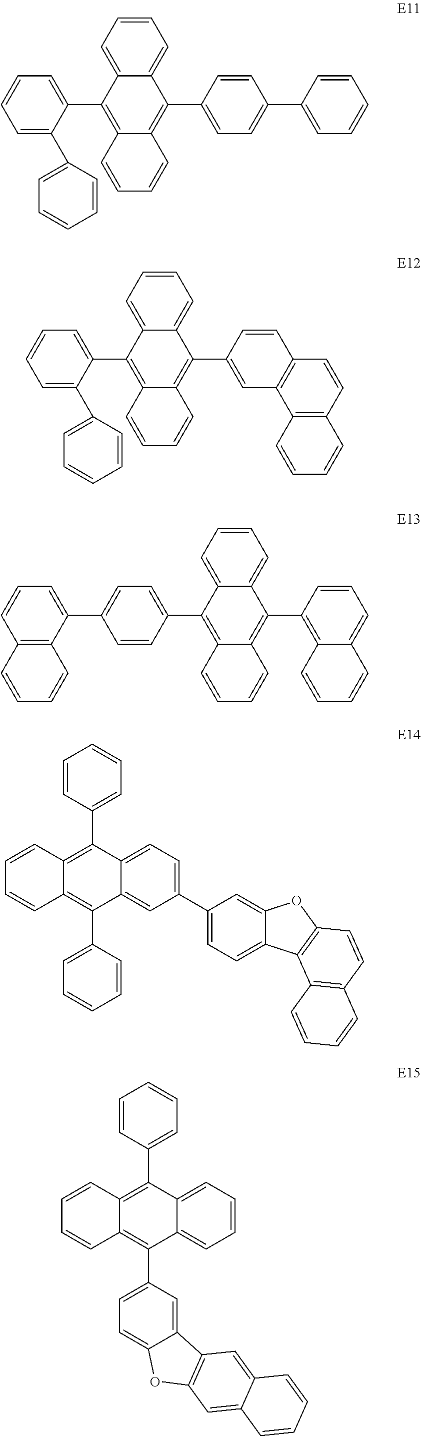

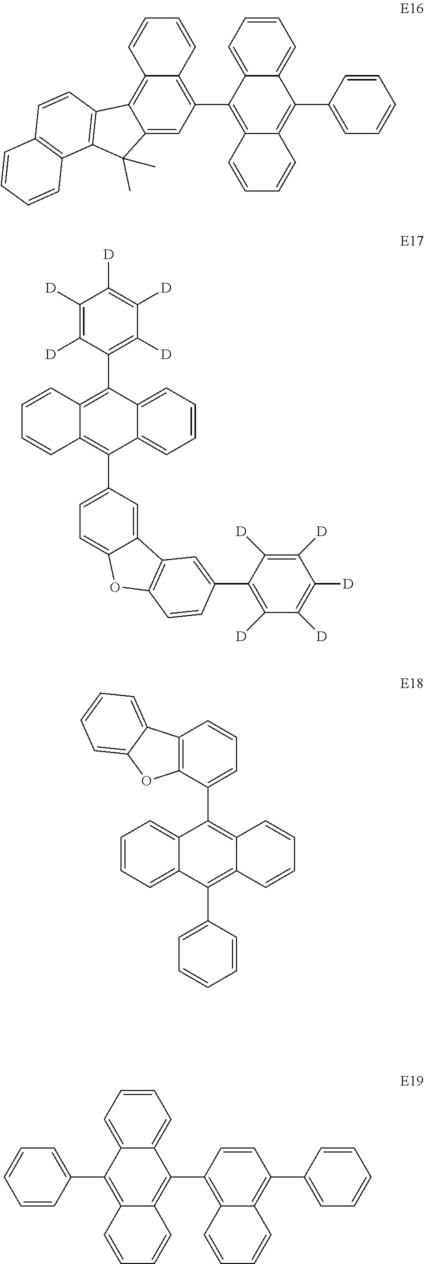

In one or more embodiments, the emission layer EML may further include a compound represented by Formula E-2a or Formula E-2b. The compound represented by Formula E-2a or Formula E-2b may be used as a host material in a phosphorescence emission layer (e.g., as a phosphorescent host material).

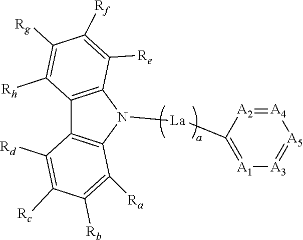

In Formula E-2a, a51 may be an integer of 0 to 10, L_{q11} may be a direct linkage, a substituted or unsubstituted arylene group of 6 to 30 ring-forming carbon atoms, or a substituted or unsubstituted heteroarylene group of 2 to 30 ring-forming carbon atoms. If (e.g., when) a51 is an integer of 2 or more, multiple L_{q11} may each independently be a substituted or unsubstituted arylene group of 6 to 30 ring-forming carbon atoms, or a substituted or unsubstituted heteroarylene group of 2 to 30 ring-forming carbon atoms.

In addition, in Formula E-2a, A₁ to A₅ may each independently be N or CRi. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be independently combined with an adjacent group to form a ring. In one or more embodiments, one or more selected from among Rₐ to Rᵢ may be each independently combined with an adjacent group to form a hydrocarbon ring or a heterocycle including N, O, S, and/or the like, as a ring-forming atom.

In Formula E-2a, two or three selected from among A₁ to A₅ may be N, and the remainder may be CRᵢ.

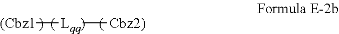

In Formula E-2b, Cbz1 and Cbz2 may each independently be an unsubstituted carbazole group, or a carbazole group substituted with an aryl group of 6 to 30 ring-forming carbon atoms. L_{qq} may be a direct linkage, a substituted or unsubstituted arylene group of 6 to 30 ring-forming carbon atoms, or a substituted or unsubstituted heteroarylene group of 2 to 30 ring-forming carbon atoms. pp is an integer of 0 to 10, and if (e.g., when) b is an integer of 2 or more, multiple L_{qq} may each independently be a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be any one selected from among the compounds in Compound Group E-2. However, the compounds shown in Compound Group E-2 are only illustrations, and the compound represented by Formula E-2a or Formula E-2b is not limited to the compounds represented in Compound Group E-2.

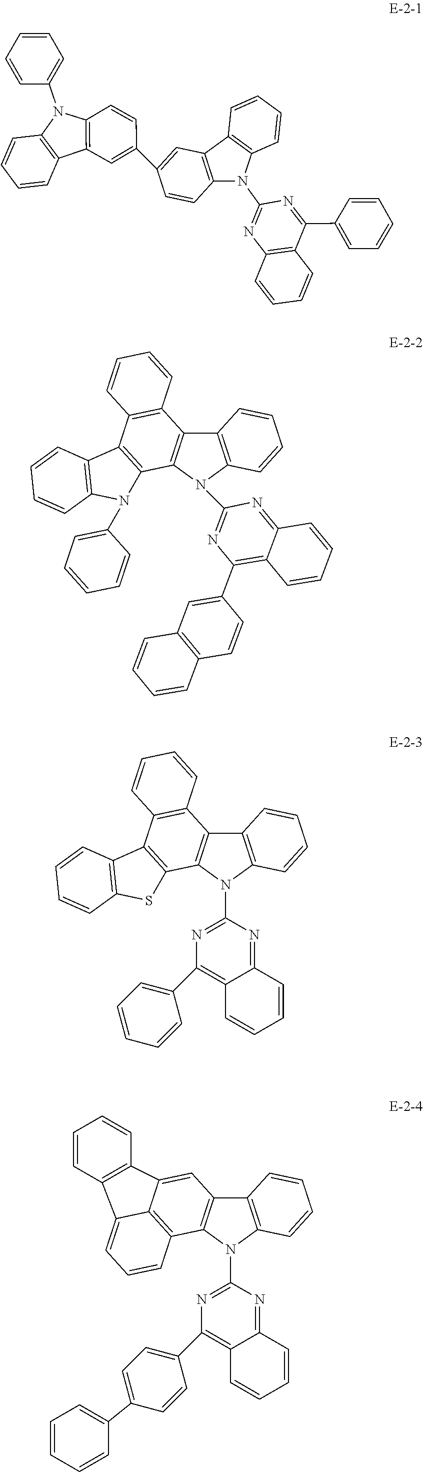 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

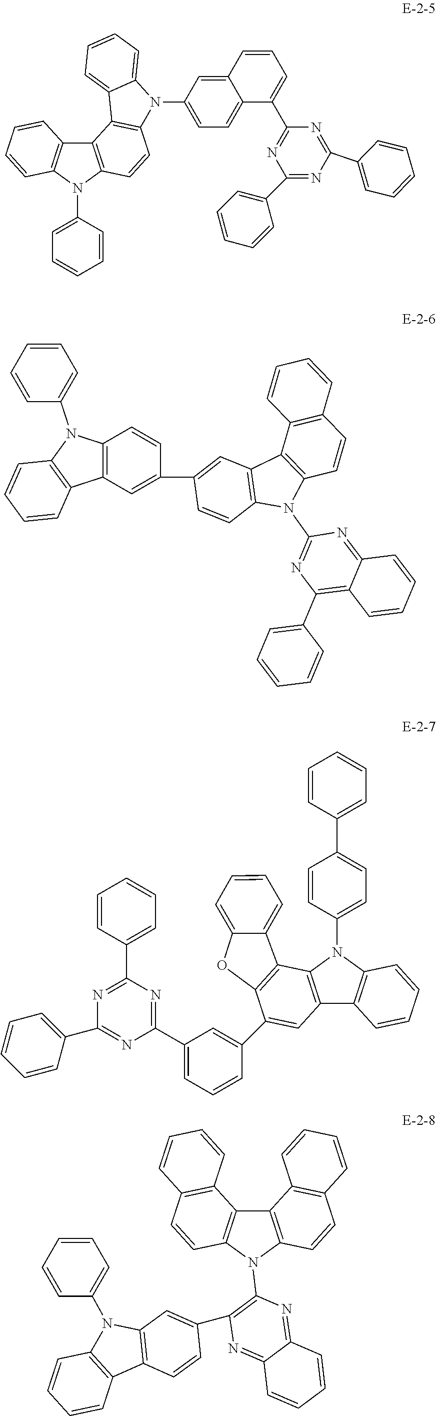

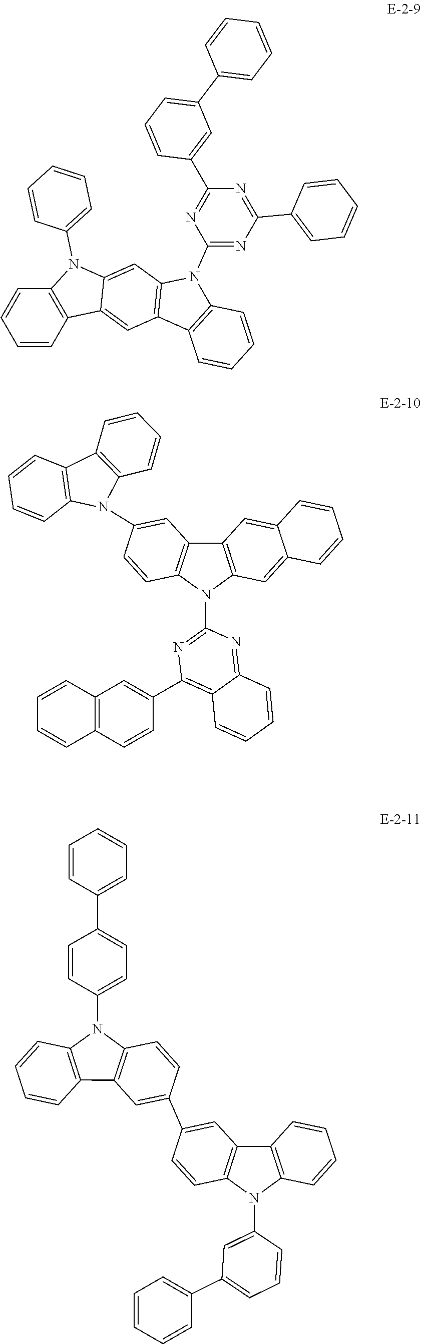 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

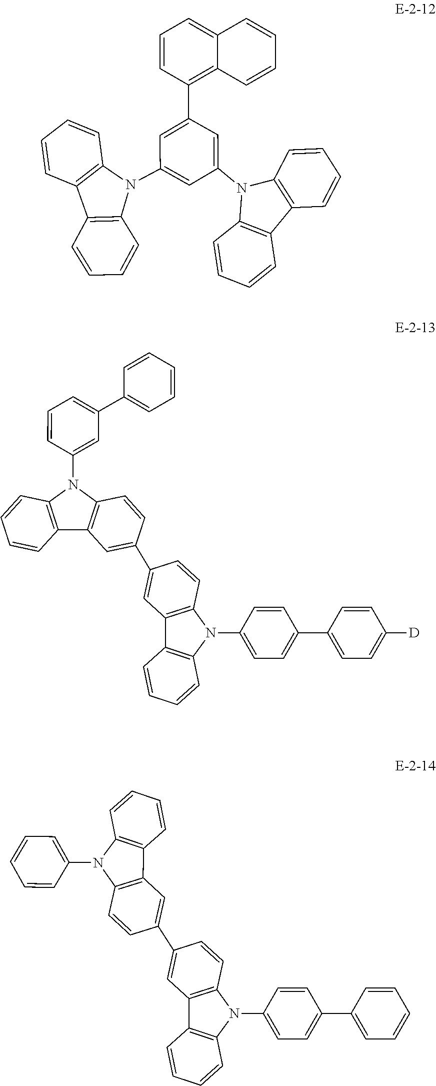 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1]

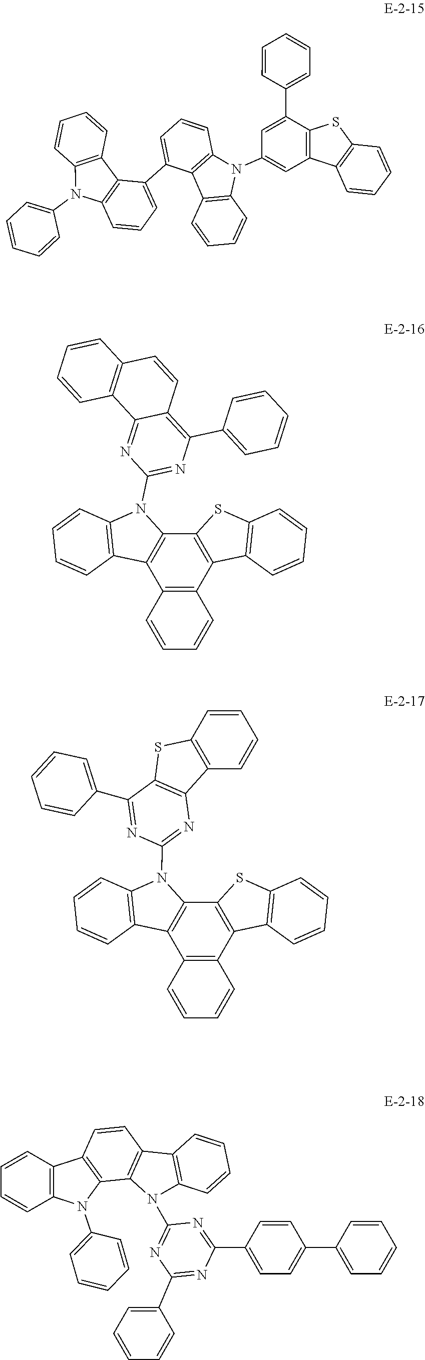 [SMILES: c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

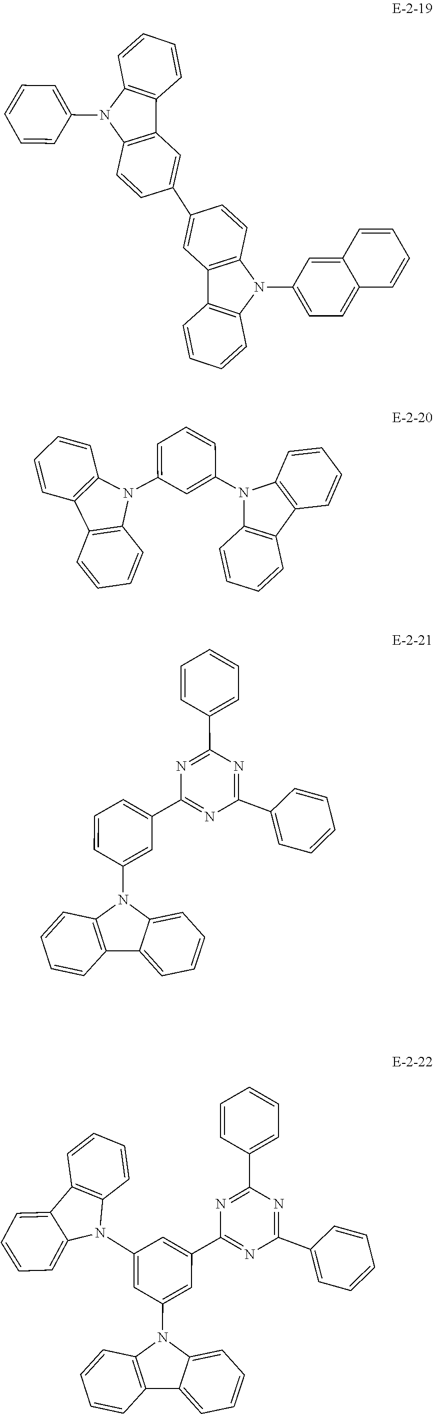 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

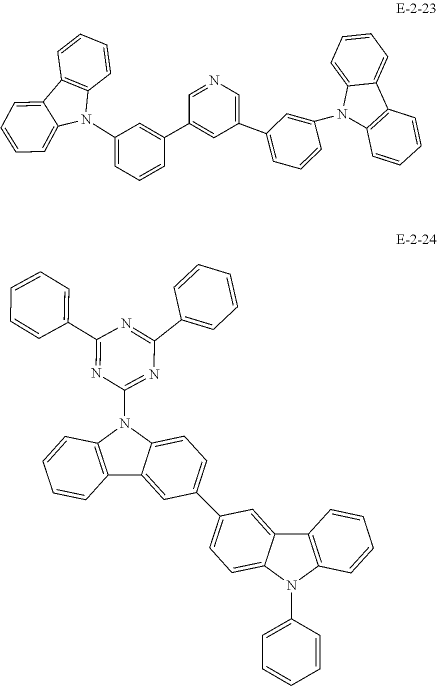 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a compound represented by Formula M-a. The compound represented by Formula M-a may be used as a phosphorescence dopant material.

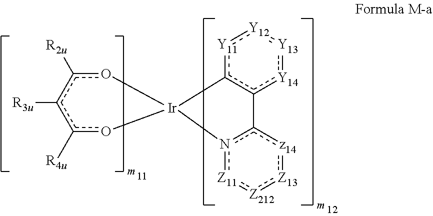

In Formula M-a, Y₁₁ to Y₁₄, and Z₁₁ to Z₁₄ may each independently be CR₁ᵤ or N, and R₁ᵤ to R₄ᵤ may each independently be a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be independently combined with an adjacent group to form a ring. In Formula M-a, m11 is 0 or 1, and m12 is 2 or 3. In Formula M-a, if (e.g., when) m11 is 0, m12 is 3, and if m11 is 1, m12 is 2.

The compound represented by Formula M-a may be used as a phosphorescence dopant.

The compound represented by Formula M-a may be any one selected from among Compounds M-a1 to M-a25. However, Compounds M-a1 to M-a25 are examples, and the compound represented by Formula M-a is not limited to the compounds represented by Compounds M-a1 to M-a25.

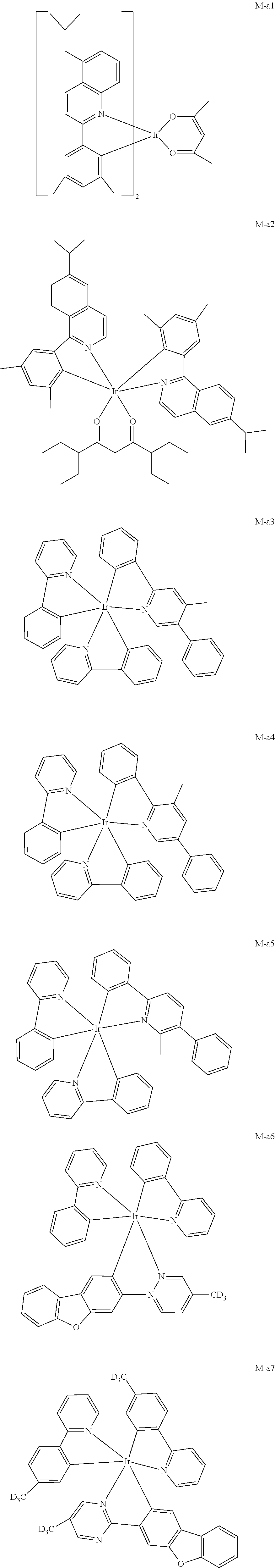

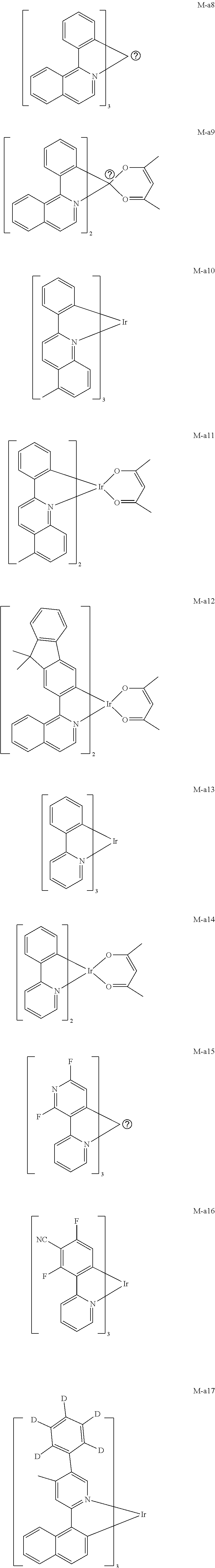

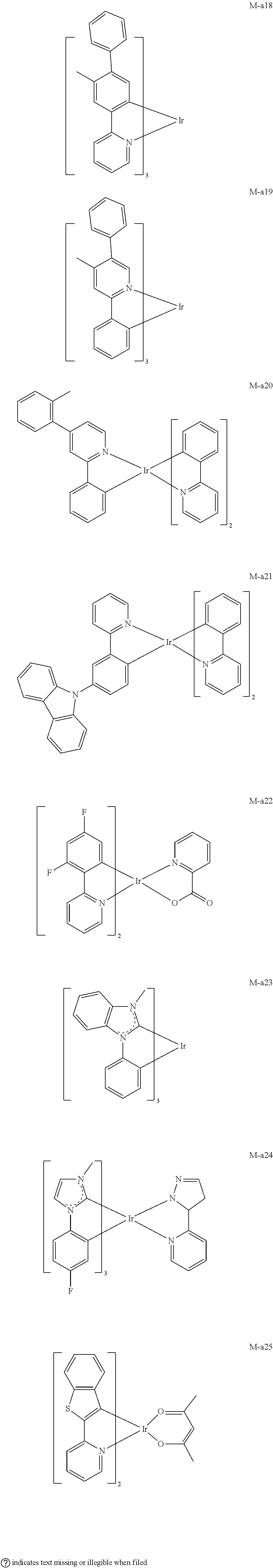

In one or more embodiments, the emission layer EML may further include at least one selected from among the compounds represented by Formula F-a to Formula F-c. The compounds represented by Formula F-a to Formula F-c may be used as fluorescence dopant materials.

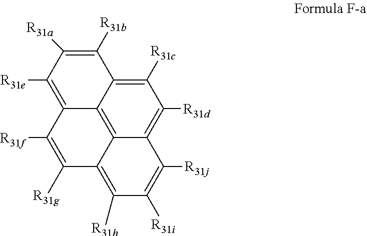

In Formula F-a, two selected from among R₃₁ₐ to R₃₁ⱼ may each independently be substituted with *—NAr₃₁Ar₃₂. The remainder not substituted with *—NAr₃₁Ar₃₂ among R₃₁ₐ to R₃₁ⱼ may each independently be a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In *—NAr₃₁Ar₃₂, Ar₃₁ and Ar₃₂ may each independently be a substituted or unsubstituted aryl group of 6 to 30 ring-forming carbon atoms, or a substituted or unsubstituted heteroaryl group of 2 to 30 ring-forming carbon atoms. For example, at least one among Ar₃₁ and Ar₃₂ may be a heteroaryl group including O or S as a ring-forming atom.

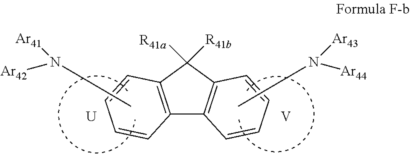

In Formula F-b, R₄₁ₐ and R_{41b} may each independently be a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, and/or may be combined with an adjacent group to form a ring. Ar₄₁ to Ar₄₄ may each independently be a substituted or unsubstituted aryl group of 6 to 30 ring-forming carbon atoms, or a substituted or unsubstituted heteroaryl group of 2 to 30 ring-forming carbon atoms.

In Formula F-b, U and V may each independently be a substituted or unsubstituted hydrocarbon ring of 5 to 30 ring-forming carbon atoms, or a substituted or unsubstituted heterocycle of 2 to 30 ring-forming carbon atoms. At least one selected from among Ar₄₁ to Ar₄₄ may be a heteroaryl group including O or S as a ring-forming atom.

In Formula F-b, the number of rings represented by U and V may each independently be 0 or 1. For example, in Formula F-b, if (e.g., when) the number of U or V is 1, one ring forms a fused ring at the designated part by U or V, and if the number of U or V is 0, a ring is not present at the designated part by U or V. For example, if (e.g., when) the number of U is 0, and the number of V is 1, or if the number of U is 1, and the number of V is 0, a fused ring having the fluorene core of Formula F-b may be a ring compound with four rings. In one or more embodiments, if the number of both U and V is 0, the fused ring of Formula F-b may be a ring compound with three rings. In one or more embodiments, if the number of both U and V is 1, a fused ring having the fluorene core of Formula F-b may be a ring compound with five rings.

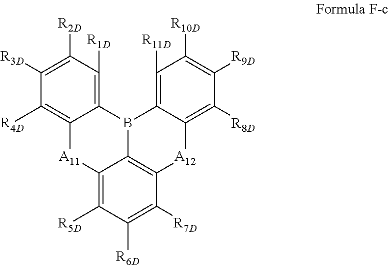

In Formula F-c, A11 and A12 may each independently be O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R_{1D} to R_{11D} may each independently be a hydrogen atom, deuterium, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group to form a ring.

In Formula F-c, A₁₁ and A₁₂ may each independently be combined with the substituents of an adjacent ring to form a fused ring. For example, if (e.g., when) A₁₁ and A12 may each independently be NRₘ, A₁₁ may be combined with R_{4D} or R_{5D} to form a ring. In one or more embodiments, A₁₂ may be combined with R_{7D} or R_{8D} to form a ring.

In one or more embodiments, the emission layer EML may include as a suitable dopant material, styryl derivatives (for example, 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino)pyrene), and/or the like.

In one or more embodiments, the emission layer EML may further include a suitable phosphorescent dopant material. For example, the phosphorescent dopant may use a metal complex including iridium (Ir), platinum (Pt), osmium (Os), gold (Au), titanium (Ti), zirconium (Zr), hafnium (Hf), europium (Eu), terbium (Tb) or thulium (Tm). For example, iridium(III) bis(4,6-difluorophenylpyridinato-N,C2′ir6(Bis(2,4-difluorophenylpyridinato)-tetrakis(1-pyrazolyl)borate iridium(III) (FIrpic), or platinum octaethyl porphyrin (PtOEP) may be used as the phosphorescence dopant. However, embodiments of the disclosure are not limited thereto.

In one or more embodiments, the emission layer EML may include a quantum dot material (e.g., quantum dot). In one or more embodiments, the quantum dot includes a core, and the core of the quantum dot may be selected from among II-VI group compounds, I-II-VI group compounds, II-IV-VI group compounds, I-II-IV-VI group compounds, II-IV-V group compounds, III-VI group compounds, I-III-VI group compounds, III-V group compounds, III-II-V group compounds, IV-VI group compounds, IV group elements, IV group compounds, and combinations thereof.

The II-VI group compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof.

The III-VI group compound may include a binary compound, such as In₂S₃, and In₂Se₃, a ternary compound such as InGaS₃, and InGaSe₃, or optional combinations thereof.

The I-III-VI group compound may be selected from among a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂ and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, InAlPSb, and mixtures thereof. In one or more embodiments, the III-V group compound may further include II group metals. For example, InZnP, and/or the like may be selected as the III-II-V group compound.

The IV-VI group compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The IV group element may be selected from the group consisting of Si, Ge, and a mixture thereof. The IV group compound may be a binary compound selected from the group consisting of SiC, SiGe, and a mixture thereof.

Each element included in a multi-element compound such as the binary compound, ternary compound, and/or quaternary compound may exist in the particle at a substantially uniform concentration or a non-substantially uniform concentration. For example, the chemical formula representing a semiconductor compound indicates the type (kind) of element included in the compound, and the element ratio in the compound may be different. For example, AgInGaS₂ may indicate AgInₓGa₁₋ₓS₂ (x is a real number between 0 and 1).

The quantum dot may have a single structure or a core-shell double structure in which the concentration of each element contained in the quantum dot is substantially uniform. For example, the material contained in the core and the material contained in the shell may be different from each other.

The shell of the quantum dot may play the role of a protection layer for preventing or reducing the chemical deformation of the core to maintain its semiconductor properties and/or a charging layer for imparting the quantum dot with electrophoretic properties. The shell may have a single layer or a multilayer. The interface between the core and the shell may have a concentration gradient where the concentration of elements present in the shell decreases toward the center.

Examples of the shell of the quantum dot may include a metal or non-metal oxide, a semiconductor compound, or combinations thereof. For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, or a ternary compound such as MgAl₂O₄, CoFe₂O₄, NiFe₂O₄ and/or CoMn₂O₄, but embodiments of the disclosure are not limited thereto.

Also, examples of the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the disclosure are not limited thereto.

Each element included in the binary compound, ternary compound, or other multi-element compound may exist in the particle at a substantially uniform or non-substantially uniform concentration. For example, the chemical formula representing the multi-element compound indicates the type (kind) of elements included in the compound, and the element ratio within the compound may be different.

The quantum dot may have a full width at half maximum (FWHM) of light emitting wavelength spectrum of about 45 nm or less, about 40 nm or less, about 30 nm or less, and within this range, color purity or color reproducibility of the quantum dot may be improved. In addition, light emitted via such a quantum dot is emitted in all directions, thereby improving the light view angle properties.

In addition, the shape of the quantum dot may be a generally used shapes in the relevant art, without specific limitation. For example, the shape of spherical, pyramidal, multi-arm, or cubic nanoparticle, nanotube, nanowire, nanofiber, nanoplate particle, and/or the like may be used.

Because the energy band gap of the quantum dots may be controlled or selected by controlling the size of the quantum dots or the element ratio in the quantum dot compound, light of one or more suitable wavelengths may be obtained from the quantum dot emission layer. Therefore, by using the quantum dots as described above (using quantum dots of different sizes or having different element ratios in the quantum dot compound), a light emitting element that emits light of one or more suitable wavelengths may be achieved. For example, the size of the quantum dots or the element ratio in the quantum dot compound may be selected so that red color light, green color light, and/or blue color light is emitted. In addition, the quantum dots may be configured to emit white light by combining light of one or more suitable colors.

In the light emitting elements ED according to one or more embodiments, as shown in FIGS. 5-9, the electron transport region ETR is provided on the emission layer EML. The electron transport region ETR may include at least one of a hole blocking layer HBL, the electron transport layer ETL or the electron injection layer EIL. However, embodiments of the present disclosure are not limited thereto.

The electron transport region ETR may have a single layer formed using a single material, a single layer formed using multiple different materials, or a multilayer structure having multiple layers formed using multiple different materials.

For example, in one or more embodiments, the electron transport region ETR may have a single layer structure of an electron injection layer EIL or an electron transport layer ETL, or a single layer structure formed using an electron injection material and an electron transport material. Further, the electron transport region ETR may have a single layer structure formed using multiple different materials, or a structure stacked from the emission layer EML of electron transport layer ETL/electron injection layer EIL, or hole blocking layer HBL/electron transport layer ETL/electron injection layer EIL, but embodiments of the present disclosure are not limited thereto. The thickness of the electron transport region ETR may be, for example, from about 1,000 Å to about 1,500 Å.

The electron transport region ETR may be formed using one or more suitable methods, such as a vacuum deposition method, a spin coating method, a cast method, a Langmuir-Blodgett (LB) method, an inkjet printing method, a laser printing method, a laser induced thermal imaging (LITI) method, and/or the like.

The electron transport region ETR may include a compound represented by Formula ET-2.

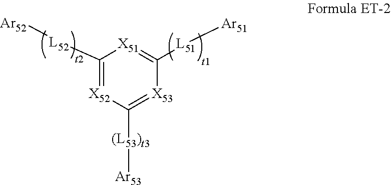

In Formula ET-2, at least one selected from among X₅₁ to X₅₃ may be N, and the remainder are CRₐ₇₁. Rₐ₇₁ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₅₁ to Ar₅₃ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, t1 to t3 may each independently be an integer of 0 to 10. In Formula ET-2, L₅₁ to L₅₃ may each independently be a direct linkage, a substituted or unsubstituted arylene group of 6 to 30 ring-forming carbon atoms, or a substituted or unsubstituted heteroarylene group of 2 to 30 ring-forming carbon atoms. If (e.g., when) each of t1 to t3 is an integer of 2 or more, a plurality of L₅₁ to L₅₃ may each independently be a substituted or unsubstituted arylene group of 6 to 30 ring-forming carbon atoms, or a substituted or unsubstituted heteroarylene group of 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenyl-4-yl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalen-2-yl)anthracene (ADN), 1,3-bis[3,5-di(pyridin-3-yl)phenyl]benzene (BmPyPhB), and/or a mixture thereof.

In one or more embodiments, the electron transport region ETR may include at least one selected from among Compounds ET1 to ET36.

[chemical structure]

[chemical structure]

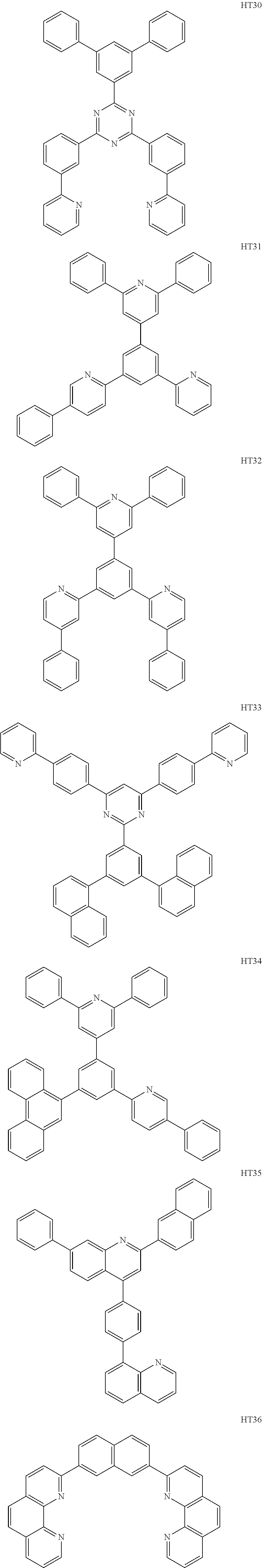

In one or more embodiments, the electron transport region ETR may include a metal halide, such as LiF, NaCl, CsF, RbCl, RbI, CuI and/or KI, a lanthanide metal such as Yb, and/or a co-depositing material of the metal halide and the lanthanide metal. For example, in one or more embodiments, the electron transport region ETR may include KI:Yb, RbI:Yb, LiF:Yb, and/or the like, as the co-depositing material. In one or more embodiments, the electron transport region ETR may use a metal oxide such as Li₂O and BaO, or 8-hydroxy-lithium quinolate (Liq). However, embodiments of the disclosure are not limited thereto. The electron transport region ETR also may be formed using a mixture material of an electron transport material and an insulating organo metal salt. The organo metal salt may be a material having an energy band gap of about 4 eV or more. For example, the organo metal salt may include, for example, metal acetates, metal benzoates, metal acetoacetates, metal acetylacetonates, and/or metal stearates.

In one or more embodiments, the electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, embodiments of the present disclosure are not limited thereto.

The electron transport region ETR may include the compounds of the electron transport region in at least one among an electron injection layer EIL, an electron transport layer ETL, and a hole blocking layer HBL.

If (e.g., when) the electron transport region ETR includes the electron transport layer ETL, a thickness of the electron transport layer ETL may be from about 100 Å to about 1,000 Å, for example, from about 150 Å to about 500 Å. If the thickness of the electron transport layer ETL satisfies the above-described range, satisfactory electron transport properties may be obtained without substantial increase in driving voltage. If (e.g., when) the electron transport region ETR includes the electron injection layer EIL, the thickness of the electron injection layer EIL may be from about 1 Å to about 100 Å, and from about 3 Å to about 90 Å. If a thickness of the electron injection layer EIL satisfies the above-described range, satisfactory electron injection properties may be obtained without inducing substantial increase in driving voltage.

The second electrode EL2 may be provided on the electron transport region ETR. The second electrode EL2 may be a common electrode. The second electrode EL2 may be a cathode or an anode, but embodiments of the present disclosure are not limited thereto. For example, if (e.g., when) the first electrode EL1 is an anode, the second cathode EL2 may be a cathode, and if (e.g., when) the first electrode EL1 is a cathode, the second electrode EL2 may be an anode.

The second electrode EL2 may be a transmissive electrode, a transflective electrode or a reflective electrode. If (e.g., when) the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or compounds or mixtures including thereof (for example, AgMg, AgYb, or MgYb). In one or more embodiments, the second electrode EL2 may have a multilayered structure including a reflective layer or a transflective layer formed using the above-described materials and a transparent conductive layer formed using ITO, IZO, ZnO, ITZO, and/or the like. For example, the second electrode EL2 may include the aforementioned metal materials, combinations of two or more metal materials selected from among the aforementioned metal materials, and/or oxides of the aforementioned metal materials.

In one or more embodiments, the second electrode EL2 may be connected with an auxiliary electrode. If (e.g., when) the second electrode EL2 is connected with the auxiliary electrode, the resistance of the second electrode EL2 may decrease.

In one or more embodiments, a capping layer CPL may be further arranged on the second electrode EL2 in the light emitting element ED. The capping layer CPL may include a multilayer or a single layer.

In one or more embodiments, the capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNx, SiOy, and/or the like.

In one or more embodiments, if (e.g., when) the capping layer CPL includes an organic material, the organic material may include α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazole sol-9-yl) triphenylamine (TCTA), and/or the like, or includes an epoxy resin, and/or an acrylate, such as methacrylate. In addition, a capping layer CPL may include at least one selected from among Compounds P1 to P5, but embodiments of the disclosure are not limited thereto.

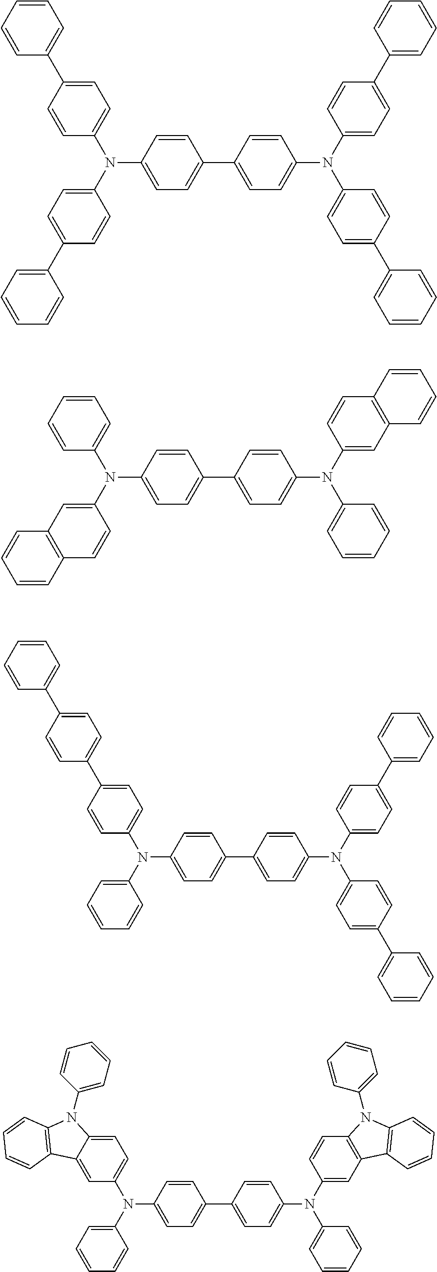 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

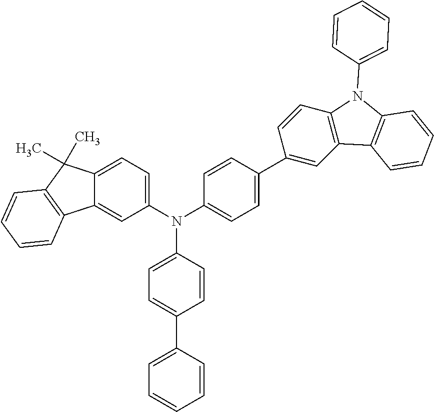 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or greater. For example, the refractive index of the capping layer CPL with respect to light in a wavelength range of about 550 nm to about 660 nm may be about 1.6 or greater.

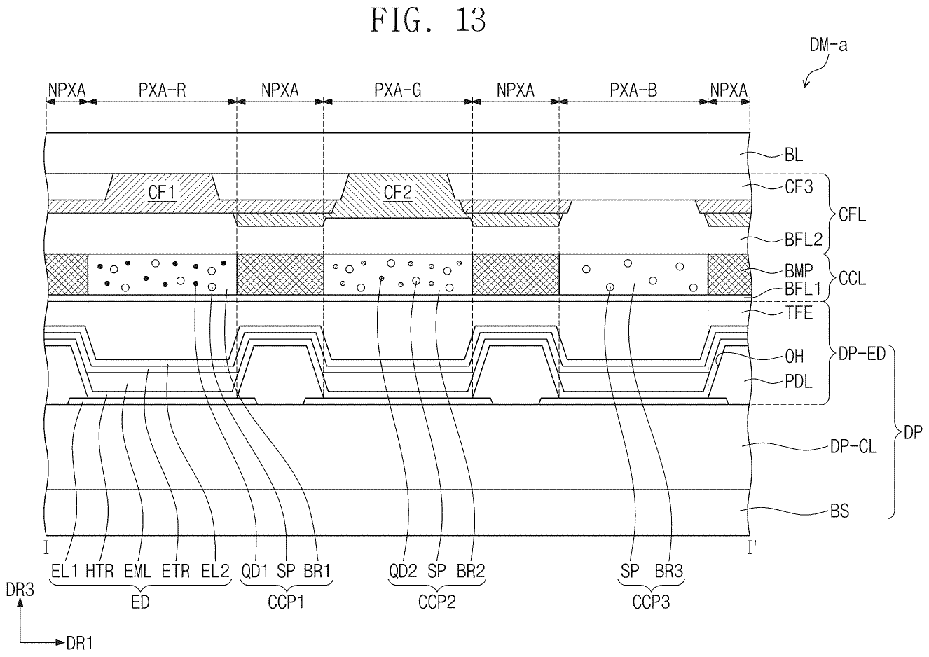

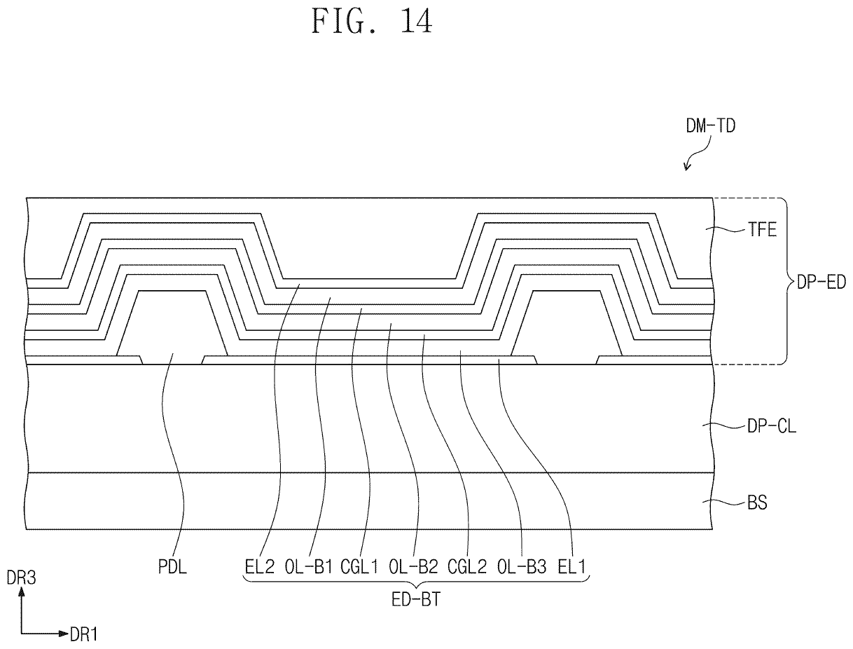

FIGS. 13-16 are cross-sectional views on display modules according to one or more embodiments. In the explanation on the display modules according to one or more embodiments referring to FIGS. 13-16, the overlapping parts with the explanation on FIG. 1 to FIG. 9 will not be explained again for conciseness, and the different features will be explained chiefly.

Referring to FIG. 13, a display module DM-a according to one or more embodiments may include a display panel DP including a display element layer DP-ED, a light control layer CCL arranged on the display panel DP, and a color filter layer CFL. In one or more embodiments shown in FIG. 13, the display panel DP includes a base layer BS, a circuit layer DP-CL provided on the base layer BS and a display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. The same structures as the light emitting elements of FIGS. 5-9 may be applied to the structure of the light emitting element ED shown in FIG. 13. The light emitting element ED illustrated in FIG. 13 may include the fused polycyclic compound of one or more embodiments. Accordingly, the light emitting element ED may exhibit high efficiency and long-life characteristics. In addition, the light emitting element ED according to one or more embodiments may exhibit high light efficiency and long-life characteristics in a blue light emitting range.

Referring to FIG. 13, the emission layer EML may be arranged in an opening part OH defined in a pixel definition layer PDL. For example, the emission layer EML divided by the pixel definition layer PDL and correspondingly provided to each of light emitting areas PXA-R, PXA-G, and PXA-B may be to emit light in substantially the same wavelength range. In the display module DM-a according to one or more embodiments, the emission layer EML may be to emit blue light. In one or more embodiments, the emission layer EML may be provided as a common layer for all light emitting areas PXA-R, PXA-G, and PXA-B.

The light control layer CCL may be arranged on the display panel DP. Although the light control layer CCL is shown as being arranged above the display element layer DP-ED, but embodiments of the present disclosure are not limited thereto, and the light control layer CCL may be arranged the display element layer DP-ED. The light control layer CCL may include a light converter. The light converter may be a quantum dot and/or a phosphor. The light converter may transform the wavelength of light provided and then emit. For example, the light control layer CCL may be a layer including a quantum dot or a layer including a phosphor.

The light control layer CCL may include multiple light control parts CCP1, CCP2, and CCP3. The light control parts CCP1, CCP2, and CCP3 may be separated from one another.

Referring to FIG. 13, a partition pattern BMP may be arranged between the separated light control parts CCP1, CCP2, and CCP3, but embodiments of the present disclosure are not limited thereto. FIG. 13 shows that the partition pattern BMP does not overlap the light control parts CCP1, CCP2, and CCP3, but at least a portion of the edge of the light control parts CCP1, CCP2, and CCP3 may overlap with the partition pattern BMP.

The light control layer CCL may include a first light control part CCP1 including a first quantum dot QD1 converting first color light provided from the light emitting element ED into second color light, a second light control part CCP2 including a second quantum dot QD2 converting the first color light into third color light, and a third light control part CCP3 transmitting the first color light.

In one or more embodiments, the first light control part CCP1 may provide red color light, which is the second color light, and the second light control part CCP2 may provide green color light, which is the third color light. The third color control part CCP3 may be to transmit and provide blue color light, which is the first color light provided from the light emitting element ED. For example, the first quantum dot QD1 may be a red color quantum dot, and the second quantum dot QD2 may be a green color quantum dot. For the quantum dots QD1 and QD2, the same contents as those described above may be applied.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) a (e.g., any) quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least any one selected from among TiO₂, ZnO, Al₂O₃, SiO₂, and hollow silica, or may be a mixture of two or more materials selected from among TiO₂, ZnO, Al₂O₃, SiO₂, and hollow silica.

Each of the first light control part CCP1, the second light control part CCP2, and the third light control part CCP3 may respectively include base resins BR1, BR2, and BR3 dispersing the quantum dots QD1 and QD2 and the scatterer SP. In one or more embodiments, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer particle SP dispersed in the third base resin BR3.

The base resins BR1, BR2, and BR3 may be mediums in which the quantum dots QD1 and QD2 and the scatterer SP are dispersed accordingly, and may be composed of one or more suitable resin compositions which may be generally referred to as a binder. For example, the base resins BR1, BR2, and BR3 may be acrylic resins, urethane-based resins, silicone-based resins, epoxy-based resins, and/or the like. The base resins BR1, BR2, and BR3 may be transparent resins. In one or more embodiments, the first base resin BR1, the second base resin BR2 and the third base resin BR3 may be the same or different from one another.

In one or more embodiments, the light control layer CCL may include a barrier layer BFL1. The barrier layer BFL1 may play the role of blocking the penetration of moisture and/or oxygen (hereinafter, will be referred to as “humidity/oxygen”). The barrier layer BFL1 may be arranged on the light control parts CCP1, CCP2, and CCP3 and may block the exposure of the light control parts CCP1, CCP2, and CCP3 to humidity/oxygen. The barrier layer BFL1 may cover the light control parts CCP1, CCP2, and CCP3. In one or more embodiments, a color filter layer CFL may include a barrier layer BFL2 arranged on the light control parts CCP1, CCP2, and CCP3.

The barrier layers BFL1 and BFL2 may each include at least one inorganic layer. For example, in one or more embodiments, the barrier layers BFL1 and BFL2 may each be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, a metal thin film securing light transmittance, and/or the like. The barrier layers BFL1 and BFL2 may each further include an organic film. The barrier layers BFL1 and BFL2 may each independently be composed of a single layer of multiple layers.

In the display module DM-a according to one or more embodiments, the color filter layer CFL may be arranged on the light control layer CCL. For example, in one or more embodiments, the color filter layer CFL may be arranged directly on the light control layer CCL. In these embodiments, the barrier layer BFL2 may not be provided.

The color filter layer CFL may include filters CF1, CF2, and CF3. The color filter layer CFL may include a first filter CF1 transmitting the second color light, a second filter CF2 transmitting the third color light, and a third filter CF3 transmitting the first color light. For example, in one or more embodiments, the first filter CF1 may be a red filter, the second filter CF2 may be a green filter, and the third filter CF3 may be a blue filter. Each of the filters CF1, CF2 and CF3 may include a polymer photosensitive resin and a pigment and/or a dye. For example, the first filter CF1 may include a red pigment and/or dye, the second filter CF2 may include a green pigment and/or dye, and the third filter CF3 may include a blue pigment and/or dye.

However, embodiments of the present disclosure are not limited thereto, and the third filter CF3 may not include (e.g., may exclude) any pigment and/or dye. The third filter CF3 may include a polymer photosensitive resin and not include any pigment or any dye. The third filter CF3 may be transparent. The third filter CF3 may be formed using a transparent photosensitive resin.

In addition, in one or more embodiments, the first filter CF1 and the second filter CF2 may be yellow filters. The first filter CF1 and the second filter CF2 may be provided in one body without distinction.

In one or more embodiments, the color filter layer CFL may further include a light blocking part. The light blocking part may be a black matrix. The light blocking part may be formed by including an organic light blocking material and/or an inorganic light blocking material, including a black pigment and/or a black dye. The light blocking part may prevent or reduce light leakage phenomenon and divide the boundaries among adjacent filters CF1, CF2, and CF3. In addition, in one or more embodiments, the light blocking part may be formed as a blue color filter.

Each of the first to third filters CF1, CF2, and CF3 may be arranged to correspond to each of the first light emitting area PXA-R, the second light emitting area PXA-G, and the third light emitting area PXA-B.

On the color filter layer CFL, a base substrate BL may be arranged. The base substrate BL may be a member providing a base surface on which the color filter layer CFL, the light control layer CCL, and/or the like are arranged. The base substrate BL may be a glass substrate, a metal substrate, a plastic substrate, and/or the like. However, one or more embodiments of the present disclosure are not limited thereto, and the base substrate BL may be an inorganic layer, an organic layer or a composite material layer. In addition, different from the drawing, the base substrate BL may not be provided in an embodiment.

FIG. 14 is a cross-sectional view showing a portion of the display module according to one or more embodiments of the present disclosure. In a display module DM-TD according to one or more embodiments, a light emitting element ED-BT may include a plurality of light emitting structures OL-B1, OL-B2, and OL-B3. At least one selected from among the plurality of light emitting structures OL-B1, OL-B2, and OL-B3 may include the fused polycyclic compound of one or more embodiments. Accordingly, the light emitting element ED-BT may exhibit high efficiency and long-life characteristics. In addition, the light emitting element ED-BT according to one or more embodiments may exhibit high light efficiency and long-life characteristics in a blue light emitting range.

The light emitting element ED-BT may include a first electrode EL1 and second electrode EL2 arranged opposite to each other, and the plurality of light emitting structures OL-B1, OL-B2, and OL-B3 stacked in order in a thickness direction and provided between the first electrode EL1 and the second electrode EL2. Each of the light emitting structures OL-B1, OL-B2, and OL-B3 may include an emission layer EML (FIG. 5), and a hole transport region HTR and an electron transport region ETR arranged with the emission layer EML (FIG. 8) therebetween. For example, the light emitting element ED-BT included in the display module DM-TD according to one or more embodiments may be a light emitting element of a tandem structure including a plurality of emission layers.

In one or more embodiments shown in FIG. 14, light emitted from the light emitting structures OL-B1, OL-B2, and OL-B3 may be all blue color light. However, embodiments of the present disclosure are not limited thereto, and the wavelength ranges of light emitted from the light emitting structures OL-B1, OL-B2, and OL-B3 may be different from each other. For example, the light emitting element ED-BT including the plurality of light emitting structures OL-B1, OL-B2, and OL-B3 emitting light in different wavelength ranges may be to emit white light (e.g., combined white light).

Between neighboring light emitting structures OL-B1, OL-B2, and OL-B3, charge generating layers CGL1 and CGL2 may be arranged. In an embodiment shown in FIG. 14, the charge generating layers CGL1 and CGL2 may include a first charge generating layer CGL1 arranged between the first light emitting structure OL-B1 and the second light emitting structure OL-B2, and a second charge generating layer CGL2 arranged between the second light emitting structure OL-B2 and the third light emitting structure OL-B3. The first and second charge generating layers CGL1 and CGL2 may each independently include a p-type (kind) charge generating layer and/or an n-type (kind) charge generating layer.

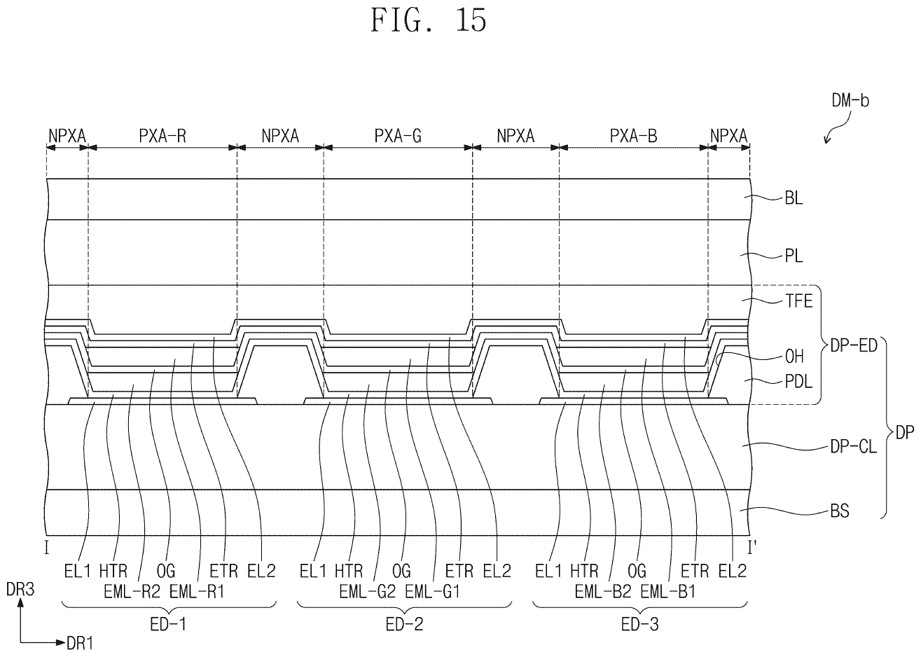

Referring to FIG. 15, a display module DM-b according to one or more embodiments may include light emitting elements ED-1, ED-2 and ED-3, in which two emission layers are stacked. At least one selected from among the light emitting elements ED-1, ED-2, and ED-3 may include the fused polycyclic compound of an embodiment. Accordingly, the light emitting elements ED-1, ED-2, and ED-3 may exhibit high efficiency and long-life characteristics. In addition, the display module DM-b according to one or more embodiments may exhibit high light efficiency and long-life characteristics in a blue light emission range.

Compared to the display module DM according to one or more embodiments, shown in FIG. 3 and FIG. 4, one or more embodiments shown in FIG. 15 is different in that the first to third light emitting elements ED-1, ED-2, and ED-3 respectively include two emission layers stacked in a thickness direction. In the first to third light emitting elements ED-1, ED-2, and ED-3, two emission layers may be to emit light in substantially the same wavelength range.

According to one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. A light emitting auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2. In this regard, at least one of the first blue-color emission layer EML-B1 or the second blue-color emission layer EML-B2 may include the fused polycyclic compound according to one or more embodiments.

The light emitting auxiliary part OG may include a single layer or a multilayer. The light emitting auxiliary part OG may include a charge generating layer. For example, the light emitting auxiliary part OG may include an electron transport region, a charge generating layer, and a hole transport region stacked in sequence (e.g., in the stated order). The light emitting auxiliary part OG may be provided as a common layer in all the first to third light emitting elements ED-1, ED-2, and ED-3. However, embodiments the present disclosure are not limited thereto, and the light emitting auxiliary part OG may be patterned and provided in an opening part OH defined in a pixel definition layer PDL.

The first red color emission layer EML-R1, the first green color emission layer EML-G1 and the first blue color emission layer EML-B1 may be arranged between the light emitting auxiliary part OG and the electron transport region ETR. The second red color emission layer EML-R2, the second green color emission layer EML-G2 and the second blue color emission layer EML-B2 may be arranged between the hole transport region HTR and the light emitting auxiliary part OG.

For example, in one or more embodiments, the first light emitting element ED-1 may include a first electrode EL1, a hole transport region HTR, a second red color emission layer EML-R2, a light emitting auxiliary part OG, a first red color emission layer EML-R1, an electron transport region ETR, and a second electrode EL2, stacked in sequence (e.g., in the stated order). The second light emitting element ED-2 may include a first electrode EL1, a hole transport region HTR, a second green color emission layer EML-G2, a light emitting auxiliary part OG, a first green emission layer EML-G1, an electron transport region ETR, and a second electrode EL2, stacked in order. The third light emitting element ED-3 may include a first electrode EL1, a hole transport region HTR, a second blue emission layer EML-B2, a light emitting auxiliary part OG, a first blue color emission layer EML-B1, an electron transport region ETR, and a second electrode EL2, stacked in sequence (e.g., in the stated order).

An optical auxiliary layer PL may be arranged on a display element layer DP-ED. The optical auxiliary layer PL may include a polarization layer. The optical auxiliary layer PL may be arranged on a display panel DP and may control reflected light at the display panel DP by external light. Different from the drawing, the optical auxiliary layer PL may not be provided in the display module according to one or more embodiments.

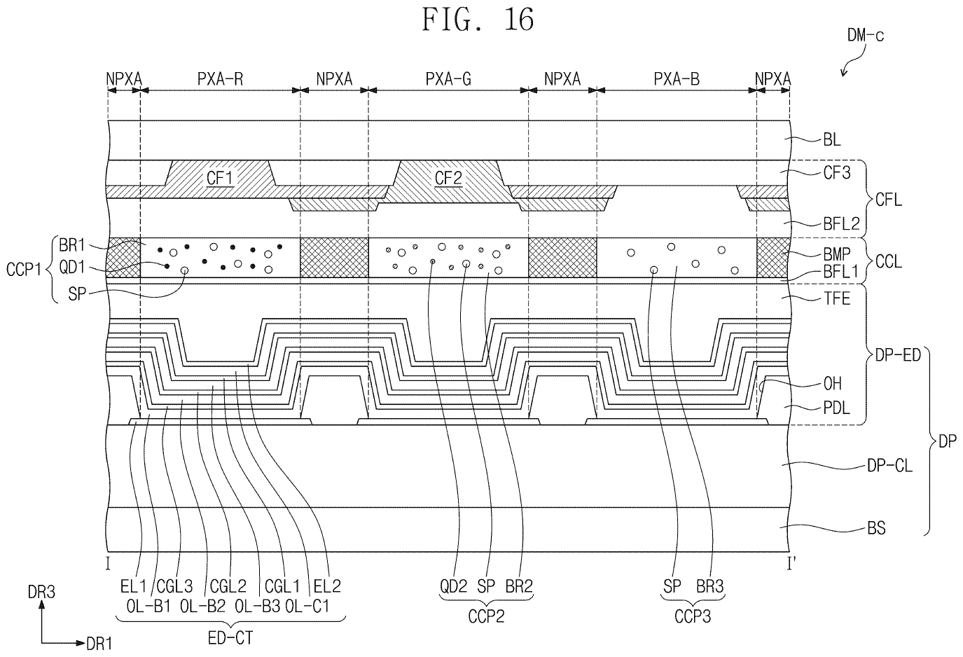

Unlike FIG. 14 and FIG. 15, FIG. 16 shows a display module DM-c according to one or more embodiments that includes four light emitting structures OL-B1, OL-B2, OL-B3, and OL-C1. A light emitting element ED-CT may include a first electrode EL1 and second electrode EL2 arranged opposite to each other, and first to fourth light emitting structures OL-B1, OL-B2, OL-B3 and OL-C1 stacked in order in a thickness direction between the first electrode EL1 and the second electrode EL2. At least one selected from among the first to fourth light emitting structures OL-B1, OL-B2, OL-B3, and OL-C1 may include the fused polycyclic compound according to one or more embodiments. Accordingly, the light emitting element ED-CT may exhibit high efficiency and long-life characteristics. In addition, the light emitting element ED-CT according to one or more embodiments may exhibit high light efficiency and long-life characteristics in a blue light emitting range.

Between the first to fourth light emitting structures OL-B1, OL-B2, OL-B3, and OL-C1, charge generating layers CGL3, CGL2 and CGL1 may be arranged. Among the four light emitting structures, the first to third light emitting structures OL-B1, OL-B2, and OL-B3 emit blue color light, and the fourth light emitting structure OL-C1 may be to emit green color light. However, embodiments of the present disclosure are not limited thereto, and the first to fourth light emitting structures OL-B1, OL-B2, OL-B3, and OL-C1 may be to emit different wavelengths of light. Charge generating layers CGL3, CGL2, and CGL1 arranged between neighboring light emitting structures OL-B1, OL-B2, OL-B3, and OL-C1 may each include a p-type (kind) charge generating layer and/or an n-type (kind) charge generating layer.

In one or more embodiments, an electronic apparatus may include a display device including a plurality of light emitting elements, and a control part for controlling the display device. In one or more embodiments, the electronic apparatus may include at least one selected from among the plurality of light emitting elements may include the fused polycyclic compound according to one or more embodiments described above in the emission layer.

The electronic apparatus of one or more embodiments may be a device activated according to electrical signals. The electronic apparatus according to one or more embodiments may include one or more display devices including the display modules according to one or more embodiments described with reference to FIG. 3, FIGS. 13-16, and/or the like. For example, the electronic apparatus may include large-sized display devices, such as televisions, monitors and outside billboards, and/or medium-sized and/or small-sized display devices, such as personal computers, laptop computers, personal digital terminals, display devices for automobiles, game consoles, portable electronic apparatuses, or cameras.

The electronic apparatus according to one or more embodiments may include a display module including the fused polycyclic compound of an embodiment and may exhibit high efficiency and long-life characteristics. The electronic apparatus according to one or more embodiments may have improved display efficiency and display lifespan and may exhibit excellent or suitable display quality.

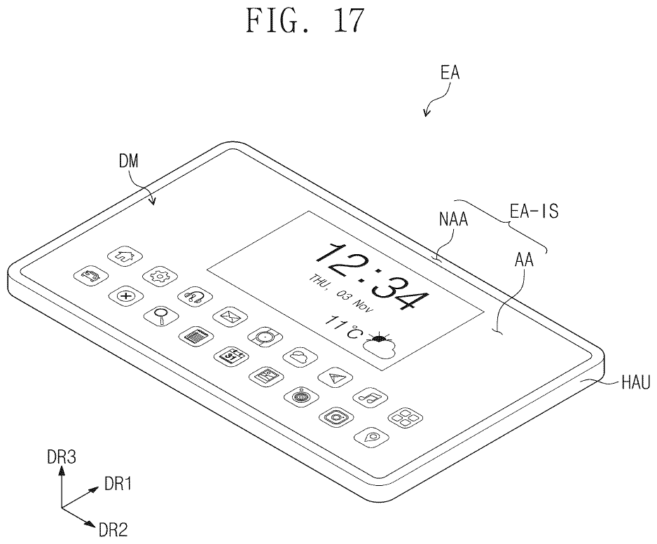

FIG. 17 illustrates a tablet terminal according to one or more embodiments of an electronic apparatus EA. The electronic apparatus EA of one or more embodiments may include a display module DM according to one or more embodiments. For example, electronic modules, a camera module, a power module, and/or the like, mounted on a main board may be arranged in a bracket/housing HAU together with the display module DM to configure a tablet terminal.

The electronic apparatus EA according to one or more embodiments illustrated in FIG. 17 may include the display module according to one or more embodiments described with reference to FIG. 3, FIGS. 13-16, and/or the like.

In one or more embodiments, an electronic apparatus EA including a display module DM having a flat display surface is shown, but embodiments of the present disclosure are not limited thereto. The electronic apparatus EA may also include a curved display surface or a three-dimensional display surface. For example, a three-dimensional display surface may include a plurality of display areas pointing in different directions and may also include a bent display surface. The electronic apparatus EA according to these embodiments may be a flexible electronic apparatus. The flexible electronic apparatus may be a foldable electronic apparatus that is foldable.

As shown in FIG. 17, a display surface EA-IS includes an active area AA on which an image is displayed and a bezel area NAA adjacent to the active area AA. The bezel area NAA is an area where an image is not displayed. FIG. 17 illustrates icon images as embodiments of the image. The active area AA may be referred to as a display area of the display module DM, and the bezel area NAA may be referred to as a non-display area of the display module DM.

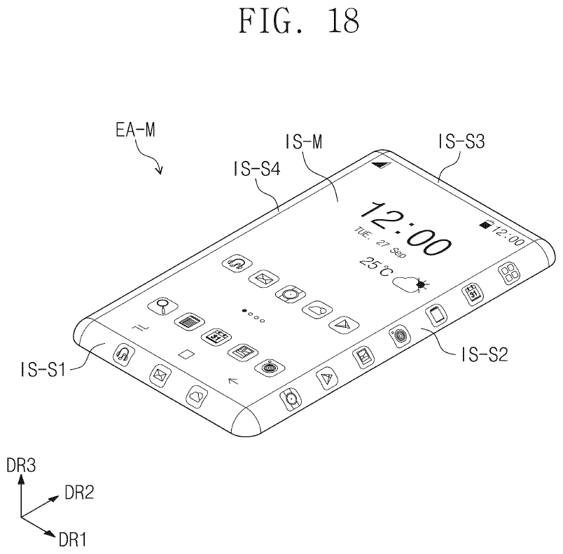

FIG. 18 illustrates a portable terminal as an embodiment of an electronic apparatus EA-M according to an embodiment. Referring to FIG. 17, the electronic apparatus EA-M according to an embodiment may include a plurality of display surfaces. The electronic apparatus EA-M of an embodiment may include display surfaces IS-M, IS-S1, IS-S2, IS-S3 and IS-S4, having different main display directions.

In one or more embodiments, the electronic apparatus EA-M may be a three-dimensional display device including an upper display surface IS-M and a plurality of side display surfaces IS-S1, IS-S2, IS-S3, and IS-S4. Each of the plurality of side display surfaces IS-S1, IS-S2, IS-S3, and IS-S4 may be a display surface extending from one side of the upper display surface IS-M. In one or more embodiments, the electronic apparatus EA-M may include a main display surface that mainly provides images in one direction and a plurality of sub-display surfaces that provide images in a direction different from the one direction. In one or more embodiments of the electronic apparatus EA-M illustrated in FIG. 18, the main display surface may be the upper display surface IS-M, and the sub-display surfaces may be the side display surfaces IS-S1, IS-S2, IS-S3, and IS-S4.

The side display surfaces IS-S1, IS-S2, IS-S3, and IS-S4 may have display surfaces that are not parallel to the upper display surface IS-M. In one or more embodiments, the plurality of side display surfaces IS-S1, IS-S2, IS-S3, and IS-S4 may be display areas that are each bent and extended from one side of the upper display surface IS-M, and for example, the plurality of side display surfaces IS-S1, IS-S2, IS-S3, and IS-S4 may be bending display areas.

The electronic apparatus EA-M illustrated in FIG. 18 may include the display modules according to one or more embodiments described with reference to FIG. 3, FIGS. 13-16, and/or the like.

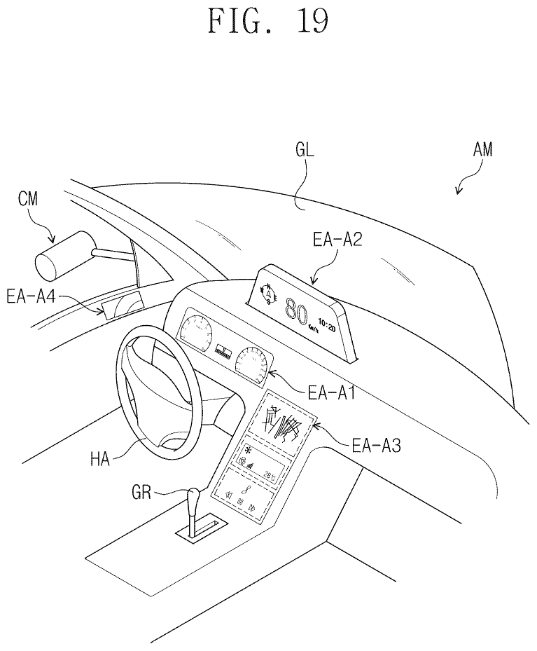

FIG. 19 is a diagram showing a vehicle AM in which first to fourth electronic apparatuses EA-1, EA-2, EA-3, and EA-4 are arranged. At least one selected from among the first to fourth electronic apparatuses EA-1, EA-2, EA-3, and EA-4 may include the display modules of embodiments described with reference to FIG. 3 and FIGS. 13-16.

In FIG. 19, a car is illustrated as a vehicle AM, but this is an example, and the first to fourth electronic apparatuses EA-1, EA-2, EA-3, and EA-4 may be arranged on other transportation refers to such as a bicycle, a motorcycle, a train, a ship, or an airplane.

At least one selected from among the first to fourth electronic apparatuses EA-1, EA-2, EA-3, and EA-4 may include the light emitting elements ED of embodiments described with reference to FIGS. 5-9. At least one selected from among the first to fourth electronic apparatuses EA-1, EA-2, EA-3, and EA-4 may include the fused polycyclic compound according to one or more embodiments. Accordingly, the first to fourth electronic apparatuses EA-1, EA-2, EA-3, and EA-4 including the fused polycyclic compound according to one or more embodiments may have improved display efficiency and display lifespan. In addition, the first to fourth electronic apparatuses EA-1, EA-2, EA-3, and EA-4 including the fused polycyclic compound according to one or more embodiments may exhibit excellent or suitable display quality.

Referring to FIG. 19, the vehicle AM may include a steering wheel HA and a gear GR for motion control and may include a front window GL arranged in front of a driver.

The first electronic apparatus EA-A1 may be a digital cluster that displays the first information of the vehicle AM. The first information may include a first scale indicating the driving speed of the vehicle AM, a second scale indicating the engine revolutions per minute (RPM), and an image indicating the fuel condition. The first scale and the second scale may be displayed as digital images. In one or more embodiments illustrated in FIG. 19, the first electronic apparatus EA-A1 may be arranged in a first area overlapping the steering wheel HA. However, embodiments of the present disclosure are not limited thereto, and the first electronic apparatus EA-A1 may be arranged on the entire dashboard or may be separately arranged in a portion opposite to (e.g., facing) the driver's seat and a portion opposite to (e.g., facing) the passenger's seat, respectively.

The second electronic apparatus EA-A2 may be arranged in a second area between the driver's seat and the front window GL. For example, the second electronic apparatus EA-A2 may be a head-up display (HUD) that displays the second information of the vehicle AM. The second electronic apparatus EA-A2 may be optically transparent. The second information includes a digital number indicating the driving speed of the vehicle AM and may further include information such as the current time. In one or more embodiments, the second information of the second electronic apparatus EA-A2 may be projected and displayed on the front window GL. The display surface of the second electronic apparatus EA-A2 may face the driver's seat. Also, the second electronic apparatus EA-A2 may provide an image in the direction of the front window GL.

The third electronic apparatus EA-A3 may be arranged in a third area adjacent to the gear GR. For example, the third electronic apparatus EA-A3 may be a vehicle information guide display (Center Information Display (CID)) arranged between the driver's seat and the passenger's seat and may display third information. The passenger's seat may be a seat spaced from the driver's seat with the gear GR therebetween. The third information may include information about road conditions (for example, navigation information), music or radio playback, dynamic image playback, temperature inside the vehicle AM, and/or the like.

The fourth electronic apparatus EA-A4 may be arranged in a fourth area separate from the steering wheel HA and the gear GR and adjacent to the side of the vehicle AM. For example, the fourth electronic apparatus EA-A4 may be a digital side mirror that displays the fourth information. The fourth electronic apparatus EA-A4 may display an image of the outside of the vehicle AM captured by a camera module CM arranged on the outside of the vehicle AM. The fourth information may include an image of the outside of the vehicle AM.

The first to fourth information described above are examples, and the first to fourth electronic apparatuses EA-A1, EA-A2, EA-A3 and EA-A4 may further display information about the inside and outside of the vehicle. The first to fourth information may include different information from one another. However, embodiments of the present disclosure are not limited thereto, and some of the first to fourth pieces of information may include the same information.

FIGS. 17-19 present embodiments of electronic apparatuses or embodiments including electronic apparatuses, and the display module including the light emitting element including the fused polycyclic compound according to one or more embodiments may be employed in other electronic apparatuses without departing from the concept and teaching of the present disclosure.

Hereinafter, the fused polycyclic compound according to one or more embodiments of the present disclosure and the light emitting element according to one or more embodiments will be specifically described with reference to examples and comparative examples. In addition, the examples shown are examples to help understanding of the disclosure, and the scope of the disclosure is not limited thereto.

### EXAMPLES

### 1. Synthesis of Fused Polycyclic Compounds of Embodiments

The synthetic method of the fused polycyclic compound according to one or more embodiments will be explained in in more detail by illustrating the synthetic methods of Compounds A-3, B-8, C-16, D-6, E-4, and E-8. In addition, the synthetic methods of the fused polycyclic compounds explained hereinafter are examples, and the synthetic method of the compound according to one or more embodiments of the present disclosure is not limited to the following examples.

### (1) Synthesis of Compound A-3

### Synthesis of Intermediate A-3-6

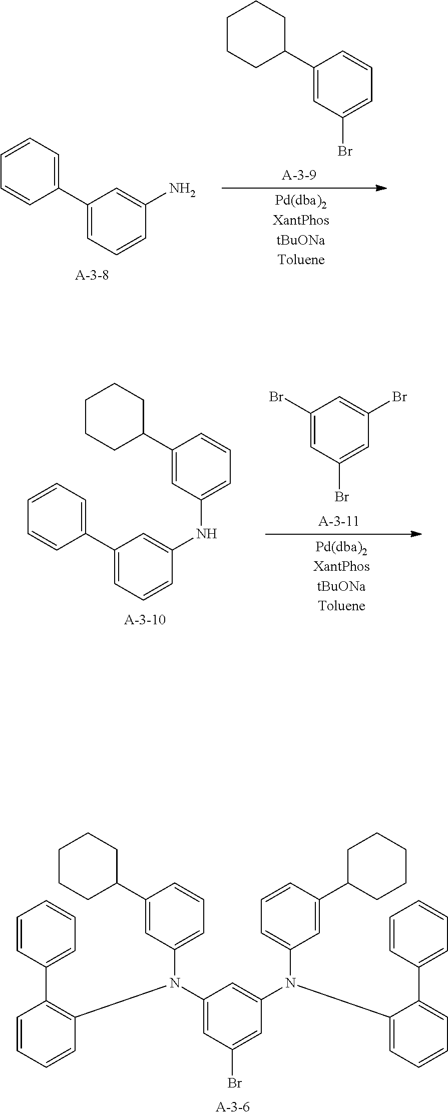 [SMILES: Nc1cccc(-c2ccccc2)c1 ; Brc1cccc(C2CCCCC2)c1 ; c1ccc(-c2cccc(Nc3cccc(C4CCCCC4)c3)c2)cc1 ; Brc1cc(Br)cc(Br)c1 ; Brc1cc(N(c2cccc(C3CCCCC3)c2)c2ccccc2-c2ccccc2)cc(N(c2cccc(C3CCCCC3)c2)c2ccccc2-c2ccccc2)c1]

Under an argon (Ar) atmosphere, A-3-8 (700 mmol), A-3-9 (700 mmol), tBuONa (1050 mmol), Pd(dba)₂ (35 mmol), and XantPhos (70 mmol) were added to a three-necked flask, and 1000 mL of toluene was added thereto, followed by stirring at about 80° C. for about 8 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 630 mmol of A-3-10 (yield 90%). The mass number of A-3-10 measured by Fast Atom Bombardment-Mass spectrometry (FAB-MS) was 327.

Next, under an argon (Ar) atmosphere, A-3-10 (630 mmol), A-3-11 (315 mmol), tBuONa (882 mmol), Pd(dba)₂ (32 mmol), and XantPhos (64 mmol) were added to a three-necked flask, 1200 mL of toluene was added thereto, and the mixture was stirred at about 80° C. for about 8 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 255 mmol of A-3-6 (yield 81%). The mass number of A-3-6 measured by FAB-MS was 807.

### Synthesis of Compound A-3

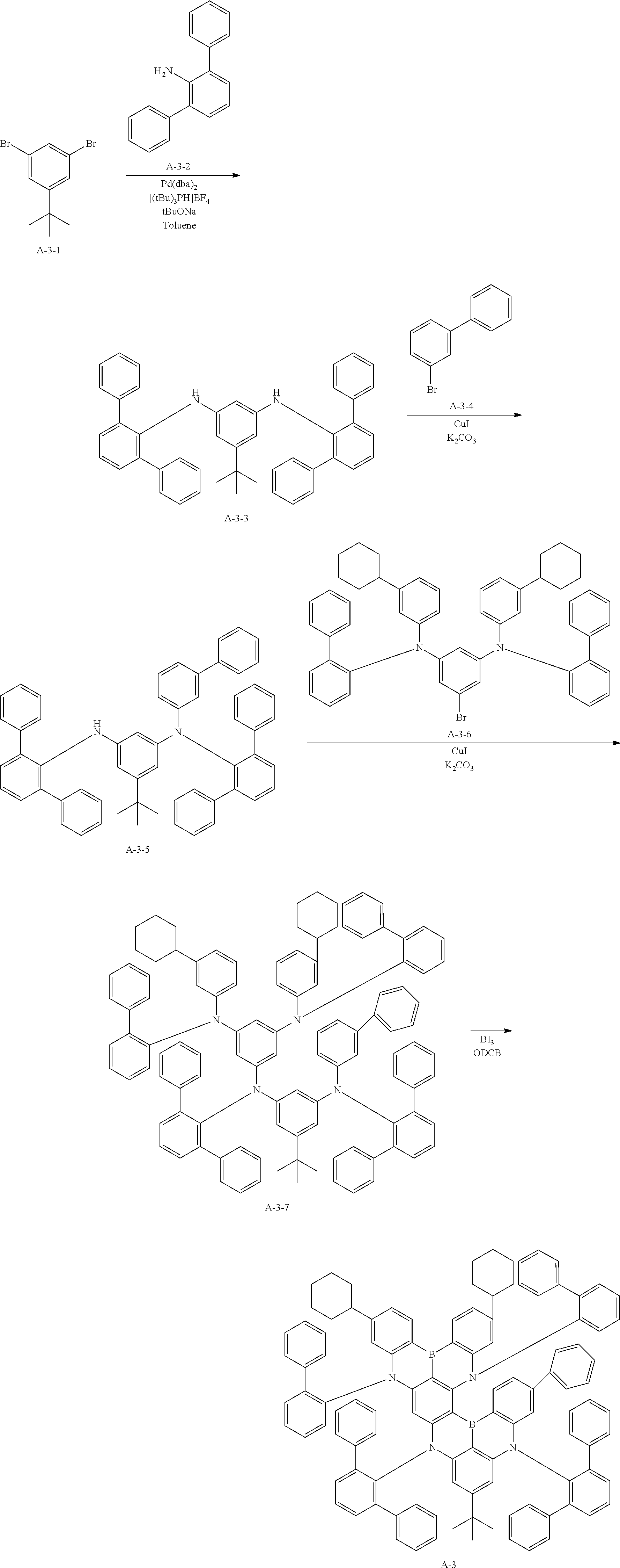

Under an argon (Ar) atmosphere, A-3-1 (200 mmol), A-3-2 (410 mmol), tBuONa (600 mmol), Pd(dba)₂ (10 mmol), and [(tBu)₃PH]BF₄ (20 mmol) were added to a three-necked flask, 1,000 mL of toluene was added thereto, and the mixture was stirred at about 90° C. for about 5 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 162 mmol of A-3-3 (81% yield). The mass number of A-3-3 measured by FAB-MS was 620.

Next, under an argon (Ar) atmosphere, A-3-3 (162 mmol), A-3-4 (810 mmol), K₂CO₃ (972 mmol), and Gui (178 mmol) were added to a three-necked flask and stirred at about 210° C. for about 72 hours. Water was added thereto, an organic layer was extracted using toluene and dried over magnesium sulfate, and the solvent was distilled off. The crude product thus obtained was purified by silica gel column chromatography (hexane/toluene mixed solvent) and recrystallization (ethanol/toluene mixed solvent) to obtain 89 mmol (55% yield) of A-3-5. The mass number of A-3-5 measured by FAB-MS was 773.

Next, under an argon (Ar) atmosphere, A-3-5 (89 mmol), A-3-6 (255 mmol), K₂CO₃ (534 mmol), and CuI (98 mmol) were added to a three-necked flask and stirred at about 210° C. for about 72 hours. Water was added thereto, an organic layer was extracted using toluene and dried over magnesium sulfate, and the solvent was distilled off. The crude product thus obtained was purified by silica gel column chromatography (hexane/toluene mixed solvent) and recrystallization (ethanol/toluene mixed solvent) to obtain 37 mmol (42% yield) of A-3-7. The mass number of A-3-7 measured by FAB-MS was 1500.

Next, under an argon (Ar) atmosphere, A-3-7 (37 mmol) was added to a three-necked flask, 37 mL of ODCB was added thereto and dissolved, BI₃ (148 mmol) was added thereto, and the mixture was stirred at about 140° C. for about 3 hours. After dispersing and washing the reaction solution using a large amount of acetonitrile, the solid was filtered and recovered. The crude product thus obtained was purified by silica gel column chromatography (hexane/toluene mixed solvent) and recrystallization (ethanol/toluene mixed solvent) to obtain 11 mmol of A-3 (yield 29%). The mass number of A-3 measured by FAB-MS was 1515.

### (2) Synthesis of Compound B-8

### Synthesis of Intermediate B-8-5

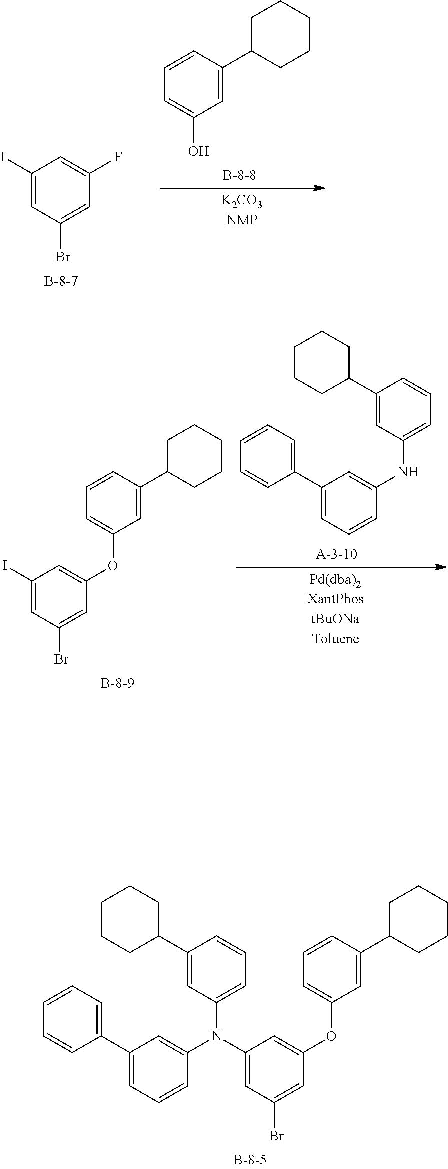

Under an argon (Ar) atmosphere, B-8-7 (300 mmol), B-8-8 (300 mmol), and K₂CO₃ (600 mmol) were added to a three-necked flask, 200 mL of NMP was added thereto, and the mixture was stirred at about 150° C. for about 24 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 237 mmol of B-8-9 (yield 79%). The mass number of B-8-9 measured by FAB-MS was 457.

Next, under an argon (Ar) atmosphere, B-8-9 (237 mmol), A-3-10 (237 mmol), tBuONa (356 mmol), Pd(dba)₂ (12 mmol), and XantPhos (24 mmol) were added to a three-necked flask, 800 mL of toluene was added thereto, and the mixture was stirred at about 80° C. for about 8 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 210 mmol of B-8-5 (yield 89%). The mass number of B-8-5 measured by FAB-MS was 656.

### Synthesis of Compound B-8

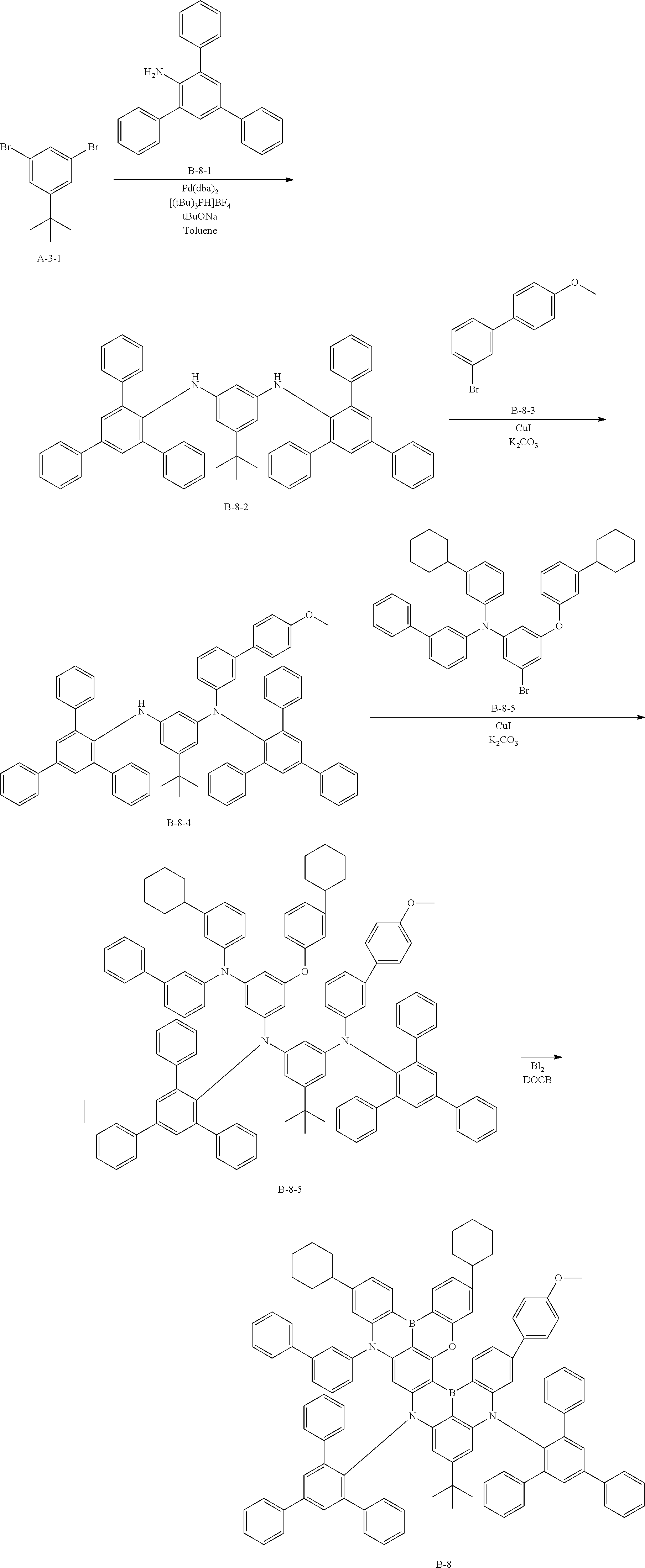

Under an argon (Ar) atmosphere, A-3-1 (200 mmol), B-8-1 (410 mmol), tBuONa (600 mmol), Pd(dba)₂ (10 mmol), and [(tBu)₃PH]BF₄ (20 mmol) were added to a three-necked flask, 1,000 mL of toluene was added thereto, and the mixture was stirred at about 90° C. for about 5 hours. Water was added thereto, an organic layer was extracted with toluene and dried over magnesium sulfate, and the solvent was distilled off. The crude product thus obtained was purified by silica gel column chromatography (hexane/toluene mixed solvent) and recrystallization (ethanol/toluene mixed solvent) to obtain 166 mmol of B-8-2 (83% yield). The mass number of B-8-2 measured by FAB-MS was 773.

Next, under an argon (Ar) atmosphere, B-8-2 (166 mmol), B-8-3 (830 mmol), K₂CO₃ (996 mmol), and CuI (183 mmol) were added to a three-necked flask and stirred at about 210° C. for about 72 hours. Water was added thereto, an organic layer was extracted using toluene and dried over magnesium sulfate, and the solvent was distilled off. The crude product thus obtained was purified by silica gel column chromatography (hexane/toluene mixed solvent) and recrystallization (ethanol/toluene mixed solvent) to obtain 81 mmol (49% yield) of B-8-4. The mass number of B-8-4 measured by FAB-MS was 955.

Next, under an argon (Ar) atmosphere, B-8-4 (81 mmol), B-8-5 (210 mmol), K₂CO₃ (486 mmol), and CuI (89 mmol) were added to a three-necked flask and stirred at about 210° C. for about 72 hours. Water was added thereto, an organic layer was extracted using toluene and dried over magnesium sulfate, and the solvent was distilled off. The crude product thus obtained was purified by silica gel column chromatography (hexane/toluene mixed solvent) and recrystallization (ethanol/toluene mixed solvent) to obtain 32 mmol (40% yield) of B-8-6. The mass number of B-8-6 measured by FAB-MS was 1531.

Next, under an argon (Ar) atmosphere, B-8-6 (32 mmol) was added to a three-necked flask, 32 mL of ODCB was added thereto and dissolved, B13 (128 mmol) was added thereto, and the mixture was stirred at about 140° C. for about 3 hours. The reaction solution was dispersed and washed with a large amount of acetonitrile, and the solid was filtered and recovered. The crude product thus obtained was purified by silica gel column chromatography (hexane/toluene mixed solvent) and recrystallization (ethanol/toluene mixed solvent) to obtain 10 mmol of B-8 (yield 33%). The mass number of B-8 measured by FAB-MS was 1546.

### (3) Synthesis of Compound C-16

### Synthesis of Intermediate C-16-2

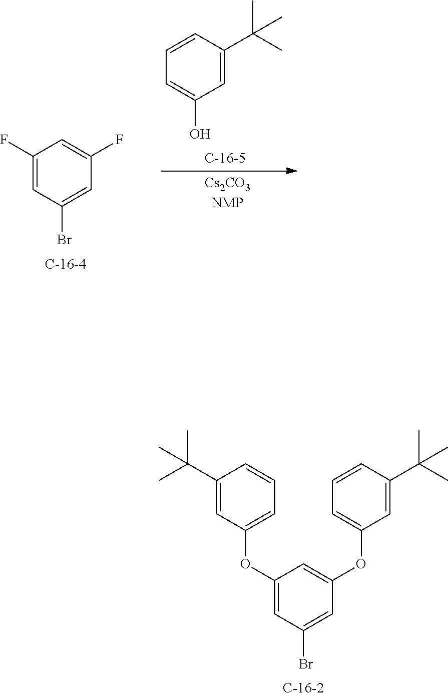

Under an argon (Ar) atmosphere, C-16-4 (300 mmol), C-16-5 (630 mmol), and Cs₂CO₃ (900 mmol) were added to a three-necked flask, 500 mL of NMP was added thereto, and the mixture was stirred at about 165° C. for about 3 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 270 mmol of C-16-2 (yield 90%). The mass number of C-16-2 measured by FAB-MS was 453.

### Synthesis of Compound C-16

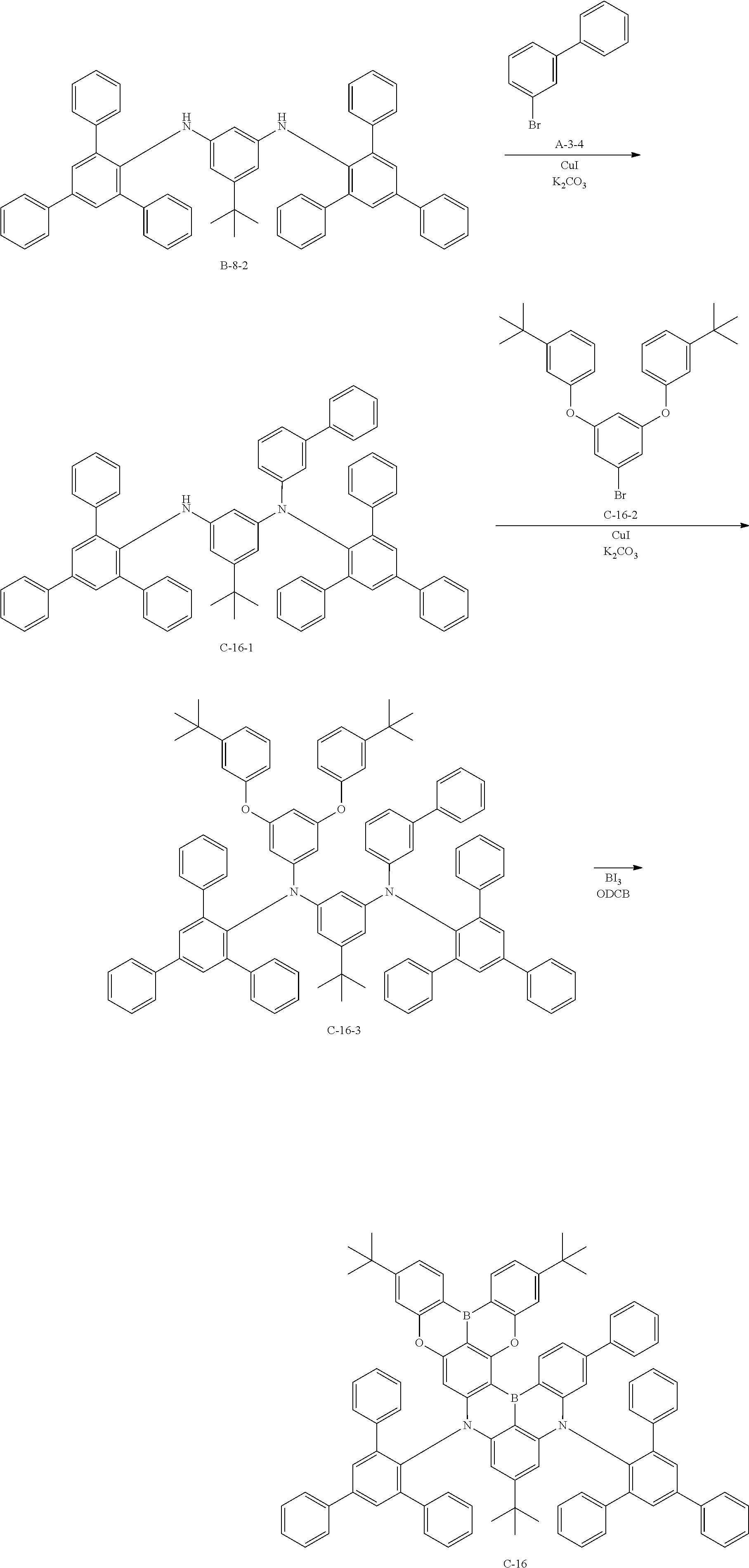

Under an argon (Ar) atmosphere, B-8-2 (111 mmol), A-3-4 (555 mmol), K₂CO₃ (666 mmol), and CuI (122 mmol) were added to a three-necked flask and stirred at about 210° C. for about 72 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 50 mmol of C-16-1 (45% yield). The mass number of C-16-1 measured by FAB-MS was 925.

Next, under an argon (Ar) atmosphere, C-16-1 (50 mmol), C-16-2 (270 mmol), K₂CO₃ (300 mmol), and CuI (55 mmol) were added to a three-necked flask and stirred at about 210° C. for about 72 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 30 mmol of C-16-3 (yield 59%). The mass number of C-16-3 measured by FAB-MS was 1297.

Next, under an argon (Ar) atmosphere, C-16-3 (30 mmol) was added to a three-necked flask, 30 mL of orthodichlorobenzene (ODCB) was added thereto and dissolved, BI₃ (120 mmol) was added thereto, and the mixture was stirred at about 140° C. for about 3 hours. The reaction solution was dispersed and washed with a large amount of acetonitrile, and the solid was filtered and recovered. The crude product thus obtained was purified by silica gel column chromatography (hexane/toluene mixed solvent) and recrystallization (ethanol/toluene mixed solvent) to obtain 17 mmol of C-16 (yield 55%). The mass number of C-16 measured by FAB-MS was 1313.

### (4) Synthesis of Compound D-6

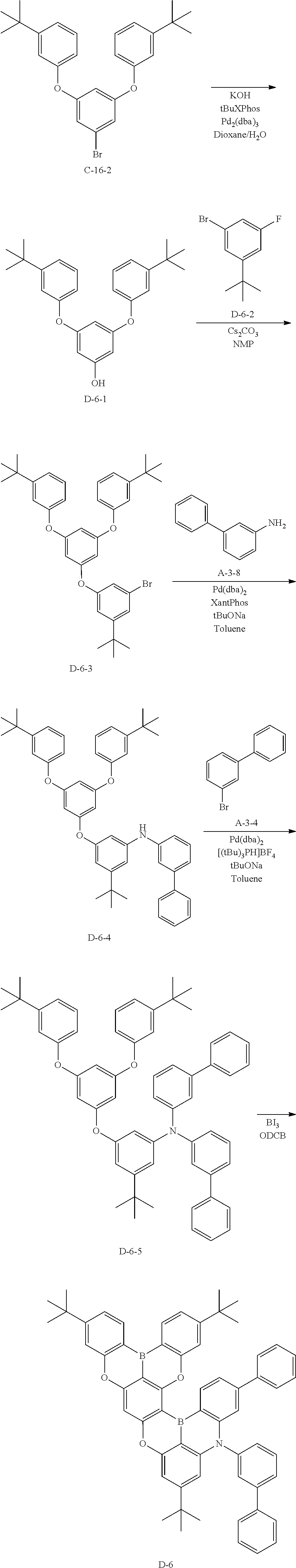

Under an argon (Ar) atmosphere, C-16-2 (270 mmol), KOH (810 mmol), Pd(dba)₂ (2 mmol), and tBuXPhos (8 mmol) were added to a three-necked flask, and 60 m L of dioxane and 60 m L of H₂O were added thereto, followed by stirring at about 100° C. for about 6 hours. 10% hydrochloric acid was added thereto, an organic layer was extracted with toluene and dried over magnesium sulfate, and the solvent was distilled off. The crude product thus obtained was purified by silica gel column chromatography (hexane/toluene mixed solvent) to obtain 137 mmol of D-6-1 (yield 51%). The mass number of D-6-1 measured by FAB-MS was 390.

Next, under an argon (Ar) atmosphere, D-6-1 (137 mmol), D-6-2 (137 mmol), and Cs₂CO₃ (411 mmol) were added to a three-necked flask, and 400 mL of NMP was added thereto, followed by stirring at about 165° C. for about 5 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 112 mmol of D-6-3 (yield 82%). The mass number of D-6-3 measured by FAB-MS was 601.

Next, under an argon (Ar) atmosphere, D-6-3 (112 mmol), A-3-8 (123 mmol), tBuONa (168 mmol), Pd(dba)₂ (6 mmol), and [(tBu)₃PH]BF₄ (12 mmol) were added to a three-necked flask, 1000 mL of toluene was added thereto, and the mixture was stirred at about 90° C. for about 6 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 99 mmol of D-6-4 (yield 89%). The mass number of D-6-4 measured by FAB-MS was 689.

Next, under an argon (Ar) atmosphere, D-6-4 (99 mmol), A-3-4 (109 mmol), tBuONa (149 mmol), Pd(dba)₂ (5 mmol), and [(tBu)₃PH]BF₄ (10 mmol) were added to a three-necked flask, 1000 mL of toluene was added thereto, and the mixture was stirred at about 90° C. for about 6 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 85 mmol of D-6-5 (yield 86%). The mass number of D-6-5 measured by FAB-MS was 842.

Next, under an argon (Ar) atmosphere, D-6-5 (85 mmol) was added to a three-necked flask, 85 mL of ODCB was added thereto and dissolved, B13 (340 mmol) was added thereto, and the mixture was stirred at about 140° C. for about 12 hours. The reaction solution was dispersed and washed with a large amount of acetonitrile, and the solid was filtered and recovered. The crude product thus obtained was purified by silica gel column chromatography (hexane/toluene mixed solvent) and recrystallization (ethanol/toluene mixed solvent) to obtain 7 mmol of D-6 (yield 9%). The mass number of D-6 measured by FAB-MS was 857.

### (5) Synthesis of Compound E-4

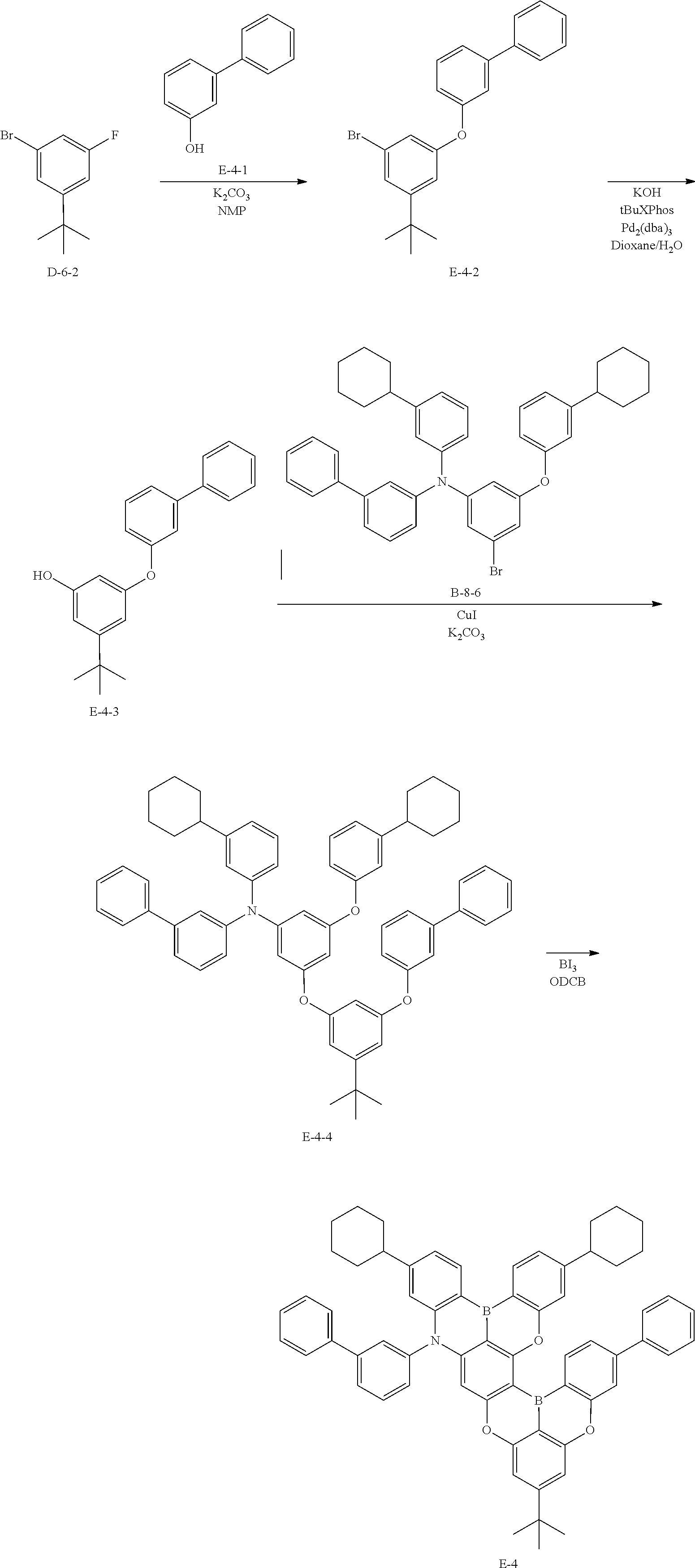

Under an argon (Ar) atmosphere, D-6-2 (300 mmol), E-4-1 (300 mmol), and K₂CO₃ (600 mmol) were added to a three-necked flask, and 200 mL of NMP was added thereto, followed by stirring at about 150° C. for about 8 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 249 mmol of E-4-2 (yield 83%). The mass number of E-4-2 measured by FAB-MS was 381.

Next, under an argon (Ar) atmosphere, E-4-2 (249 mmol), KOH (747 mmol), Pd(dba)₂ (2 mmol), and tBuXPhos (8 mmol) were added to a three-necked flask, 60 mL of dioxane and 60 mL of H₂O were added thereto, and the mixture was stirred at about 100° C. for about 6 hours. 10% hydrochloric acid was added thereto, an organic layer was extracted using toluene dried over magnesium sulfate, and the solvent was distilled off. The crude product thus obtained was purified by silica gel column chromatography (hexane/toluene mixed solvent) to obtain 100 mmol of E-4-3 (yield 40%). The mass number of E-4-3 measured by FAB-MS was 318.

Next, under an argon (Ar) atmosphere, E-4-3 (100 mmol), B-8-5 (300 mmol), K₂CO₃ (600 mmol), CuI (110 mmol), and 13 mL of ODCB were added to a three-necked flask and stirred at about 170° C. for about 8 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 41 mmol of E-4-4 (yield 41%). The mass number of E-4-4 measured by FAB-MS was 894.

Next, under an argon (Ar) atmosphere, E-4-4 (41 mmol) was added to a three-necked flask, 41 mL of ODCB was added thereto and dissolved, BI₃ (164 mmol) was added thereto, and the mixture was stirred at about 140° C. for about 3 hours. After dispersing and washing the reaction solution using a large amount of acetonitrile, the solid was filtered and recovered. The crude product thus obtained was purified by silica gel column chromatography (hexane/toluene mixed solvent) and recrystallization (ethanol/toluene mixed solvent) to obtain 5 mmol of E-4 (yield 12%). The mass number of E-4 measured by FAB-MS was 909.

### (6) Synthesis of Compound E-8

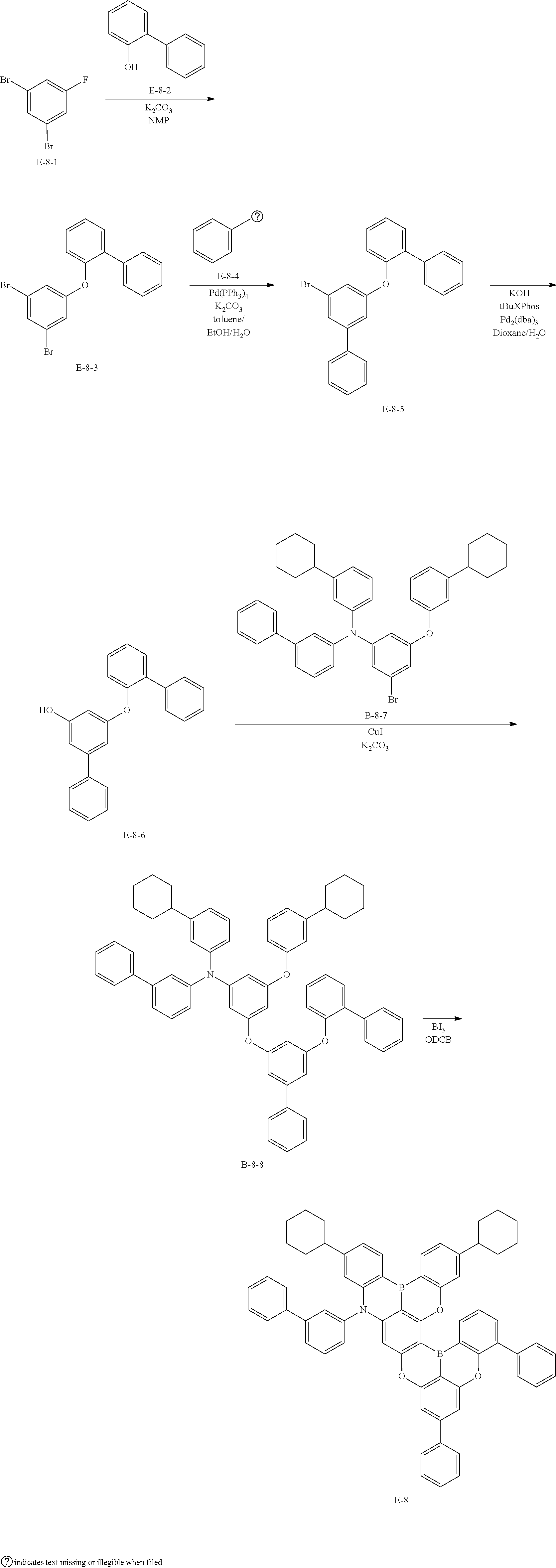

Under an argon (Ar) atmosphere, E-8-1 (300 mmol), E-8-2 (300 mmol), and K₂CO₃ (600 mmol) were added to a three-necked flask, and 200 mL of NMP was added thereto, followed by stirring at about 150° C. for about 10 hours. Water was added thereto, an organic layer was extracted with toluene and dried over magnesium sulfate, and the solvent was distilled off. The crude product thus obtained was purified by silica gel column chromatography (hexane/toluene mixed solvent) to obtain 255 mmol of E-8-3 (yield 85%). The mass number of E-8-3 measured by FAB-MS was 404.

Next, under an argon (Ar) atmosphere, E-8-3 (255 mmol), E-8-4 (255 mmol), Pd(PPh₃)₄ (13 mmol), and K₂CO₃ (280 mmol) were added to a three-necked flask, 500 mL of toluene, 125 mL of EtOH, and 250 mL of H₂O were added thereto, and the mixture was stirred at about 80° C. for about 6 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 102 mmol of E-8-5 (yield 40%). The mass number of E-8-5 measured by FAB-MS was 401.

Next, under an argon (Ar) atmosphere, E-8-5 (102 mmol), KOH (306 mmol), Pd(dba)₂ (1 mmol), and tBuXPhos (4 mmol) were added to a three-necked flask, 30 mL of dioxane and 30 mL of H₂O were added thereto, and the mixture was stirred at about 100° C. for about 6 hours. 10% hydrochloric acid was added thereto, an organic layer was extracted using toluene and dried over magnesium sulfate, and the solvent was distilled off. The crude product thus obtained was purified by silica gel column chromatography (hexane/toluene mixed solvent) to obtain 45 mmol of E-8-6 (yield 44%). The mass number of E-8-6 measured by FAB-MS was 338.

Next, under an argon (Ar) atmosphere, E-8-6 (45 mmol), B-8-7 (135 mmol), K₂CO₃ (270 mmol), CuI (50 mmol), and 6 mL of ODCB were added to a three-necked flask and stirred at about 170° C. for about 12 hours. Water was added thereto, an organic layer was extracted using toluene and dried over magnesium sulfate, and the solvent was distilled off. The crude product thus obtained was purified by silica gel column chromatography (hexane/toluene mixed solvent) to obtain 27 mmol of E-8-8 (yield 61%). The mass number of E-8-8 measured by FAB-MS was 914.

Next, under an argon (Ar) atmosphere, E-8-8 (27 mmol) was added to a three-necked flask, 27 mL of ODCB was added thereto and dissolved, B13 (108 mmol) was added thereto, and the mixture was stirred at about 140° C. for about 3 hours. After dispersing and washing the reaction solution using a large amount of acetonitrile, the solid was filtered and recovered. The crude product thus obtained was purified by silica gel column chromatography (hexane/toluene mixed solvent) and recrystallization (ethanol/toluene mixed solvent) to obtain 1 mmol of E-8 (yield 4%). The mass number of E-8 measured by FAB-MS was 929.

### 2. Evaluation of Compounds

Table 1 shows the evaluation results of the Example Compounds and Comparative Compounds. Compounds A-3, B-8, C-16, D-6, E-4, and E-8, which are fused polycyclic compounds of the Examples, were evaluated as Example Compounds. Compounds X1 to X8 were evaluated as Comparative Compounds.

### Example Compounds

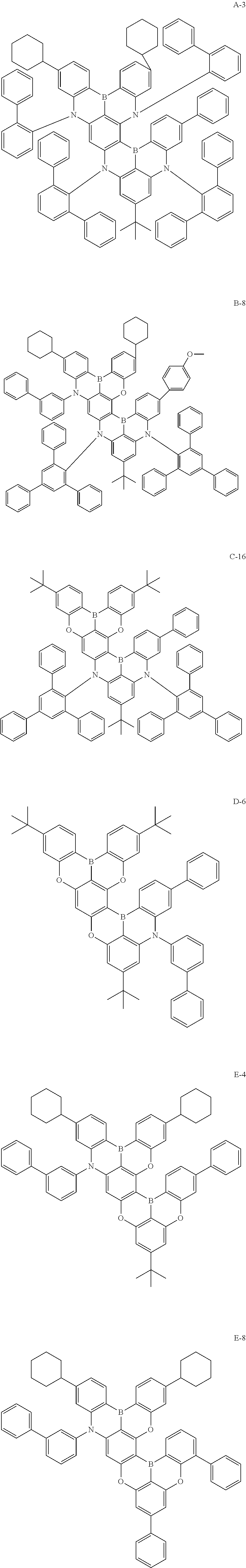

### Comparative Compounds

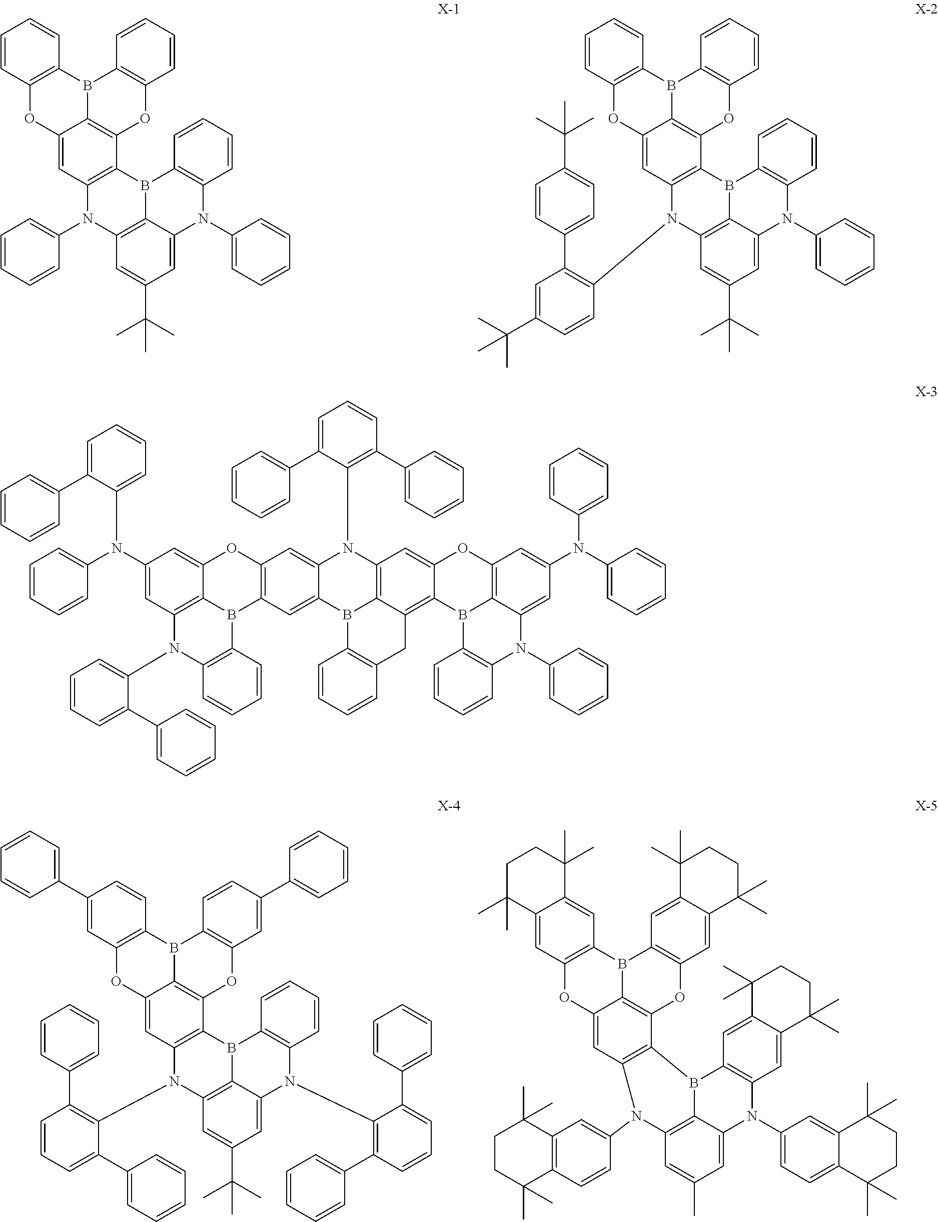

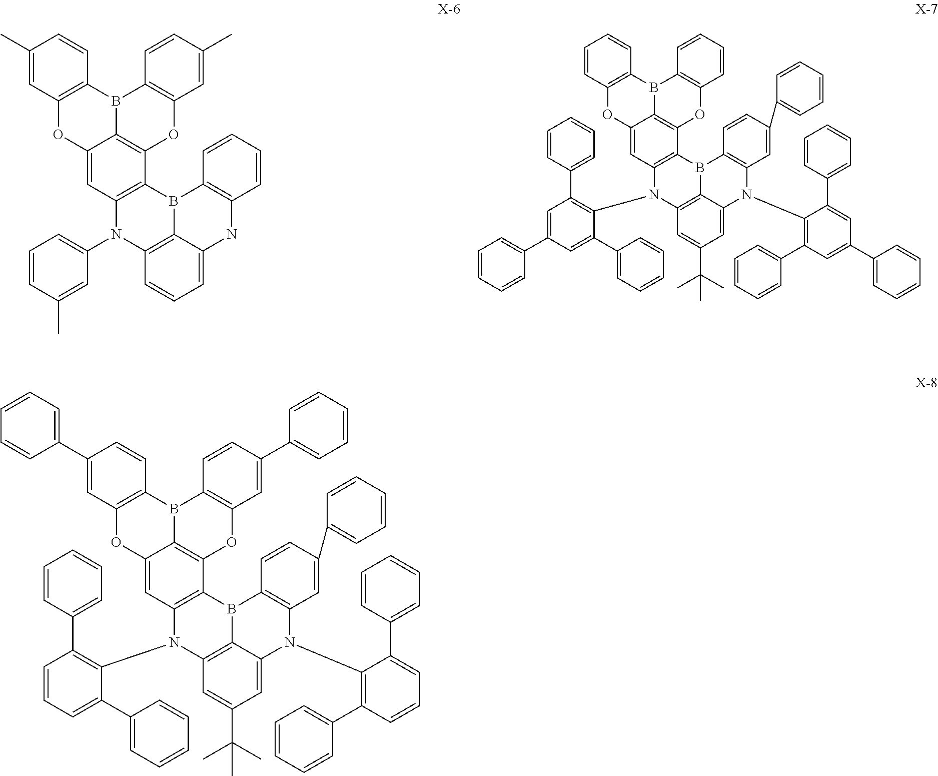 [SMILES: Cc1cccc(N2c3cccc4c3B(c3ccccc3N4)c3c2cc2c4c3Oc3cc(C)ccc3B4c3ccc(C)cc3O2)c1 ; CC(C)(C)c1cc2c3c(c1)N(c1c(-c4ccccc4)cc(-c4ccccc4)cc1-c1ccccc1)c1cc4c5c(c1B3c1ccc(-c3ccccc3)cc1N2c1c(-c2ccccc2)cc(-c2ccccc2)cc1-c1ccccc1)Oc1ccccc1B5c1ccccc1O4 ; CC(C)(C)c1cc2c3c(c1)N(c1c(-c4ccccc4)cccc1-c1ccccc1)c1cc4c5c(c1B3c1ccc(-c3ccccc3)cc1N2c1c(-c2ccccc2)cccc1-c1ccccc1)Oc1cc(-c2ccccc2)ccc1B5c1ccc(-c2ccccc2)cc1O4]

### (1) Evaluation of Light Emitting Properties

Table 1 shows the evaluation results of the light emitting properties. Using a JASCO V-670 spectrometer, films obtained by doping with about 20 wt % of each of the Example Compounds and Comparative Compounds using PPF as a matrix, were deposited on quartz glass. The maximum emission wavelength (λₘₐₓ (nm)) of the obtained films was determined from the fluorescence emission spectrum. In addition, the fluorescence quantum yield was measured using a JASCOILF-835 integrating sphere system.

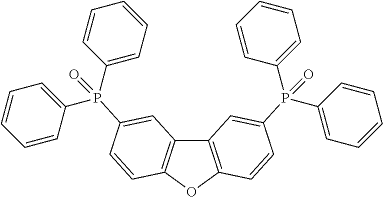 [SMILES: O=P(c1ccccc1)(c1ccccc1)c1ccc2oc3ccc(P(=O)(c4ccccc4)c4ccccc4)cc3c2c1]

TABLE 1

| | | Fluorescence |
|---|---|---|
| | λₘₐₓ | quantum efficiency |
| Compound | (nm) | (%) |
| Example Compound A-3 | 465 | 81 |
| Example Compound B-8 | 460 | 83 |
| Example Compound C-16 | 457 | 84 |
| Example Compound D-6 | 455 | 81 |
| Example Compound E-4 | 452 | 80 |
| Example Compound E-8 | 453 | 80 |
| Comparative Compound | 455 | 75 |
| X-1 | | |
| Comparative Compound | 454 | 78 |
| X-2 | | |
| Comparative Compound | 466 | 79 |
| X-3 | | |
| Comparative Compound | 458 | 79 |
| X-4 | | |
| Comparative Compound | 462 | 76 |
| X-5 | | |
| Comparative Compound | 453 | 72 |
| X-6 | | |
| Comparative Compound | 457 | 78 |
| X-7 | | |
| Comparative Compound | 463 | 78 |
| X-8 | | |

Referring to Table 1, it is shown that the Example Compounds and Comparative Compounds have a λₘₐₓ of about 450 nm or more and about 470 nm or less. In addition, it is shown that the Example Compounds have a high fluorescence quantum yield compared to Comparative Compounds X-1 to X-8.

Example Compounds A-3, B-8, C-16, D-6, E-4, and E-8 are fused polycyclic compounds according to one or more embodiments and include a first substituent and a second substituent, bonded to a fused ring of nine rings, containing four heteroatoms and two boron atoms as ring-forming atoms (that is, a central structure). In the Example Compounds, the first substituents (R^{a1} and R^{a2} in Formula 1) are substituted or unsubstituted alkyl groups having 1 to 20 carbon atoms, or substituted or unsubstituted cycloalkyl groups having 3 to 30 carbon atoms, and the second substituents (R^{b1} to R^{b4} in Formula 1) are substituted or unsubstituted aryl groups having 6 to 30 carbon atoms. Thus, the fused polycyclic compound of one or more embodiments including the first and second substituents bonded to the fused ring of nine rings exhibit excellent or suitable fluorescence quantum yields.

Comparative Compounds X-1 to X-8 include a fused ring of nine rings, but the first and second substituents are different from the fused polycyclic compound according to one or more embodiments. Comparative Compounds X-1 and X-2 include a hydrogen atom as both the first and second substituents. Comparative Compound X-3 has a structure including a fused ring of 13 rings, containing 8 heteroatoms and 3 boron atoms as ring-forming atoms. Comparative Compound X-4 has an aryl group as the first substituent and a hydrogen atom as the second substituent. Comparative Compound X-5 has a structure in which both the first substituent and the second substituent are alkyl groups and form a ring. Comparative Compound X-6 has an alkyl group as the first substituent but a hydrogen atom as the second substituent. Comparative Compound X-7 has an aryl group as the second substituent but a hydrogen atom as the first substituent. Comparative compound X-8 has aryl groups as both the first and second substituents. Thus, the Comparative Compounds exhibit lower fluorescence quantum yields compared to the Example Compounds, which include a first substituent that is a substituted or unsubstituted alkyl group having 1 to 20 carbon atoms, or a substituted or unsubstituted cycloalkyl group having 3 to 30 ring-forming carbon atoms, and a second substituent that is a substituted or unsubstituted aryl group having 6 to 30 ring-forming carbon atoms.

### (2) Analysis of Full Width at Half Maximum and Stokes Shift

Table 2 shows the analysis results of the full width at half maximum and stokes shift. Molecular orbitals were calculated using Gaussian, and the full width at half maximum (FWHM) and stokes shift were measured from the molecular orbitals. In this case, a nonpolar solvent used in the Gaussian calculation was toluene (tol), and a polar solvent was 2-methyltetrahydrofuran (2-MeTHF).

TABLE 2

| | | Stokes | FWHM | Stokes |
|---|---|---|---|---|
| | FWHM | shift | (2- | shift (2- |
| Compound | (tol) | (tol) | MeTHF) | MeTHF) |
| Example Compound A-3 | 16.9 | 8.7 | 23.6 | 11.3 |
| Example Compound C-16 | 22.0 | 16.0 | 24.8 | 19.2 |
| Example Compound E-4 | 23.9 | 11.7 | 19.4 | 8.8 |
| Comparative Compound | 24.8 | 17.0 | 42.6 | 29.8 |
| X-4 | | | | |
| Comparative Compound | 21.8 | 16.2 | 33.6 | 23.8 |
| X-8 | | | | |

Referring to Table 2, it was confirmed that Example Compounds A-3, C-16, and E-4 had narrower full width at half maximum and narrower stokes shifts than Comparative Compounds X-4 and X-8. More specifically, Example Compounds A-3, C-16, and E-4 exhibited similar or narrower full width at half maximum and very narrow stokes shifts than Comparative Compounds X-4 and X-8 in toluene (tol), and very narrower full width at half maximum and stokes shifts than Comparative Compounds X-4 and X-8 in 2-methyltetrahydrofuran (2-MeTHF).

Comparative Compound X-4 has a phenyl group as the first substituent and a hydrogen atom as the second substituent, while Comparative Compound X-8 has phenyl groups as both the first and second substituents. Therefore, the LUMO orbital is expanded, the first substituent protrudes outward, and the redox active site may not be protected, resulting in low stability of the compound. Therefore, Comparative Compounds X-4 and X-8 have broader full width at half maximum and broader stock shifts than Examples Compounds A-3, C-3, and E-4.

### 3. Manufacture and Evaluation of Light Emitting Elements

### (1) Manufacture of Light Emitting Elements

Light emitting elements including the fused polycyclic compounds of embodiments or Comparative Compounds in emission layers were manufactured by a method. The fused polycyclic compounds according to one or more embodiments were used as emission layer dopant materials to manufacture light emitting elements of Examples 1 to 6. Comparative Examples 1 to 8 were manufactured using Comparative Compounds X-1 to X-8 as emission layer dopant materials.

An ITO with a thickness of about 1,500 Å was patterned on a glass substrate as a first electrode, and was cleansed with ultrapure water and UV ozone treatment for about 10 minutes. Next, a hole injection layer with a thickness of about 100 Å was formed using HAT-CN, and a hole transport layer with a thickness of about 100 Å was formed using α-NPD.

Next, an electron blocking layer with a thickness of about 50 Å was formed using mCBP, and an emission layer was formed by providing the Example Compound or Comparative Compound and mCBP at a weight ratio of about 1:99. The emission layer was formed into a thickness of about 200 Å. An electron transport layer with a thickness of about 300 Å was formed using TPBi, and an electron injection layer with a thickness of about 5 Å was formed using LiF. Next, a second electrode with a thickness of about 1000 Å was formed using aluminum (Al). The hole injection layer, hole transport layer, electron blocking layer, emission layer, electron transport layer, electron injection layer, and second electrode were formed using a vacuum deposition apparatus.

The compounds used for the manufacture of light emitting elements are as follows:

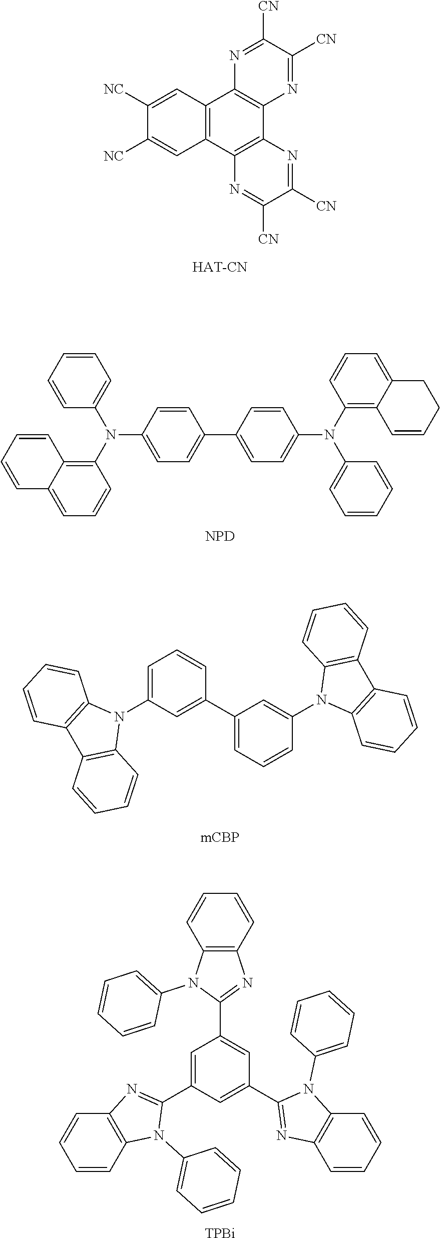

### (2) Evaluation of Light Emitting Elements

Table 3 shows the evaluation results of the light emitting elements of the Examples and Comparative Examples. Table 3 shows the maximum emission wavelength (λₘₐₓ (nm)), maximum external quantum yield (EQEₘₐₓ), and relative element lifespan (LT₅₀) for the light emitting elements of the Examples and Comparative Examples. The voltage and current density of the light emitting elements were measured using a sourcemeter (product of Keithley Instrument Co., 2400 series), and the luminance and external quantum efficiency (EQE) were measured using an external quantum efficiency measurement device C9920-12 from Hamamatsu Photonics Co. The lifespan (LT₅₀) was measured by measuring the time desired or required for the initial luminance to decrease from 100% to 50%, and is a relative value expressed by setting the lifespan of Comparative Example 1 as 100%. In addition, the maximum emission wavelength (λₘₐₓ (nm)) was confirmed from the fluorescence emission spectrum of the light emitting elements.

TABLE 3

| | | λₘₐₓ | EQEₘₐₓ | LT₅₀ |
|---|---|---|---|---|
| Division | Dopant material | (nm) | (%) | (%) |
| Example 1 | Example Compound A-3 | 467 | 23 | 385 |
| Example 2 | Example Compound B-8 | 462 | 24 | 398 |
| Example 3 | Example Compound C-16 | 460 | 25 | 415 |
| Example 4 | Example Compound D-6 | 458 | 23 | 371 |
| Example 5 | Example Compound E-4 | 456 | 22 | 352 |
| Example 6 | Example Compound E-8 | 457 | 23 | 366 |
| Comparative | Comparative Compound | 458 | 16 | 100 |
| Example 1 | X-1 | | | |
| Comparative | Comparative Compound | 457 | 19 | 156 |
| Example 2 | X-2 | | | |
| Comparative | Comparative Compound | 468 | 20 | 330 |
| Example 3 | X-3 | | | |
| Comparative | Comparative Compound | 462 | 21 | 342 |
| Example 4 | X-4 | | | |
| Comparative | Comparative Compound | 463 | 17 | 166 |
| Example 5 | X-5 | | | |
| Comparative | Comparative Compound | 457 | 14 | 126 |
| Example 6 | X-6 | | | |
| Comparative | Comparative Compound | 459 | 19 | 189 |
| Example 7 | X-7 | | | |
| Comparative | Comparative Compound | 463 | 20 | 339 |
| Example 8 | X-8 | | | |

Referring to Table 3, the light emitting elements of the Examples emit light with a wavelength close to about 460 nm and exhibit a color purity close to pure blue. In addition, the light emitting elements of the Examples exhibited increased element lifespan and a higher maximum external quantum yield (EQEₘₐₓ) compared to the light emitting elements of the Comparative Examples. Thus, it can be confirmed that the light emitting elements of the Examples exhibit longer lifespan and higher efficiency compared to the light emitting elements of the Comparative Examples.

The Comparative Compounds used in Comparative Examples 1 to 8 contain fused rings, but the first and second substituents are different from those of the fused polycyclic compounds of the Examples. Accordingly, Comparative Examples 1 to 8 exhibited both reduced element lifespan and light emitting efficiency compared to the Examples.

Comparative Compounds X-1 and X-2 of Comparative Examples 1 and 2 have a hydrogen atom as the first and second substituents both. Comparative Compounds X-1 and X-2, with a hydrogen atom as the first and second substituents, may not protect the redox-active sites of the molecule, and the stability of the compound may be low, and narrow full width at half maximum and narrow stokes shifts may not be secured. Accordingly, it was confirmed that both efficiency and lifespan characteristics were degraded.

Comparative Compound X-3 of Comparative Example 3 includes a fused ring of 13 rings, containing 8 heteroatoms and 3 boron atoms as ring-forming atoms, and is a CT (Charge Transfer) type (kind), in which the distribution of the HOMO and LUMO orbitals are separated. Structures similar to Comparative Example X-3 exhibit partial overlap between the HOMO and LUMO orbitals, and AEST (Singlet-Triplet Energy Gap) increases, resulting in low efficiency even if (e.g., when) electron-donating substituents are bonded.

Comparative Compound X-4 of Comparative Example 4 has an aryl group as the first substituent and a hydrogen atom as the second substituent. By the aryl group as the first substituent, the LUMO orbital may be expanded, redox-active site of the molecule may be protruded, and molecular stability may be reduced. In addition, because the second substituent is a hydrogen atom, narrow full width at half maximum and narrow stokes shift characteristics may not be secured.

Comparative Compound X-5 of Comparative Example 5 has a structure in which both the first and second substituents are alkyl groups and form a ring. In Comparative Compound X-5, the first substituent is an alkyl group, and the second substituent is an alkyl group, not an aryl group, resulting in increased full width at half maximum and stokes shift values, thereby decreasing efficiency.

Comparative Compound X-6 of Comparative Example 6 has an alkyl group as the first substituent, but a hydrogen atom as the second substituent. In Comparative Compound X-6, the first substituent is an alkyl group, but the second substituent is an alkyl group, not an aryl group, making it difficult to secure narrow full width at half maximum and narrow stokes shift characteristics.

Comparative Compound X-7 of Comparative Example 7 has an aryl group as the second substituent, but a hydrogen atom as the first substituent, and the redox-active site of the molecule may not be protected, and the stability of the compound is low, and lifespan characteristics are degraded.

Comparative Compound X-8 of Comparative Example 8 has aryl groups as both the first and second substituents. Comparative Compound X-8 has an aryl group as the second substituent, but the LUMO orbital may be expanded, and the redox-active site of the molecule may protrude outward due to the aryl group as the first substituent, resulting in reduced stability. Accordingly, it was confirmed that the element lifespan and light emitting efficiency were reduced compared to the Examples.

The fused polycyclic compound of an embodiment includes a fused ring structure of nine rings, containing four heteroatoms and two boron atoms as ring-forming atoms, as a central structure. In addition, by including an alkyl group or a cycloalkyl group as the first substituent and an aryl group as the second substituent, the narrow full width at half maximum and narrow stokes shift characteristics may be exhibited, resulting in high efficiency and excellent or suitable material stability via the suppression of the expansion of the LUMO orbital. Accordingly, the fused polycyclic compound according to one or more embodiments may exhibit improved lifespan characteristics and excellent or suitable light emitting efficiency characteristics. In addition, the light emitting element of one or more embodiments, which includes the fused polycyclic compound of an embodiment in the emission layer, may exhibit excellent or suitable light emitting efficiency characteristics in the blue light emitting range and long-life characteristics.

An electronic apparatus including the light emitting element including the fused polycyclic compound according to one or more embodiments may exhibit excellent or suitable reliability characteristics due to the long-life characteristics of the light emitting element. In addition, an electronic apparatus including the light emitting element including the polycyclic compound of an embodiment with improved light emitting efficiency, may exhibit improved luminance characteristics and display quality.

The light emitting element according to one or more embodiments may show high efficiency and long-life characteristics by including the fused polycyclic compound of an embodiment in an emission layer.

The fused polycyclic compound according to one or more embodiments may contribute to the increase of light efficiency and lifespan of a light emitting element.

The electronic apparatus according to one or more embodiments may show excellent or suitable display quality and improved reliability properties.

For example, the above comparative analysis demonstrates that the specific substituent configuration of the fused polycyclic compound-namely, the inclusion of an alkyl or cycloalkyl group as the first substituent and an aryl group as the second substituent-plays a critical role in achieving high light emission efficiency, narrow spectral characteristics, and extended operational lifespan. These structural features contribute to the suppression of LUMO orbital expansion and stabilization of redox-active sites, which in turn enhance the photophysical properties of the compound. When incorporated into an emission layer alongside suitable host materials (e.g., HT-1 and/or ET-1) and, optionally, a sensitizer (e.g., D-1), the compound enables efficient energy transfer and delayed fluorescence emission, particularly in the blue wavelength range. As such, the disclosed compound and device architecture provide a synergistic effect that supports the improved performance metrics observed in the Examples, and are suitable for integration into high-reliability electronic apparatuses requiring advanced display quality.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value. Also, it should be understood that, even if the terms “about,” “approximately,” or “substantially” are not expressly recited in a given element *e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting element, the display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims.

Therefore, the technical scope of the disclosure is not to be limited to the contents stated in the detailed description of the disclosure, but should be determined by the appended claims and equivalents thereof.

What is claimed is:

1. A light emitting element, comprising:
a first electrode;
a second electrode on the first electrode; and
an emission layer between the first electrode and the second electrode, and comprising a first compound represented by Formula 1: 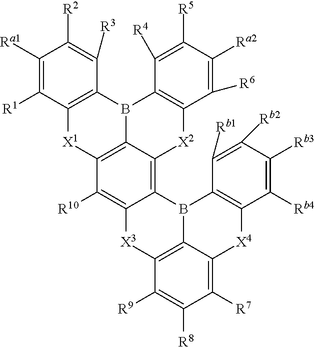
wherein, in Formula 1,
X^{a} to X^{d} are each independently O, S, or NR^{X},
R^{X} is a hydrogen atom, a deuterium atom, a halogen atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 30 ring-forming carbon atoms, or is represented by Formula x,
R^{a1} and R^{a2} are each independently a substituted or unsubstituted alkyl group of 1 to 20 carbon atoms, or a substituted or unsubstituted cycloalkyl group of 3 to 30 ring-forming carbon atoms,
R¹ to R¹⁰ and R^{b1} to R^{b4} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
at least one selected from among R^{b1} to R^{b4} is a substituted or unsubstituted aryl group of 6 to 30 ring-forming carbon atoms: 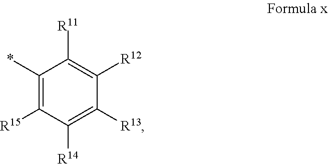
and
wherein, in Formula x,
R¹¹ to R¹⁵ are each independently a hydrogen atom, a deuterium atom, a halogen atom, a substituted or unsubstituted alkyl group of 1 to 20 carbon atoms, a substituted or unsubstituted cycloalkyl group of 3 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or be combined with an adjacent group from each other to form a ring.

2. The light emitting element of claim 1, wherein the emission layer further comprises at least one of a second compound represented by Formula HT-1 or a third compound represented by Formula ET-1: 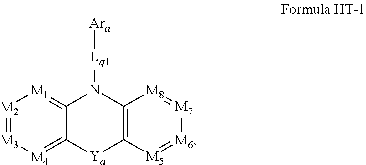
in Formula HT-1,
M₁ to M₈ are each independently N or CRₐ₁₁,
L_{q1} is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CRₐ₁₂Rₐ₁₃, or SiRₐ₁₄Rₐ₁₅,
Arₐ is a substituted or unsubstituted aryl group of 6 to 30 ring-forming carbon atoms, or a substituted or unsubstituted heteroaryl group of 2 to 30 ring-forming carbon atoms, and
Rₐ₁₁ to Rₐ₁₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms, and/or are combined with an adjacent group from each other to form a ring; 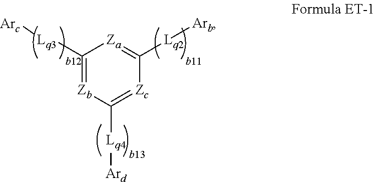
and
in Formula ET-1
at least one selected from among Zₐ to Z_{c} is N, and the remainder are CRₐ₁₆,
Rₐ₁₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms,
b11 to b13 are each independently an integer of 0 to 10,
Ar_{b} to Ar_{d} are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and
L_{q2} to L_{q4} are each independently a direct linkage, a substituted or unsubstituted arylene group of 6 to 30 ring-forming carbon atoms, or a substituted or unsubstituted heteroarylene group or 2 to 30 ring-forming carbon atoms.

3. The light emitting element of claim 2, wherein the emission layer further comprises a fourth compound represented by Formula D-1: 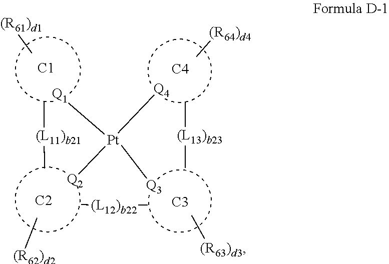
in Formula D-1
Q₁ to Q₄ are each independently C or N,
C1 to C4 are each independently a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms,
L₁₁ to L₁₃ are each independently a direct linkage, 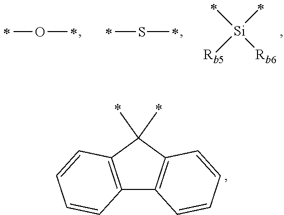
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b21 to b23 are each independently 0 or 1,
R₆₁ to R₆₄, R_{b5}, and R_{b6} are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer of 0 to 4.

4. The light emitting element of claim 1, wherein the emission layer is to emit delayed fluorescence.

5. The light emitting element of claim 1, wherein the emission layer is to emit blue color light.

6. The light emitting element of claim 1, wherein at least one a hydrogen atom of the first compound is substituted with a deuterium atom.

7. The light emitting element of claim 1, wherein Formula 1 is represented by any one selected from among Formula 1-1 to Formula 1-5: 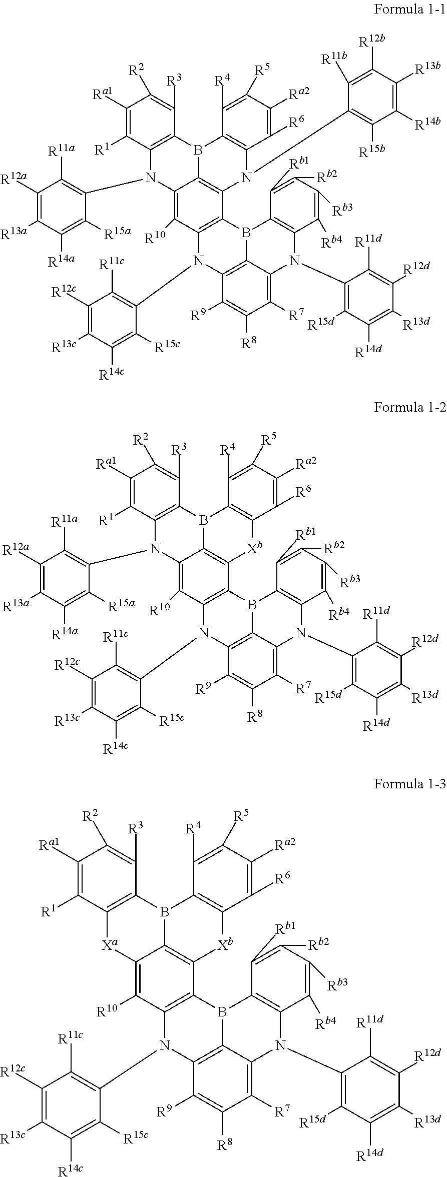 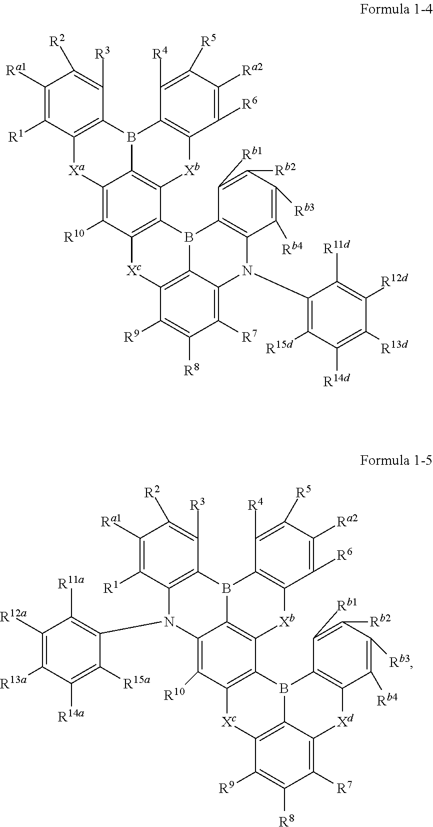
in Formula 1-1 to Formula 1-5,
R^{11a} to R^{15a}, R^{11b} to R^{15b}, R^{11c} to R^{15c}, and R^{11d} to R^{15d} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring, and
X^{a} to X^{d} and R¹ to R¹⁰ are the same as defined in Formula 1.

8. The light emitting element of claim 1, wherein, in Formula 1, at least one selected from among R^{b1} to R^{b4} is represented by Formula b: 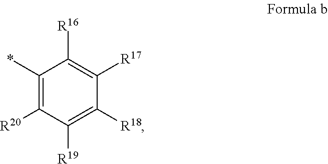
in Formula b,
R¹⁶ to R²⁰ are each independently a hydrogen atom, a deuterium atom, a halogen atom, a cyano group, a substituted or unsubstituted thio group, a substituted or unsubstituted oxy group of 1 to 20 carbon atoms, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring.

9. The light emitting element of claim 1, wherein the first compound is any one selected from among the compounds in Compound Group 1: 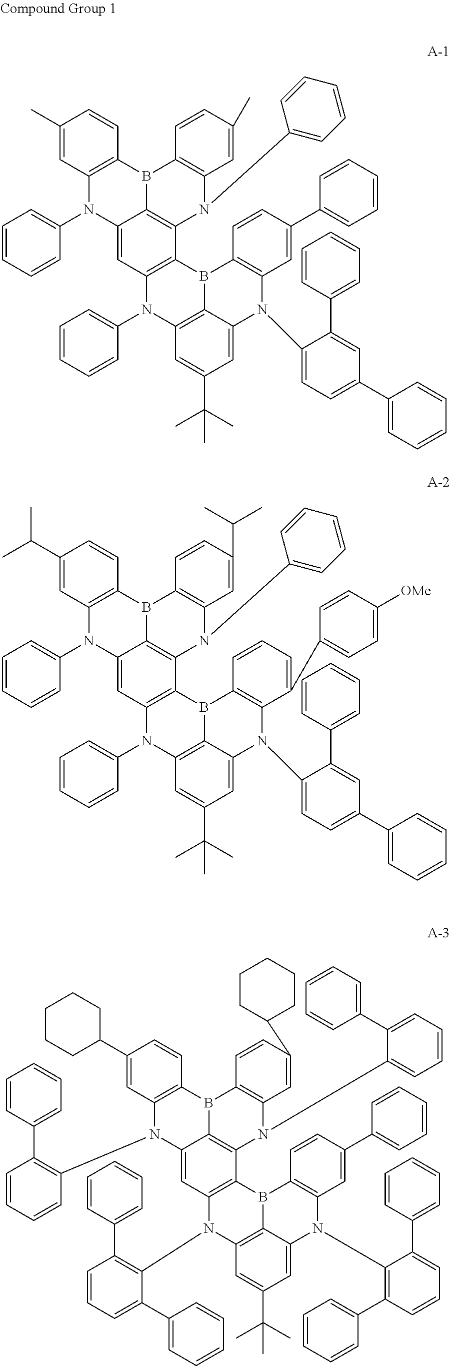 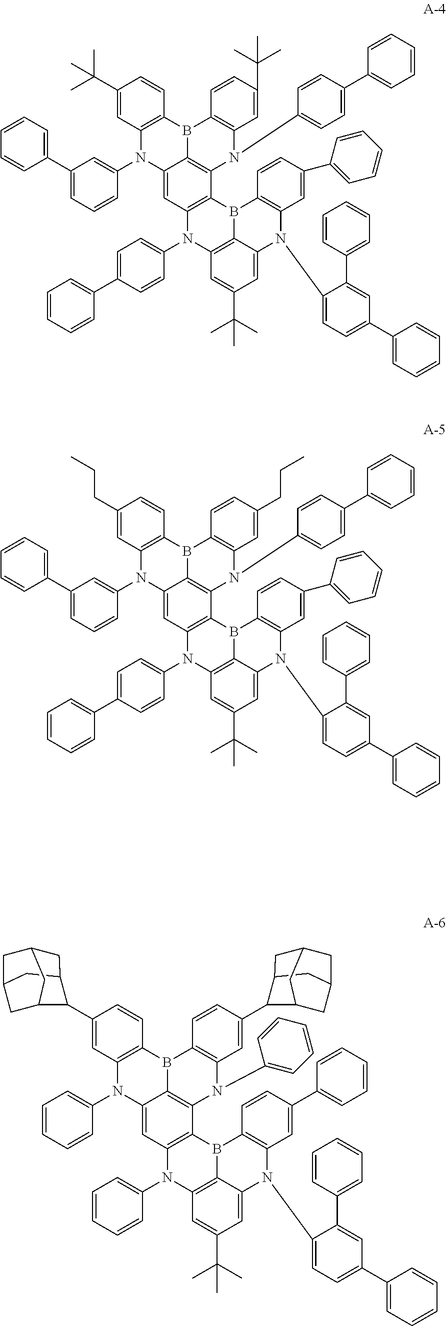 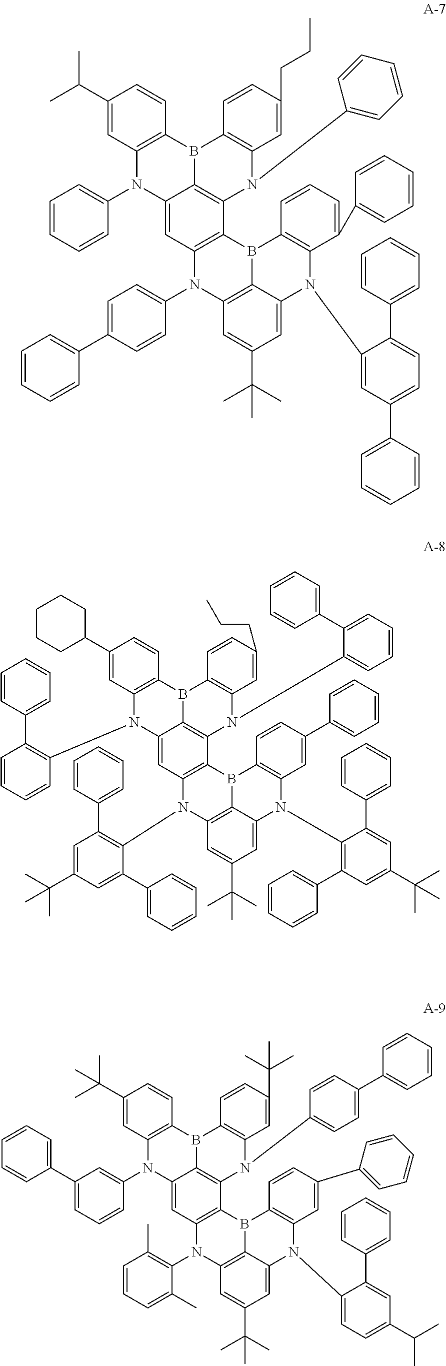 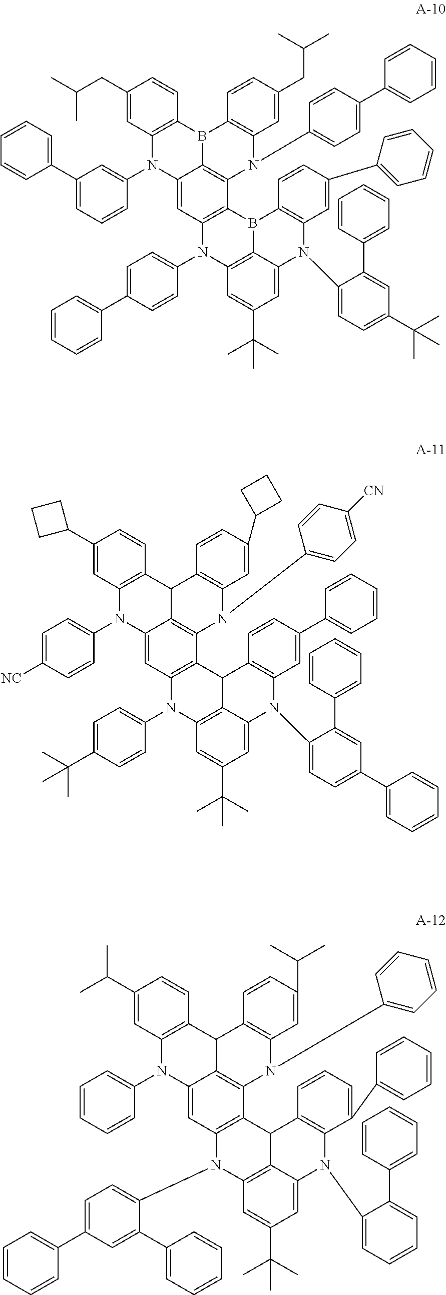 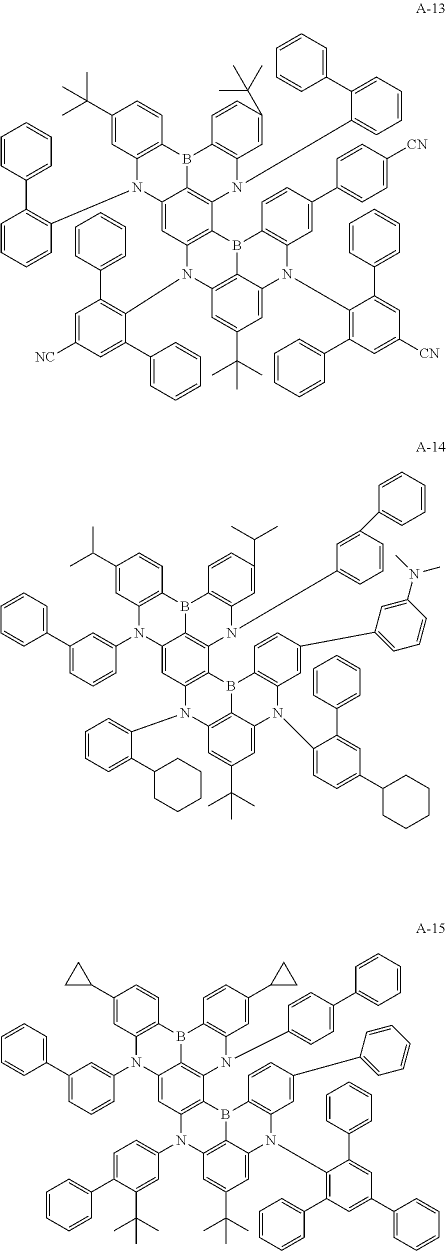 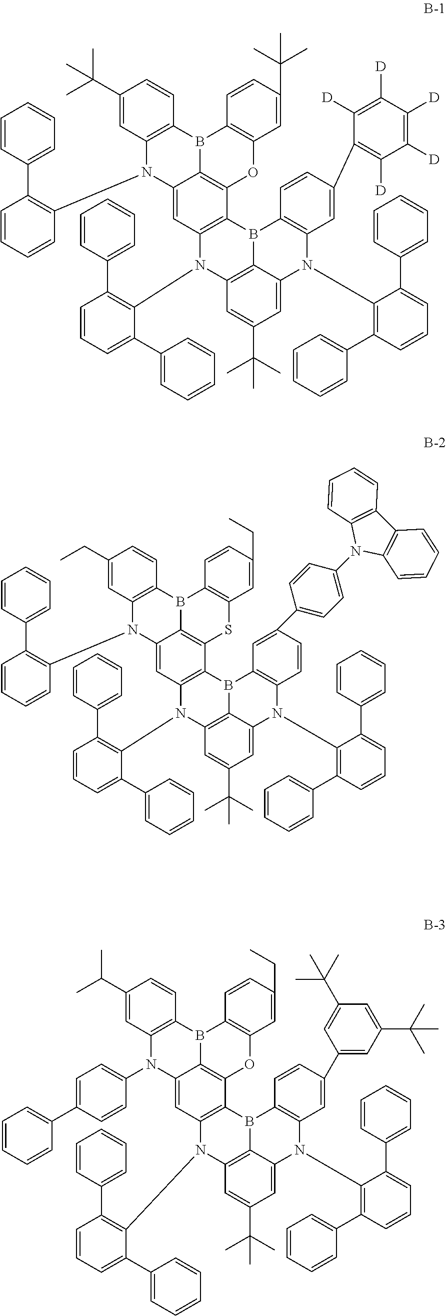 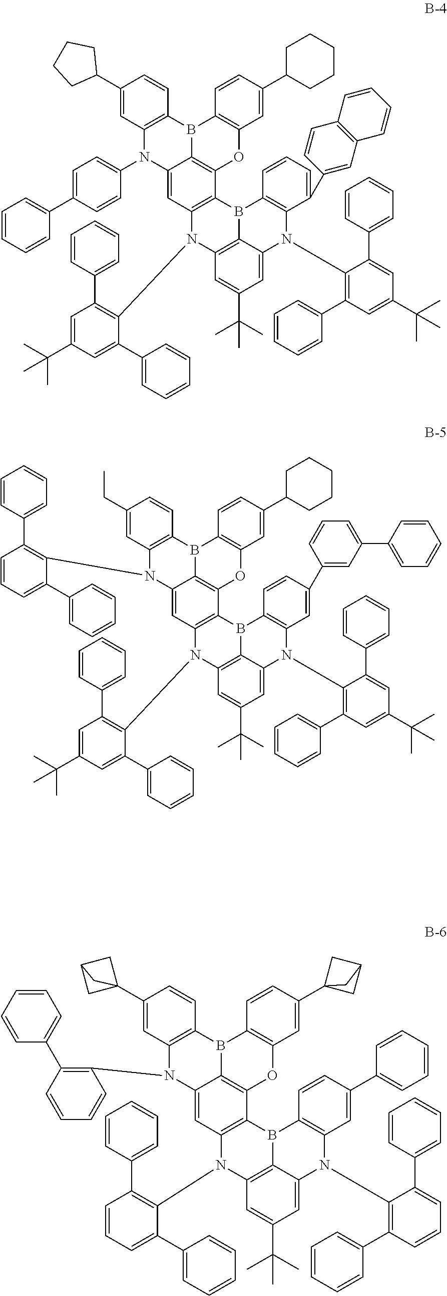 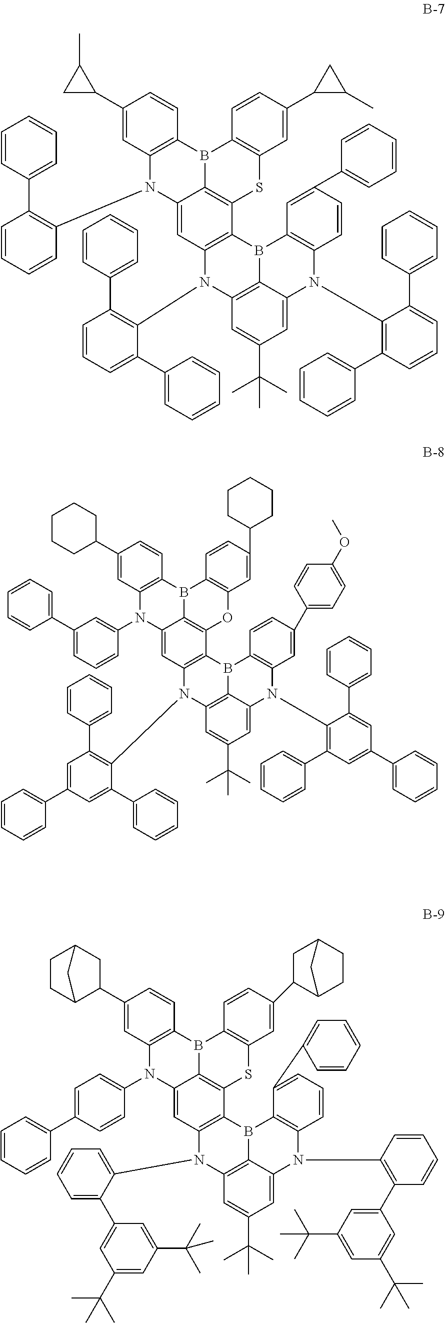 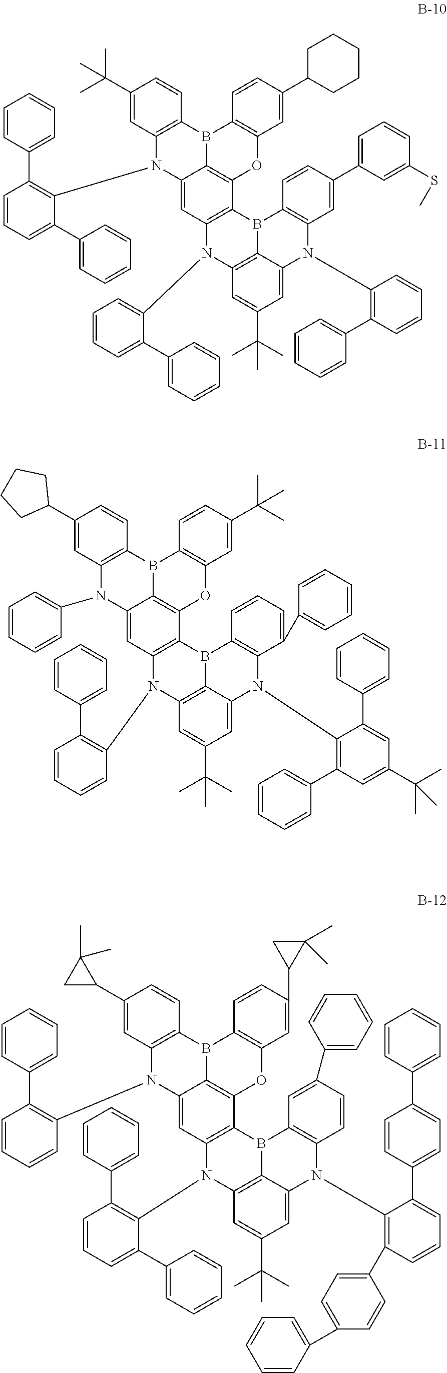 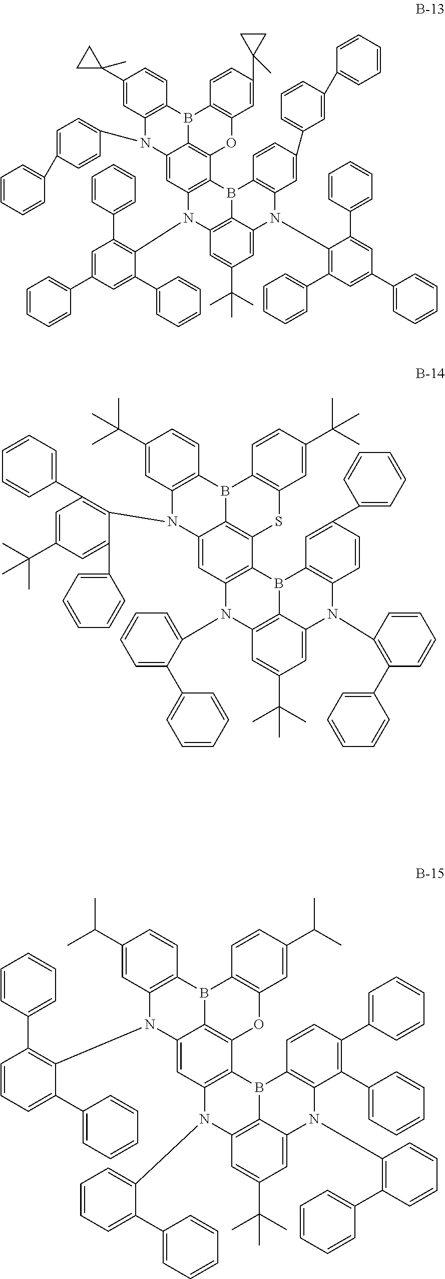 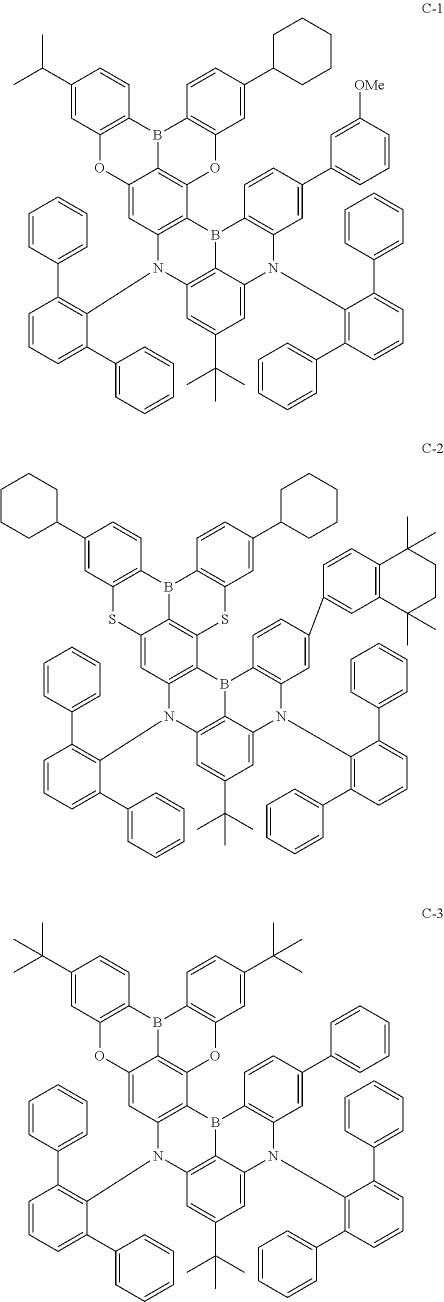 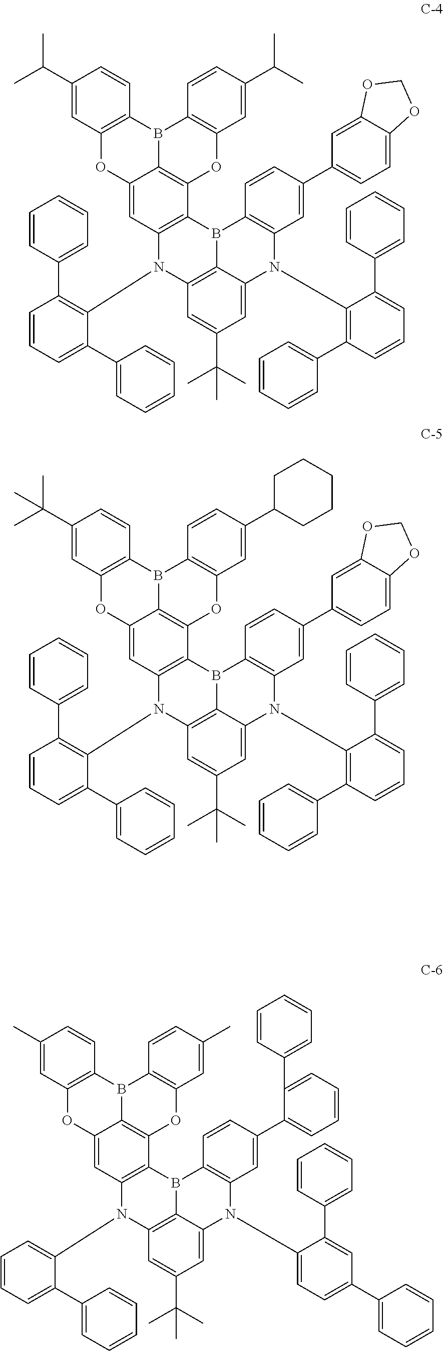 [SMILES: CC(C)c1ccc2c(c1)Oc1cc3c(c4c1B2c1ccc(C(C)C)cc1O4)B1c2ccc(-c4ccc5c(c4)OCO5)cc2N(c2c(-c4ccccc4)cccc2-c2ccccc2)c2cc(C(C)(C)C)cc(c21)N3c1c(-c2ccccc2)cccc1-c1ccccc1 ; CC(C)(C)c1ccc2c(c1)Oc1cc3c(c4c1B2c1ccc(C2CCCCC2)cc1O4)B1c2ccc(-c4ccc5c(c4)OCO5)cc2N(c2c(-c4ccccc4)cccc2-c2ccccc2)c2cc(C(C)(C)C)cc(c21)N3c1c(-c2ccccc2)cccc1-c1ccccc1 ; Cc1ccc2c(c1)Oc1cc3c(c4c1B2c1ccc(C)cc1O4)B1c2ccc(-c4ccccc4-c4ccccc4)cc2N(c2ccc(-c4ccccc4)cc2-c2ccccc2)c2cc(C(C)(C)C)cc(c21)N3c1ccccc1-c1ccccc1] 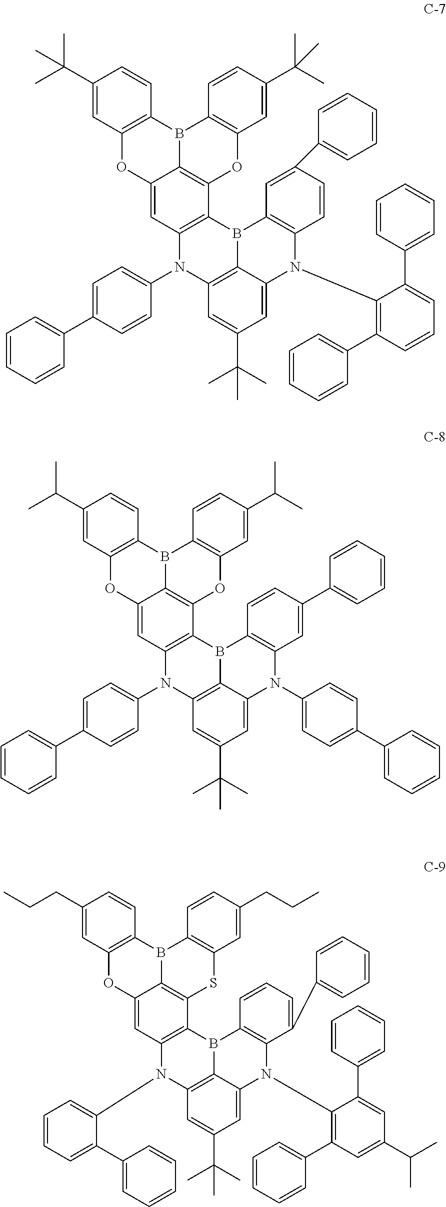 [SMILES: CC(C)(C)c1ccc2c(c1)Oc1cc3c(c4c1B2c1ccc(C(C)(C)C)cc1O4)B1c2cc(-c4ccccc4)ccc2N(c2c(-c4ccccc4)cccc2-c2ccccc2)c2cc(C(C)(C)C)cc(c21)N3c1ccc(-c2ccccc2)cc1 ; CC(C)c1ccc2c(c1)Oc1cc3c(c4c1B2c1ccc(C(C)C)cc1O4)B1c2ccc(-c4ccccc4)cc2N(c2ccc(-c4ccccc4)cc2)c2cc(C(C)(C)C)cc(c21)N3c1ccc(-c2ccccc2)cc1 ; CCCc1ccc2c(c1)Oc1cc3c(c4c1B2c1ccc(CCC)cc1S4)B1c2cccc(-c4ccccc4)c2N(c2c(-c4ccccc4)cc(C(C)C)cc2-c2ccccc2)c2cc(C(C)(C)C)cc(c21)N3c1ccccc1-c1ccccc1] 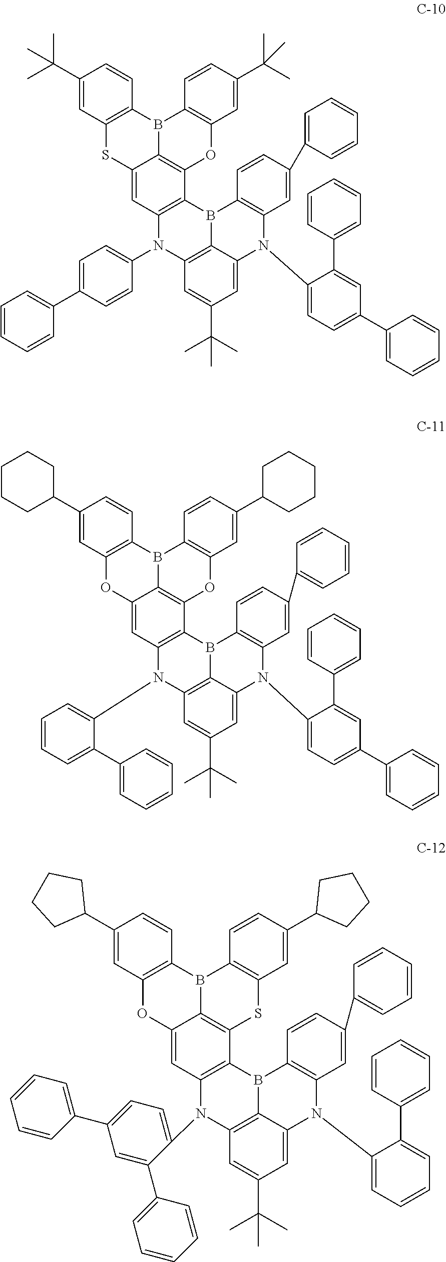 [SMILES: CC(C)(C)c1ccc2c(c1)Oc1c3c(cc4c1B1c5ccc(-c6ccccc6)cc5N(c5ccc(-c6ccccc6)cc5-c5ccccc5)c5cc(C(C)(C)C)cc(c51)N4c1ccc(-c4ccccc4)cc1)Sc1cc(C(C)(C)C)ccc1B23 ; CC(C)(C)c1cc2c3c(c1)N(c1ccccc1-c1ccccc1)c1cc4c5c(c1B3c1ccc(-c3ccccc3)cc1N2c1ccc(-c2ccccc2)cc1-c1ccccc1)Oc1cc(C2CCCCC2)ccc1B5c1ccc(C2CCCCC2)cc1O4 ; CC(C)(C)c1cc2c3c(c1)N(c1ccc(-c4ccccc4)cc1-c1ccccc1)c1cc4c5c(c1B3c1ccc(-c3ccccc3)cc1N2c1ccccc1-c1ccccc1)Sc1cc(C2CCCC2)ccc1B5c1ccc(C2CCCC2)cc1O4] 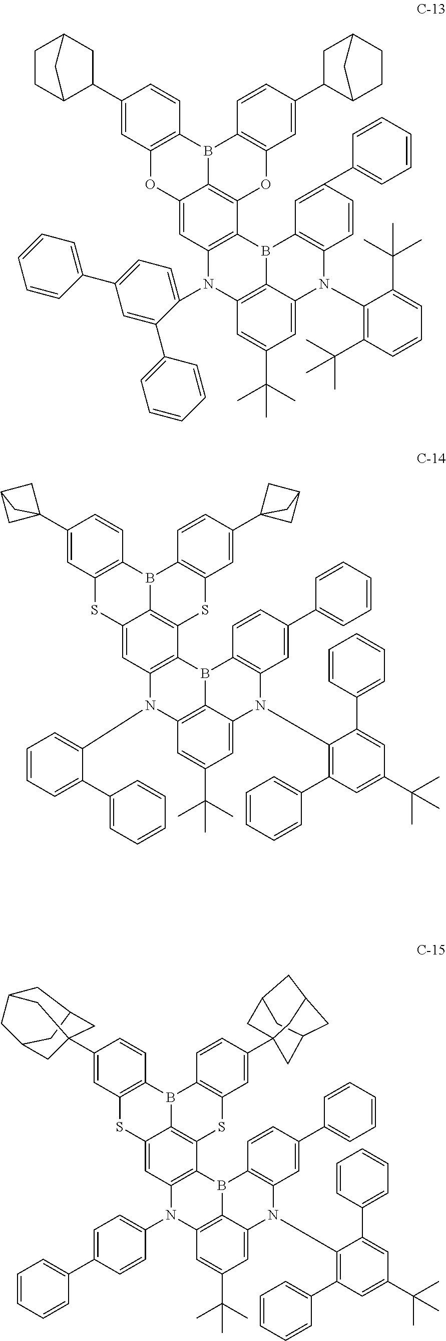 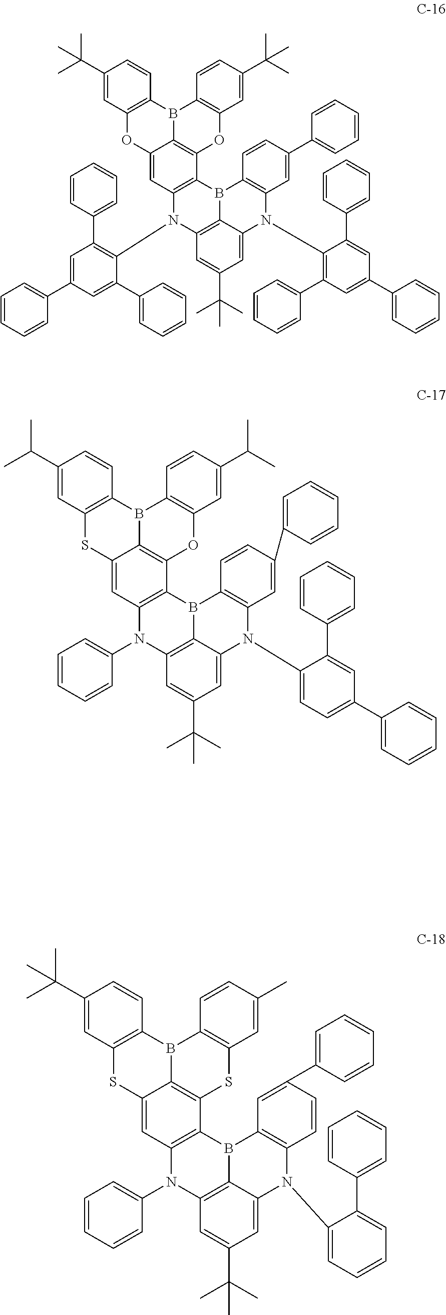 [SMILES: CC(C)(C)c1ccc2c(c1)Oc1cc3c(c4c1B2c1ccc(C(C)(C)C)cc1O4)B1c2ccc(-c4ccccc4)cc2N(c2c(-c4ccccc4)cc(-c4ccccc4)cc2-c2ccccc2)c2cc(C(C)(C)C)cc(c21)N3c1c(-c2ccccc2)cc(-c2ccccc2)cc1-c1ccccc1 ; CC(C)c1ccc2c(c1)Oc1c3c(cc4c1B1c5ccc(-c6ccccc6)cc5N(c5ccc(-c6ccccc6)cc5-c5ccccc5)c5cc(C(C)(C)C)cc(c51)N4c1ccccc1)Sc1cc(C(C)C)ccc1B23 ; Cc1ccc2c(c1)Sc1c3c(cc4c1B1c5cc(-c6ccccc6)ccc5N(c5ccccc5-c5ccccc5)c5cc(C(C)(C)C)cc(c51)N4c1ccccc1)Sc1cc(C(C)(C)C)ccc1B23] 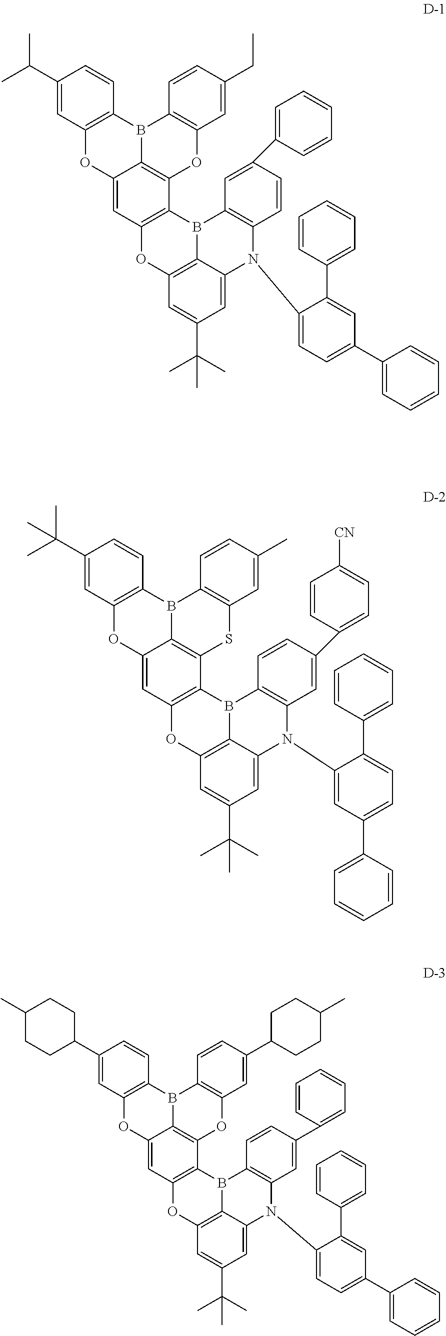 [SMILES: CCc1ccc2c(c1)Oc1c3c(cc4c1B1c5cc(-c6ccccc6)ccc5N(c5ccc(-c6ccccc6)cc5-c5ccccc5)c5cc(C(C)(C)C)cc(c51)O4)Oc1cc(C(C)C)ccc1B23 ; Cc1ccc2c(c1)Sc1c3c(cc4c1B1c5ccc(-c6ccc(C#N)cc6)cc5N(c5cc(-c6ccccc6)ccc5-c5ccccc5)c5cc(C(C)(C)C)cc(c51)O4)Oc1cc(C(C)(C)C)ccc1B23 ; CC1CCC(c2ccc3c(c2)Oc2cc4c(c5c2B3c2ccc(C3CCC(C)CC3)cc2O5)B2c3ccc(-c5ccccc5)cc3N(c3ccc(-c5ccccc5)cc3-c3ccccc3)c3cc(C(C)(C)C)cc(c32)O4)CC1] 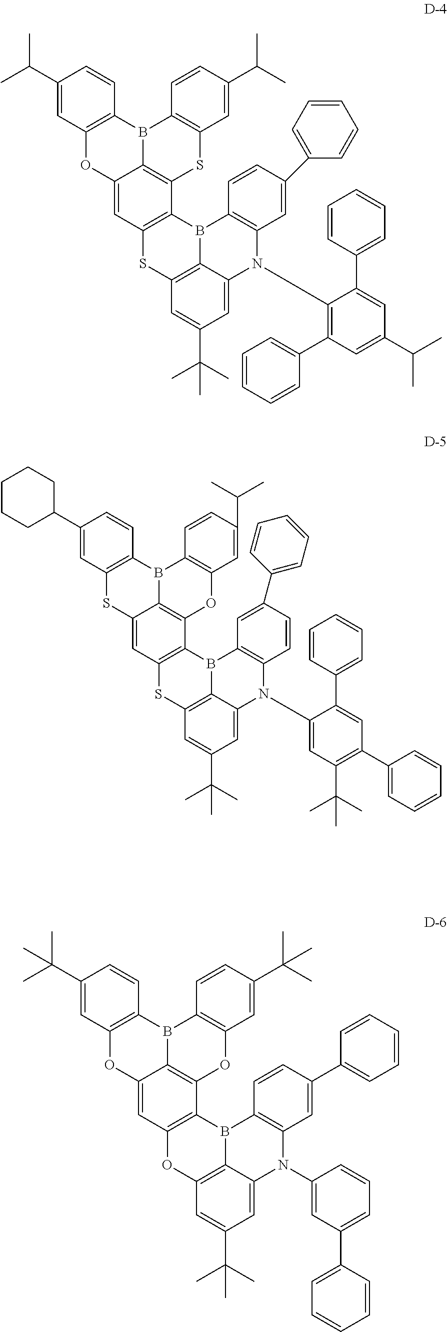 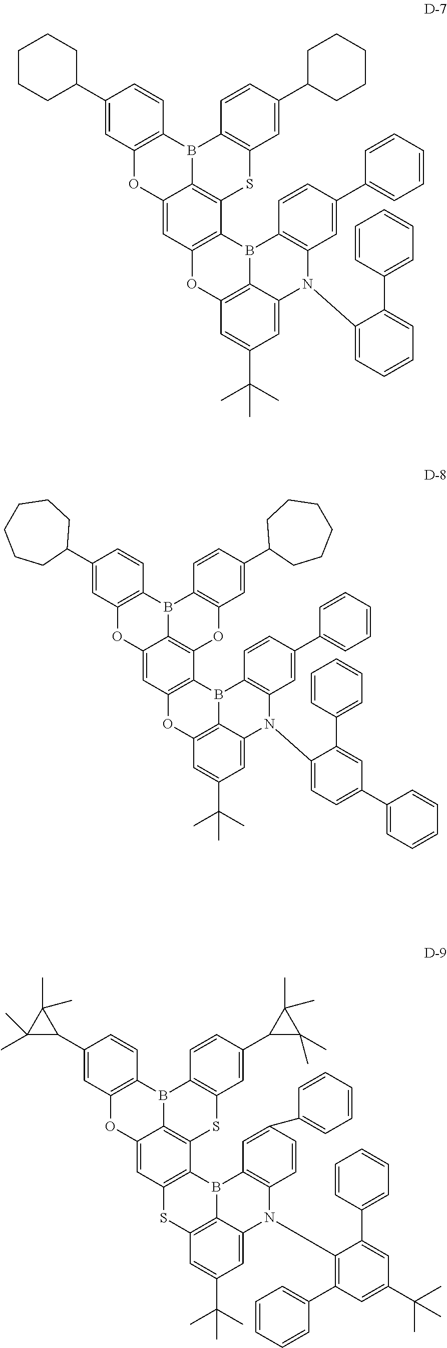 [SMILES: CC(C)(C)c1cc2c3c(c1)N(c1ccccc1-c1ccccc1)c1cc(-c4ccccc4)ccc1B3c1c(cc3c4c1Sc1cc(C5CCCCC5)ccc1B4c1ccc(C4CCCCC4)cc1O3)O2 ; CC(C)(C)c1cc2c3c(c1)N(c1ccc(-c4ccccc4)cc1-c1ccccc1)c1cc(-c4ccccc4)ccc1B3c1c(cc3c4c1Oc1cc(C5CCCCCC5)ccc1B4c1ccc(C4CCCCCC4)cc1O3)O2 ; CC(C)(C)c1cc(-c2ccccc2)c(N2c3ccc(-c4ccccc4)cc3B3c4c(cc(C(C)(C)C)cc42)Sc2cc4c5c(c23)Sc2cc(C3C(C)(C)C3(C)C)ccc2B5c2ccc(C3C(C)(C)C3(C)C)cc2O4)c(-c2ccccc2)c1] 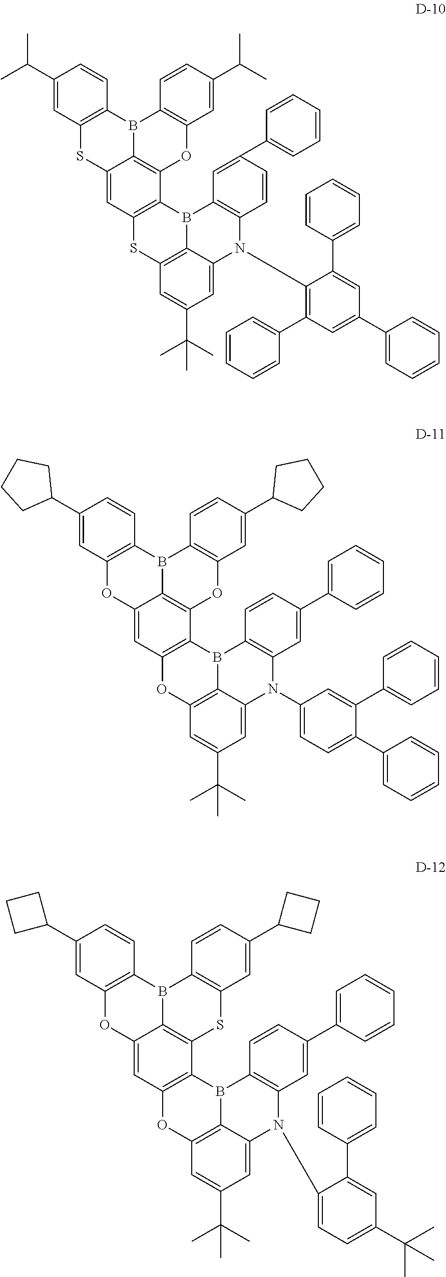 [SMILES: CC(C)c1ccc2c(c1)Oc1c3c(cc4c1B1c5cc(-c6ccccc6)ccc5N(c5c(-c6ccccc6)cc(-c6ccccc6)cc5-c5ccccc5)c5cc(C(C)(C)C)cc(c51)S4)Sc1cc(C(C)C)ccc1B23 ; CC(C)(C)c1cc2c3c(c1)N(c1ccc(-c4ccccc4)c(-c4ccccc4)c1)c1cc(-c4ccccc4)ccc1B3c1c(cc3c4c1Oc1cc(C5CCCC5)ccc1B4c1ccc(C4CCCC4)cc1O3)O2 ; CC(C)(C)c1ccc(N2c3cc(-c4ccccc4)ccc3B3c4c(cc(C(C)(C)C)cc42)Oc2cc4c5c(c23)Sc2cc(C3CCC3)ccc2B5c2ccc(C3CCC3)cc2O4)c(-c2ccccc2)c1] 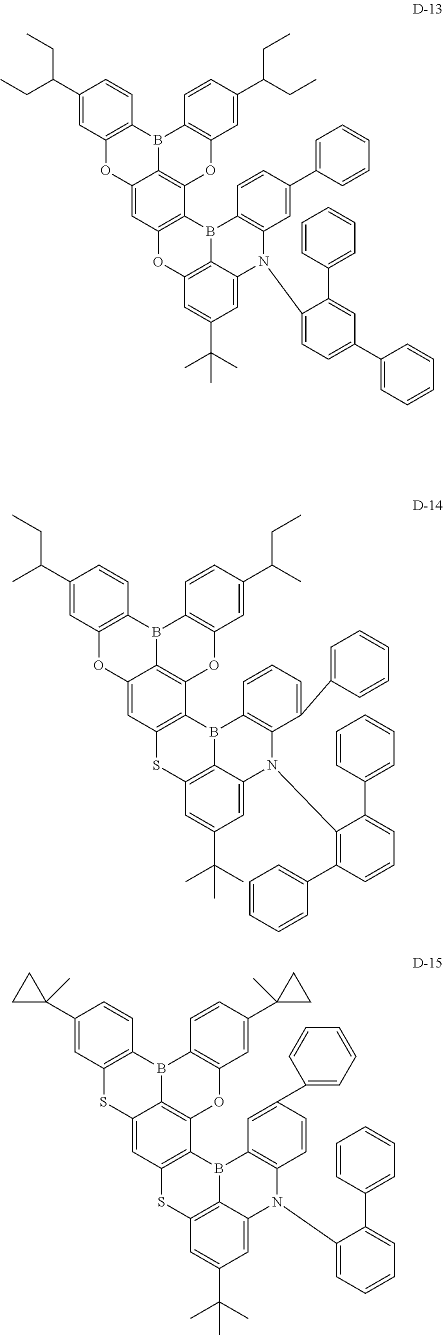 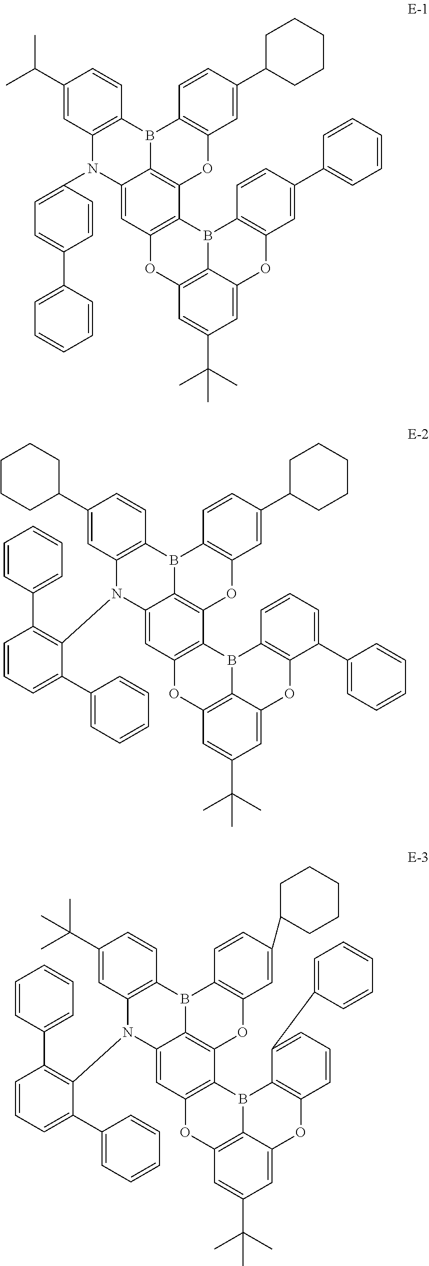 [SMILES: CC(C)c1ccc2c(c1)N(c1ccc(-c3ccccc3)cc1)c1cc3c(c4c1B2c1ccc(C2CCCCC2)cc1O4)B1c2ccc(-c4ccccc4)cc2Oc2cc(C(C)(C)C)cc(c21)O3 ; CC(C)(C)c1cc2c3c(c1)Oc1c(cccc1-c1ccccc1)B3c1c(cc3c4c1Oc1cc(C5CCCCC5)ccc1B4c1ccc(C4CCCCC4)cc1N3c1c(-c3ccccc3)cccc1-c1ccccc1)O2 ; CC(C)(C)c1cc2c3c(c1)Oc1cc4c5c(c1B3c1c(cccc1-c1ccccc1)O2)Oc1cc(C2CCCCC2)ccc1B5c1ccc(C(C)(C)C)cc1N4c1c(-c2ccccc2)cccc1-c1ccccc1] 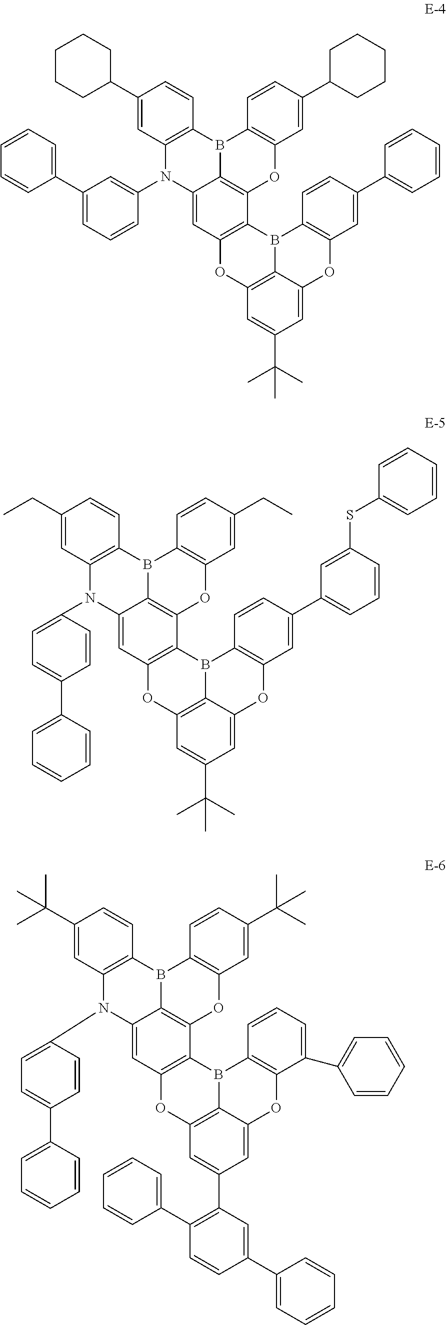 [SMILES: CC(C)(C)c1cc2c3c(c1)Oc1cc4c5c(c1B3c1ccc(-c3ccccc3)cc1O2)Oc1cc(C2CCCCC2)ccc1B5c1ccc(C2CCCCC2)cc1N4c1cccc(-c2ccccc2)c1 ; CCc1ccc2c(c1)Oc1c3c(cc4c1B2c1ccc(CC)cc1N4c1ccc(-c2ccccc2)cc1)Oc1cc(C(C)(C)C)cc2c1B3c1ccc(-c3cccc(Sc4ccccc4)c3)cc1O2 ; CC(C)(C)c1ccc2c(c1)Oc1c3c(cc4c1B2c1ccc(C(C)(C)C)cc1N4c1ccc(-c2ccccc2)cc1)Oc1cc(-c2cc(-c4ccccc4)ccc2-c2ccccc2)cc2c1B3c1cccc(-c3ccccc3)c1O2] 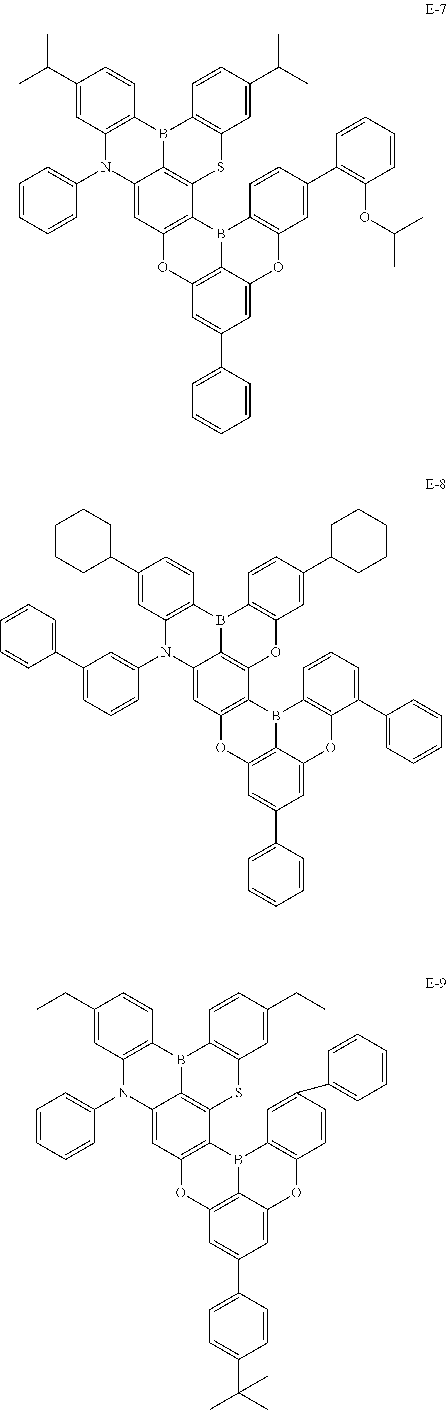 [SMILES: CC(C)Oc1ccccc1-c1ccc2c(c1)Oc1cc(-c3ccccc3)cc3c1B2c1c(cc2c4c1Sc1cc(C(C)C)ccc1B4c1ccc(C(C)C)cc1N2c1ccccc1)O3 ; c1ccc(-c2cccc(N3c4cc(C5CCCCC5)ccc4B4c5ccc(C6CCCCC6)cc5Oc5c6c(cc3c54)Oc3cc(-c4ccccc4)cc4c3B6c3cccc(-c5ccccc5)c3O4)c2)cc1 ; CCc1ccc2c(c1)Sc1c3c(cc4c1B2c1ccc(CC)cc1N4c1ccccc1)Oc1cc(-c2ccc(C(C)(C)C)cc2)cc2c1B3c1cc(-c3ccccc3)ccc1O2] 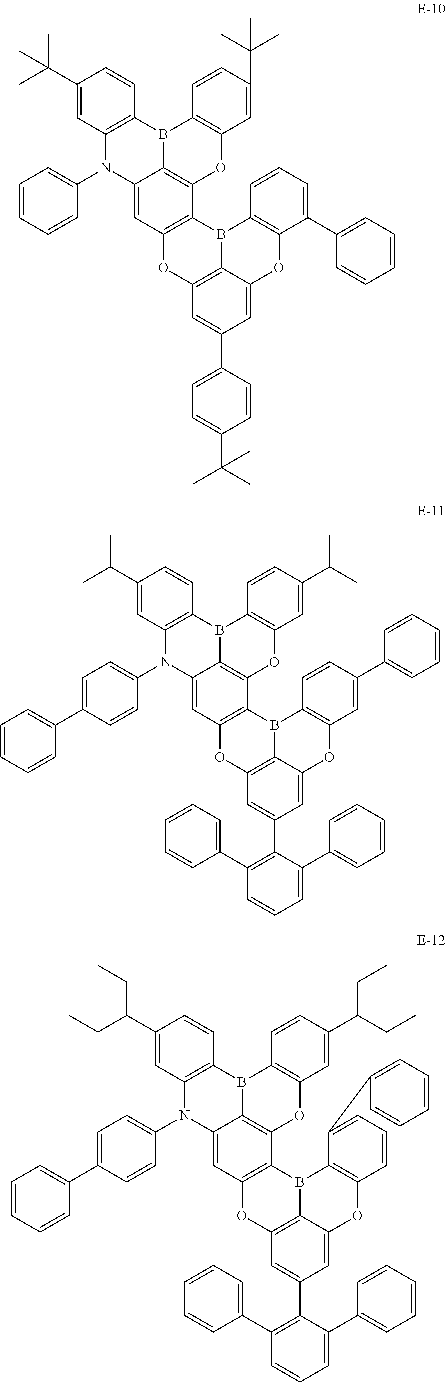 [SMILES: CC(C)(C)c1ccc(-c2cc3c4c(c2)Oc2c(cccc2-c2ccccc2)B4c2c(cc4c5c2Oc2cc(C(C)(C)C)ccc2B5c2ccc(C(C)(C)C)cc2N4c2ccccc2)O3)cc1 ; CC(C)c1ccc2c(c1)Oc1c3c(cc4c1B2c1ccc(C(C)C)cc1N4c1ccc(-c2ccccc2)cc1)Oc1cc(-c2c(-c4ccccc4)cccc2-c2ccccc2)cc2c1B3c1ccc(-c3ccccc3)cc1O2 ; CCC(CC)c1ccc2c(c1)Oc1c3c(cc4c1B2c1ccc(C(CC)CC)cc1N4c1ccc(-c2ccccc2)cc1)Oc1cc(-c2c(-c4ccccc4)cccc2-c2ccccc2)cc2c1B3c1c(cccc1-c1ccccc1)O2] 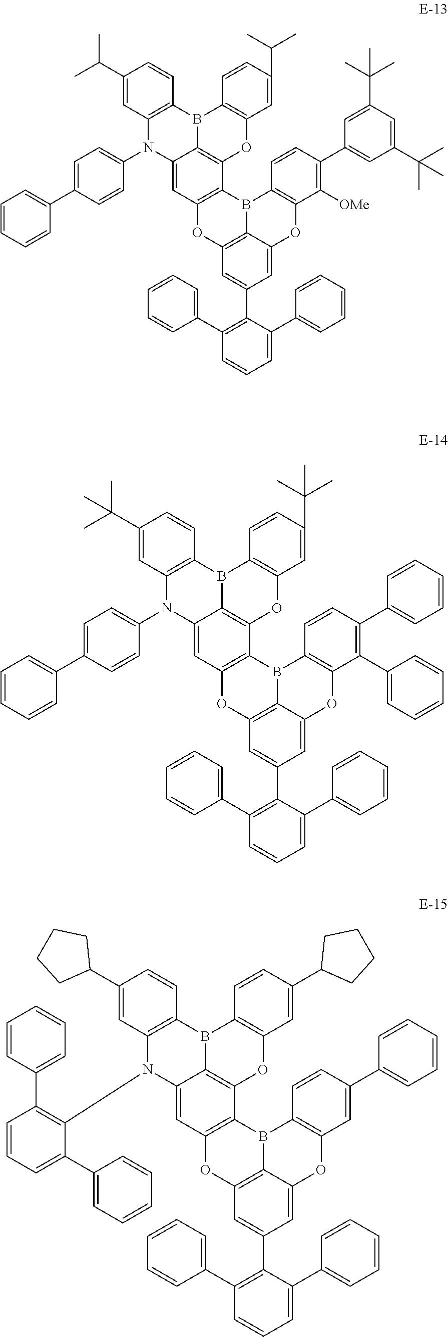 [SMILES: COc1c(-c2cc(C(C)(C)C)cc(C(C)(C)C)c2)ccc2c1Oc1cc(-c3c(-c4ccccc4)cccc3-c3ccccc3)cc3c1B2c1c(cc2c4c1Oc1cc(C(C)C)ccc1B4c1ccc(C(C)C)cc1N2c1ccc(-c2ccccc2)cc1)O3 ; CC(C)(C)c1ccc2c(c1)Oc1c3c(cc4c1B2c1ccc(C(C)(C)C)cc1N4c1ccc(-c2ccccc2)cc1)Oc1cc(-c2c(-c4ccccc4)cccc2-c2ccccc2)cc2c1B3c1ccc(-c3ccccc3)c(-c3ccccc3)c1O2 ; c1ccc(-c2ccc3c(c2)Oc2cc(-c4c(-c5ccccc5)cccc4-c4ccccc4)cc4c2B3c2c(cc3c5c2Oc2cc(C6CCCC6)ccc2B5c2ccc(C5CCCC5)cc2N3c2c(-c3ccccc3)cccc2-c2ccccc2)O4)cc1] 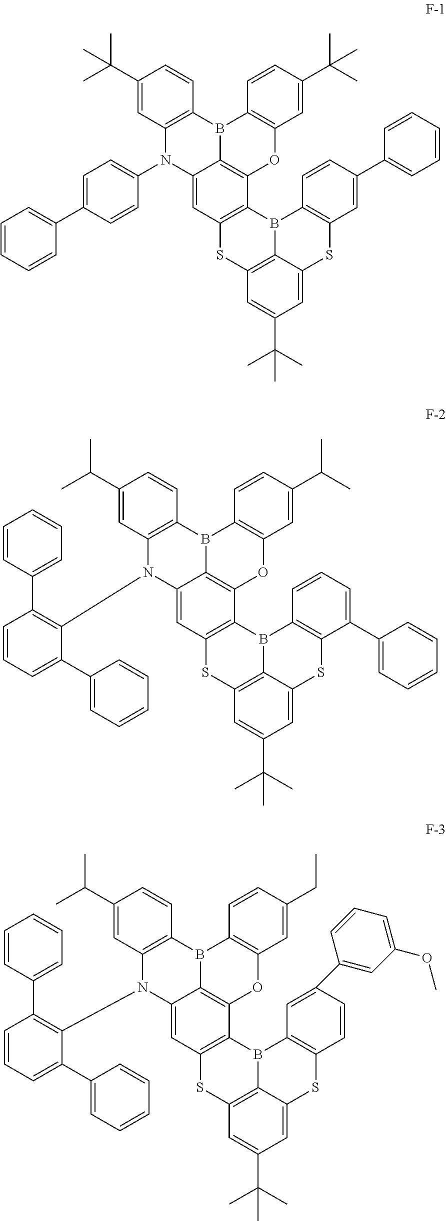 [SMILES: CC(C)(C)c1ccc2c(c1)Oc1c3c(cc4c1B2c1ccc(C(C)(C)C)cc1N4c1ccc(-c2ccccc2)cc1)Sc1cc(C(C)(C)C)cc2c1B3c1ccc(-c3ccccc3)cc1S2 ; CC(C)c1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cccc(-c3ccccc3)c1S2 ; CCc1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cc(-c3cccc(OC)c3)ccc1S2] 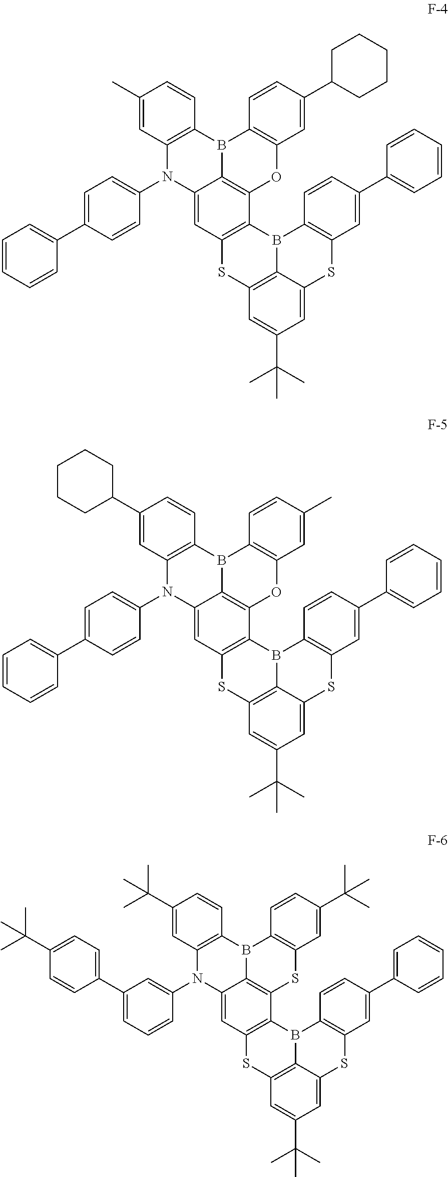 [SMILES: Cc1ccc2c(c1)N(c1ccc(-c3ccccc3)cc1)c1cc3c(c4c1B2c1ccc(C2CCCCC2)cc1O4)B1c2ccc(-c4ccccc4)cc2Sc2cc(C(C)(C)C)cc(c21)S3 ; Cc1ccc2c(c1)Oc1c3c(cc4c1B2c1ccc(C2CCCCC2)cc1N4c1ccc(-c2ccccc2)cc1)Sc1cc(C(C)(C)C)cc2c1B3c1ccc(-c3ccccc3)cc1S2 ; CC(C)(C)c1ccc(-c2cccc(N3c4cc(C(C)(C)C)ccc4B4c5ccc(C(C)(C)C)cc5Sc5c6c(cc3c54)Sc3cc(C(C)(C)C)cc4c3B6c3ccc(-c5ccccc5)cc3S4)c2)cc1] 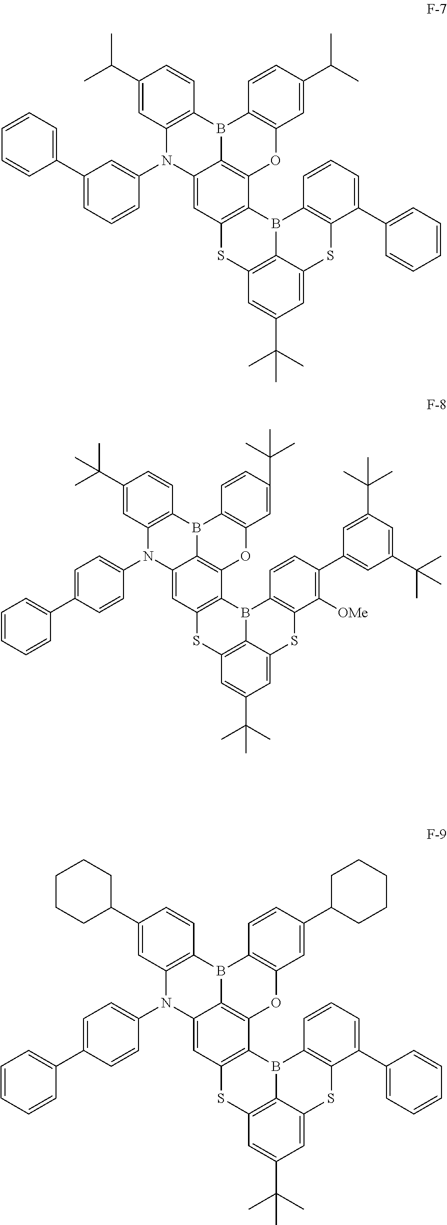 [SMILES: CC(C)c1ccc2c(c1)Oc1c3c(cc4c1B2c1ccc(C(C)C)cc1N4c1cccc(-c2ccccc2)c1)Sc1cc(C(C)(C)C)cc2c1B3c1cccc(-c3ccccc3)c1S2 ; COc1c(-c2cc(C(C)(C)C)cc(C(C)(C)C)c2)ccc2c1Sc1cc(C(C)(C)C)cc3c1B2c1c(cc2c4c1Oc1cc(C(C)(C)C)ccc1B4c1ccc(C(C)(C)C)cc1N2c1ccc(-c2ccccc2)cc1)S3 ; CC(C)(C)c1cc2c3c(c1)Sc1c(cccc1-c1ccccc1)B3c1c(cc3c4c1Oc1cc(C5CCCCC5)ccc1B4c1ccc(C4CCCCC4)cc1N3c1ccc(-c3ccccc3)cc1)S2] 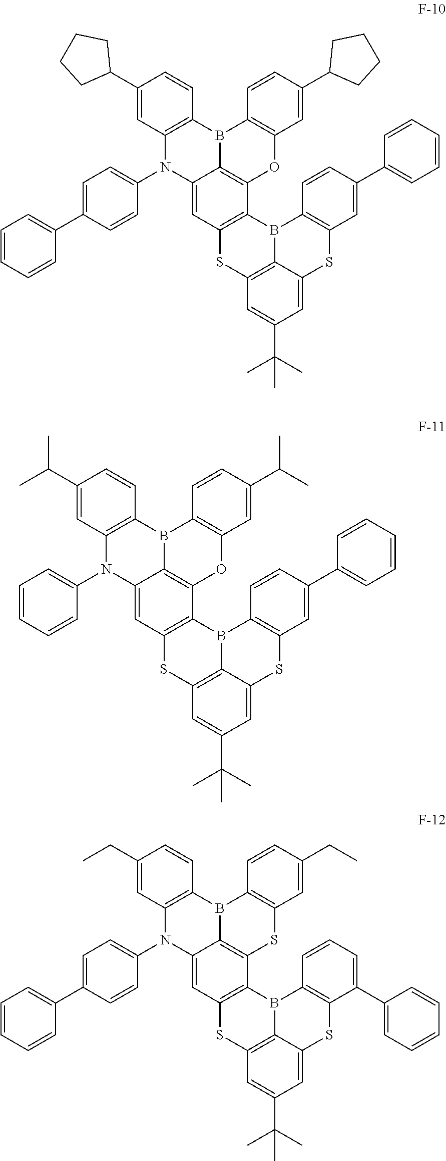 [SMILES: CC(C)(C)c1cc2c3c(c1)Sc1cc4c5c(c1B3c1ccc(-c3ccccc3)cc1S2)Oc1cc(C2CCCC2)ccc1B5c1ccc(C2CCCC2)cc1N4c1ccc(-c2ccccc2)cc1 ; CC(C)c1ccc2c(c1)Oc1c3c(cc4c1B2c1ccc(C(C)C)cc1N4c1ccccc1)Sc1cc(C(C)(C)C)cc2c1B3c1ccc(-c3ccccc3)cc1S2 ; CCc1ccc2c(c1)Sc1c3c(cc4c1B2c1ccc(CC)cc1N4c1ccc(-c2ccccc2)cc1)Sc1cc(C(C)(C)C)cc2c1B3c1cccc(-c3ccccc3)c1S2] 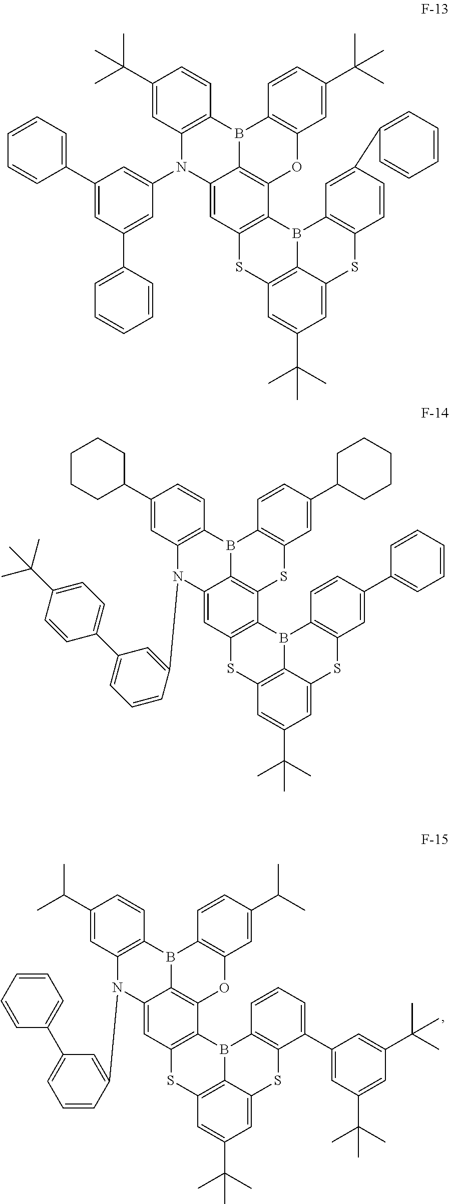 [SMILES: CC(C)(C)c1ccc2c(c1)Oc1c3c(cc4c1B2c1ccc(C(C)(C)C)cc1N4c1cc(-c2ccccc2)cc(-c2ccccc2)c1)Sc1cc(C(C)(C)C)cc2c1B3c1cc(-c3ccccc3)ccc1S2 ; CC(C)(C)c1ccc(-c2cccc(N3c4cc(C5CCCCC5)ccc4B4c5ccc(C6CCCCC6)cc5Sc5c6c(cc3c54)Sc3cc(C(C)(C)C)cc4c3B6c3ccc(-c5ccccc5)cc3S4)c2)cc1 ; CC(C)c1ccc2c(c1)Oc1c3c(cc4c1B2c1ccc(C(C)C)cc1N4c1cccc(-c2ccccc2)c1)Sc1cc(C(C)(C)C)cc2c1B3c1cccc(-c3cc(C(C)(C)C)cc(C(C)(C)C)c3)c1S2]
in Compound Group 1, D is a deuterium atom.

10. A fused polycyclic compound represented by Formula 1: 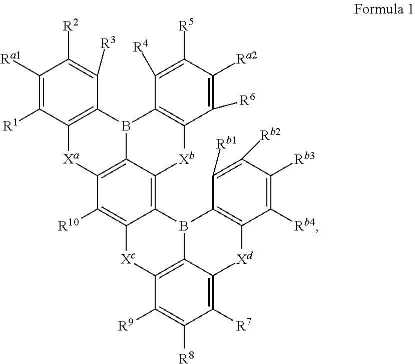
wherein, in Formula 1,
X^{a} to X^{d} are each independently O, S, or NR^{X},
R^{X} is a hydrogen atom, a deuterium atom, a halogen atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 30 ring-forming carbon atoms, or is represented by Formula x,
R^{a1} and R^{a2} are each independently a substituted or unsubstituted alkyl group of 1 to 20 carbon atoms, or a substituted or unsubstituted cycloalkyl group of 3 to 30 ring-forming carbon atoms,
R¹ to R¹⁰ and R^{b1} to R^{b4} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
at least one selected from among R^{b1} to R^{b4} is a substituted or unsubstituted aryl group of 6 to 30 ring-forming carbon atoms: 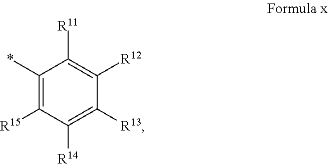
and
wherein, in Formula x,
R¹¹ to R¹⁵ are each independently a hydrogen atom, a deuterium atom, a halogen atom, a substituted or unsubstituted alkyl group of 1 to 20 carbon atoms, a substituted or unsubstituted cycloalkyl group of 3 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring.

11. The fused polycyclic compound of claim 10, wherein the fused polycyclic compound represented by Formula 1 is represented by any one selected from among Formula 1-1 to Formula 1-5: 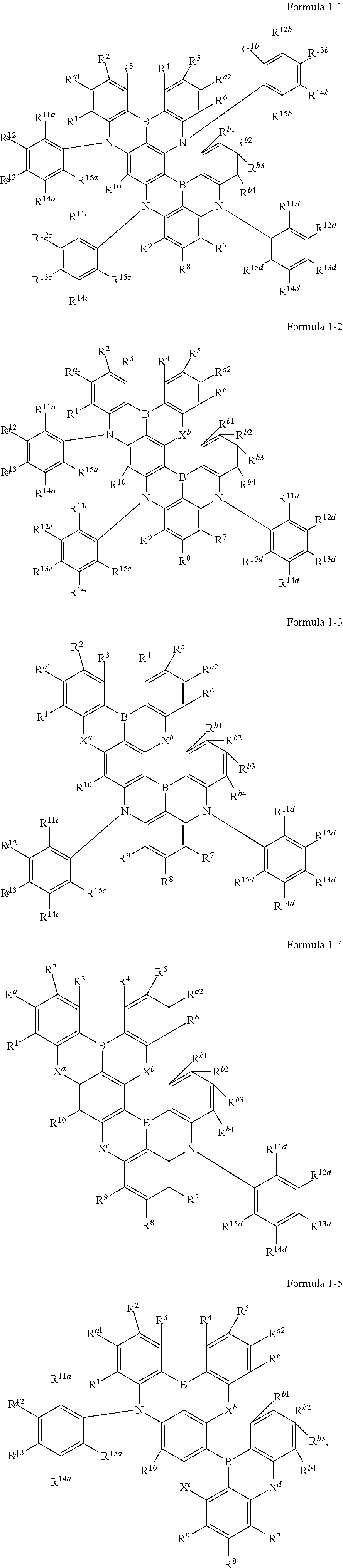
in Formula 1-1 to Formula 1-5,
R^{11a} to R^{15a}, R^{11b} to R^{15b}, R^{11c} to R^{15c}, and R^{11d} to R^{15d} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring, and
X^{a} to X^{d} and R¹ to R¹⁰ are the same as defined in Formula 1.

12. The fused polycyclic compound of claim 10, wherein, in Formula 1, at least one among R^{b1} to R^{b4} is represented by Formula b: 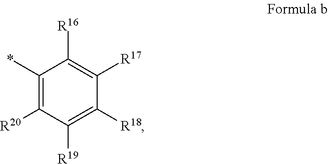
in Formula b,
R¹⁶ to R²⁰ are each independently a hydrogen atom, a deuterium atom, a halogen atom, a cyano group, a substituted or unsubstituted thio group, a substituted or unsubstituted oxy group of 1 to 20 carbon atoms, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring.

13. The fused polycyclic compound of claim 10, wherein, in Formula 1, R^{a1} and R^{a2} are each independently a substituted or unsubstituted methyl group, a substituted or unsubstituted ethyl group, a substituted or unsubstituted propyl group, a substituted or unsubstituted isopropyl group, a substituted or unsubstituted isobutyl group, a substituted or unsubstituted t-butyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted cycloheptyl group, a substituted or unsubstituted bicyclopentyl group, a substituted or unsubstituted norbornyl group, or a substituted or unsubstituted adamantyl group.

14. The fused polycyclic compound of claim 10, wherein, in Formula 1, R⁸ is a substituted or unsubstituted alkyl group of 1 to 20 carbon atoms, or a substituted or unsubstituted aryl group of 6 to 30 ring-forming carbon atoms.

15. The fused polycyclic compound of claim 10, wherein at least one hydrogen atom of the compound represented by Formula 1 is substituted with a deuterium atom.

16. The fused polycyclic compound of claim 10, wherein the fused polycyclic compound is represented by any one selected from among the compounds in Compound Group 1: 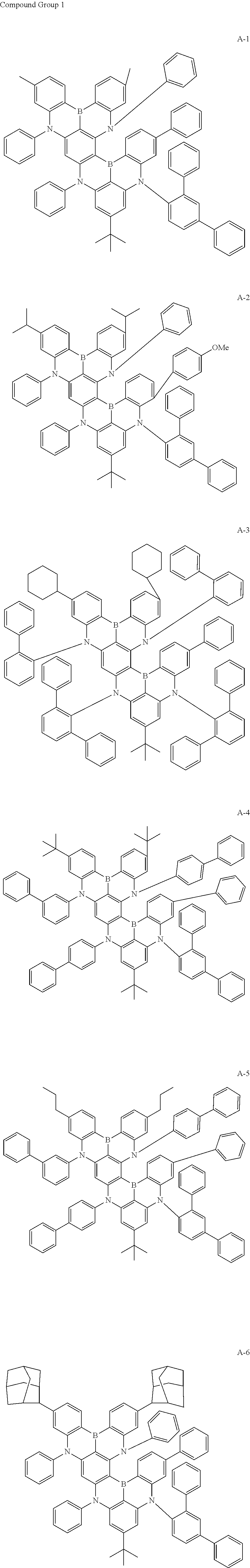 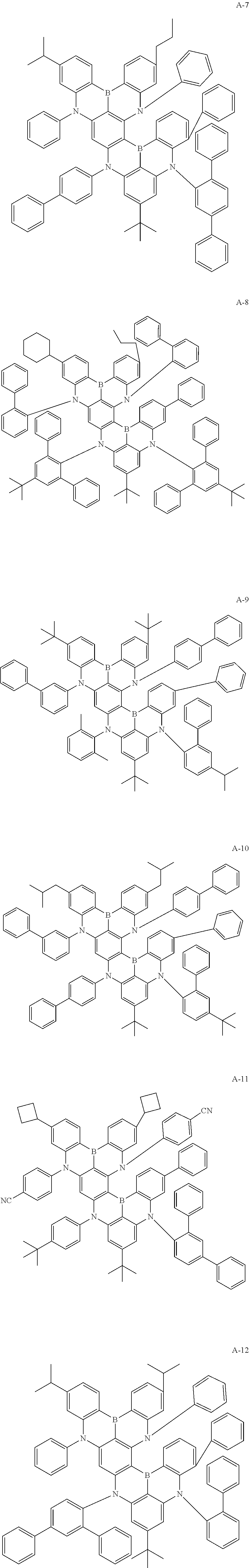 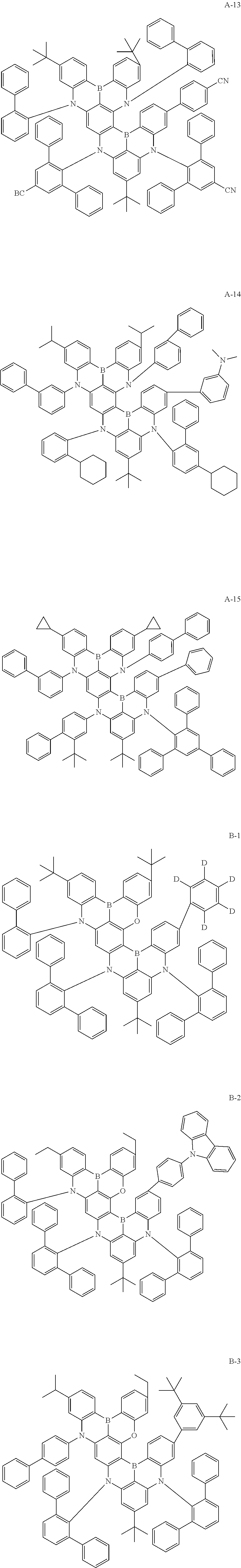 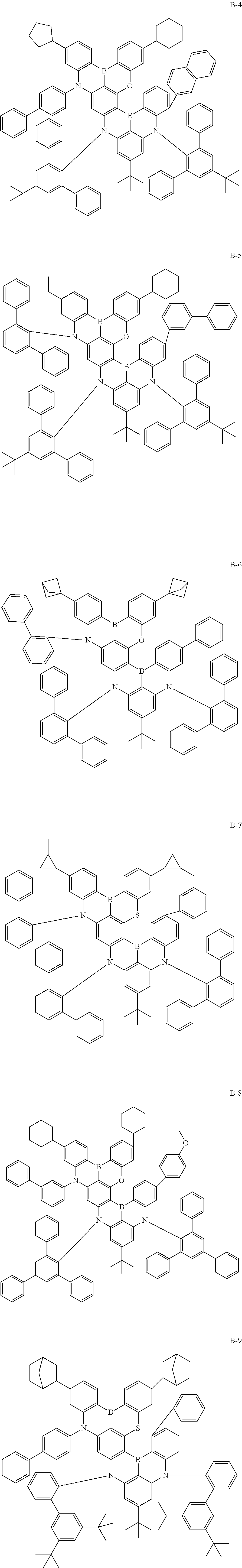 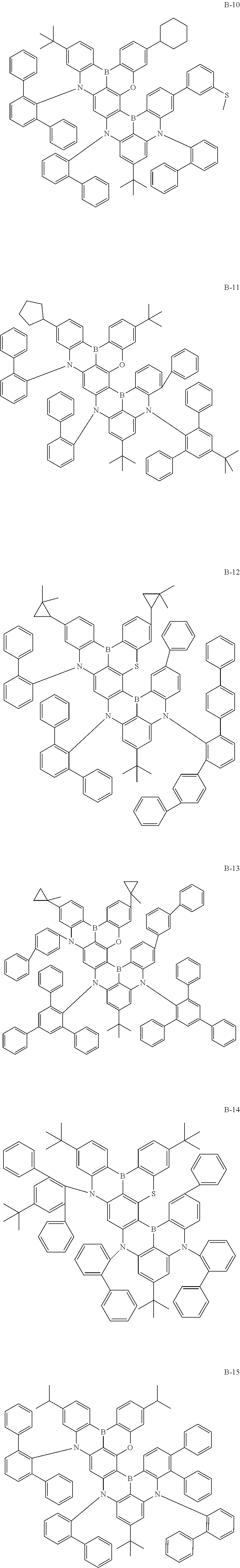 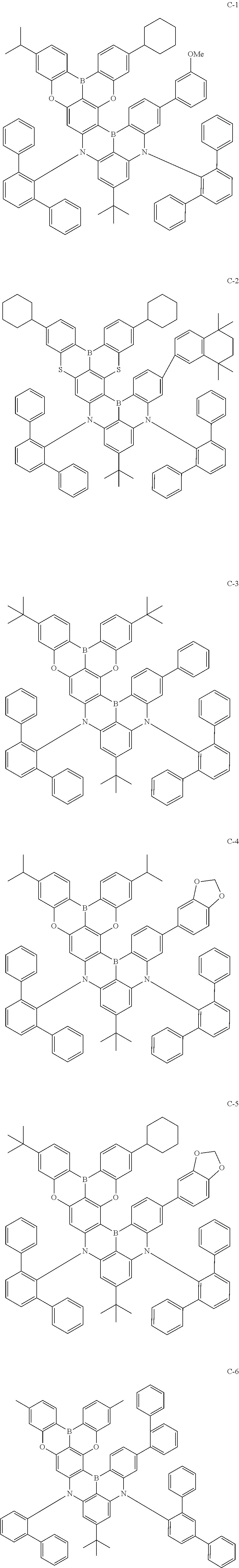 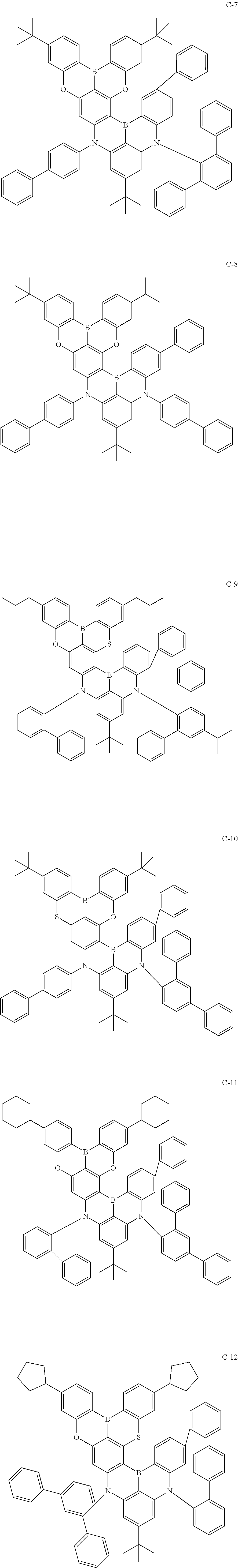 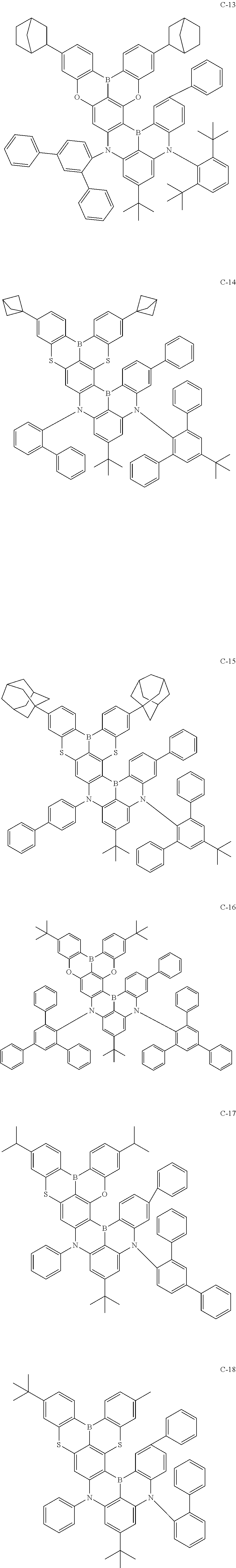 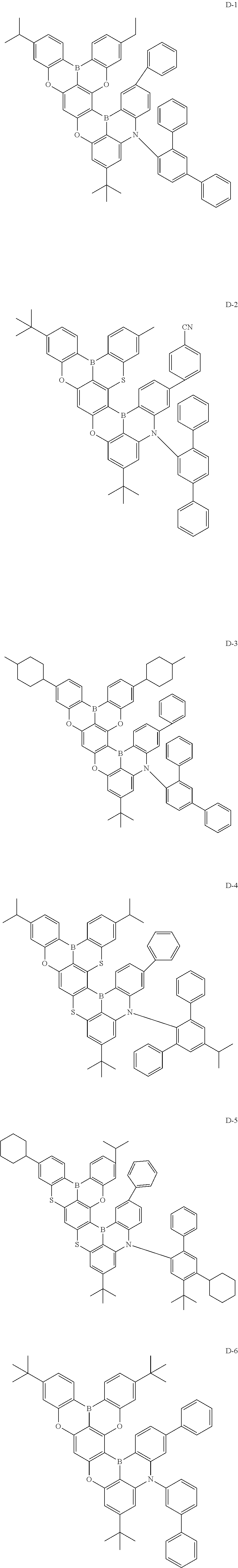 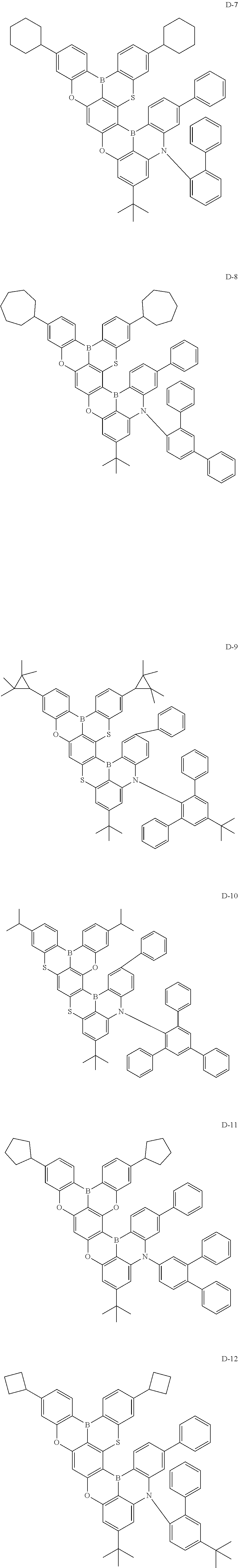 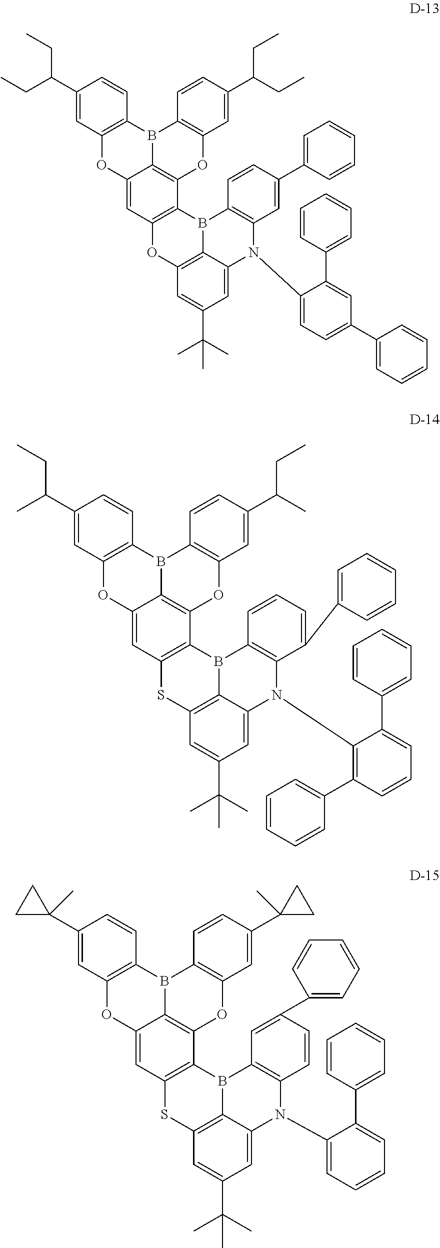 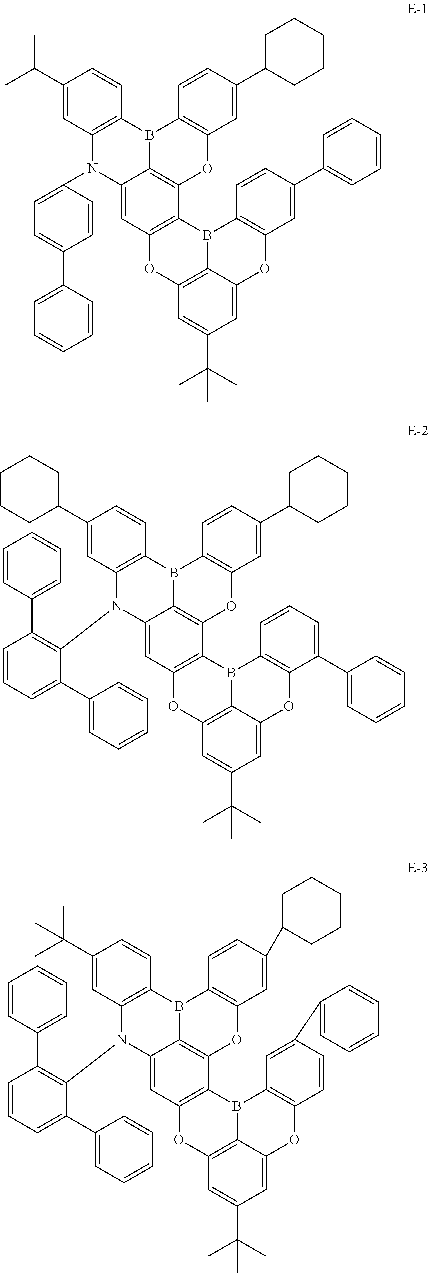 [SMILES: CC(C)c1ccc2c(c1)N(c1ccc(-c3ccccc3)cc1)c1cc3c(c4c1B2c1ccc(C2CCCCC2)cc1O4)B1c2ccc(-c4ccccc4)cc2Oc2cc(C(C)(C)C)cc(c21)O3 ; CC(C)(C)c1cc2c3c(c1)Oc1c(cccc1-c1ccccc1)B3c1c(cc3c4c1Oc1cc(C5CCCCC5)ccc1B4c1ccc(C4CCCCC4)cc1N3c1c(-c3ccccc3)cccc1-c1ccccc1)O2 ; CC(C)(C)c1cc2c3c(c1)Oc1cc4c5c(c1B3c1cc(-c3ccccc3)ccc1O2)Oc1cc(C2CCCCC2)ccc1B5c1ccc(C(C)(C)C)cc1N4c1c(-c2ccccc2)cccc1-c1ccccc1] 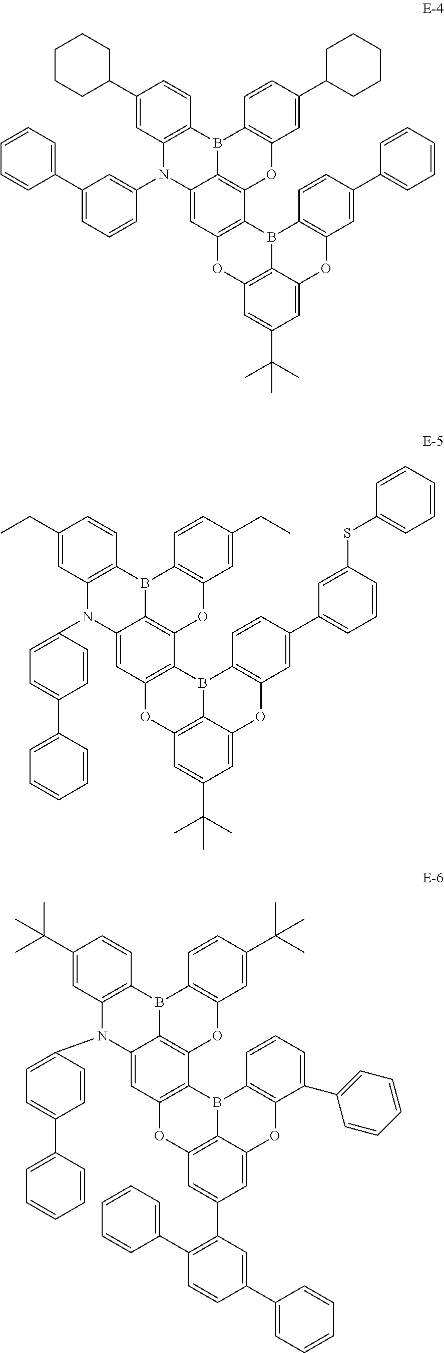 [SMILES: CC(C)(C)c1cc2c3c(c1)Oc1cc4c5c(c1B3c1ccc(-c3ccccc3)cc1O2)Oc1cc(C2CCCCC2)ccc1B5c1ccc(C2CCCCC2)cc1N4c1cccc(-c2ccccc2)c1 ; CCc1ccc2c(c1)Oc1c3c(cc4c1B2c1ccc(CC)cc1N4c1ccc(-c2ccccc2)cc1)Oc1cc(C(C)(C)C)cc2c1B3c1ccc(-c3cccc(Sc4ccccc4)c3)cc1O2 ; CC(C)(C)c1ccc2c(c1)Oc1c3c(cc4c1B2c1ccc(C(C)(C)C)cc1N4c1ccc(-c2ccccc2)cc1)Oc1cc(-c2cc(-c4ccccc4)ccc2-c2ccccc2)cc2c1B3c1cccc(-c3ccccc3)c1O2] 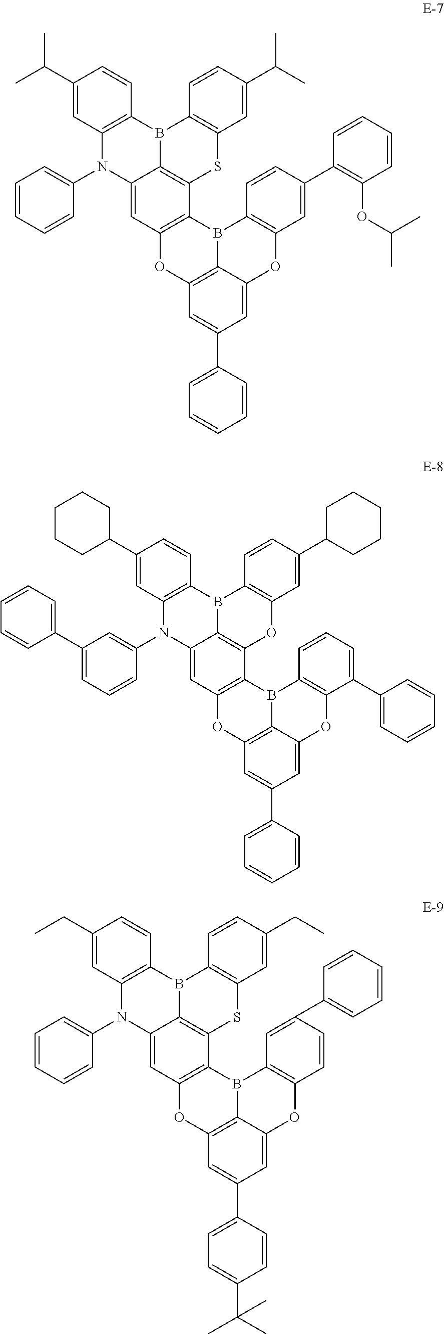 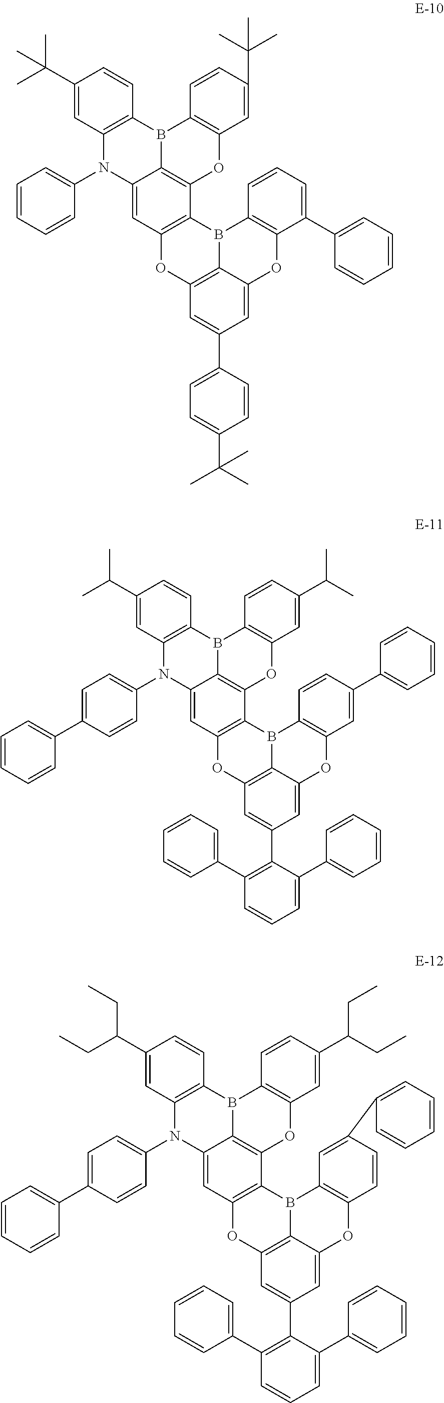 [SMILES: CC(C)(C)c1ccc(-c2cc3c4c(c2)Oc2c(cccc2-c2ccccc2)B4c2c(cc4c5c2Oc2cc(C(C)(C)C)ccc2B5c2ccc(C(C)(C)C)cc2N4c2ccccc2)O3)cc1 ; CC(C)c1ccc2c(c1)Oc1c3c(cc4c1B2c1ccc(C(C)C)cc1N4c1ccc(-c2ccccc2)cc1)Oc1cc(-c2c(-c4ccccc4)cccc2-c2ccccc2)cc2c1B3c1ccc(-c3ccccc3)cc1O2 ; CCC(CC)c1ccc2c(c1)Oc1c3c(cc4c1B2c1ccc(C(CC)CC)cc1N4c1ccc(-c2ccccc2)cc1)Oc1cc(-c2c(-c4ccccc4)cccc2-c2ccccc2)cc2c1B3c1cc(-c3ccccc3)ccc1O2] 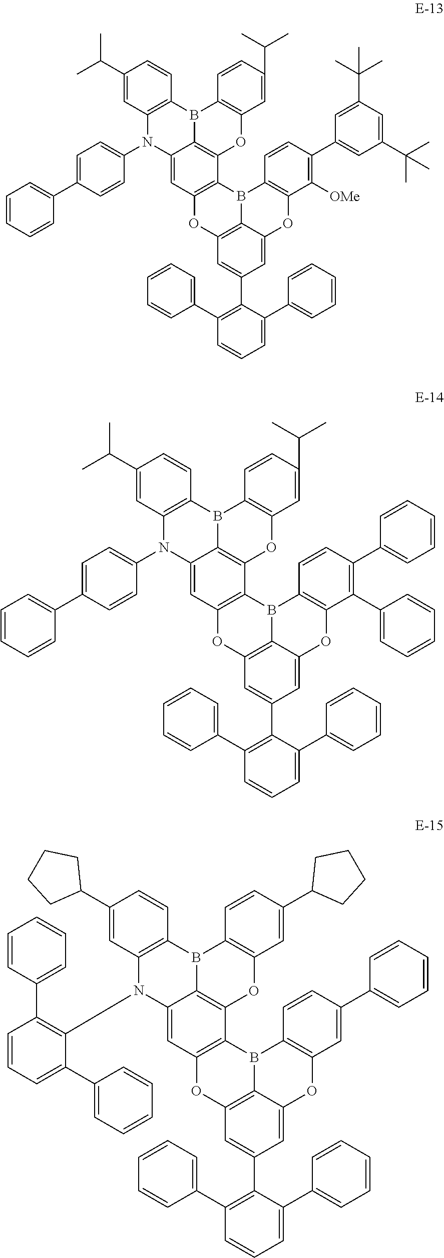 [SMILES: COc1c(-c2cc(C(C)(C)C)cc(C(C)(C)C)c2)ccc2c1Oc1cc(-c3c(-c4ccccc4)cccc3-c3ccccc3)cc3c1B2c1c(cc2c4c1Oc1cc(C(C)C)ccc1B4c1ccc(C(C)C)cc1N2c1ccc(-c2ccccc2)cc1)O3 ; CC(C)c1ccc2c(c1)Oc1c3c(cc4c1B2c1ccc(C(C)C)cc1N4c1ccc(-c2ccccc2)cc1)Oc1cc(-c2c(-c4ccccc4)cccc2-c2ccccc2)cc2c1B3c1ccc(-c3ccccc3)c(-c3ccccc3)c1O2 ; c1ccc(-c2ccc3c(c2)Oc2cc(-c4c(-c5ccccc5)cccc4-c4ccccc4)cc4c2B3c2c(cc3c5c2Oc2cc(C6CCCC6)ccc2B5c2ccc(C5CCCC5)cc2N3c2c(-c3ccccc3)cccc2-c2ccccc2)O4)cc1] 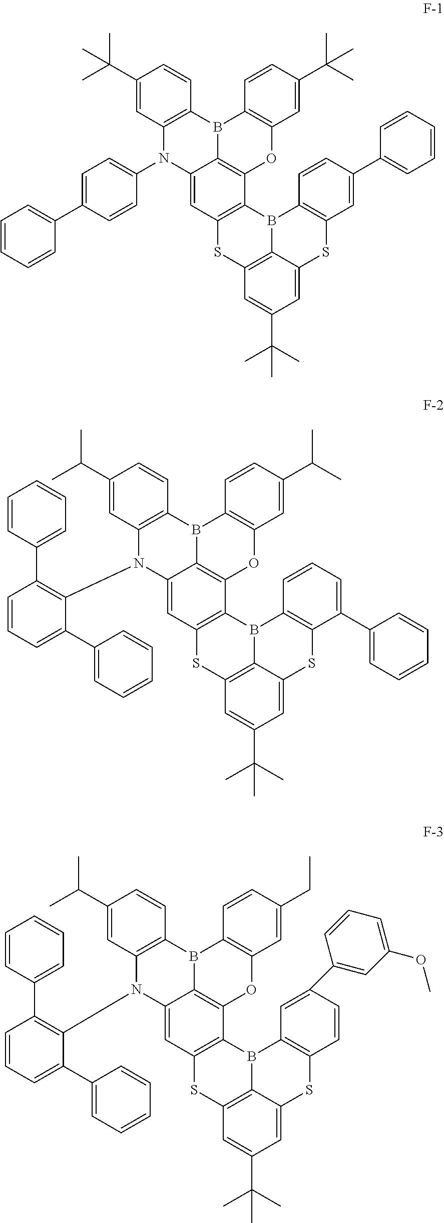 [SMILES: CC(C)(C)c1ccc2c(c1)Oc1c3c(cc4c1B2c1ccc(C(C)(C)C)cc1N4c1ccc(-c2ccccc2)cc1)Sc1cc(C(C)(C)C)cc2c1B3c1ccc(-c3ccccc3)cc1S2 ; CC(C)c1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cccc(-c3ccccc3)c1S2 ; CCc1ccc2c(c1)Oc1c3c(cc4c1B2c1ccc(C(C)C)cc1N4c1c(-c2ccccc2)cccc1-c1ccccc1)Sc1cc(C(C)(C)C)cc2c1B3c1cc(-c3cccc(OC)c3)ccc1S2] 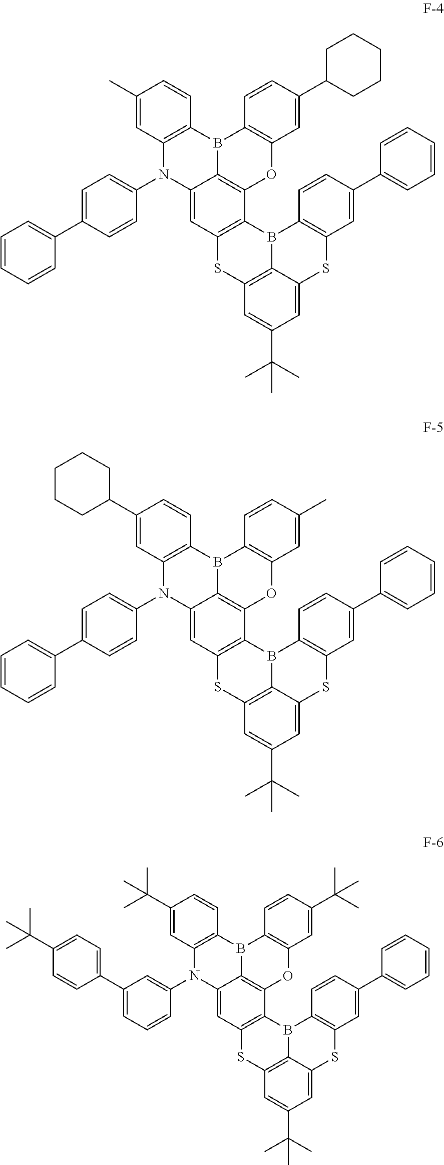 [SMILES: Cc1ccc2c(c1)N(c1ccc(-c3ccccc3)cc1)c1cc3c(c4c1B2c1ccc(C2CCCCC2)cc1O4)B1c2ccc(-c4ccccc4)cc2Sc2cc(C(C)(C)C)cc(c21)S3 ; Cc1ccc2c(c1)Oc1c3c(cc4c1B2c1ccc(C2CCCCC2)cc1N4c1ccc(-c2ccccc2)cc1)Sc1cc(C(C)(C)C)cc2c1B3c1ccc(-c3ccccc3)cc1S2 ; CC(C)(C)c1ccc(-c2cccc(N3c4cc(C(C)(C)C)ccc4B4c5ccc(C(C)(C)C)cc5Oc5c6c(cc3c54)Sc3cc(C(C)(C)C)cc4c3B6c3ccc(-c5ccccc5)cc3S4)c2)cc1] 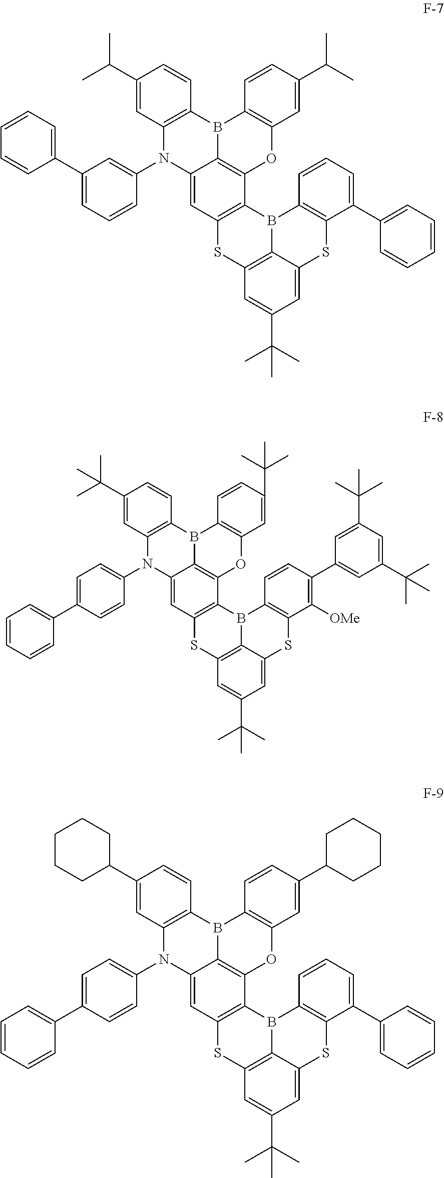 [SMILES: CC(C)c1ccc2c(c1)Oc1c3c(cc4c1B2c1ccc(C(C)C)cc1N4c1cccc(-c2ccccc2)c1)Sc1cc(C(C)(C)C)cc2c1B3c1cccc(-c3ccccc3)c1S2 ; COc1c(-c2cc(C(C)(C)C)cc(C(C)(C)C)c2)ccc2c1Sc1cc(C(C)(C)C)cc3c1B2c1c(cc2c4c1Oc1cc(C(C)(C)C)ccc1B4c1ccc(C(C)(C)C)cc1N2c1ccc(-c2ccccc2)cc1)S3 ; CC(C)(C)c1cc2c3c(c1)Sc1c(cccc1-c1ccccc1)B3c1c(cc3c4c1Oc1cc(C5CCCCC5)ccc1B4c1ccc(C4CCCCC4)cc1N3c1ccc(-c3ccccc3)cc1)S2] 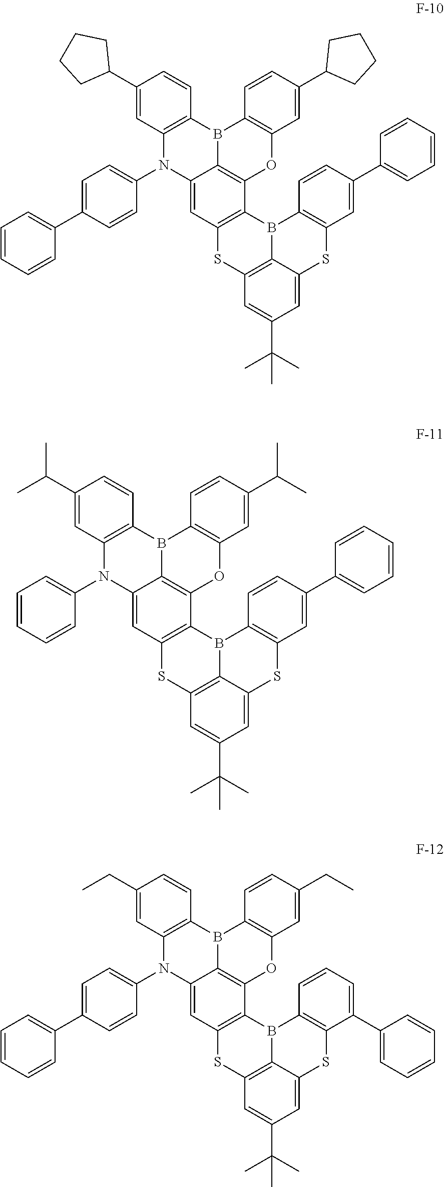 [SMILES: CC(C)(C)c1cc2c3c(c1)Sc1cc4c5c(c1B3c1ccc(-c3ccccc3)cc1S2)Oc1cc(C2CCCC2)ccc1B5c1ccc(C2CCCC2)cc1N4c1ccc(-c2ccccc2)cc1 ; CC(C)c1ccc2c(c1)Oc1c3c(cc4c1B2c1ccc(C(C)C)cc1N4c1ccccc1)Sc1cc(C(C)(C)C)cc2c1B3c1ccc(-c3ccccc3)cc1S2 ; CCc1ccc2c(c1)Oc1c3c(cc4c1B2c1ccc(CC)cc1N4c1ccc(-c2ccccc2)cc1)Sc1cc(C(C)(C)C)cc2c1B3c1cccc(-c3ccccc3)c1S2] 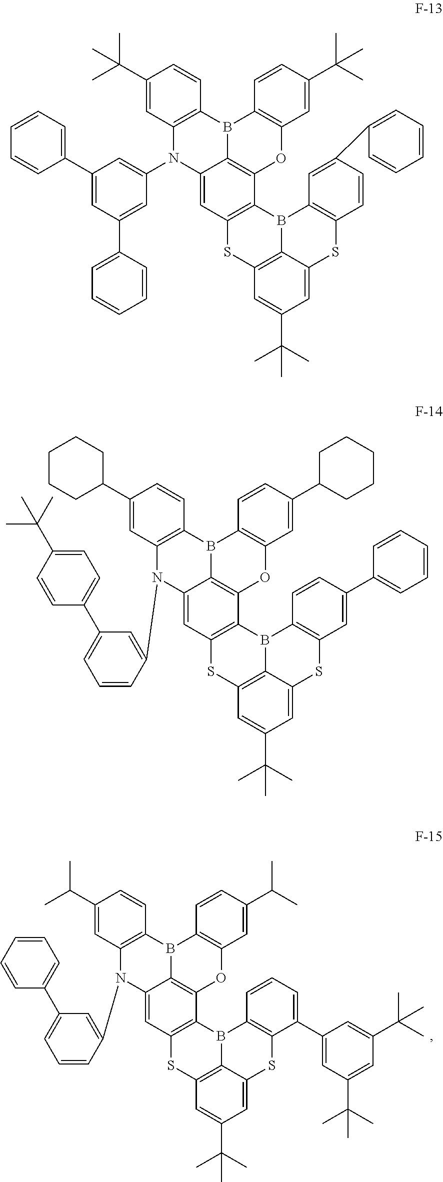 [SMILES: CC(C)(C)c1ccc2c(c1)Oc1c3c(cc4c1B2c1ccc(C(C)(C)C)cc1N4c1cc(-c2ccccc2)cc(-c2ccccc2)c1)Sc1cc(C(C)(C)C)cc2c1B3c1cc(-c3ccccc3)ccc1S2 ; CC(C)(C)c1ccc(-c2cccc(N3c4cc(C5CCCCC5)ccc4B4c5ccc(C6CCCCC6)cc5Oc5c6c(cc3c54)Sc3cc(C(C)(C)C)cc4c3B6c3ccc(-c5ccccc5)cc3S4)c2)cc1 ; CC(C)c1ccc2c(c1)Oc1c3c(cc4c1B2c1ccc(C(C)C)cc1N4c1cccc(-c2ccccc2)c1)Sc1cc(C(C)(C)C)cc2c1B3c1cccc(-c3cc(C(C)(C)C)cc(C(C)(C)C)c3)c1S2]
in Compound Group 1, D is a deuterium atom.

17. An electronic apparatus comprising a display module, the display module comprising a plurality of light emitting elements,
wherein at least one of the plurality of light emitting elements comprises a first electrode, a second electrode on the first electrode, and an emission layer between the first electrode and the second electrode, and comprising a fused polycyclic compound represented by Formula 1: 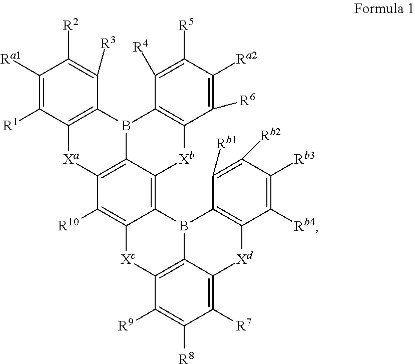
wherein, in Formula 1,
X^{a} to X^{d} are each independently O, S, or NR^{X},
R^{X} is a hydrogen atom, a deuterium atom, a halogen atom, a substituted or unsubstituted alkyl group of 1 to 20 carbon atoms, a substituted or unsubstituted aryl group of 6 to 60 ring-forming carbon atoms, or a substituted or unsubstituted heteroaryl group of 2 to 30 ring-forming carbon atoms, or is represented by Formula x,
R^{a1} and R^{a2} are each independently a substituted or unsubstituted alkyl group of 1 to 20 carbon atoms, or a substituted or unsubstituted cycloalkyl group of 3 to 30 ring-forming carbon atoms,
R¹ to R¹⁰ and R^{b1} to R^{b4} are each independently a hydrogen atom, a deuterium atom, a halogen atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, and
at least one selected from among R^{b1} to R^{b4} is a substituted or unsubstituted aryl group of 6 to 30 ring-forming carbon atoms: 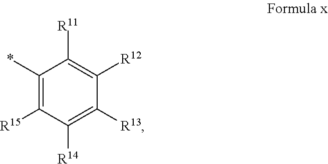
and
wherein, in Formula x,
R¹¹ to R¹⁵ are each independently a hydrogen atom, a deuterium atom, a halogen atom, a substituted or unsubstituted alkyl group of 1 to 20 carbon atoms, a substituted or unsubstituted cycloalkyl group of 3 to 30 ring-forming carbon atoms, a substituted or unsubstituted aryl group of 6 to 30 ring-forming carbon atoms, or a substituted or unsubstituted heteroaryl group of 2 to 30 ring-forming carbon atoms, and/or are combined with an adjacent group from each other to form a ring.

18. The electronic apparatus of claim 17,
wherein the electronic apparatus comprises a plurality of display devices each controlled independently and configured to display an image, and
at least one of the display devices comprises the display module.

19. The electronic apparatus of claim 17, further comprising at least one of a processor, a memory, or a power module.

20. The electronic apparatus of claim 17, wherein the electronic apparatus is at least one of a television, a monitor, an outdoor billboard, a personal computer, a laptop computer, a personal digital assistant, a vehicle device, a game console, a smartphone, a tablet computer, a smartwatch, a head-mounted display, or a camera.
